(19) United States
(12) Patent Application Publication
(10) Pub. No.: US 2026/0304955 A1
(43) Pub. Date: Oct. 1, 2026

(54) SEMICONDUCTOR DEVICE, DRIVER CIRCUIT, AND DISPLAY APPARATUS

(71) Applicant: SEMICONDUCTOR ENERGY LABORATORY CO., LTD., Atsugi-shi, Kanagawa-ken (JP)

(72) Inventors: Susumu KAWASHIMA, Atsugi, Kanagawa (JP); Minato ITO, Atsugi, Kanagawa (JP); Hajime KIMURA, Atsugi, Kanagawa (JP); Tatsunori INOUE, Yamato, Kanagawa (JP)

(21) Appl. No.: 19/477,588

(22) PCT Filed: Apr. 23, 2024
(86) PCT No.: PCT/IB2024/053924

§ 371 Date: Oct. 22, 2025

(30) Foreign Application Priority Data
May 1, 2023 (JP) 2023-075546

(51) Int. Cl. H10D 86/40; G09G 3/32; G09G 3/3225; G09G 3/3266; G09G 3/3275; H10D 86/60

(52) U.S. Cl. CPC H10D 86/441; G09G 3/32; G09G 3/3225; G09G 3/3266; G09G 3/3275; H10D 86/60; G09G 2300/0426; G09G 2310/0286; G09G 2310/0289; G09G 2330/021

(57) ABSTRACT

A semiconductor device capable of low-speed operation is provided. The semiconductor device includes first to eighth transistors and first and second capacitor elements. Gates of the first transistor and the second transistor are connected to each other. A first terminal of the first transistor is electrically connected to a first terminal of the fourth transistor and a first terminal of the fifth transistor. A first terminal of the third transistor is electrically connected to a first terminal of the second transistor, a gate of the fourth transistor, a first terminal of the first capacitor element, a gate of the seventh transistor, and a first terminal of the eighth transistor. A second terminal of the fifth transistor is electrically connected to a gate of the sixth transistor and a first terminal of the second capacitor element. A first terminal of the sixth transistor is electrically connected to a second terminal of the second capacitor element, a first terminal of the seventh transistor, and a gate of the eighth transistor.

### TECHNICAL FIELD

One embodiment of the present invention relates to a semiconductor device, a driver circuit, and a display apparatus.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus (including a liquid crystal display apparatus), a light-emitting apparatus, a power storage device, an imaging device, a memory device, a signal processing device, a sensor, a processing device (including a processor), an electronic device, a system, an operation method thereof, a manufacturing method thereof, and a testing method thereof.

### BACKGROUND ART

In recent years, display apparatuses included in, for example, electronic devices for XR (Extended Reality or Cross Reality) such as VR (virtual reality) or AR (augmented reality), mobile phones (e.g., smartphones), tablet information terminals, and laptop PCs (personal computers) have been improved in various aspects. For example, display apparatuses have been developed aiming for improvement such as a higher screen definition, higher color reproducibility (NTSC ratio), a smaller driver circuit, and lower power consumption.

Using a transistor including an oxide semiconductor in a pixel circuit, a driver circuit, or the like has attracted attention to improve display apparatuses. Examples of the oxide semiconductor include not only single-component metal oxides, such as indium oxide and zinc oxide, but also multi-component metal oxides. Among the multi-component metal oxides, in particular, an In—Ga—Zn oxide (hereinafter also referred to as IGZO) has been actively researched.

When an n-channel transistor is manufactured using an In—Ga—Zn oxide as an active layer, the off-state current of the transistor can be extremely low (see Non-Patent Document 1). LSI (Large Scale Integration) and a display apparatus utilizing such characteristics are reported in Non-Patent Document 2 and Non-Patent Document 3.

Meanwhile, it is difficult to manufacture a p-channel transistor using an oxide semiconductor as an active layer in terms of mobility and reliability. Thus, a circuit including a transistor using an oxide semiconductor as an active layer is generally an n-channel single-polarity circuit (a circuit including only n-channel transistors). Patent Document 1 discloses an invention of a single-polarity driver circuit using an n-channel transistor using an oxide semiconductor as an active layer.

### REFERENCES

### Patent Document

[Patent Document 1] Japanese Published Patent Application No. 2022-176166

### Non-Patent Documents

[Non-Patent Document 1]K. Kato et al., “Japanese Journal of Applied Physics”, 2012, volume 51, p. 021201-1-021201-7
[Non-Patent Document 2]S. Matsuda et al., “2015 Symposium on VLSI Technology Digest of Technical Papers”, 2015, p. T216-T217
[Non-Patent Document 3]S. Amano et al., “SID Symposium Digest of Technical Papers”, 2010, volume 41, issue 1, p. 626-629

### SUMMARY OF THE INVENTION

### Problems to be Solved by the Invention

In general, by driving a driver circuit such as a source driver circuit or a gate driver circuit provided in a display apparatus, an image can be displayed on a display portion of the display apparatus. The driver circuit is provided with a shift register to transmit a predetermined signal to each row or each column.

The shift register has a structure in which retention circuits are continuously connected and a signal input to a retention circuit is transmitted to an adjacent retention circuit sequentially. When an operation malfunction occurs in one of the plurality of retention circuits, a defect such as missing or distortion may appear in a waveform of an output signal from the retention circuit. When a defect appears in the waveform of the signal output from the retention circuit, the signal is input to the retention circuits in the next and subsequent stages, and the effect spreads throughout the entire shift register. Thus, the defect such as missing or distortion may appear also in the waveform of a signal output from the shift register.

In particular, when a retention circuit included in a shift register is a single-polarity circuit (not a CMOS circuit including an n-channel transistor and a p-channel transistor, but a circuit including only one of an n-channel transistor and a p-channel transistor), the shift register might output a faulty signal at low-speed driving.

In recent years, with downsizing of display apparatuses, transistors tend to be reduced in size in order to reduce the circuit area of driver circuits; a shorter channel length of a transistor is prone to cause a shift register to output a large number of faulty signals as described above.

An object of one embodiment of the present invention is to provide a semiconductor device capable of being driven at low speed. Another object of one embodiment of the present invention is to provide a semiconductor device capable of stabilizing an output signal. Another object of one embodiment of the present invention is to provide a semiconductor device with a reduced circuit area. Another object of one embodiment of the present invention is to provide a semiconductor device with a reduced malfunction. Another object of one embodiment of the present invention is to provide a driver circuit including the above semiconductor device. Another object of one embodiment of the present invention is to provide a display apparatus including the above driver circuit. Another object of one embodiment of the present invention is to provide a novel semiconductor device, a novel driver circuit, or a novel display apparatus.

Note that the objects of one embodiment of the present invention are not limited to the above objects. The above objects do not preclude the presence of other objects. Note that the other objects are objects that are not described in this section and are described below. The objects that are not described in this section will be derived from the description of the specification, the drawings, and the like and can be extracted as appropriate from the description by those skilled in the art. Note that one embodiment of the present invention is to achieve at least one of the above objects and the other objects and does not necessarily achieve all of the above objects and the other objects.

### Means for Solving the Problems

A cause of the above-described defect that appears in a signal output from a retention circuit of a shift register is probably an unintentional change in the potential of a retention node that retains data of a signal in the retention circuit during operation of the shift register. Thus, in one embodiment of the present invention, the retention circuit is configured to prevent an unintentional change in the potential of the retention node during operation of the shift register.

Examples of a semiconductor device (a retention circuit), a driver circuit, and a display apparatus for solving the above problems are described below.

(1)

One embodiment of the present invention is a semiconductor device including a first transistor, a second transistor, a third transistor, a fourth transistor, a fifth transistor, a sixth transistor, a seventh transistor, an eighth transistor, a first capacitor element, and a second capacitor element.

A gate of the first transistor is electrically connected to a gate of the second transistor, and one of a source and a drain of the first transistor is electrically connected to one of a source and a drain of the fourth transistor and one of a source and a drain of the fifth transistor. One of a source and a drain of the third transistor is electrically connected to one of a source and a drain of the second transistor, a gate of the fourth transistor, a first terminal of the first capacitor element, a gate of the seventh transistor, and one of a source and a drain of the eighth transistor. The other of the source and the drain of the fifth transistor is electrically connected to a gate of the sixth transistor and a first terminal of the second capacitor element. One of a source and a drain of the sixth transistor is electrically connected to a second terminal of the second capacitor element, one of a source and a drain of the seventh transistor, and a gate of the eighth transistor.

(2)

Another embodiment of the present invention is a semiconductor device that has a structure different from the above structure (1) and includes a first transistor, a second transistor, a third transistor, a fourth transistor, a fifth transistor, a sixth transistor, a seventh transistor, an eighth transistor, a first capacitor element, and a second capacitor element.

A gate of the first transistor is electrically connected to a gate of the second transistor, and one of a source and a drain of the first transistor is electrically connected to one of a source and a drain of the fourth transistor and one of a source and a drain of the fifth transistor. One of a source and a drain of the third transistor is electrically connected to one of a source and a drain of the second transistor, a gate of the fourth transistor, a first terminal of the first capacitor element, a gate of the seventh transistor, and one of a source and a drain of the eighth transistor. The other of the source and the drain of the fifth transistor is electrically connected to a gate of the sixth transistor, a first terminal of the second capacitor element, and a gate of the eighth transistor. One of a source and a drain of the sixth transistor is electrically connected to a second terminal of the second capacitor element and one of a source and a drain of the seventh transistor.

(3)

Another embodiment of the present invention is a semiconductor device that has a structure different from the above structures (1) and (2) and includes a first transistor, a second transistor, a third transistor, a fourth transistor, a fifth transistor, a sixth transistor, a seventh transistor, an eighth transistor, a first capacitor element, and a second capacitor element.

A gate of the first transistor is electrically connected to a gate of the second transistor, one of a source and a drain of the first transistor is electrically connected to one of a source and a drain of the fourth transistor, one of a source and a drain of the fifth transistor, and a gate of the eighth transistor. One of a source and a drain of the third transistor is electrically connected to one of a source and a drain of the second transistor, a gate of the fourth transistor, a first terminal of the first capacitor element, a gate of the seventh transistor, and one of a source and a drain of the eighth transistor. The other of the source and the drain of the fifth transistor is electrically connected to a gate of the sixth transistor and a first terminal of the second capacitor element. One of a source and a drain of the sixth transistor is electrically connected to a second terminal of the second capacitor element and one of a source and a drain of the seventh transistor.

(4)

Another embodiment of the present invention may include a ninth transistor, a tenth transistor, an eleventh transistor, and a third capacitor element in any one of the above structures (1) to (3).

In particular, one of a source and a drain of the ninth transistor is preferably electrically connected to the one of the source and the drain of the first transistor, the one of the source and the drain of the fourth transistor, and the one of the source and the drain of the fifth transistor, and the other of the source and the drain of the ninth transistor is preferably electrically connected to a gate of the tenth transistor and a first terminal of the third capacitor element. One of a source and a drain of the tenth transistor is preferably electrically connected to a second terminal of the third capacitor element and one of a source and a drain of the eleventh transistor. A gate of the eleventh transistor is preferably electrically connected to the one of the source and the drain of the third transistor, the one of the source and the drain of the second transistor, the gate of the fourth transistor, the first terminal of the first capacitor element, and the gate of the seventh transistor.

(5)

Another embodiment of the present invention may have the above structure (4) in which each of the first transistor, the second transistor, the third transistor, the fourth transistor, the fifth transistor, the sixth transistor, the seventh transistor, the eighth transistor, the ninth transistor, the tenth transistor, and the eleventh transistor is a vertical-channel-type transistor. In particular, the vertical-channel-type transistor preferably includes one or more selected from indium, zinc, and an element Min a channel formation region.

Note that the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

(6)

Another embodiment of the present invention is a driver circuit including a first semiconductor device and a second semiconductor device, each of which is the above semiconductor device according to (5). The first semiconductor device includes a first output terminal, and the second semiconductor device includes an input terminal. The first output terminal is electrically connected to the one of the source and the drain of the tenth transistor of the first semiconductor device. The input terminal is electrically connected to the gate of the first transistor and the gate of the second transistor of the second semiconductor device. The first output terminal is electrically connected to the input terminal.

(7)

Another embodiment of the present invention is a display apparatus including the above driver circuit according to (6) and a pixel circuit. The first semiconductor device includes a second output terminal, and the second output terminal is electrically connected to the one of the source and the drain of the sixth transistor. The driver circuit has a function of transmitting a signal output from the second output terminal of the first semiconductor device to the pixel circuit.

(8)

Another embodiment of the present invention is a display apparatus including the above driver circuit according to (6), a pixel circuit, and a sensor portion. The first semiconductor device includes a second output terminal, and the second output terminal is electrically connected to the one of the source and the drain of the sixth transistor. The driver circuit has a function of transmitting a signal output from the second output terminal of the first semiconductor device to the sensor portion. The sensor portion includes a region overlapping with the pixel circuit.

### Effect of the Invention

The use of the structure of any of the above semiconductor devices for a retention circuit included in a shift register enables an output signal of the retention circuit to be fed back to a retention node side. When the retention node side receives the feedback of the output signal, a fixed potential from a power supply line or the like is supplied to the retention node, for example, so that the retention node is not brought into a floating state. This can suppress a change in the potential of the retention node, whereby the output signal of the retention circuit can be stable. Note that the fixed potential is preferably equal to a potential corresponding to information retained in the retention circuit.

One embodiment of the present invention can provide a semiconductor device capable of being driven at low speed. Another embodiment of the present invention can provide a semiconductor device capable of stabilizing an output signal. Another embodiment of the present invention can provide a semiconductor device with a reduced circuit area. Another embodiment of the present invention can provide a semiconductor device with a reduced malfunction. Another embodiment of the present invention can provide a driver circuit including the above semiconductor device. Another embodiment of the present invention can provide a display apparatus including the above driver circuit. Another embodiment of the present invention can provide a novel semiconductor device, a novel driver circuit, or a novel display apparatus.

Note that the effects of one embodiment of the present invention are not limited to the above effects. The above effects do not preclude the presence of other effects. Note that the other effects are effects that are not described in this section and are described below. The effects that are not described in this section will be derived from the description of the specification, the drawings, and the like and can be extracted as appropriate from the description by those skilled in the art. Note that one embodiment of the present invention has at least one of the above effects and the other effects. Accordingly, one embodiment of the present invention sometimes does not have the above effects depending on the case.

### BRIEF DESCRIPTION OF THE DRAWINGS

FIG. 1 is a circuit diagram illustrating a structure example of a semiconductor device.

FIG. 2A and FIG. 2B are circuit diagrams each illustrating a structure example of a circuit included in a semiconductor device.

FIG. 3 is a circuit diagram illustrating a structure example of a semiconductor device.

FIG. 4A and FIG. 4B are circuit diagrams each illustrating a structure example of a semiconductor device.

FIG. 5 is a circuit diagram illustrating a structure example of a semiconductor device.

FIG. 6A and FIG. 6B are circuit diagrams each illustrating a structure example of a semiconductor device.

FIG. 7A and FIG. 7B are circuit diagrams each illustrating a structure example of a semiconductor device.

FIG. 8A to FIG. 8F are circuit diagrams each illustrating a structure example of a circuit included in a semiconductor device.

FIG. 9 is a circuit diagram illustrating a structure example of a semiconductor device.

FIG. 10 is a circuit diagram illustrating a structure example of a semiconductor device.

FIG. 11A and FIG. 11B are circuit diagrams each illustrating a structure example of a semiconductor device.

FIG. 12 is a circuit diagram illustrating a structure example of a semiconductor device.

FIG. 13 is a circuit diagram illustrating a structure example of a semiconductor device.

FIG. 14 is a circuit diagram illustrating a structure example of a semiconductor device.

FIG. 15A and FIG. 15B are circuit diagrams each illustrating a structure example of a semiconductor device.

FIG. 16 is a circuit diagram illustrating a structure example of a semiconductor device.

FIG. 17 is a plan view illustrating a layout example of a semiconductor device.

FIG. 18 is a plan view illustrating a layout example of a semiconductor device.

FIG. 19 is a plan view illustrating a layout example of a semiconductor device.

FIG. 20 is a plan view illustrating a layout example of a semiconductor device.

FIG. 21 is a plan view illustrating a layout example of a semiconductor device.

FIG. 22 is a circuit diagram illustrating a structure example of a semiconductor device.

FIG. 23A and FIG. 23B are circuit diagrams each illustrating a structure example of a semiconductor device.

FIG. 24A and FIG. 24B are circuit diagrams each illustrating a structure example of a semiconductor device.

FIG. 25A and FIG. 25B are circuit diagrams each illustrating a structure example of a semiconductor device.

FIG. 26A and FIG. 26B are circuit diagrams each illustrating a structure example of a semiconductor device.

FIG. 27A and FIG. 27B are circuit diagrams each illustrating a structure example of a semiconductor device.

FIG. 28A and FIG. 28B are circuit diagrams each illustrating a structure example of a semiconductor device.

FIG. 29A and FIG. 29B are circuit diagrams each illustrating a structure example of a semiconductor device.

FIG. 30A and FIG. 30B are circuit diagrams each illustrating a structure example of a semiconductor device.

FIG. 31A and FIG. 31B are circuit diagrams each illustrating a structure example of a semiconductor device.

FIG. 32 is a block diagram illustrating a structure example of a display apparatus.

FIG. 33 is a block diagram illustrating a structure example of a driver circuit.

FIG. 34 is a block diagram illustrating a structure example of a driver circuit.

FIG. 35 is a timing chart showing an operation example of a driver circuit.

FIG. 36 is a circuit diagram illustrating a structure example of a semiconductor device.

FIG. 37 is a circuit diagram illustrating a structure example of a semiconductor device.

FIG. 38 is a circuit diagram illustrating a structure example of a semiconductor device.

FIG. 39 is a circuit diagram illustrating a structure example of a semiconductor device.

FIG. 40 is a circuit diagram illustrating a structure example of a semiconductor device.

FIG. 41 is a circuit diagram illustrating a structure example of a semiconductor device.

FIG. 42 is a timing chart showing an operation example of a semiconductor device.

FIG. 43 is a block diagram illustrating a structure example of a driver circuit.

FIG. 44 is a timing chart showing an operation example of a semiconductor device.

FIG. 45 is a circuit diagram illustrating a structure example of a semiconductor device.

FIG. 46 is a circuit diagram illustrating a structure example of a semiconductor device.

FIG. 47 is a circuit diagram illustrating a structure example of a semiconductor device.

FIG. 48 is a block diagram illustrating a structure example of a driver circuit.

FIG. 49 is a circuit diagram illustrating a structure example of a semiconductor device.

FIG. 50 is a circuit diagram illustrating a structure example of a semiconductor device.

FIG. 51A to FIG. 51C are schematic perspective views each illustrating a structure example of a display apparatus.

FIG. 52 is a block diagram illustrating a structure example of a display apparatus.

FIG. 53 is a schematic cross-sectional view illustrating a structure example of a display apparatus.

FIG. 54A is a schematic plan view illustrating a structure example of a transistor, and FIG. 54B and FIG. 54C are schematic cross-sectional views illustrating a structure example of the transistor.

FIG. 55A is a schematic plan view illustrating a structure example of a transistor, and FIG. 55B and FIG. 55C are schematic cross-sectional views illustrating a structure example of the transistor.

FIG. 56A to FIG. 56C are schematic cross-sectional views each illustrating a structure example of part of a display apparatus.

FIG. 57 is a schematic cross-sectional view illustrating a structure example of a display apparatus.

FIG. 58 is a schematic cross-sectional view illustrating a structure example of a display apparatus.

FIG. 59A is a schematic cross-sectional view illustrating a structure example of an LED package, and FIG. 59B and FIG. 59C are schematic plan views each illustrating a structure example of an LED package.

FIG. 60 is a schematic cross-sectional view illustrating a structure example of a display apparatus.

FIG. 61 is a schematic cross-sectional view illustrating a structure example of a display apparatus.

FIG. 62A and FIG. 62B are diagrams illustrating a structure example of a display module.

FIG. 63A to FIG. 63I are perspective views illustrating examples of electronic devices.

FIG. 64A is a schematic perspective view illustrating a structure example of a memory device, and

FIG. 64B is a block diagram illustrating a structure example of a semiconductor device.

FIG. 65 is a block diagram illustrating a structure example of a memory device.

FIG. 66A and FIG. 66B are diagrams each illustrating an example of an electronic component.

FIG. 67A and FIG. 67B are diagrams each illustrating an example of an electronic device, and FIG. 67C to FIG. 67E are diagrams illustrating an example of a large computer.

FIG. 68 is a diagram illustrating an example of space equipment.

FIG. 69 is a diagram illustrating an example of a storage system that can be used in a data center.

FIG. 70A to FIG. 701 are diagrams each showing that “A and B are connected”.

FIG. 71A to FIG. 71F are diagrams are diagrams each showing a “circuit element” in this specification.

FIG. 72 is a block diagram illustrating a structure of a shift register according to Example.

FIG. 73 is a circuit diagram illustrating a structure of a circuit included in a shift register according to Example.

FIG. 74 is a timing chart illustrating an operation of a shift register according to Example.

FIG. 75A to FIG. 75C are graphs showing waveforms of output voltages of a shift register according to Example.

FIG. 76A and FIG. 76B are graphs showing waveforms of output voltages of a shift register according to Example.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. An example of a semiconductor device is an integrated circuit. Another example of a semiconductor device is a chip that includes an integrated circuit. Another example of a semiconductor device is an electronic component in which a chip is stored in a package. Moreover, a memory device, a display apparatus, a light-emitting apparatus, a lighting device, an electronic device, and the like themselves are semiconductor devices in some cases and include semiconductor devices in other cases.

Ordinal numbers such as “first”, “second”, and “third” in this specification and the like are used in order to avoid confusion among components. Thus, the ordinal numbers do not limit the number of components. In addition, the terms do not limit the order of components. For example, a “first” component in one embodiment in this specification and the like can be referred to as a “second” component in other embodiments or the scope of claims. Moreover, in this specification and the like, for example, a “first” component in one embodiment can be omitted in other embodiments or the scope of claims.

In this specification and the like, the terms for describing positioning, such as “over” and “under”, are sometimes used for convenience to describe the positional relationship between components with reference to drawings. The positional relationship between components is changed as appropriate in accordance with the direction in which the components are described. Thus, the positional relationship is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing showing these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the drawing is rotated by 90°.

In this specification and the like, the terms “film” and “layer” can be interchanged with each other depending on the situation. For example, the term “conductive layer” can be changed into the term “conductive film” in some cases. For another example, the term “insulating film” can be changed into the term “insulating layer” in some cases. The terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, and “terminal” do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also refers to the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Conversely, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. The timing chart used in this specification and the like shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length in the timing chart, the two periods have different lengths in some cases. Furthermore, for example, even when one of two periods is shown long and the other is shown short, the two periods can have the equal length in some cases, or the one period can have a short length and the other can have a long length in other cases. To clearly show the timing chart, two or more overlapping signals are sometimes shown to be intentionally shifted from each other, for example.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also referred to as a metal oxide in some cases. A metal oxide containing nitrogen is referred to as a metal oxynitride in some cases.

In this specification and the like, an impurity in a semiconductor refers to, for example, an element other than a main component of a semiconductor layer. For example, an element with a concentration of lower than 0.1 atomic % is an impurity. When an impurity is contained, for example, one or more of an increase in the density of defect states in a semiconductor, a decrease in carrier mobility, and a decrease in crystallinity occur in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen.

In this specification and the like, a device fabricated using a metal mask or an FMM (fine metal mask, high-resolution metal mask) may be referred to as a device having an MM (metal mask) structure. In this specification and the like, a device fabricated without using a metal mask or an FMM is sometimes referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device having a single structure includes one light-emitting unit between a pair of electrodes, and the light-emitting unit preferably includes one or more light-emitting layers. When white light emission is obtained using two light-emitting layers, the two light-emitting layers are preferably selected such that emission colors of the two light-emitting layers are complementary colors. For example, when the emission color of a first light-emitting layer and the emission color of a second light-emitting layer have a relationship of complementary colors, a structure in which the light-emitting device emits white light as a whole can be obtained. When white light emission is obtained using three or more light-emitting layers, a light-emitting device is preferably configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, the light-emitting device is preferably configured to emit white light by combining light from light-emitting layers of a plurality of light-emitting units. Note that a structure for obtaining white light emission is similar to the structure of the case of a single structure. In the device having a tandem structure, an intermediate layer such as a charge-generation layer is suitably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. To reduce power consumption, the light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 600 and less than or equal to 120°.

In this specification and the like, one embodiment of the present invention can be constituted by appropriately combining a structure described in an embodiment with any of the structures described in the other embodiments. In the case where a plurality of structure examples are described in one embodiment, the structure examples can be combined as appropriate.

Note that a part or the whole content described in one embodiment can be applied to, combined with, or replaced with at least one of another content in the embodiment and a content described in one or a plurality of different embodiments.

Note that in each embodiment, a content described in the embodiment is a content described with reference to a variety of diagrams or a content described with text disclosed in the specification.

Note that by combining a diagram (part or whole thereof) described in one embodiment with at least one of another part of the diagram, a different diagram (part or whole thereof) described in the embodiment, and a diagram (part or whole thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, they are not limited to the illustrated scale. Note that the drawings are schematic views showing ideal examples, and embodiments of the present invention are not limited to shapes, values, or the like shown in the drawings.

### Embodiment 1

In this embodiment, a retention circuit, which is the semiconductor device of one embodiment of the present invention, will be described.

### <Structure Example 1 of Retention Circuit>

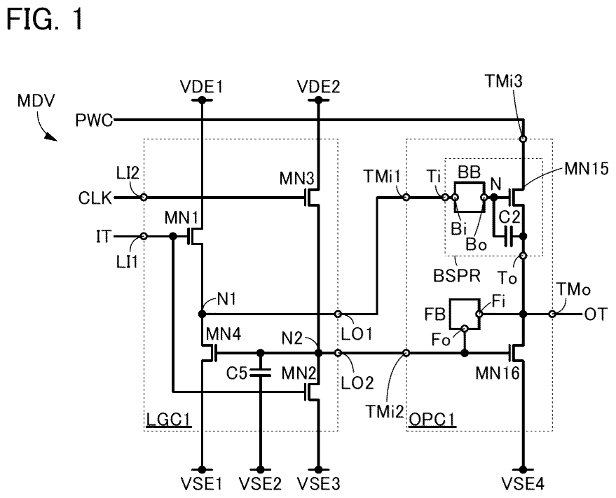

A circuit MDV illustrated in FIG. 1 is an example of the retention circuit, which is the semiconductor device of one embodiment of the present invention, and is a circuit applicable to a shift register described in Embodiment 4.

The shift register can be applied to, for example, a driver circuit capable of being driven at low speed and driving a touch panel, a read circuit for reading current flowing through a light-emitting device including an organic EL material, or a source driver circuit, a gate driver circuit, or the like provided in an electronic device with a low frame rate (e.g., an e-book reader). Note that the shift register can be sometimes used in circuits other than the above depending on the situation.

The circuit MDV in FIG. 1 includes, for example, a terminal IT, a terminal PWC, a terminal CLK, a terminal OT, a circuit LGC1, and a circuit OPC1.

The terminal IT, the terminal PWC, and the terminal CLK are each a terminal having a function of an input terminal in the circuit MDV, and the terminal OT is a terminal having a function of an output terminal in the circuit MDV.

The terminal IT has a function of a terminal that receives a 1-bit signal to be retained in the circuit MDV from the outside of the circuit MDV, for example. Thus, the signal can be, for example, a high-level potential or a low-level potential.

The terminal PWC and the terminal CLK each have a function of a terminal that receives a clock signal for operating the circuit MDV, for example. Note that a clock signal input to the terminal CLK is preferably different from a clock signal input to the terminal PWC. For example, the terminal PWC can receive a clock signal with a pulse width different from that of the clock signal input to the terminal CLK. Note that depending on the case, clock signals input to the terminal PWC and the terminal CLK may be the same. In that case, the terminal CLK and the terminal PWC may be combined into one terminal.

The terminal OT has a function of a terminal that outputs a 1-bit signal retained in the circuit MDV.

For convenience, the circuit LGC1 in FIG. 1 is illustrated as including a terminal LIT, a terminal LI2, a terminal LO1, and a terminal LO2. Likewise, the circuit OPC1 is illustrated as including a terminal TMi1, a terminal TMi2, a terminal TMi3, and a terminal TMo. Thus, in the circuit MDV in FIG. 1, the terminal IT is connected to the terminal LIT, the terminal CLK is connected to the terminal LI2, the terminal LO1 is connected to the terminal TMi1, the terminal L02 is connected to the terminal TMi2, the terminal PWC is connected to the terminal TMi3, and the terminal TMo is connected to the terminal OT.

The circuit MDV can be separated into the circuit LGC1 and the circuit OPC1 on the basis of the functions. The circuit LGC1 has a function of, for example, a logic circuit that processes a signal input to the terminal IT. Specifically, the circuit LGC1 has a function of, for example, outputting to the terminal LO1 a signal with the same logic as the signal input to the terminal IT and outputting to the terminal LO2 a signal whose logic is inverted from the signal input to the terminal IT. The circuit OPC1 has a function of, for example, a logic circuit that generates signals corresponding to potentials input to the terminal TMi1 to the terminal TMi3 and outputs the signals to the terminal TMo. Note that one or both of the circuit LGC1 and the circuit OPC1 may be not a logic circuit but an analog circuit.

As illustrated in FIG. 1, the circuit LGC1 includes a transistor MN1 to a transistor MN4 and a capacitor element C5, for example. The circuit OPC1 includes, for example, a transistor MN16, a circuit BSPR, and a circuit FB. Note that the circuit BSPR includes a circuit BB, a transistor MN15, and a capacitor element C2. The circuit BSPR includes, for example, a terminal Ti having a function of an input terminal and a terminal To having a function of an output terminal. The circuit BB includes, for example, a terminal Bi having a function of an input terminal and a terminal Bo having a function of an output terminal. The circuit FB includes, for example, a terminal Fi having a function of an input terminal and a terminal Fo having a function of an output terminal.

Note that FIG. 1 shows an example of separating the transistor MN1 to the transistor MN4, the transistor MN15, the transistor MN16, the capacitor element C2, and the capacitor element C5 into the circuit LGC1 and the circuit OPC1, and the structures of the circuit LGC1 and the circuit OPC1 are not particularly limited. For example, in FIG. 1, the capacitor element C5 may be provided not in the circuit LGC1 but in the circuit OPC1.

As each of the transistor MNT to the transistor MN4, the transistor MN15, and the transistor MN16, an OS transistor is preferably used, for example. In particular, a metal oxide contained in a channel formation region of the OS transistor is preferably an In-M-Zn oxide containing indium, an element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony), for example. Alternatively, as each of the transistor MN1 to the transistor MN4, the transistor MN15, and the transistor MN16, a transistor containing silicon in a channel formation region (hereinafter referred to as a Si transistor) may be used. As the silicon, single crystal silicon, amorphous silicon (referred to as hydrogenated amorphous silicon in some cases), microcrystalline silicon, or polycrystalline silicon can be used, for example. As a transistor other than an OS transistor and a Si transistor, for example, a transistor containing germanium (Ge) or the like in a channel formation region, a transistor containing a compound semiconductor such as zinc selenide (ZnSe), cadmium sulfide (CdS), gallium arsenide (GaAs), indium phosphide (InP), gallium nitride (GaN), or silicon germanium (SiGe) in a channel formation region, a transistor containing a carbon nanotube in a channel formation region, or a transistor containing an organic semiconductor in a channel formation region can be used.

Although the transistor MN1 to the transistor MN4, the transistor MN15, and the transistor MN16 are n-channel transistors in FIG. 1, one or more selected from the transistor MN1 to the transistor MN4, the transistor MN15, and the transistor MNN16 can be change into p-channel transistors depending on the situation.

Note that the above description of the transistor applies to transistors described in other parts of the specification and transistors illustrated in other drawings, not only to the transistors illustrated in FIG. 1.

In FIG. 1, the terminal LIT is connected to a gate of the transistor MN1 and a gate of the transistor MN2. A first terminal of the transistor MN1 is connected to a wiring VDE1, and a second terminal of the transistor MN1 is connected to a first terminal of the transistor MN4 and the terminal LOT. The terminal CLK is connected to agate of the transistor MN3, a first terminal of the transistor MN3 is connected to a wiring VDE2, and a second terminal of the transistor MN3 is connected to a gate of the transistor MN4, a first terminal of the transistor MN2, a first terminal of the capacitor element C5, and the terminal L02. A second terminal of the transistor MN4 is connected to a wiring VSE1, a second terminal of the capacitor element C5 is connected to a wiring VSE2, and a second terminal of the transistor MN2 is connected to a wiring VSE3.

The terminal TMi1 is connected to the terminal Ti of the circuit BSPR, and the terminal Ti of the circuit BSPR is connected to the terminal Bi of the circuit BB. The terminal Bo of the circuit BB is connected to a gate of the transistor MN15 and a first terminal of the capacitor element C2, a first terminal of the transistor MN15 is connected to the terminal TMi3, and a second terminal of the transistor MN15 is connected to a second terminal of the capacitor element C2 and the terminal To of the circuit BSPR.

The terminal TMi2 is connected to a gate of the transistor MN16 and the terminal Fo of the circuit FB. The terminal To of the circuit BSPR is connected to the terminal TMo, a first terminal of the transistor MN16, and the terminal Fi of the circuit FB. A second terminal of the transistor MN16 is connected to a wiring VSE4.

Note that in this specification and the like, a region where the second terminal of the transistor MN1, the first terminal of the transistor MN4, and the terminal Bi of the circuit BB are connected (a region including the terminal LO1 and the terminal TMi1) is referred to as a node N1, and a region where the first terminal of the transistor MN2, the second terminal of the transistor MN3, the gate of the transistor MN4, the gate of the transistor MN16, and the terminal Fo of the circuit FB are connected (a region including the terminal L02 and the terminal Tmi2) is referred to as a node N2.

The wiring VDE1 and the wiring VDE2 each has a function of a wiring for supplying a fixed potential, for example. The fixed potential can be a high-level potential, for example. Note that the wiring VDE1 and the wiring VDE2 can supply fixed potentials equal to each other or fixed potentials different from each other. Note that in the case where the wiring VDE1 and the wiring VDE2 supply fixed potentials equal to each other, for example, the wiring VDE1 and the wiring VDE2 may be the same wiring.

One or both of the wiring VDE1 and the wiring VDE2 may be a wiring for supplying not a fixed potential but a variable potential (sometimes referred to as a pulse voltage, a pulse potential, a pulse signal, a clock signal, or the like).

The wiring VSE1 to the wiring VSE4 each have a function of a wiring for supplying a fixed potential, for example. The fixed potential can be, for example, a low-level potential, a ground potential, or a negative potential. Note that the wiring VSE1 to the wiring VSE4 can supply fixed potentials equal to each other or fixed potentials different from each other. Alternatively, two or more wirings selected from the wiring VSE1 to the wiring VSE4 may supply fixed potentials equal to each other, and the other wiring(s) may supply a potential different from the fixed potentials. Furthermore, the two or more wirings among the wiring VSE1 to the wiring VSE4 which supply fixed potentials equal to each other may be the same wiring. For example, in the case where the wiring VSE1 and the wiring VSE2 supply fixed potentials equal to each other, the wiring VSE1 and the wiring VSE2 may be the same wiring.

One or more selected from the wiring VSE1 to the wiring VSE4 may have a function of a wiring for supplying not a fixed potential but a variable potential.

Here, the operation of the circuit LGC1 illustrated in FIG. 1 is described assuming that a high-level potential is input to each of the wiring VDE1 and the wiring VDE2 and a low-level potential is input to each of the wiring VSE1 to the wiring VSE3.

When the terminal IT is supplied with a low-level potential and the terminal CLK is supplied with a high-level potential in the circuit LGC1 in FIG. 1, for example, the transistor MN1 and transistor MN2 are in an off state and the transistor MN3 is in an on state. When the transistor MN2 is in an off state and the transistor MN3 is in an on state, the potential of the node N2 is a potential obtained by subtracting the threshold voltage of the transistor MN3 from the high-level potential supplied by the wiring VDE2. Thus, the transistor MN4 is brought into an on state, and the potential of the node N1 becomes a low-level potential supplied from the wiring VSE2. Note that the potential obtained by subtracting the threshold voltage of the transistor MN3 from the high-level potential supplied by the wiring VDE2 is input to the gate of the transistor MN4; thus, the potential of the node N1 may be slightly higher than the low-level potential supplied by the wiring VSE2.

Next, for example, when the high-level potential supplied to the terminal CLK changes to the low-level potential, the transistor MN3 is brought into an off state, the node N2 is brought into a floating state, and the potential obtained by subtracting the threshold voltage of the transistor MN3 from the high-level potential supplied by the wiring VDE2 is retained in the first terminal of the capacitor element C5. Since the transistor MN4 remains in an on state, the potential of the node N1 does not change from the low-level potential supplied by the wiring VSE1 (or the potential slightly higher than the low-level potential).

When the terminal IT is supplied with a high-level potential and the terminal CLK is supplied with a low-level potential, the transistor MN2 is in an on state and the transistor MN3 is in an off state, so that the potential of the node N2 is the low-level potential supplied by the wiring VSE3. In addition, the transistor MN1 is in an on state and the transistor MN4 is in an off state, so that the potential of the node N1 is a potential obtained by subtracting the threshold voltage of the transistor MN1 from the high-level potential supplied by the wiring VDE1.

Next, for example, when the high-level potential supplied to the terminal IT changes to the low-level potential, the transistor MN1 is brought into an off state, the node N1 is brought into a floating state, and ideally, the potential of the node N1 does not change from the potential obtained by subtracting the threshold voltage of the transistor MN1 from the high-level potential supplied by the wiring VDE1. Moreover, since the transistor MN2 is also brought into an off state, the node N2 is brought into a floating state, and the low-level potential supplied by the wiring VSE3 is retained in the first terminal of the capacitor element C5.

The following is the summary of the above description. When a low-level potential is input to the terminal CLK and a high-level potential is input to the terminal IT, ideally, the potential of the node N1 is a high-level potential and the potential of the node N2 is a low-level potential. When a high-level potential is input to the terminal CLK and a low-level potential is input to the terminal IT, ideally, the potential of the node N1 is a low-level potential and the potential of the node N2 is a high-level potential. When a low-level potential is input to the terminal IT and the potential of the terminal CLK changes from a high-level potential to a low-level potential, the potentials of the node N1 and the node N2 do not change before and after the change in the potential of the terminal CLK. Similarly, when a low-level potential is input to the terminal CLK and the potential of the terminal IT changes from a high-level potential to a low-level potential, the potentials of the node N1 and the node N2 do not change before and after the change in the potential of the terminal IT.

Next, the operation of the circuit OPC1 illustrated in FIG. 1 is described assuming that a low-level potential is input to the wiring VSE4.

The circuit BSPR illustrated in FIG. 1 is an example of an amplifier circuit and includes the circuit BB, the transistor MN15, and the capacitor element C2 as described above. As described above, the circuit BB includes, for example, the terminal Bi having a function of an input terminal and the terminal Bo having a function of an output terminal.

The transistor MN15 is normally off and the threshold voltage of the transistor MN15 is set to V_{th_MN15}. The threshold voltage V_{th_MN15} is set to satisfy V_{High}−V_{Low}>V_{th_MN15}. Note that V_{High} is a high-level potential and V_{Low} is a low-level potential.

Note that in this specification and the like, normally off means a state where a current does not flow through a transistor when a gate-source voltage is 0 V. Normally off of an OS transistor means that a current per micrometer of channel width flowing through a transistor is lower than or equal to 1×10⁻²⁰ A at room temperature, lower than or equal to 1×10⁻¹⁸ A at 85° C., or lower than or equal to 1×10⁻¹⁶ A at 125° C. when agate-source voltage is 0 V. Meanwhile, normally on means a state where a channel exists even when a gate-source voltage is 0 V, and current flows through a transistor.

Note that in this embodiment, a region where the terminal Bo of the circuit BB, the gate of the transistor MN15, and the first terminal of the capacitor element C2 are connected to each other is referred to as a node N.

The circuit BB has a function of bringing the node N into a floating state, for example. Thus, the circuit BB can have a structure including a switching element, for example. The circuit BB also has a function of outputting, to the terminal Bo, a potential corresponding to the potential input to the terminal Bi. For example, the circuit BB can have a structure in which when the high-level potential V_{High} is supplied to the terminal Bi, a potential V_{Mid} is output to the terminal Bo. Note that V_{Mid} is a potential lower than the high-level potential V_{High} and higher than the low-level potential V_{Low}. In addition, V_{Mid} is a voltage satisfying V_{Mid}−V_{Low}>V_{th_MN15}.

Here, the potential of the node N of the circuit BSPR in FIG. 1 is assumed to be the potential V_{Mid}, which is lower than the high-level potential V_{High}. In this case, the node N is assumed not to be in a floating state. The potentials of the node N1 and the node N2 are low-level potentials. Thus, the transistor MN16 is in an off state. In addition, the low-level potential V_{Low} is assumed to be supplied to the first terminal of the transistor MN15 from a terminal CLK1.

At this time, the gate-source voltage (the gate-first terminal voltage at this timing) of the transistor MN15 is V_{Mid}−V_{Low}. Since V_{Mid}−V_{Low}>V_{th_MN15} is satisfied, the transistor MN15 is in an on state. Thus, in the circuit MDV, the potential of the terminal TMo is the low-level potential V_{Low} input from the terminal PWC through the source-drain of the transistor MN15.

Next, the low-level potential V_{Low} supplied to the first terminal of the transistor MN15 from the terminal PWC through the terminal TMi3 is assumed to change to the high-level potential V_{High}. In addition, the node N is assumed to be brought into a floating state by the circuit BB. At this time, the gate-source voltage (the gate-second terminal voltage at this timing) of the transistor MN15 is V_{Mid}−V_{Low}, whereby the transistor MN15 is in an on state. Consequently, current flows from the terminal PWC to the terminal TMo through the terminal TMi3 and the transistor MN15, which renders the potential of the terminal TMo higher than V_{Low}. Note that since the node N is in a floating state, the capacitive coupling with the capacitor element C2 causes an increase in the potential of the node N from V_{Mid} in response to the increase in the potential of the terminal TMo. The gate-source voltage of the transistor MN15 is retained by the capacitor element C2, whereby the potential of the terminal TMo increases to V_{High}, and the potential of the terminal OT in the circuit MDV becomes High. Ideally, the potential of the node N becomes V_{Mid}+V_{High}−V_{Low}.

As described above, in the circuit BSPR, when V_{Mid} lower than the high-level potential is input to the node N and the potential of the terminal PWC changes from the low-level potential V_{Low} to the high-level potential V_{High}, the potential of the terminal OT becomes V_{High}. In this specification and the like, increasing the gate potential of a transistor with an increase in the potential of the first terminal or the second terminal of a transistor by utilizing capacitive coupling in such a manner is referred to as a bootstrap.

In the circuit BSPR in FIG. 1, when the potential of the first terminal of the transistor MN15 changes from the low-level potential V_{Low} to the high-level potential V_{High} owing to the terminal PWC and the potential V_{Mid} is supplied to the node N, the potential of the node N increases to V_{Mid}+V_{High}−V_{Low} by bootstrap, and the potential output to the terminal To of the circuit BSPR becomes V_{High}.

The circuit FB has a function of obtaining a potential output from the terminal To of the circuit BSPR and supplying a fixed potential to the node N2, for example. That is, the circuit FB can be regarded as a circuit that supplies feedback to the gate of the transistor MN4, the gate of the transistor MN16, and the first terminal of the capacitor element C5 on the basis of the potential output from the terminal To of the circuit BSPR. Specifically, for example, the circuit FB may have a structure in which a fixed potential (e.g., the low-level potential V_{Low}) is output to the terminal Fo when the high-level potential V_{High} is input to the terminal Fi.

When the circuit FB has the above structure and the high-level potential V_{High} is output from the terminal To of the circuit BSPR, for example, a fixed potential output from the terminal Fo of the circuit FB is supplied to the node N2 (the gate of the transistor MN16). Thus, for example, even when the amount of off-state current flowing between the source and the drain or the amount of leakage current flowing between the gate and the source or between the gate and the drain becomes large in the transistor MN3 for retaining the potential of the node N2 (the gate of the transistor MN16), the potential of the node N2 (the gate of the transistor MN16) remains a fixed potential supplied from the circuit FB. When a noise signal is input to the node N2, the potential of the node N2 remains a fixed potential supplied from the circuit FB. That is, an increase in the potential of the node N2 (the gate of the transistor MN16) due to the above-described factors can be prevented. Accordingly, the potential of the node N2 does not change due to the above-described factors, so that the leakage current due to the transistor MN16 can be reduced. Thus, the potential output from the terminal TMo of the circuit OPC1 (the potential output from the terminal OT of the circuit MDV) can be stabilized.

In the above description, the potential input to the terminal PWC is V_{High} or V_{Low}; however, the potential input to the terminal PWC may be, for example, a potential higher than V_{High} or a potential higher than V_{Low} and lower than V_{High}. Here, for example, the potential input to the terminal PWC is described as a potential V_{HH} higher than V_{High}. When the potential input to the terminal PWC is V_{HH}, the circuit MDV can output V_{HH} from the terminal OT (the terminal TMo of the circuit OPC1) when the potential retained at the node N1 is V_{High} (or V_{High}−V_{th_MN1}). That is, when the potential input to the terminal PWC is set to V_{HH}, the circuit OPC1 level-shifts V_{High} (or V_{High}−V_{th_MN1}), which is the potential of the node N1, to V_{HH} and outputs V_{HH}. Thus, the circuit OPC1 can have a function of a level shifter. When the circuit OPC1 has a function of a level shifter, the level shifter does not need to be provided at the connection destination of the terminal OT of the circuit MDV, for example; thus, the area of the circuit including the circuit MDV can be reduced.

Note that the transistor MN15 illustrated in FIG. 1 may include a back gate, for example. Specifically, for example, the transistor MN15 of the circuit BSPR in FIG. 1 may be a transistor having a structure including gates over and under a channel formation region.

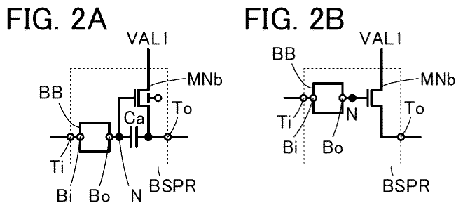

For example, the transistor MN15 illustrated in FIG. 1 can be a transistor like a transistor MNb illustrated in FIG. 2A, which has a structure including a gate above a channel formation region and a back gate below the channel formation region. The circuit BSPR in FIG. 2A is a circuit diagram illustrating a structure example different from that of the circuit BSPR illustrated in FIG. 1, and the circuit BSPR in FIG. 2A includes the transistor MNb, a capacitor element Ca, and the circuit BB. Note that the transistor MNb corresponds to the transistor MN15 in FIG. 1, and the capacitor element Ca corresponds to the capacitor element C2 in FIG. 1. A wiring VAL1 illustrated in FIG. 2 is a wiring connected to the terminal PWC in FIG. 1.

Note that the transistor MNb illustrated in FIG. 2A is, for example, an n-channel transistor which has a structure including a gate over a channel formation region and a back gate under the channel formation region; the transistor MNb includes a second gate in addition to a first gate. Note that in this specification and the like, for convenience, the first gate is referred to as a gate (sometimes referred to as a front gate) and the second gate is referred to as a back gate so that they are distinguished from each other in some cases. In this specification and the like, the first gate and the second gate can be interchanged, and thus the term “gate” can be replaced with the term “back gate”. Similarly, the term “back gate” can be replaced with the term “gate”. As a specific example, a connection structure in which “a gate is connected to a first wiring and a back gate is connected to a second wiring” can be replaced with a connection structure in which “a back gate is connected to a first wiring and a gate is connected to a second wiring”.

FIG. 2A illustrates the back gate of the transistor MNb, but does not illustrate the connection structure of the back gate. Note that the destination to which the back gate is connected can be determined at the design stage. For example, in a transistor including a back gate, a gate and the back gate may be electrically connected to each other so that high-level potentials are applied to the gate and the back gate and the on-state current of the transistor increases. In other words, for example, the gate and the back gate of the transistor MNb can be electrically connected to each other. Alternatively, for example, a transistor including a back gate can have a structure in which a wiring for connecting the back gate of the transistor to an external circuit is provided and a potential is supplied to the back gate of the transistor with the external circuit to change the threshold voltage of the transistor or to reduce the off-state current of the transistor.

Note that although the case where the transistor MN15 includes a back gate is described above, transistors described in other parts of the specification or transistors illustrated in other drawings may each also include a back gate. For example, the transistor MN1 to the transistor MN4 included in the circuit LGC1, the transistor MN16 included in the circuit OPC1, and the like may each have a structure including a back gate.

Note that in the case where the gate capacitance between the gate and the channel formation region (sometimes including one or both of the first terminal and the second terminal depending on the situation) of the transistor MN15 in FIG. 1 is large, the circuit BSPR in FIG. 1 can have a structure without the capacitor element C2. Specifically, for example, the circuit BSPR in FIG. 1 can have a structure without the capacitor element Ca like the circuit structure of the circuit BSPR illustrated in FIG. 2B. In this case, the circuit area of the circuit BSPR can be reduced.

### <<Structure Example 1 of Circuit FB>>

Next, a structure example of the circuit FB illustrated in FIG. 1 is described.

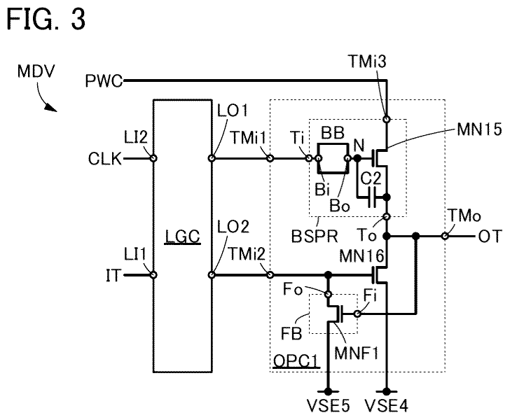

FIG. 3 illustrates a specific structure example of the circuit FB. Note that in order to show the connection structure of the periphery of the circuit FB, FIG. 3 illustrates a circuit LGC and the circuit OPC1.

Like the circuit LGC1 in FIG. 1, the circuit LGC illustrated in FIG. 3 has a function of, for example, outputting to the terminal LO1 a signal with the same logic as the signal input to the terminal IT and outputting to the terminal L02 a signal whose logic is inverted from the signal input to the terminal IT. Thus, the circuit LGC1 in FIG. 1 can be used as the circuit LGC illustrated in FIG. 3, for example.

In FIG. 3, the circuit FB has a structure including a transistor MNF1, for example. As the transistor MNF1, a transistor that can be used as the transistor MN15 can be used, for example.

A first terminal of the transistor MNF1 is connected to the terminal Fo, and a second terminal of the transistor MNF1 is connected to a wiring VSE5. A gate of the transistor MNF1 is connected to the terminal Fi.

Like the wiring VSE1 to the wiring VSE4, the wiring VSE5 has a function of a wiring for supplying a fixed potential, for example. The fixed potential can be, for example, a low-level potential, a ground potential, or a negative potential. The wiring VSE5 may have a function of a wiring for supplying a variable potential depending on the situation.

The fixed potential supplied from the wiring VSE5 may be a fixed potential equal to that supplied from one selected from the wiring VSE1 to the wiring VSE4. In the case where the potentials of the wiring VSE5 and one selected from the wiring VSE1 to the wiring VSE4 are equal to each other, the wiring VSE5 and the one selected from the wiring VSE1 to the wiring VSE4 may be the same wiring.

Here, an operation example of the circuit FB in FIG. 3 is described.

For the operation of the circuit BSPR, the description of the operation example of the circuit BSPR in FIG. 1 can be referred to. For example, when the high-level potential V_{High} is input to the terminal Ti of the circuit BSPR, the circuit BB outputs the potential V_{Mid} to the terminal Bo. Thus, V_{Mid} is supplied to the gate of the transistor MN15 (a first terminal of the capacitor element Ca). The low-level potential V_{Low} is assumed to be supplied to the first terminal of the transistor MN15 from the terminal CLK1. The low-level potential V_{Low} is assumed to be supplied to the second terminal of the transistor MN16 from the wiring VSE4. The low-level potential V_{Low} is assumed to be supplied to the second terminal of the transistor MNF1 from the wiring VSE5.

At this time, the gate-source voltage (here, the gate-first terminal voltage) of the transistor MN15 is V_{Mid}−V_{Low}, whereby the transistor MN15 is in an on state. Consequently, the terminal PWC outputs the low-level potential V_{Low} to the terminal TMo through the transistor MN15.

Thus, V_{Low}, which is the same as the potential of the terminal TMo, is input to the terminal Fi of the circuit FB. In this manner, the low-level potential V_{Low} is supplied to the gate of the transistor MNF1.

The transistor MNF1 is normally off and the threshold voltage of the transistor MNF1 is set to V_{th_MNF1}. The threshold voltage V_{th_MNF1} is set to satisfy V_{High}−V_{Low}>V_{th_MNF1}.

The gate-source voltage (here, the gate-first terminal voltage) of the transistor MNF1 is V_{Low}−V_{High}<V_{th_MNF1}, the transistor MNF1 is in an off state.

Next, the potential supplied to the first terminal of the transistor MN15 from the terminal PWC through the terminal TMi3 is assumed to change from the low-level potential V_{Low} to the high-level potential V_{High}. In addition, the node N is assumed to be brought into a floating state by the circuit BB. At this time, the gate-source voltage (here, the gate-first terminal voltage) of the transistor MN15 is V_{Mid}−V_{Low}, whereby the transistor MN15 is in an on state. Consequently, current flows from the terminal PWC to the terminal TMo of the circuit BSPR through the terminal TMi3 and the transistor MN15, which renders the potential of the terminal TMo higher than V_{Low}. Note that since the node N is in a floating state, the capacitive coupling with the capacitor element C2 causes an increase in the potential of the node N from V_{Mid} in response to the increase in the potential of the terminal To. Accordingly, the gate-source voltage of the transistor MN15 is retained by the capacitor element C2, whereby the potential of the terminal TMo increases to V_{High}.

That is, the potential of the terminal OT becomes V_{High}. Ideally, the potential of the node N becomes V_{Mid}+V_{High}−V_{Low}.

At this time, V_{High}, which is the same as the potential of the terminal To, is input to the terminal Fi of the circuit FB. In this manner, the high-level potential V_{High} is supplied to the gate of the transistor MNF1.

Here, the gate-source voltage of the transistor MNF1 (here, the gate-second terminal voltage) is, for example, V_{High}−V_{Low}. Since the transistor MNF1 is normally off, the transistor MNF1 is brought into an on state.

When the transistor MNF1 is brought into an on state, the low-level potential V_{Low} is supplied from the wiring VSE5 to the gate of the transistor MN16. That is, the potentials of the terminal LO2 of the circuit LGC and the terminal TMi2 of the circuit OPC1 (the node N2 illustrated in FIG. 1) can be set to V_{Low}.

As described above, the potential of the node N2 becomes V_{Low} when the potential of the terminal TMo becomes the high-level potential V_{High}, so that V_{Low} is continuously input to the gate of the transistor MN16, and the circuit FB can make the transistor MN16 in an off state all the time. In addition, since the node N2 (the gate of the transistor MN16) is not in a floating state, the potential of the node N2 returns to the low-level potential V_{Low} even when the potential of the node N2 is changed by noise or the like. This almost eliminates the leakage of electric charge in the terminal TMo, thereby stabilizing the potential of the terminal TMo and accordingly stabilizing the potential of the terminal OT.

### <<Structure Example 2 of Circuit FB>>

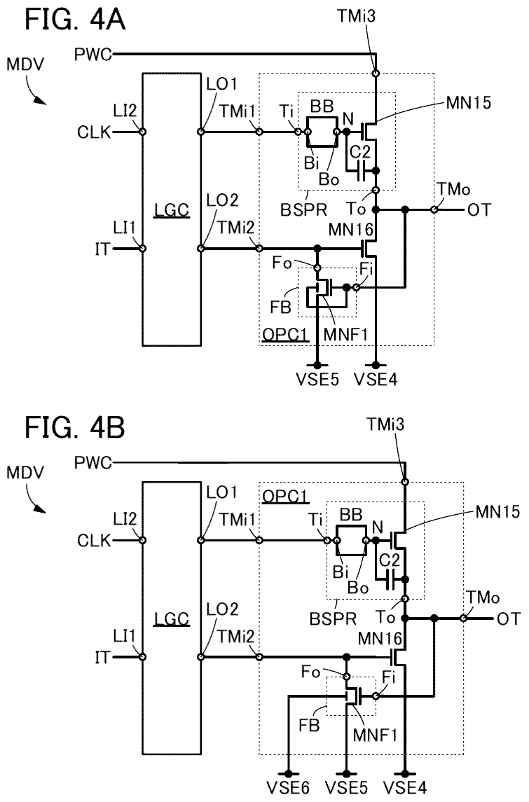

Note that in the semiconductor device of one embodiment of the present invention, the structure of the circuit FB is not limited to that illustrated in FIG. 3. The semiconductor device of one embodiment of the present invention may have a structure in which, for example, the transistor MNF1 includes the gate positioned above the channel formation region and the back gate positioned below the channel formation region as in the circuit FB illustrated in each of FIG. 4A and FIG. 4B.

In particular, in the circuit FB illustrated in FIG. 4A, the back gate of the transistor MNF1 is electrically connected to the gate of the transistor MNF1.

As described above, when the gate and the back gate of the transistor are electrically connected to each other, the on-state current of the transistor can be increased. That is, electrically connecting the gate and the back gate of the transistor MNF1 in the circuit FB in FIG. 4A can increase the on-state current that flows when the transistor MNF1 is in an on state. This can increase the speed at which the potential of the node N2 (the gate of the transistor MN16) changes to a fixed potential (e.g., V_{Low}) output from the terminal Fo of the circuit FB.

In the circuit FB illustrated in FIG. 4B, the back gate of the transistor MNF1 is connected to a wiring VSE6.

Like the wiring VSE1 to the wiring VSE5, the wiring VSE6 has a function of a wiring for supplying a fixed potential, for example. The fixed potential can be, for example, a low-level potential, a ground potential, or a negative potential. The wiring VSE6 may have a function of a wiring for supplying a variable potential depending on the situation.

The fixed potential supplied from the wiring VSE6 may be a fixed potential equal to that supplied from one selected from the wiring VSE1 to the wiring VSE5. In the case where the potentials of the wiring VSE6 and one selected from the wiring VSE1 to the wiring VSE5 are equal to each other, the wiring VSE6 and the one selected from the wiring VSE1 to the wiring VSE5 may be the same wiring.

As described above, when a low-level potential is input from the wiring VSE6 to the back gate of the transistor MNF1, for example, the threshold voltage of the transistor MNF1 increases. This enables the transistor MNF1 to be normally off, whereby the off-state current flowing between the source and the drain of the transistor MNF1 can be reduced.

### <<Structure Example 3 of Circuit FB>>

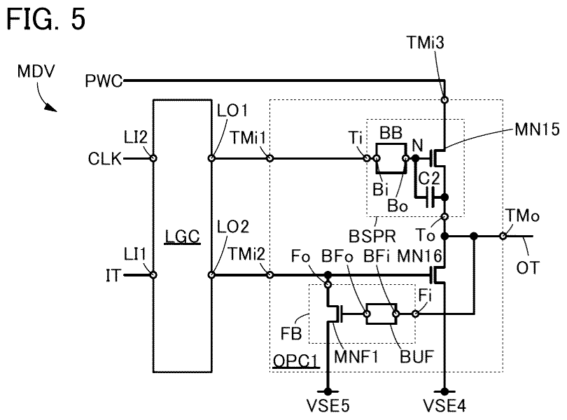

The circuit FB in the circuit MDV illustrated in FIG. 5, which is different from the circuit FB illustrated in each of FIG. 3, FIG. 4A, and FIG. 4B, can be used as the circuit FB illustrated in FIG. 1. The circuit FB in FIG. 5 is different from the circuit FB in each of FIG. 3, FIG. 4A, and FIG. 4B in that a circuit BUF is provided. The circuit FB in FIG. 5 is different from the circuit FB in each of FIG. 3, FIG. 4A, and FIG. 4B also in that the terminal Fi of the circuit FB and the gate of the transistor MNF1 are not directly connected to each other, the terminal Fi of the circuit FB is connected to a terminal BFi to be described later, and the gate of the transistor MNF1 is connected to a terminal BFo to be described later.

In the circuit FB in FIG. 5, the circuit BUF includes the terminal BFi and the terminal BFo.

The circuit BUF has a function of amplifying a potential input to the terminal BFi and outputting the amplified potential to the terminal BFo, for example. In particular, here, the circuit BUF functions as a buffer circuit.

When the circuit BUF is used as a buffer circuit in the circuit FB in FIG. 5, a stable fixed potential can be supplied to the gate of the transistor MNF1 even when the potential output from the terminal TMo is slightly changed by a noise signal or the like, for example.

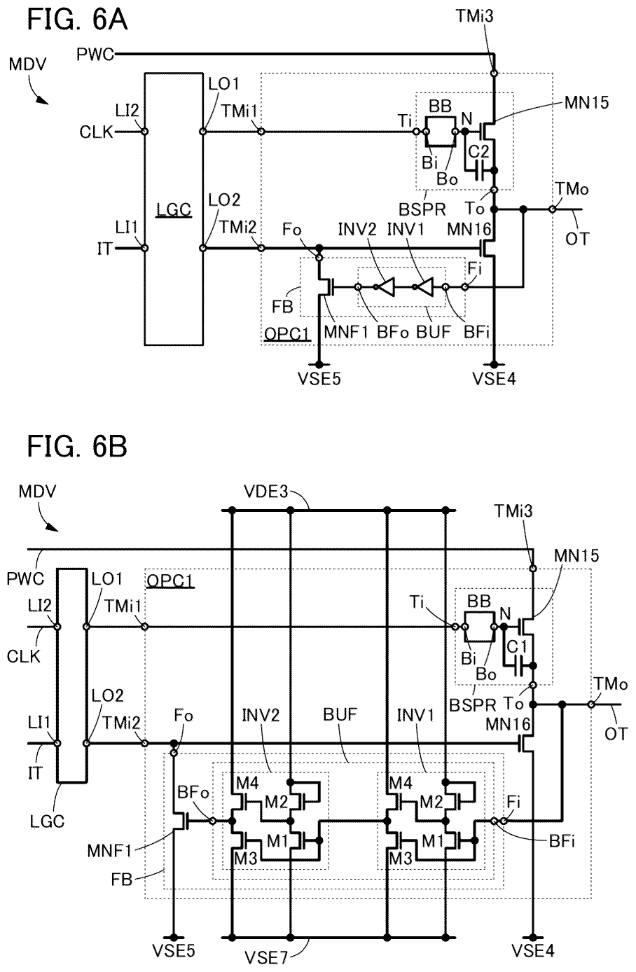

FIG. 6A illustrates a structure example of the circuit BUF of the circuit FB illustrated in FIG. 5. Note that in order to show the connection structure of the periphery of the circuit FB, FIG. 6A also illustrates the circuit LGC and the circuit OPC1.

In the circuit FB illustrated in FIG. 6A, the circuit BUF includes a logic circuit INV1 and a logic circuit INV2.

An input terminal of the logic circuit INV1 is connected to the terminal BFi, an output terminal of the logic circuit INV1 is connected to an input terminal of the logic circuit INV2, and an output terminal of the logic circuit INV2 is connected to the terminal BFo.

Each of the logic circuit INV1 and the logic circuit INV2 has a function of generating an inverted signal of a signal input to the input terminal and outputting the inverted signal. As the logic circuit INV1 and the logic circuit INV2, for example, inverter circuits can be used. In addition to the inverter circuit, a NAND circuit, a NOR circuit, an XOR circuit, or a logic circuit including a combination thereof can be used, for example.

FIG. 6B illustrates a structure example of the logic circuit INV1 and the logic circuit INV2 included in the circuit BUF of the circuit FB illustrated in FIG. 6A.

In the circuit FB illustrated in FIG. 6B, each of the logic circuit INV1 and the logic circuit INV2 includes a transistor M1, a transistor M2, a transistor M3, and a transistor M4.

As each of the transistor M1 to the transistor M4, a transistor that can be used as the transistor MN15 can be used, for example.

In the logic circuit INV1, each of a gate of the transistor M1 and a gate of the transistor M3 is connected to the input terminal of the logic circuit INV1 (the terminal BFi of the circuit BUF). A first terminal of the transistor M1 is connected to the first terminal of the transistor M2 and a gate of the transistor M4. A second terminal of the transistor M1 is connected to a wiring VSE7. A second terminal of the transistor M2 is electrically connected to a gate of the transistor M2. The second terminal of the transistor M2 and the gate of the transistor M2 are connected to a wiring VDE3. A first terminal of the transistor M3 is connected to a first terminal of the transistor M4 and the output terminal of the logic circuit INV1. A second terminal of the transistor M3 is connected to the wiring VSE7. A second terminal of the transistor M4 is connected to the wiring VDE3.

In the logic circuit INV2, each of the gate of the transistor M1 and the gate of the transistor M3 is connected to the input terminal of the logic circuit INV2 (the output terminal of the logic circuit INV1). The first terminal of the transistor M1 is connected to the first terminal of the transistor M2 and the gate of the transistor M4. The second terminal of the transistor M1 is connected to the wiring VSE7. The second terminal of the transistor M2 is electrically connected to the gate of the transistor M2. The second terminal of the transistor M2 and the gate of the transistor M2 are connected to the wiring VDE3. The first terminal of the transistor M3 is connected to the first terminal of the transistor M4 and the output terminal of the logic circuit INV2 (the terminal BFo of the circuit BUF). The second terminal of the transistor M3 is connected to the wiring VSE7. The second terminal of the transistor M4 is connected to the wiring VDE3.

The wiring VDE3 has a function of a power supply line for supplying a high-level potential to each of the logic circuit INV1 and the logic circuit INV2, for example. Note that the wiring VDE3 may have a function of a wiring for supplying not a high-level potential but a low-level potential, a ground potential, or a negative potential. Alternatively, the wiring VDE3 may have a function of a wiring for supplying not a fixed potential but a variable potential.

The wiring VSE7 has a function of a power supply line for supplying a low-level potential to each of the logic circuit INV1 and the logic circuit INV2, for example. Note that the wiring VSE7 may have a function of a wiring for supplying not a low-level potential but a high-level potential, a ground potential, or a negative potential. Alternatively, the wiring VSE7 may have a function of a wiring for supplying not a fixed potential but a variable potential.

Note that one wiring VDE3 is connected to the second terminal of the transistor M2 and the second terminal of the transistor M4 which are included in each of the logic circuit INV1 and the logic circuit INV2; alternatively, different wirings may be connected to the second terminal of the transistor M2 and the second terminal of the transistor M4 which are included in each of the logic circuit INV1 and the logic circuit INV2. Similarly, one wiring VSE7 is connected to the second terminal of the transistor M1 and the second terminal of the transistor M3 which are included in each of the logic circuit INV1 and the logic circuit INV2; alternatively, different wirings may be connected to the second terminal of the transistor M1 and the second terminal of the transistor M3 which are included in each of the logic circuit INV1 and the logic circuit INV2.

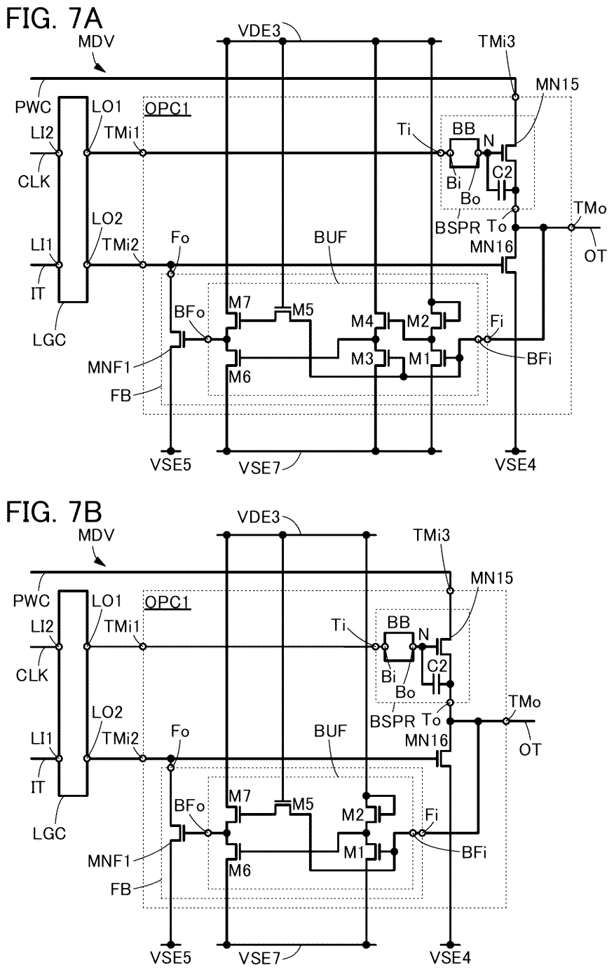

FIG. 7A illustrates a structure example of the circuit BUF of the circuit FB illustrated in FIG. 5, which is different from the structure example in FIG. 6B. The circuit FB illustrated in FIG. 7A is a modification example of the circuit FB in FIG. 6B and is different from the circuit FB in the number of transistors included in the circuit BUF and the connection structure.

The circuit BUF included in the circuit FB in FIG. 7A includes the transistor M1, the transistor M2, the transistor M3, the transistor M4, a transistor M5, a transistor M6, and a transistor M7.

As each of the transistor M1 to the transistor M7, a transistor that can be used as the transistor MN15 can be used, for example.

In the circuit BUF of the circuit FB in FIG. 7A, each of the gate of the transistor M1, the gate of the transistor M3, and a first terminal of the transistor M5 is connected to the terminal BFi of the circuit BUF (the terminal Fi of the circuit FB). The first terminal of the transistor M1 is connected to the first terminal of the transistor M2 and the gate of the transistor M4. The second terminal of the transistor M1 is connected to the wiring VSE7. The second terminal of the transistor M2 is electrically connected to the gate of the transistor M2. The second terminal of the transistor M2 and the gate of the transistor M2 are connected to the wiring VDE3. The first terminal of the transistor M3 is connected to the first terminal of the transistor M4 and a gate of the transistor M6. The second terminal of the transistor M3 is connected to the wiring VSE7. The second terminal of the transistor M4 is connected to the wiring VDE3. A second terminal of the transistor M5 is connected to a gate of the transistor M7, and a gate of the transistor M5 is connected to the wiring VDE3. A first terminal of the transistor M6 is connected to a first terminal of the transistor M7 and the terminal Bfo of the circuit BUF. A second terminal of the transistor M6 is connected to the wiring VSE7. A second terminal of the transistor M7 is connected to the wiring VDE3.

Note that one wiring VDE3 is connected to the second terminal of the transistor M2, the gate of the transistor M5, and the second terminal of the transistor M7; alternatively, different wirings may be connected to the second terminal of the transistor M2, the second terminal of the transistor M4, the gate of the transistor M5, and the second terminal of the transistor M7. Similarly, one wiring VSE7 is connected to the second terminal of the transistor M1, the second terminal of the transistor M3, and the second terminal of the transistor M6; alternatively, different wirings may be connected to the second terminal of the transistor M1, the second terminal of the transistor M3, and the second terminal of the transistor M6.

FIG. 7B illustrates a structure example of the circuit BUF of the circuit FB illustrated in FIG. 5, which is different from the circuit FB in FIG. 7A. The circuit FB illustrated in FIG. 7B is a modification example of the circuit FB in FIG. 7A and is different from the circuit FB in FIG. 7A in the number of transistors included in the circuit BUF and the connection structure.

The circuit BUF included in the circuit FB in FIG. 7B includes the transistor M1, the transistor M2, the transistor M5, the transistor M6, and the transistor M7.

In the circuit BUF in the circuit FB in FIG. 7B, each of the gate of the transistor M1 and the first terminal of the transistor M5 is connected to the terminal BFi of the circuit BUF (the terminal Fi of the circuit FB). The first terminal of the transistor M1 is connected to the first terminal of the transistor M2 and the gate of the transistor M6. The second terminal of the transistor M1 is connected to the wiring VSE7. The second terminal of the transistor M2 is electrically connected to the gate of the transistor M2. The second terminal of the transistor M2 and the gate of the transistor M2 are connected to the wiring VDE3. The second terminal of the transistor M5 is connected to the gate of the transistor M7, and the gate of the transistor M5 is connected to the wiring VDE3. The first terminal of the transistor M6 is connected to the first terminal of the transistor M7 and the terminal Bfo of the circuit BUF. The second terminal of the transistor M6 is connected to the wiring VSE7. The second terminal of the transistor M7 is connected to the wiring VDE3.

When the circuit BUF in the circuit FB illustrated in FIG. 5 is changed into any of the circuit BUF illustrated in FIG. 6A (the circuit BUF illustrated in FIG. 6B), the circuit BUF illustrated in FIG. 7A, and the circuit BUF illustrated in FIG. 7B, a stable potential can be supplied to the gate of the transistor MNF1.

Note that the circuit BUF in the circuit FB illustrated in FIG. 5 can be configured as a single-polarity circuit using an n-channel transistor especially like the circuit BUF in each of FIG. 6B, FIG. 7A, and FIG. 7B, or can be configured as a CMOS circuit using an n-channel transistor and a p-channel transistor. Alternatively, the circuit BUF in the circuit FB illustrated in FIG. 5 can be configured as a single-polarity circuit using a p-channel transistor depending on the situation.

### <<Structure Example 1 of Circuit BB>>

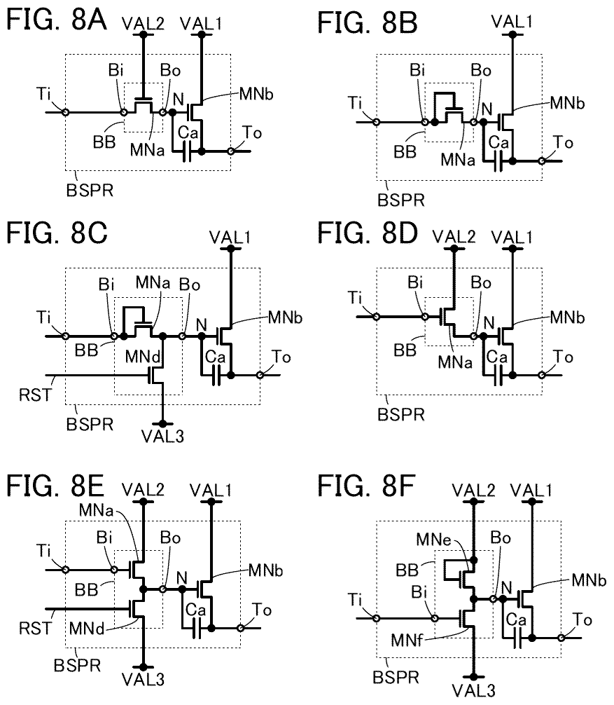

Next, structure examples of the circuit BB included in the circuit BSPR illustrated in each of FIG. 1 to FIG. 7B are described. Note that the circuit BB is described with reference to FIG. 8A to FIG. 8F. FIG. 8A to FIG. 8F each illustrate a structure of the circuit BSPR to show a connection structure around the circuit BB.

Note that the circuit BSPR illustrated in FIG. 8 includes the transistor MNb and the capacitor element Ca in addition to the circuit BB. Note that the transistor MNb corresponds to the transistor MN15 in FIG. 1 and FIG. 3 to FIG. 7B, and the capacitor element Ca corresponds to the capacitor element C2 in FIG. 1 and FIG. 3 to FIG. 7B.

The circuit BSPR illustrated in FIG. 8A has a structure including a transistor MNa in the circuit BB. As the transistor MNa, a transistor that can be used as the transistor MNb can be used, for example.

A first terminal of the transistor MNa is connected to the terminal Bi, and a second terminal of the transistor MNa is connected to the terminal Bo. A gate of the transistor MNa is connected to a wiring VAL2.

Like the wiring VAL1, the wiring VAL2 has a function of a wiring for supplying a fixed potential or a variable potential, for example. Examples of the fixed potential include a high-level potential, a low-level potential, a ground potential, and a negative potential. Examples of the variable potential include a pulse signal and a clock signal.

The wiring VAL2 may be connected to the wiring VAL1. In that case, the wiring VAL1 and the wiring VAL2 can be the same wiring. When the wiring VAL1 and the wiring VAL2 are the same wiring, the number of wirings can be reduced, so that the circuit area of the circuit MDV can be reduced.

Note that the wiring VAL1 can be a wiring connected to the terminal PWC in FIG. 1 and FIG. 3 to FIG. 7B.

Here, an operation example of the circuit BSPR in FIG. 8A is described. For example, the high-level potential V_{High} is assumed to be input to the terminal Ti of the circuit BSPR. That is, Vᵢₙ=V_{High} is satisfied. The high-level potential V_{High} is assumed to be supplied to the gate of the transistor MNa from the wiring VAL2. The potential of the node N (the gate of the transistor MNb and the first terminal of the capacitor element Ca) is assumed to be the low-level potential V_{Low}.

The transistor MNa is normally off and the threshold voltage of the transistor MNa is set to V_{th_MNa}. The threshold voltage V_{th_MNa} is set to satisfy V_{High}−V_{Low}>V_{th_MNa}.

Since the gate-source voltage (the gate-second terminal voltage at this timing) of the transistor MNa is V_{High}−V_{Low}, the transistor MNa is in an on state. Consequently, electric charge is accumulated in the node N because of current flowing from the terminal Ti through the transistor MNa, so that the potential of the node N increases until the transistor MNa is brought into an off state. Specifically, the transistor MNa is brought into an off state when the gate-source voltage of the transistor MNa decreases to V_{th_MNa}; thus, the potential of the node N (the second terminal of the transistor MNa) at this time is V_{High}−V_{th_MNa}. Note that V_{High}−V_{th_MNa} corresponds to V_{Mid} described in FIG. 1.

### <<Structure Example 2 of Circuit BB>>

The circuit BB of the circuit BSPR illustrated in FIG. 8B is a modification example of the circuit BB of the circuit BSPR in FIG. 8A and is different from the circuit BB of the circuit BSPR in FIG. 8A in that the gate of the transistor MNa is electrically connected not to the wiring VAL2 but to the first terminal of the transistor MNa.

In FIG. 8B, since the first terminal of the transistor MNa and the gate of the transistor MNa are electrically connected to each other, the transistor MNa can be said to be diode-connected. Hence, for example, when the high-level potential V_{High} is input to the terminal Ti of the circuit BSPR, the potentials of the first terminal and the gate of the transistor MNa each become the high-level potential V_{High}; thus, the potential of the node N (the second terminal of the transistor MNa) becomes V_{High}−V_{th_MNa}.

When the potential V_{High}−V_{th_MNa} of the node N (the second terminal of the transistor MNa) is to be decreased, that is, when the node N is to be discharged, the circuit BB of the circuit BSPR in FIG. 8B should be further modified.

The circuit BB of the circuit BSPR illustrated in FIG. 8C is a modification example of the circuit BB of the circuit BSPR in FIG. 8B and is different from the circuit BB of the circuit BSPR in FIG. 8B in that the node N can be discharged.

In the circuit BSPR in FIG. 8C, the circuit BB includes a transistor MNd in addition to the transistor MNa.

As the transistor MNd, a transistor that can be used as the transistor MNa or the transistor MNb can be used, for example.

The first terminal of the transistor MNd is connected to the second terminal of the transistor MNa and the terminal Bo, the second terminal of the transistor MNd is connected to a wiring VAL3, and the gate of the transistor MNd is connected to a wiring RST.

Like the wiring VAL1 or the wiring VAL2, the wiring VAL3 functions as a wiring for supplying a fixed potential, for example. An example of the fixed potential is a low-level potential. Other examples of the fixed potential include a ground potential and a negative potential. Depending on the situation, the wiring VAL3 may function as a wiring for supplying a variable potential.

The wiring RST functions as a wiring for transmitting a signal for selecting whether the node N is discharged or not, for example. Specifically, for example, when the node N is not discharged, the wiring RST is supplied with the low-level potential V_{Low} as a signal to bring the transistor MNd into an off state. For example, when the nodeN is discharged, the wiring RST is supplied with the high-level potential V_{High} as a signal to bring the transistor MNd into an on state.

When the potential of the node N is to be increased (when the potential of the node N is to be V_{High}−V_{th_MNa}), for example, the high-level potential V_{High} is preferably supplied to the terminal Ti after the low-level potential V_{Low} is supplied to the wiring RST to bring the transistor MNd into an off state. When the potential of the node N is to be decreased (when the potential of the node N is to be V_{Low}), for example, the high-level potential V_{High} is preferably supplied to the wiring RST to bring the transistor MNd into an on state after the low-level potential V_{Low} is supplied to the terminal Ti to bring the transistor MNa into an off state. Here, when the potential supplied by the wiring VAL3 is the low-level potential V_{Low}, the electric charge in the node N 35 flows to the wiring VAL3, whereby the potential of the node N becomes V_{Low}.

### <<Structure Example 3 of Circuit BB>>

The circuit BB of the circuit BSPR illustrated in FIG. 8D is a modification example of the circuit BB of the circuit BSPR in FIG. 8A and is different from the circuit BB of the circuit BSPR in FIG. 8A in that the gate of the transistor MNa is connected not to the wiring VAL2 but to the terminal Bi and that the first terminal of the transistor MNa is connected not to the terminal Bi but to the wiring VAL2.

Here, an operation example of the circuit BSPR in FIG. 8D is described. For example, the high-level potential V_{High} is assumed to be input to the terminal Ti of the circuit BSPR. The high-level potential V_{High} is assumed to be supplied to the first terminal of the transistor MNa from the wiring VAL2. The potential of the node N is assumed to be the low-level potential V_{Low}.

Since the gate-source voltage (the gate-second terminal voltage at this timing) of the transistor MNa is V_{High}−V_{Low}, the transistor MNa is in an on state. Consequently, electric charge is accumulated in the node N because of current flowing from the wiring VAL2 through the transistor MNa, so that the potential of the node N increases until the transistor MNa is brought into an off state. Specifically, the transistor MNa is brought into an off state when the gate-source voltage of the transistor MNa decreases to V_{th_MNa}; thus, the potential of the node N (the second terminal of the transistor MNa) at this time is V_{High}−V_{th_MNa}. Note that V_{High}−V_{th_MNa} corresponds to V_{Mid} described in FIG. 1.

When the potential V_{High}−V_{th_MNa} of the node N (the second terminal of the transistor MNa) is to be decreased, that is, when the node N is to be discharged, the circuit BB of the circuit BSPR in FIG. 8D should be further modified.

The circuit BB of the circuit BSPR illustrated in FIG. 8E is a modification example of the circuit BB of the circuit BSPR in FIG. 8D and is different from the circuit BB of the circuit BSPR in FIG. 8D in that the node N can be discharged.

In the circuit BSPR in FIG. 8E, the circuit BB includes the transistor MNd in addition to the transistor MNa.

The first terminal of the transistor MNd is connected to the second terminal of the transistor MNa and the terminal Bo, the second terminal of the transistor MNd is connected to the wiring VAL3, and the gate of the transistor MNd is connected to the wiring RST.

For the transistor MNd, the wiring VAL3, and the wiring RST, the description of the transistor MNd, the wiring VAL3, and the wiring RST in the circuit BSPR in FIG. 8C can be referred to.

When the potential of the node N is to be increased (when the potential of the node N is to be V_{High}−V_{th_MNa}), for example, the high-level potential V_{High} is preferably supplied to the terminal Ti after the low-level potential V_{Low} is supplied to the wiring RST to bring the transistor MNd into an off state. When the potential of the node N is to be decreased (when the potential of the node N is to be V_{Low}), for example, the high-level potential V_{High} is preferably supplied to the wiring RST to bring the transistor MNd into an on state after the low-level potential V_{Low} is supplied to the terminal Ti to bring the transistor MNa into an off state. Here, when the potential supplied by the wiring VAL3 is the low-level potential V_{Low}, the electric charge in the node N flows to the wiring VAL3, whereby the potential of the node N becomes V_{Low}.

### <<Structure Example 4 of Circuit BB>>

The circuit BSPR illustrated in FIG. 8F has a structure including an inverter circuit in the circuit BB. Specifically, the circuit BB includes a transistor MNe and a transistor MNf, and the transistor MNe and the transistor MNf form the inverter circuit.

As each of the transistor MNe and the transistor MNf, a transistor that can be used as the transistor MNb can be used, for example.

A first terminal of the transistor MNe is electrically connected to a gate of the transistor MNe. The first terminal of the transistor MNe and the gate of the transistor MNe are connected to the wiring VAL2. A second terminal of the transistor MNe is connected to the terminal Bo and a first terminal of the transistor MNf. A second terminal of the transistor MNf is connected to the wiring VAL3, and a gate of the transistor MNf is connected to the terminal Bi.

For the wiring VAL2, the description of the wiring VAL2 of the circuit BSPR in FIG. 8A can be referred to. For the wiring VAL3, the description of the wiring VAL3 of the circuit BSPR in FIG. 8C can be referred to.

Here, an operation example of the circuit BSPR in FIG. 8F is described. For example, the high-level potential V_{High} is assumed to be supplied from the wiring VAL2 to the first terminal and the gate of the transistor MNe. The low-level potential V_{Low} is assumed to be supplied to the second terminal of the transistor MNf from the wiring VAL3. The potential of the node N (the gate of the transistor MNb and the first terminal of the capacitor element Ca) is assumed to be the low-level potential V_{Low}.

The transistor MNe and the transistor MNf are normally off; in particular, the threshold voltage of the transistor MNe is V_{th_MNe}, and V_{th_MNe} is the voltage satisfying V_{High}−V_{Low}>V_{th_MNe}.

First, a case where the low-level potential V_{Low} is input to the terminal Ti is considered. In this case, V_{Low} is input to the gate of the transistor MNf, so that the transistor MNf is brought into an off state. Since the gate-source voltage (the gate-second terminal voltage at this timing) of the transistor MNe is V_{High}−V_{Low}, the transistor MNe is in an on state. Consequently, electric charge is accumulated in the node N because of current flowing from the wiring VAL2 through the transistor MNe, so that the potential of the node N increases until the transistor MNe is brought into an off state. Specifically, the transistor MNe is brought into an off state when the gate-source voltage of the transistor MNe decreases to V_{th_MNe}; thus, the potential of the node N (the second terminal of the transistor MNe) at this time is V_{High}−V_{th_MNe}. Note that V_{High}−V_{th_MNe} corresponds to V_{Mid} described in FIG. 1.

Then, a case where the high-level potential V_{High} is input to the terminal Ti is considered. In this case, V_{High} is input to the gate of the transistor MNf, so that the transistor MNf is brought into an on state. Since the transistor MNf is brought into an on state, current flows from the node N to the wiring VAL3 through the transistor MNf and electric charge is released, whereby the potential of the node N ideally becomes the low-level potential V_{Low} supplied by the wiring VAL3. Note that a reduction in the potential of the second terminal of the transistor MNe (the node N) brings the transistor Mne into an on state, so that the potential of the node N actually becomes higher than or equal to the low-level potential V_{Low} and lower than or equal to the high-level potential V_{High}.

### <Structure Example 2 of Retention Circuit>

Next, a structure example of the circuit MDV, which is different from that illustrated in FIG. 1 in the structure of the circuit OPC1, is described.

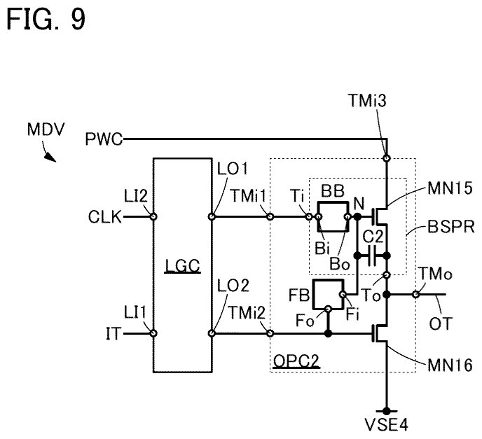

The circuit MDV illustrated in FIG. 9 includes the circuit LGC and a circuit OPC2.

The circuit OPC2 is a modification example of the circuit OPC1 in FIG. 1 and is specifically different from the circuit OPC1 in FIG. 1 in that the terminal Fi of the circuit FB is connected not to the terminal TMo (the terminal To of the circuit BSPR) but to the terminal Bo of the circuit BB, the gate of the transistor MN15, and the first terminal of the capacitor element C2.

Note that like the circuit LGC1 in FIG. 1, the circuit LGC1 has a function of, for example, outputting to the terminal LO1 a signal with the same logic as the signal input to the terminal IT and outputting to the terminal L02 a signal whose logic is inverted from the signal input to the terminal IT.

As the circuit FB illustrated in FIG. 9, any of the circuits FB described above with reference to FIG. 3 to FIG. 7B can be used, for example.

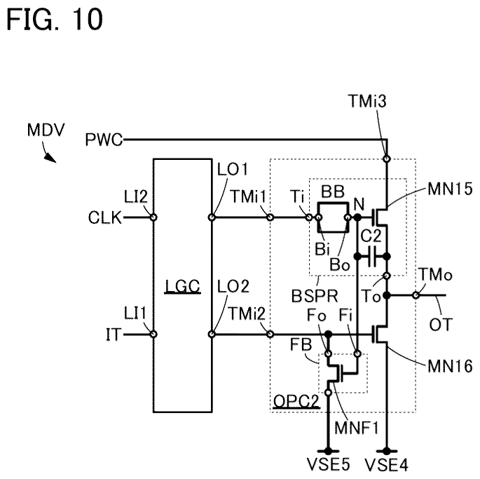

As an example, FIG. 10 illustrates a structure example in which the circuit FB of the circuit OPC1 in FIG. 3 is used as the circuit FB of the circuit OPC2 in FIG. 9.

The circuit OPC2 in FIG. 10 includes the circuit FB having the structure illustrated in FIG. 3. Thus, in the circuit OPC2 in FIG. 10, the gate of the transistor MNF1 is connected to the terminal Bo of the circuit BB, the gate of the transistor MN15, and the first terminal of the capacitor element C2.

Next, an operation example of the circuit OPC2 in FIG. 10 is described.

For the operation of the circuit BSPR, the operation example of the circuit BSPR in FIG. 1 can be referred to. For example, when the high-level potential V_{High} is input to the terminal TMi1 of the circuit OPC2, the circuit BB outputs the potential V_{Mid} to the terminal Bo. Thus, V_{Mid} is supplied to the gate of the transistor MN15 (a first terminal of a capacitor element C1). The low-level potential V_{Low} is assumed to be supplied to the first terminal of the transistor MN15 from the terminal PWC through the terminal TMi3. The low-level potential V_{Low} is assumed to be supplied to the second terminal of the transistor MNF1 from the wiring VSE5.

At this time, the gate-source voltage (here, the gate-first terminal voltage) of the transistor MN15 is V_{Mid}−V_{Low}, whereby the transistor MN15 is in an on state. Consequently, the terminal PWC outputs the low-level potential V_{Low} to the terminal To of the circuit BSPR through the transistor MN15.

At this time, V_{Mid}, which is the same as the potential of the node N, is input to the terminal Fi of the circuit FB. In this manner, V_{Mid} is supplied to the gate of the transistor MNF1.

The transistor MNF1 is normally off and the threshold voltage of the transistor MNF1 is set to V_{th_MNF1}. The threshold voltage V_{th_MNF1} is set to satisfy V_{High}−V_{Low}>V_{th_MNF1}.

Here, the gate-source voltage (here, the gate-second terminal voltage) of the transistor MNF1 is V_{Mid}−V_{Low}, whereby the transistor MNF1 is in an on state. Consequently, the wiring VSE5 supplies the low-level potential V_{Low} to the gate of the transistor MN16 through the transistor MNF1. As a result, the gate-source voltage (here, the gate-second terminal voltage) of the transistor MNF16 becomes V_{Low}−V_{Low}=0, whereby the transistor MN16 is brought into an off state.

Next, the potential supplied to the first terminal of the transistor MN15 from the terminal PWC through the terminal TMi3 is assumed to change from the low-level potential V_{Low} to the high-level potential V_{High}. In addition, the node N is assumed to be brought into a floating state by the circuit BB. At this time, the gate-source voltage (here, the gate-second terminal voltage) of the transistor MN15 is V_{Mid}−V_{Low}, whereby the transistor MN15 is in an on state. Consequently, current flows from the terminal PWC to the terminal To of the circuit BSPR through the terminal TMi3 and the transistor MN15, which renders the potential of the terminal To higher than V_{Low}. Note that since the node N is in a floating state, the capacitive coupling with the capacitor element C1 causes an increase in the potential of the node N from V_{Mid} in response to the increase in the potential of the terminal To. Accordingly, the gate-source voltage of the transistor MN15 is retained by the capacitor element C1, whereby the potential of the terminal To increases to V_{High}. Ideally, the potential of the node N becomes V_{Mid}+V_{High}−V_{Low}.

At this time, the same potential as that of the node N is input to the terminal Fi of the circuit FB. In this manner, the potential is supplied to the gate of the transistor MNF1. Here, V_{Mid}+V_{High}−V_{Low} is assumed to be supplied to the gate of the transistor MNF1, for example.

Here, the gate-source voltage of the transistor MNF1 (here, the gate-second terminal voltage) is, for example, V_{Mid}+V_{High}−V_{Low}−V_{Low}=V_{Mid}+V_{High}−2V_{Low}. Since V_{Mid}=V_{High}−V_{th_MNa}, the gate-source voltage of the transistor MNF1 becomes 2V_{High}−2V_{Low}−V_{th_MNa}. Since V_{High}−V_{Low}>V_{th_MNa}, 2V_{High}−2V_{Low}>V_{th_MNa}. Accordingly, the transistor MNF1 is in an on state.

In particular, the gate-source voltage of the transistor MNF1 increases when the potential of the terminal PWC changes from the low-level potential V_{Low} to the high-level potential V_{High}. Thus, the on-state current of the transistor MNF1 increases, so that electric charge accumulated in the gate of the transistor MN16 can be released earlier. Accordingly, the transistor MN16 is switched from an on state to an off state quickly.

Since the transistor MNF1 is brought into an on state when the potential of the terminal TMo becomes the high-level potential V_{High}, V_{Low} is continuously input to the gate of the transistor MN16. Thus, the circuit FB can make the transistor MN16 in an off state all the time. In addition, since the gate of the transistor MN16 is not in a floating state, the potential of the gate of the transistor MN16 immediately returns to the low-level potential V_{Low} even when the potential of the gate of the transistor MN16 is changed by noise or the like. This almost eliminates the leakage of electric charge in the terminal TMo, thereby stabilizing the potential of the terminal TMo and accordingly stabilizing the potential of the terminal OT.

Note that in the above operation example, the gate-source voltage of the transistor MNF1 in an on state is 2V_{High}−2V_{Low}−V_{th_MNa}, which is higher than the gate-source voltages of other transistors in an on state. Hence, the transistor MNF1 preferably has a higher gate-source breakdown voltage than the other transistors. Examples of the transistor with a high gate-source breakdown voltage include a transistor with a TGSA (Top-Gate Self Align) structure and a transistor with a VLFET (Vertical Lateral Field Effect Transistor) structure. Note that the transistor with a TGSA structure and the transistor with a VLFET structure will be described in detail in Embodiment 4.

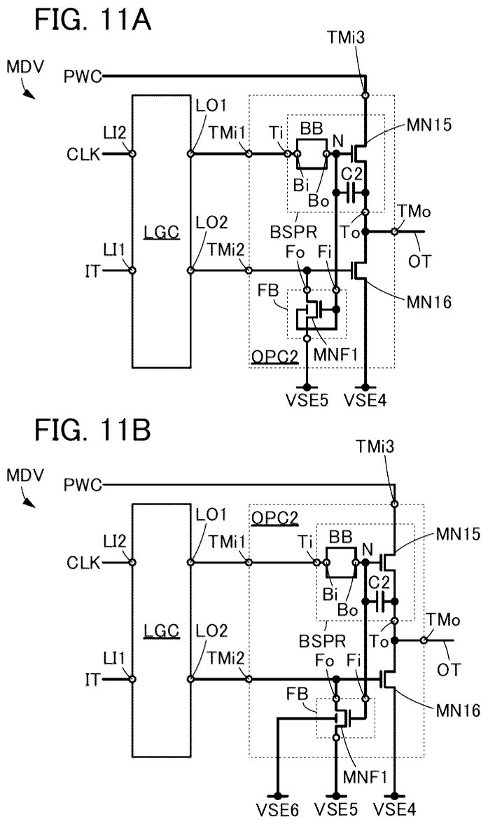

Note that in the semiconductor device of one embodiment of the present invention, the structure of the circuit MDV is not limited to that illustrated in FIG. 10. The semiconductor device of one embodiment of the present invention may have a structure in which, for example, the transistor MNF1 in the circuit FB includes the gate positioned above the channel formation region and the back gate positioned below the channel formation region as illustrated in each of FIG. 11A and FIG. 11B.

Note that like the circuit FB illustrated in FIG. 4A, the circuit FB in FIG. 11A includes the transistor MNF1 including the gate and the back gate which are electrically connected to each other, and like the circuit FB illustrated in FIG. 4B, the circuit FB in FIG. 11B includes the transistor MNF1 including the back gate connected to the wiring VSE6.

Thus, the description of FIG. 4A can be referred to for the structure and operation of the circuit FB in FIG. 11A. The description of FIG. 4B can be referred to for the structure and operation of the circuit FB in FIG. 111B.

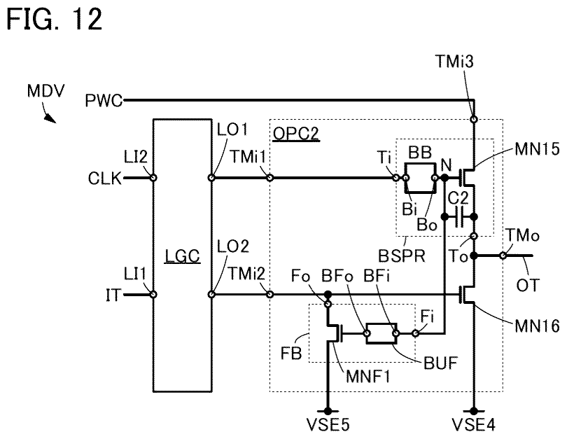

The semiconductor device of one embodiment of the present invention may have a structure in which, for example, the circuit FB includes the circuit BUF as illustrated in FIG. 12. The circuit FB in FIG. 12 has a structure similar to that of the circuit FB in FIG. 5. Thus, the description of FIG. 5 can be referred to for the structure and operation of the circuit FB in FIG. 12. For example, the circuit BUF illustrated in FIG. 6A, the circuit BUF illustrated in FIG. 6B, the circuit BUF illustrated in FIG. 7A, or the circuit BUF illustrated in FIG. 7B can be used as the circuit BUF included in the circuit FB in FIG. 12.

### <Structure Example 3 of Retention Circuit>

Next, a structure example of the circuit MDV, which is different from that illustrated in FIG. 1 or FIG. 9 in the structure of the circuit OPC1 or the circuit OPC2, is described.

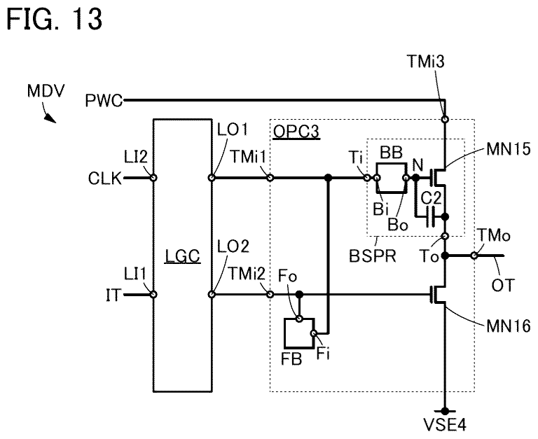

The circuit MDV illustrated in FIG. 13 includes the circuit LGC and a circuit OPC3.

The circuit OPC3 is a modification example of the circuit OPC1 in FIG. 1 and is specifically different from the circuit OPC1 in FIG. 1 in that the terminal Fi of the circuit FB is connected not to the terminal TMo (the terminal To of the circuit BSPR) but to the terminal Ti of the circuit BSPR (the terminal Bi of the circuit BB) and the terminal TMi1.

As the circuit FB illustrated in FIG. 13, any of the circuits FB described above with reference to FIG. 3 to FIG. 7B can be used, for example.

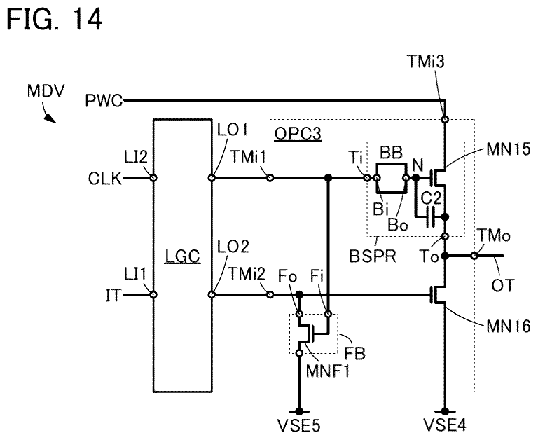

As an example, FIG. 14 illustrates a structure example in which the circuit FB of the circuit OPC1 in FIG. 3 is used as the circuit FB of the circuit OPC3 in FIG. 13.

The circuit OPC3 in FIG. 14 includes the circuit FB having the structure illustrated in FIG. 3. Thus, in the circuit OPC3 in FIG. 14, the gate of the transistor MNF1 is connected to the terminal Bi of the circuit BB and the terminal TMi1.

Next, an operation example of the circuit OPC3 in FIG. 14 is described.

For the operation of the circuit BSPR, the operation example of the circuit BSPR in FIG. 1 can be referred to. For example, when the high-level potential V_{High} is input to the terminal TMi1 of the circuit OPC3, the circuit BB outputs the potential V_{Mid} to the terminal Bo. Thus, V_{Mid} is supplied to the gate of the transistor MN15 (the first terminal of the capacitor element C1). The low-level potential V_{Low} is assumed to be supplied to the first terminal of the transistor MN15 from the terminal PWC through the terminal TMi3. The low-level potential V_{Low} is assumed to be supplied to the second terminal of the transistor MNF1 from the wiring VSE5.

At this time, the gate-source voltage (here, the gate-first terminal voltage) of the transistor MN15 is V_{Mid}−V_{Low}, whereby the transistor MN15 is in an on state. Consequently, the terminal PWC outputs the low-level potential V_{Low} to the terminal To of the circuit BSPR through the transistor MN15.

At this time, V_{High}, which is the same as the potential of the terminal TMi1 and the potential of the terminal Ti, is input to the terminal Fi of the circuit FB. In this manner, V_{Mid} is supplied to the gate of the transistor MNF1.

The transistor MNF1 is normally off and the threshold voltage of the transistor MNF1 is set to V_{th_MNF1}. The threshold voltage V_{th_MNF1} is set to satisfy V_{High}−V_{Low}>V_{th_MNF1}.

Here, the gate-source voltage (here, the gate-second terminal voltage) of the transistor MNF1 is V_{High}−V_{Low}, whereby the transistor MNF1 is in an on state. Consequently, the wiring VSE5 supplies the low-level potential V_{Low} to the gate of the transistor MN16 through the transistor MNF1. As a result, the gate-source voltage (here, the gate-second terminal voltage) of the transistor MNF16 becomes V_{Low}−V_{Low}=0, whereby the transistor MN16 is brought into an off state.

That is, the circuit MDV illustrated in FIG. 13 and FIG. 14 has a structure in which the low-level potential V_{Low} is supplied to the gate of the transistor MN16 when the high-level potential V_{High} is supplied to each of the terminal TMi1 and the terminal Ti.

Next, the potential supplied to the first terminal of the transistor MN15 from the terminal PWC through the terminal TMi3 is changed from the low-level potential V_{Low} to the high-level potential V_{High}; for such a case, the description of the operation example of the retention circuit in FIG. 10 can be referred to.

Since the transistor MNF1 is brought into an on state when the potential of each of the terminal TMi1 and the terminal Ti becomes the high-level potential V_{High}, V_{Low} is continuously input to the gate of the transistor MN16. Thus, the circuit FB can make the transistor MN16 in an off state all the time. In addition, since the gate of the transistor MN16 is not in a floating state, the potential of the gate of the transistor MN16 immediately returns to the low-level potential VL_{ow} even when the potential of the gate of the transistor MN16 is changed by noise or the like. This almost eliminates the leakage of electric charge in the terminal TMo, thereby stabilizing the potential of the terminal TMo and accordingly stabilizing the potential of the terminal To.

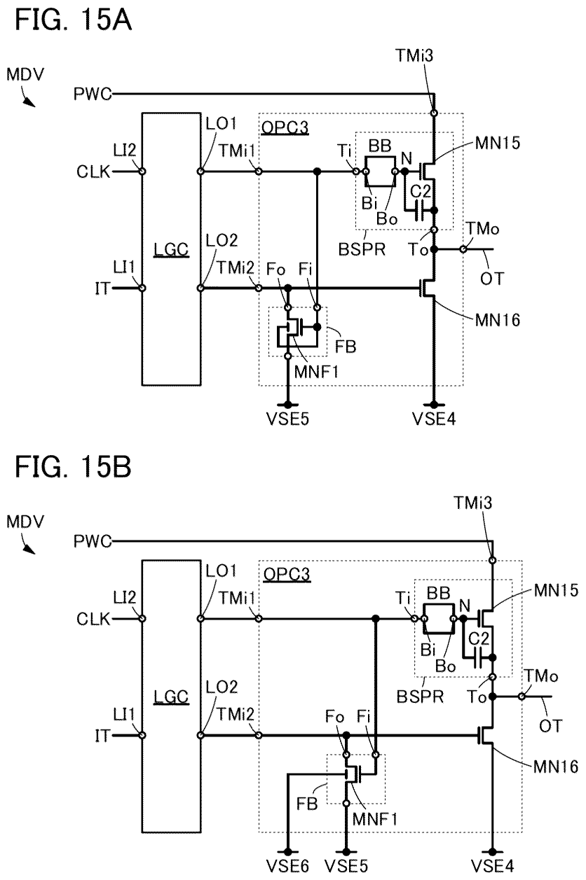

Note that in the semiconductor device of one embodiment of the present invention, the structure of the circuit MDV is not limited to that illustrated in FIG. 14. The semiconductor device of one embodiment of the present invention may have a structure in which, for example, the transistor MNF1 in the circuit FB includes the gate and the back gate as illustrated in each of FIG. 15A and FIG. 15B.

Note that like the circuit FB illustrated in FIG. 4A, the circuit FB in FIG. 15A includes the transistor MNF1 including the gate and the back gate which are electrically connected to each other, and like the circuit FB illustrated in FIG. 4B, the circuit FB in FIG. 15B includes the transistor MNF1 including the back gate connected to the wiring VSE6.

Thus, the description of FIG. 4A can be referred to for the structure and operation of the circuit FB in FIG. 15A. The description of FIG. 4B can be referred to for the structure and operation of the circuit FB in FIG. 15B.

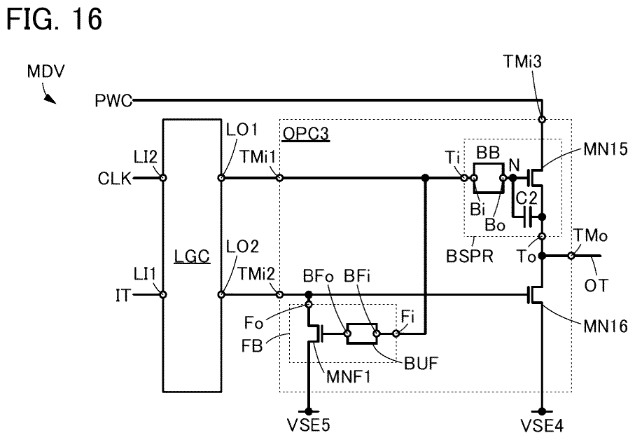

The semiconductor device of one embodiment of the present invention may have a structure in which, for example, the circuit FB includes the circuit BUF as illustrated in FIG. 16. The circuit FB in FIG. 16 has a structure similar to that of the circuit FB in FIG. 5. Thus, the description of FIG. 5 can be referred to for the structure and operation of the circuit FB in FIG. 16. For example, the circuit BUF illustrated in FIG. 6A, the circuit BUF illustrated in FIG. 6B, the circuit BUF illustrated in FIG. 7A, or the circuit BUF illustrated in FIG. 7B can be used as the circuit BUF included in the circuit FB in FIG. 16.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 2

In this embodiment, a layout example of the retention circuit described in the above embodiment will be described.

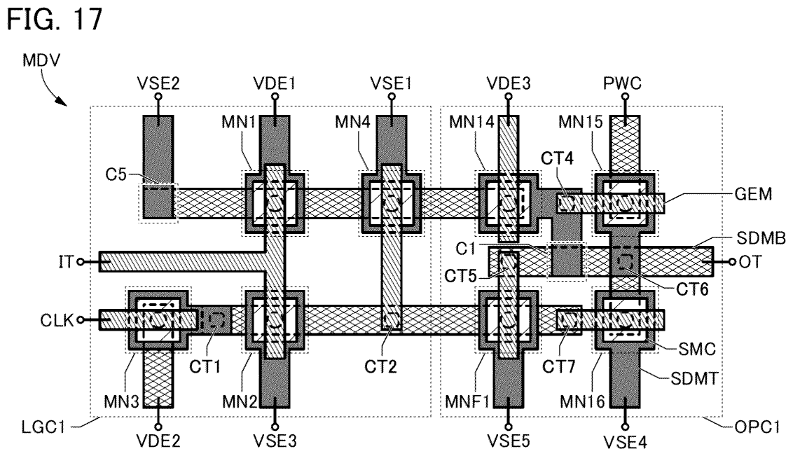

FIG. 17 is a layout diagram (plan view) of the circuit MDV illustrated in FIG. 1, and FIG. 17 illustrates the circuit LGC1 and the circuit OPC1. In FIG. 17, the circuit BB illustrated in FIG. 8A is used as the circuit BB of the circuit MDV in FIG. 1. Thus, in the layout diagram of FIG. 17, the transistor MN14 is illustrated as the transistor MNa illustrated in FIG. 8A. In FIG. 17, the circuit FB illustrated in FIG. 3 is used as the circuit FB of the circuit MDV in FIG. 1. Thus, the layout diagram of FIG. 17 illustrates the transistor MNF1.

Note that in the layout diagram of FIG. 17, the transistor MN1 to the transistor MN4, the transistor MN14 to the transistor MN16, and the transistor MNF1 each have a structure of a vertical-channel-type transistor described in Embodiment 5. Thus, cross-sectional structures of the transistor MN1 to the transistor MN4, the transistor MN14 to the transistor MN16, and the transistor MNF1 are described in detail in Embodiment 5.

In FIG. 17, the circuit MDV includes a conductive layer GEM, a conductive layer SDMB, a conductive layer SDMT, and a semiconductor layer SMC. Note that an insulating layer included in the circuit MDV is not illustrated in FIG. 17.

The semiconductor layer SMC is positioned below the conductive layer GEM, for example. The conductive layer SDMT is positioned below the semiconductor layer SMC, for example. The conductive layer SDMB is positioned below the conductive layer SDMT, for example. That is, in the circuit MDV in FIG. 17, the conductive layer SDMB, the conductive layer SDMT, the semiconductor layer SMC, and the conductive layer GEM are formed in this order from the bottom.

Part of the conductive layer GEM functions as the gates (sometimes referred to as first gates) of the transistor MN1 to the transistor MN4, the transistor MN14 to the transistor MN16, and the transistor MNF1, for example.

Part of the conductive layer SDMT functions as the sources or drains of the transistor MN1 to the transistor MN4, the transistor MN14 to the transistor MN16, and the transistor MNF1, for example.

Part of the conductive layer SDMB functions as the sources or drains of the transistor MN1 to the transistor MN4, the transistor MN14 to the transistor MN16, and the transistor MNF1, for example.

The conductive layer SDMB, the conductive layer SDMT, the semiconductor layer SMC, and the conductive layer GEM can be formed by a lithography method, for example. Specifically, for example, in the case where the conductive layer GEM is formed, a conductive material to be the conductive layer GEM is formed by one or more methods selected from a sputtering method, a CVD (Chemical Vapor Deposition) method, a PLD (Pulsed Laser Deposition) method, and an ALD (Atomic Layer Deposition) method, and then a desired pattern is formed by a lithography method. The conductive layer SDMB, the conductive layer SDMT, and the semiconductor layer SMC can also be formed in a manner similar to the above.

Insulating layers may be provided between the semiconductor layer SMC and the conductive layer GEM, between the conductive layer GEM and the conductive layer SDMT, and between the conductive layer SDMB and the conductive layer SDMT. In particular, an insulator provided between the semiconductor layer SMC and the conductive layer GEM functions as a gate insulating film (sometimes referred to as a first gate insulating film, a front gate insulating film, or the like) in some cases.

In a region CT1 and a region CT6 where part of the conductive layer SDMB and part of the conductive layer SDMT overlap with each other, electrical continuity is established between the part of the conductive layer SDMB and the part of the conductive layer SDMT. Specifically, for example, an opening is formed in the region CT1 and the region CT6, and a conductive layer functioning as a plug or a wiring is embedded in the opening. As a result, electrical continuity is established between the conductive layer SDMT included in the transistor MN3 and the conductive layer SDMB included in the transistor MN4 and the transistor MNF1. In addition, electrical continuity is established between the conductive layer SDMT included in the transistor MN15 and the conductive layer SDMB included in the transistor MN16.

In a region CT2, a region CT5, and a region CT7 where part of the conductive layer SDMB and part of the conductive layer GEM overlap with each other, electrical continuity is established between the part of the conductive layer SDMB and the part of the conductive layer GEM. Specifically, for example, an opening is formed in the region CT2, the region CT5, and the region CT7, and a conductive layer functioning as a plug or a wiring is embedded in the opening. As a result, electrical continuity is established between the conductive layer SDMB included in the transistor MN2 and the transistor MNF1 and the conductive layer GEM included in the transistor MN4, and electrical continuity is established between the conductive layer SDMB included in the transistor MN2 and the transistor MNF1 and the conductive layer GEM included in the transistor MN16. In addition, electrical continuity is established between the conductive layer SDMB included in the transistor MN16 and the conductive layer GEM included in the transistor MNF1.

In a region CT4 where part of the conductive layer SDMT and part of the conductive layer GEM overlap with each other, electrical continuity is established between the part of the conductive layer SDMT and the part of the conductive layer GEM. Specifically, for example, an opening is formed in the region CT4, and a conductive layer functioning as a plug or a wiring is embedded in the opening. As a result, electrical continuity is established between the conductive layer SDMT included in the transistor MN14 and the conductive layer GEM included in the transistor MN15.

The capacitor element C1 and the capacitor element C5 illustrated in FIG. 17 each include part of the conductive layer SDMB and part of the conductive layer SDMT. Specifically, each of the capacitor element C1 and the capacitor element C5 includes a region where part of the conductive layer SDMB and part of the conductor SDMT overlap with each other. That is, in each of the capacitor element C1 and the capacitor element C5, the part of the conductive layer SDMB serves as one of a pair of electrodes, and the part of the conductor SDMT serves as the other of the pair of electrodes.

Note that the layout diagram of the semiconductor device of one embodiment of the present invention is not limited to FIG. 17. The layout diagram of the display apparatus of one embodiment of the present invention may be FIG. 17 that has been changed as appropriate.

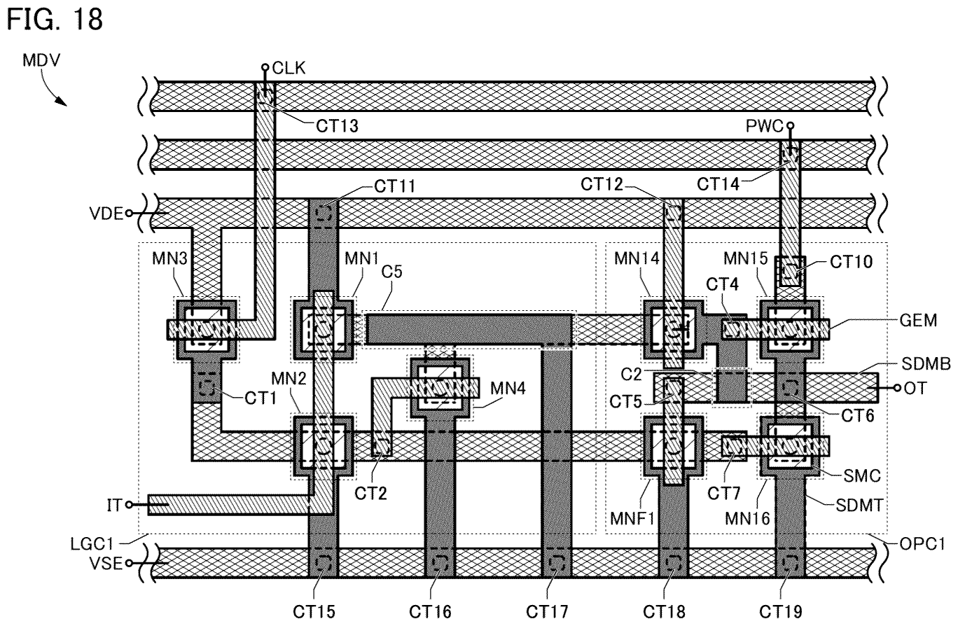

For example, the layout diagram of the circuit MDV in FIG. 17 can be changed into the layout diagram illustrated in FIG. 18. FIG. 18 is an example of the layout diagram of the circuit MDV of the case where the wiring VDE1 to the wiring VDE3 are combined into one wiring VDE and the wiring VSE1 to the wiring VSE5 are combined into one wiring VSE in the layout diagram of FIG. 17. In the layout diagram of FIG. 18, a wiring connected to the terminal PWC and a wiring connected to the terminal CLK are provided to extend in the same direction as the wiring VDE and the wiring VSE.

As illustrated in FIG. 18, the conductive layer SDMB included in the transistor MN3 has a function of the wiring VDE and thus is provided to extend on the left and right sides of the drawing. The conductive layer SDMB includes a region overlapping with the conductive layer SDMT included in the transistor MN1 and the conductive layer GEM included in the transistor MN14; in particular, electrical continuity is established between the conductive layer SDMB and the conductive layer SDMT included in the transistor MN1 in a region CT11 where they overlap with each other, and electrical continuity is established between the conductive layer SDMB and the conductive layer GEM included in the transistor MN14 in a region CT12 where they overlap with each other.

In FIG. 18, electrical continuity is established between the conductive layer SDMB having a function of a wiring connected to the terminal CLK and the conductive layer GEM part of which is included in the conductive layer MN3 in a region CT13 where they overlap with each other.

In FIG. 18, the conductive layer SDMB part of which is included in the transistor MN15 and the conductive layer SDMB having a function of a wiring connected to the terminal PWC include regions overlapping with the conductive layer SDMT. In particular, electrical continuity is established between the conductive layer SDMB part of which is included in the transistor MN15 and the conductive layer SDMT in a region CT10 where they overlap with each other. Electrical continuity is established between the conductive layer SDMB having a function of a wiring connected to the terminal PWC and the conductive layer SDMT in a region CT14 where they overlap with each other.

In FIG. 18, the conductive layer SDMT part of which is included in the transistor MN2, the conductive layer SDMT part of which is included in the transistor MN4, the conductive layer SDMT part of which is included in the transistor MNF1, the conductive layer SDMT part of which is included in the transistor MN16, and the conductive layer SDMT part of which has a function of the second terminal of the capacitor element C5 each include a region overlapping with the conductive layer SDMB having a function of the wiring VSE. In particular, electrical continuity is established between the conductive layer SDMT part of which is included in the transistor MN2 and the conductive layer SDMB in a region CT15 where they overlap with each other. Similarly, electrical continuity is established between the conductive layer SDMT part of which is included in the transistor MN4 and the conductive layer SDMB in a region CT16 where they overlap with each other. Electrical continuity is established between the conductive layer SDMT part of which has a function of the second terminal of the capacitor element C5 and the conductive layer SDMB in a region CT17 where they overlap with each other. Electrical continuity is established between the conductive layer SDMT part of which is included in the transistor MNF1 and the conductive layer SDMB in a region CT18 where they overlap with each other. Electrical continuity is established between the conductive layer SDMT part of which is included in the transistor MN16 and the conductive layer SDMB in a region CT19 where they overlap with each other.

When the wiring connected to the terminal PWC, the wiring connected to the terminal CLK, the wiring VDE, and the wiring VSE are provided to extend in the same direction as illustrated in the layout diagram of FIG. 18, a plurality of circuits MDV can be easily connected in series. For example, as described later in Embodiment 4, a plurality of circuits MDV need to be connected in series to form a shift register, which means that extending the wiring VDE, the wiring VSE, the wiring connected to the terminal CLK, and the wiring connected to the terminal PWC in the same direction as illustrated in FIG. 18 is suitable for formation of a shift register. In addition, extending the wiring VDE, the wiring VSE, the wiring connected to the terminal CLK, and the wiring connected to the terminal PWC in the same direction can reduce the circuit area in some cases.

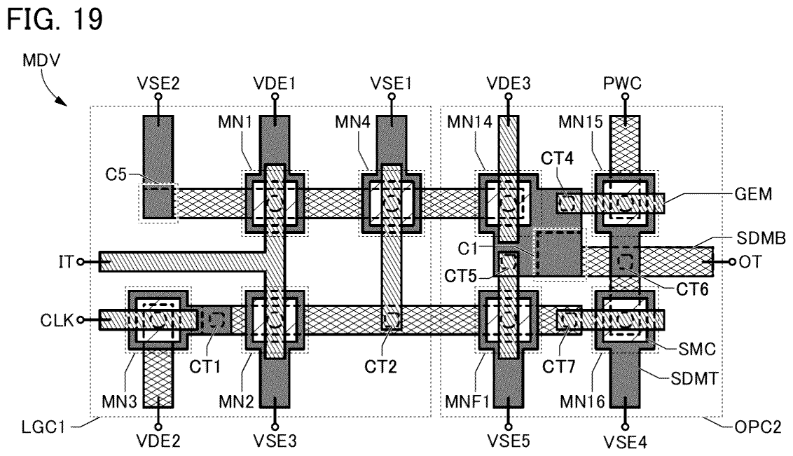

For example, the layout diagram of the circuit MDV in FIG. 17 can be changed into the layout diagram illustrated in FIG. 19. The circuit MDV in FIG. 19 is a layout diagram in which the circuit OPC1 of the circuit MDV in FIG. 17 is changed into the circuit OPC2 illustrated in FIG. 9. In FIG. 19, the circuit FB illustrated in FIG. 10 is used as the circuit FB of the circuit MDV in FIG. 9.

Thus, the layout diagram in FIG. 19 is different from the layout diagram in FIG. 17 in that in the region CT5, electrical continuity is established between part of the conductive layer GEM included in the transistor MNF1 and part of the conductive layer SDMT included in the transistor MN14 and electrical continuity is not established between part of the conductive layer GEM included in the transistor MNF1 and part of the conductive layer SDMB included in the transistor MN16.

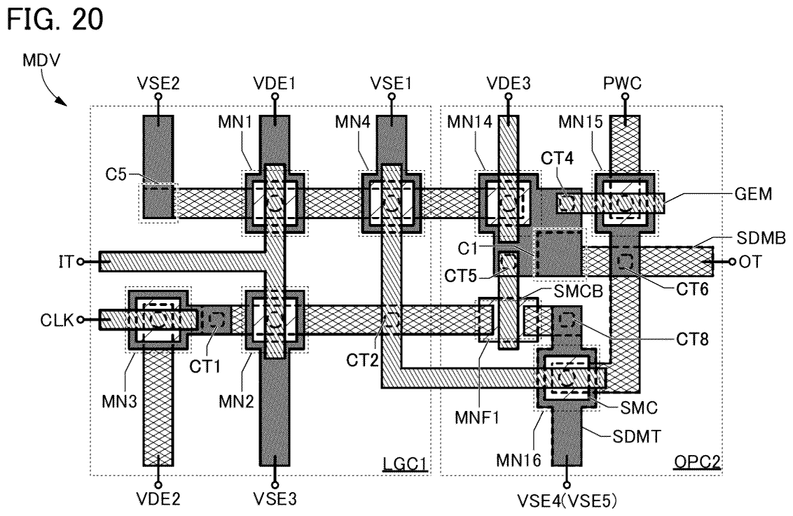

The layout diagram illustrated in FIG. 19 may be changed into the layout diagram illustrated in FIG. 20. The layout diagram of FIG. 20 is different from the layout diagram of FIG. 19 in that two conductive layers SDMT connected to the wiring VSE4 and the wiring VSE5 are combined into one, and that the transistor MN16 is not a vertical-channel-type transistor but a transistor with a TGSA structure. Note that the transistor with a TGSA structure is described in Embodiment 4.

In the layout diagram illustrated in FIG. 20, the circuit MDV includes a semiconductor layer SMCB that is different from the semiconductor layer SMC. The semiconductor layer SMCB is a semiconductor layer including a channel formation region of the transistor MN16 and is positioned below the conductive layer SDMB in the layout diagram of FIG. 20. Note that the top surface of the semiconductor layer SMCB includes a region in contact with the conductive layer SDMB.

The conductive layer GEM having a function of the gate of the transistor MNF1 is connected to the conductive layer SDMT, part of which is included in the transistor MN14, through the region CT5. The conductive layer SDMB having a function of one of the source and the drain of the transistor MNF1 can be the same layer as the conductive layer SDMT part of which is included in the transistor MN2. The conductive layer SDMB having a function of the other of the source and the drain of the transistor MNF1 includes a region overlapping with the conductive layer SDMT part of which is included in the transistor MN16. In particular, electrical continuity is established between the conductive layer SDMB having a function of the other of the source and the drain of the transistor MNF1 and the conductive layer SDMT part of which is included in the transistor MN16 in a region CT8 where they overlap with each other.

The conductive layer GEM part of which is included in the transistor MN4 is the same as the conductive layer GEM part of which is included in the transistor MN16.

The transistor with a TGSA structure as in the layout diagram can have higher withstand voltage to the gate potential than a vertical-channel-type transistor. In particular, the potential of the gate of the transistor MNF1 is increased by bootstrap in the capacitor element C1, which means that the transistor with a TGSA structure having high withstand voltage to the gate potential is suitably used as the transistor MNF1.

Note that other than the transistor with a TGSA structure, a VLFET can be used as the transistor MNF1, for example. Note that the VLFET is described in Embodiment 4.

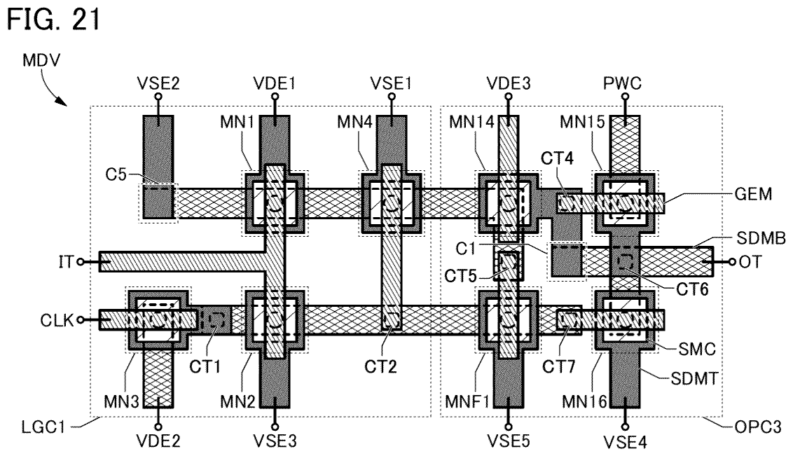

For example, the layout diagram of the circuit MDV in FIG. 17 can be changed into the layout diagram illustrated in FIG. 21. The circuit MDV in FIG. 21 is a layout diagram in which the circuit OPC1 of the circuit MDV in FIG. 17 is changed into the circuit OPC3 illustrated in FIG. 13. In FIG. 21, the circuit FB illustrated in FIG. 14 is used as the circuit FB of the circuit MDV in FIG. 13.

Thus, the layout diagram in FIG. 19 is different from the layout diagram in FIG. 17 in that in the region CT5, electrical continuity is established between part of the conductive layer GEM included in the transistor MNF1 and part of the conductive layer SDMB included in the transistor MN14 and electrical continuity is not established between part of the conductive layer GEM included in the transistor MNF1 and part of the conductive layer SDMB included in the transistor MN16.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 3

In this embodiment, a structure example of the retention circuit, which is the semiconductor device of one embodiment of the present invention and is different from the retention circuit described in Embodiment 1, will be described. Like the retention circuit described in Embodiment 1, the retention circuit described in this embodiment can be used for the shift register described in Embodiment 4.

### <Structure Example 1 of Retention Circuit>

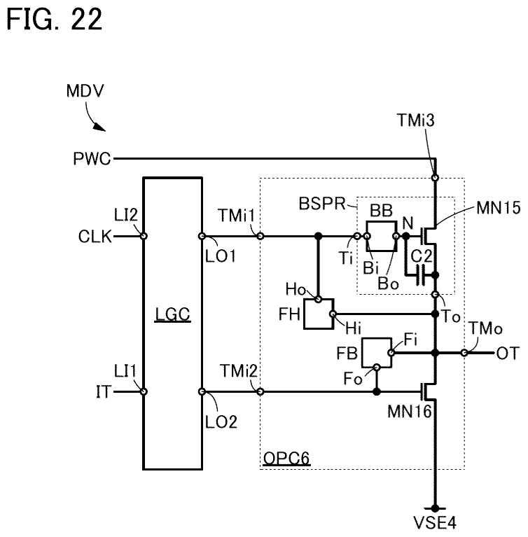

The circuit MDV illustrated in FIG. 22 is a retention circuit including the circuit LGC and a circuit OPC6. The circuit OPC6 is a modification example of the circuit OPC1 illustrated in FIG. 1, and is different from the circuit OPC1 in FIG. 1 in that a circuit FH is additionally provided. Note that the circuit LGC in FIG. 22 corresponds to the circuit LGC1 illustrated in FIG. 1.

The circuit FH includes a terminal Hi and a terminal Ho, for example.

The terminal Hi of the circuit FH is connected to the terminal To of the circuit BSPR, the terminal TMo of the circuit OPC6, the terminal Fi of the circuit FB, and the first terminal of the transistor MN16. The terminal Ho of the circuit FH is connected to the terminal Ti of the circuit BSPR and the terminal TMo of the circuit OPC6.

The circuit FH has a function of obtaining a potential output from the terminal To of the circuit BSPR and supplying a fixed potential to the terminal Ti of the circuit BSPR, for example. That is, the circuit FH can be regarded as a circuit that supplies feedback to the circuit BSPR on the basis of the potential output from the terminal To of the circuit BSPR. Specifically, for example, the circuit FH can have a structure in which a fixed potential (e.g., the high-level potential V_{High}) is output to the terminal Ho when the high-level potential V_{High} is input to the terminal Hi.

When the circuit FH has the above structure and the high-level potential V_{High} is output from the terminal To of the circuit BSPR, for example, a fixed potential output from the terminal Ho of the circuit FH is supplied to the terminal Ti of the circuit BSPR. Thus, for example, even when the amount of off-state current flowing between the source and the drain or the amount of leakage current flowing between the gate and the source or between the gate and the drain becomes large in the transistor for retaining the potential of the terminal Ti (the terminal TMi), the potential of the terminal Ti (the terminal TMi) remains a fixed potential supplied from the circuit FH. When a noise signal is input to the terminal Ti (the terminal TMi), the potential of the terminal Ti (the terminal TMi) remains a fixed potential supplied from the circuit FH. Accordingly, the potential of the terminal To of the circuit BSPR does not change due to the above-described factors, so that the potential of the node N is less likely to be affected. Thus, the potential output from the terminal To of the circuit BSPR is stabilized.

Here, an operation example of the circuit BSPR in FIG. 22 is described. The high-level potential V_{High} is assumed to be supplied to the first terminal of the transistor MN15 from the terminal PWC through the terminal TMi3. The low-level potential V_{Low} is assumed to be supplied to the second terminal of the transistor MN16 from the wiring VSE4.

For output of the high-level potential V_{High} from the terminal TMo of the circuit OPC6, the low-level potential V_{Low} is first input to the terminal TMi2 to bring the transistor MN16 into an off state. Then, the high-level potential V_{High} is input to the terminal TMi1, whereby the high-level potential V_{High} is output from the terminal TMo. For the output operation of the high-level potential V_{High} from the terminal TMo, the operation example of the circuit OPC1 in FIG. 1 can be referred to.

Then, for output of the low-level potential V_{Low} from the terminal TMo of the circuit OPC6, the high-level potential V_{High} is input to the terminal TMi2 to bring the transistor MN16 into an on state. Thus, electrical continuity is established between the terminal TMo and the wiring VSE4, so that electric charge accumulated in the terminal TMo flows to the wiring VSE4, which makes the potential of the terminal TMo become the low-level potential V_{Low}. At this time, the low-level potential V_{Low} is supplied to the terminal TMi1 so that the potential of the gate of the transistor MN15 is set to the low-level potential V_{Low}, whereby the transistor MN15 is brought into an off state and electrical continuity is not established between the terminal PWC and the terminal TMo; hence, the potential of the terminal TMo can steeply drop to the low-level potential V_{Low}.

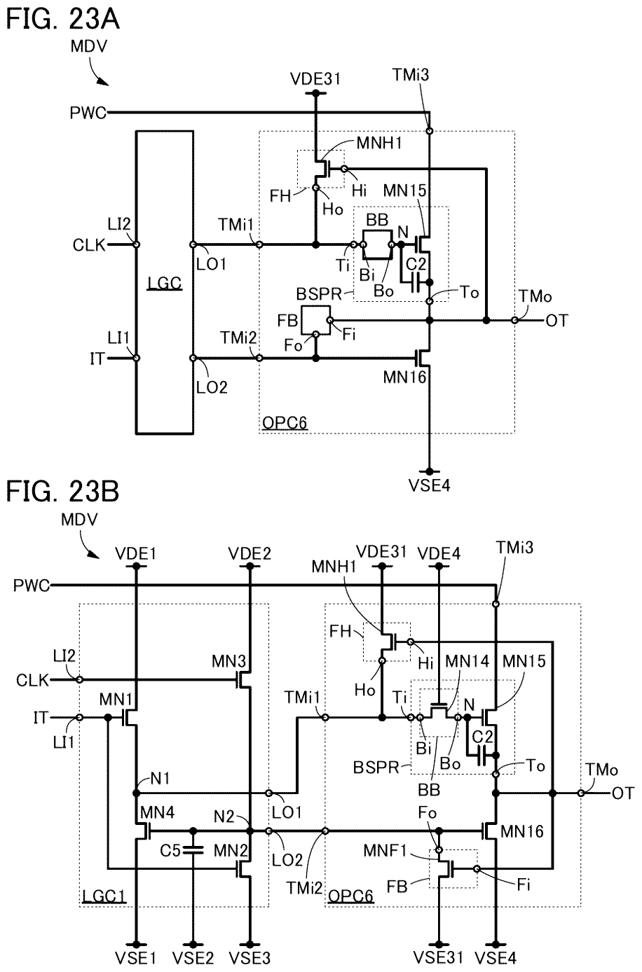

Next, a specific structure example of the circuit FH included in the circuit OPC6 illustrated in FIG. 22 is described. FIG. 23A is a circuit diagram of the circuit MDV showing a specific example of the circuit FH illustrated in FIG. 22. As illustrated in FIG. 23A, the circuit FH includes a transistor MNH1.

As the transistor MNH1, for example, the transistors that can be used as the transistor MN1 to the transistor MN4, the transistor MN15, and the transistor MN16 described in Embodiment 1 can be used.

A gate of the transistor MNH1 is connected to the terminal Hi of the circuit FH, a first terminal of the transistor MNH1 is connected to a wiring VDE31, and a second terminal of the transistor MNH1 is connected to the terminal Ho.

The wiring VDE31 has a function of a wiring for supplying a fixed potential, for example. The fixed potential can be a high-level potential, for example. The wiring VDE31 may have a function of a wiring for supplying not a fixed potential but a variable potential (sometimes referred to as a pulse voltage, a pulse potential, a pulse signal, a clock signal, or the like).

Here, an operation example of a circuit BSFB1 in FIG. 23A is described.

For the operation of the circuit BSPR, the operation example of the circuit BSPR in FIG. 1 can be referred to. For example, when the high-level potential V_{High} is input to the terminal TMi1 of the circuit OPC1, the circuit BB outputs the potential V_{Mid} to the terminal Bo. Thus, V_{Mid} is supplied to the gate of the transistor MN15 (the first terminal of the capacitor element C2). The low-level potential V_{Low} is assumed to be supplied to the first terminal of the transistor MN15 from the terminal PWC. The high-level potential V_{High} is assumed to be supplied to the first terminal of the transistor MNH1 from the wiring VDE31.

At this time, the gate-source voltage (the gate-first terminal voltage at this timing) of the transistor MN15 is V_{Mid}−V_{Low}, whereby the transistor MN15 is in an on state. Consequently, the low-level potential V_{Low} of the terminal PWC is output to the terminal To of the circuit BSPR through the transistor MN15.

Thus, V_{Low}, which is the same as the potential of the terminal To, is input to the terminal Hi of the circuit FH. In this manner, the low-level potential V_{Low} is supplied to the gate of the transistor MNH1.

The transistor MNF1 is normally off and the threshold voltage of the transistor MNF1 is set to V_{th_MNH1}. The threshold voltage V_{th_MNH1} is set to satisfy V_{High}−V_{Low}>V_{th_MNH1}.

The gate-source voltage (here, the gate-first terminal voltage) of the transistor MNH1 is V_{Low}−V_{High}<V_{th_MNH1}, the transistor MNH1 is in an off state.

Next, the potential supplied to the first terminal of the transistor MN15 from the terminal PWC is assumed to change from the low-level potential V_{Low} to the high-level potential V_{High}. In addition, the nodeN is assumed to be brought into a floating state by the circuit BB. At this time, the gate-source voltage (here, the gate-second terminal voltage) of the transistor MN15 is V_{Mid}−V_{Low}, whereby the transistor MN15 is in an on state. Consequently, current flows from the terminal PWC to the terminal To of the circuit BSPR through the transistor MN15, which renders the potential of the terminal To higher than V_{Low}. Note that since the nodeN is in a floating state, the capacitive coupling with the capacitor element C2 causes an increase in the potential of the node N from V_{Mid} in response to the increase in the potential of the terminal To. Accordingly, the gate-source voltage of the transistor MN15 is retained by the capacitor element C2, whereby the potential of the terminal To increases to V_{High}. Ideally, the potential of the node N becomes V_{Mid}+V_{High}−V_{Low}.

At this time, V_{High}, which is the same as the potential of the terminal To, is input to the terminal Hi of the circuit FH. In this manner, the high-level potential V_{High} is Supplied to the gate of the transistor MNH1.

Here, the gate-source voltage of the transistor MNH1 (here, the gate-second terminal voltage) is, for example, V_{High}−V_{High}=0. Since the transistor MNH1 is normally off, the transistor MNH1 is in an off state.

In this state, when the potential of the terminal Ti of the circuit BSPR (the second terminal of the transistor MNH1) decreases from the high-level potential V_{High} and the gate-first terminal voltage of the transistor MNH1 becomes higher than the threshold voltage, the transistor MNH1 is brought into an on state. At this time, electric charge from the wiring VDE31 is accumulated in the terminal Ti of the circuit BSPR, and the potential of the terminal Ti of the circuit BSPR increases. Specifically, the transistor MNH1 is brought into an off state when the gate-source voltage of the transistor MNH1 becomes V_{th_MNH1}; thus, the potential of the terminal Ti of the circuit BSPR (the second terminal of the transistor MNH1) at this time is V_{High}−V_{th_MNH1}.

As described above, in the circuit OPC6, when the high-level potential V_{High} is output from the terminal TMo and the potential of the terminal Ti of the circuit BSPR decreases, the circuit FH can supply the potential V_{High}−V_{th_MNH1} to the terminal Ti. Thus, the potential of the terminal Ti is almost kept at V_{High}−V_{th_MNH1}, whereby the potential output from the terminal To of the circuit BSPR is stabilized.

FIG. 23B is a specific structure example of the circuit MDV in FIG. 22, in which the circuit LGC1 illustrated in FIG. 1 is used as the circuit LGC, the circuit FH illustrated in FIG. 23A is used as the circuit FH, the circuit FB illustrated in FIG. 3 is used as the circuit FB, and the circuit BB in FIG. 8A is used as the circuit BB. Note that in the circuit BB in FIG. 23B, the transistor MN14 corresponds to the transistor MNa illustrated in FIG. 8A, and a wiring VDE4 corresponds to the wiring VAL2 illustrated in FIG. 8A. In FIG. 23B, the description of the circuit MDV in FIG. 1 can be referred to for the operation example of the circuit LGC1, the operation example of the circuit FB in FIG. 3 can be referred to for the operation example of the circuit FB, and the operation example of the circuit BB in FIG. 8A can be referred to for the operation example of the circuit BB.

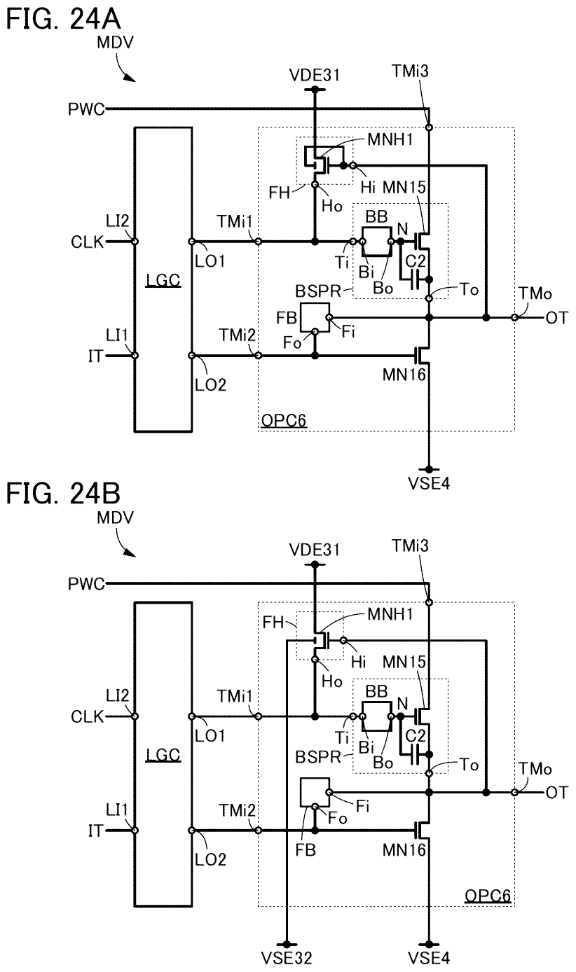

Note that in the semiconductor device of one embodiment of the present invention, the circuit MDV is not limited to that illustrated in FIG. 23A. In the semiconductor device of one embodiment of the present invention, for example, the transistor MNH1 included in the circuit FH can be not a single-gate transistor but a transistor with a back gate as in the circuit MDV illustrated in FIG. 24A or FIG. 24B.

In FIG. 24A, the back gate of the transistor MNH1 is connected to the terminal Hi of the circuit FH. In particular, the back gate of the transistor MNH1 is preferably electrically connected to the gate of the transistor MNH1.

When the gate and the back gate of the transistor are electrically connected to each other, the on-state current of the transistor can be increased. That is, electrically connecting the gate and the back gate of the transistor MNH1 in the circuit FH can increase the on-state current that flows when the transistor MNH1 is in an on state. This can increase the speed at which the potential of the terminal TMi changes to a potential (e.g., V_{High}−V_{th_MNH1}) output from the terminal Ho of the circuit FH.

In FIG. 24B, the back gate of the transistor MNH1 is connected to a wiring VSE32.

Like the wiring VSE4, the wiring VSE32 has a function of a wiring for supplying a fixed potential, for example. An example of the fixed potential is a low-level potential, a ground potential, and a negative potential. Other examples of the fixed potential include a high-level potential. Depending on the situation, the wiring VSE32 may have a function of a wiring for supplying a variable potential.

As described above, when a low-level potential is input from the wiring VSE32 to the back gate of the transistor MNH1, for example, the threshold voltage of the transistor MNH1 increases. This enables the transistor MNH1 to be normally off, whereby the off-state current flowing between the source and the drain of the transistor MNH1 can be reduced.

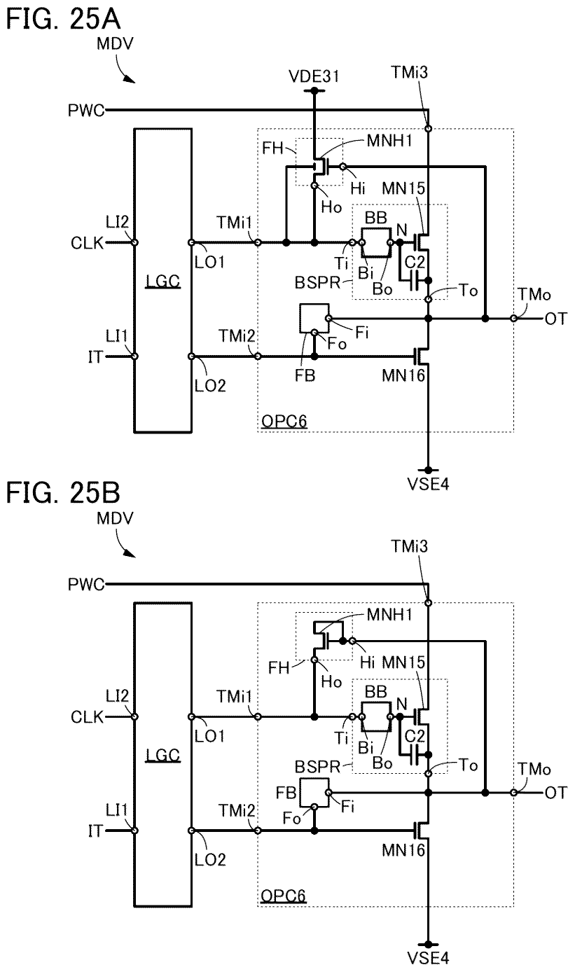

The circuit OPC6 illustrated in FIG. 25A has a structure in which the back gate of the transistor MNH1 included in the circuit FH is connected to the terminal TMi of the circuit OPC6, the terminal Ho of the circuit FH, and the terminal Ti of the circuit BSPR.

In the transistor MNH1 of the circuit OPC6 in FIG. 25A, when the low-level potential V_{Low} is input to the terminal TMi, the low-level potential V_{Low} is input to the back gate of the transistor MNH1, so that the threshold voltage of the transistor MNH1 is increased. In the case where the low-level potential V_{Low} is output from the terminal TMo at this time, the low-level potential V_{Low} is input to the gate of the transistor MNH1; thus, the transistor MNH1 is brought into an off state, and the off-state current flowing between the source and the drain of the transistor MNH1 at this time can be reduced.

In the transistor MNH1 of the circuit OPC6 in FIG. 25A, when the high-level potential V_{High} is input to the terminal TMi, the high-level potential V_{High} is input to the back gate of the transistor MNH1, so that the threshold voltage of the transistor MNH1 is decreased. In the case where the high-level potential V_{High} is output to the terminal TMo at this time by the operation of the circuit BSPR, the high-level potential V_{High} is input to the gate of the transistor MNH1; thus, the transistor MNH1 is brought into an on state. The amount of on-state current flowing between the source and the drain of the transistor MNH1 at this time is increased because the high-level potential V_{High} is input to the back gate of the transistor MNH1. This can increase the speed at which the potential of the terminal TMi changes to a potential (e.g., V_{High}−V_{th_MNH1}) output from the terminal Ho of the circuit FH.

The circuit OPC6 illustrate in FIG. 25B has a structure in which the second terminal of the transistor MNH1 is connected to the terminal Hi of the circuit FH. In particular, the second terminal of the transistor MNH1 is preferably electrically connected to the gate of the transistor MNH1.

In the case where the high-level potential V_{High} is input to the gate of the transistor MNH1 (in the case where the high-level potential V_{High} is output from the terminal To of the circuit BSPR), the transistor MNH1 is brought into an on state when the potential of the first terminal of the transistor MNH1 is lower than V_{High}−V_{th_MNH1}. At this time, current output from the terminal To flows to the terminal TMi through the circuit FH and the source-drain of the transistor MNH1. When current flows to the terminal TMi and the potential of the first terminal of the transistor MNH1 becomes V_{High}−V_{th_MNH1}, the transistor MNH1 is brought into an off state.

Even when the circuit OPC6 illustrated in FIG. 25B is used, as in the circuit OPC1 illustrated in FIG. 22, the potential output from the terminal To of the circuit BSPR is converted (amplified) by the circuit FH to be fed back to the terminal Ti side of the circuit BSPR.

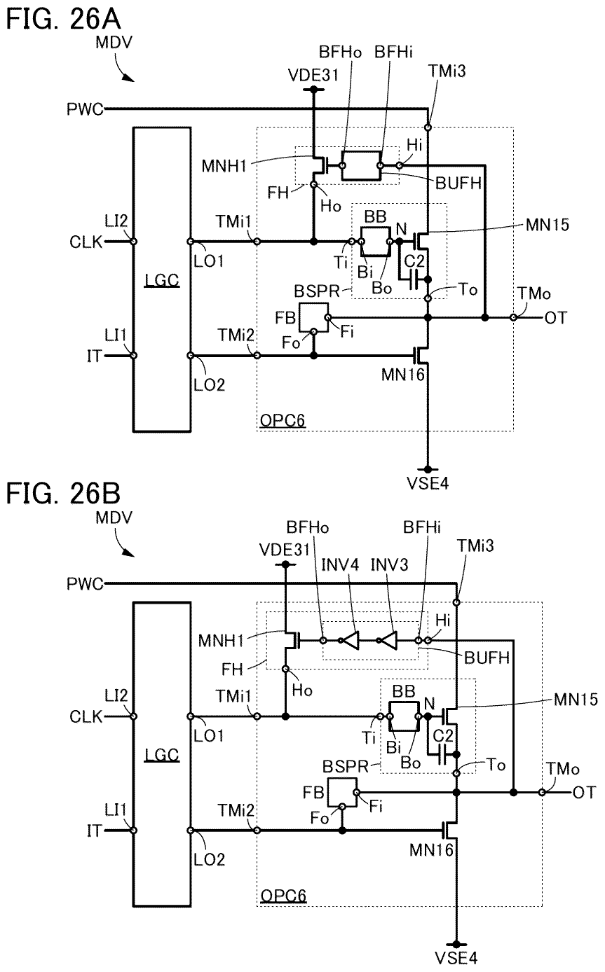

The circuit OPC6 illustrated in FIG. 26A has a structure in which the circuit FH is provided with a circuit BUFH. The circuit BUFH includes a terminal BFHi and a terminal BFHo, the terminal BFHi of the circuit BUFH is connected to the terminal Hi, and the terminal BFHo of the circuit BUFH is connected to the gate of the transistor MNH1.

The circuit BUFH has a function of amplifying a potential input to the terminal BFHi and outputting the amplified potential to the terminal BFHo, for example. In particular, here, the circuit BUFH functions as a buffer circuit.

When the circuit BUFH is used as a buffer circuit in the circuit OPC6 in FIG. 26A, a stable fixed potential can be supplied to the gate of the transistor MNH1 even when the potential output from the terminal TMo is slightly changed by a noise signal or the like, for example.

Thus, as the circuit BUFH illustrated in FIG. 26A, the circuit that can be used as the circuit BUF in FIG. 5 described in Embodiment 1 can be used.

For example, FIG. 26B illustrates a structure in which the circuit BUF in FIG. 6A is used as the circuit BUFH in FIG. 26A. Note that FIG. 26B also illustrates components such as the circuit BSPR, the terminal TMi, and the terminal TMo to show the connection structure.

In the circuit OPC6 illustrated in FIG. 26B, the circuit BUFH includes a logic circuit INV3 and a logic circuit INV4. Note that the logic circuit INV3 corresponds to the logic circuit INV1 illustrated in FIG. 6A, and the logic circuit INV4 corresponds to the logic circuit INV2 illustrated in FIG. 6A.

An input terminal of the logic circuit INV3 is electrically connected to the terminal BFHi, an output terminal of the logic circuit INV3 is electrically connected to an input terminal of the logic circuit INV4, and an output terminal of the logic circuit INV4 is electrically connected to the terminal BFHo.

For the logic circuit INV3 and the logic circuit INV4, the description of the logic circuit INV1 and the logic circuit INV2 illustrated in FIG. 6A can be referred to. For example, the structures of the logic circuit INV1 and the logic circuit INV2 illustrated in FIG. 6B can be used for the structures of the logic circuit INV3 and the logic circuit INV4 in FIG. 26B.

The circuit BUF illustrated in FIG. 7A or FIG. 7B can be used as the circuit BUFH in FIG. 26A.

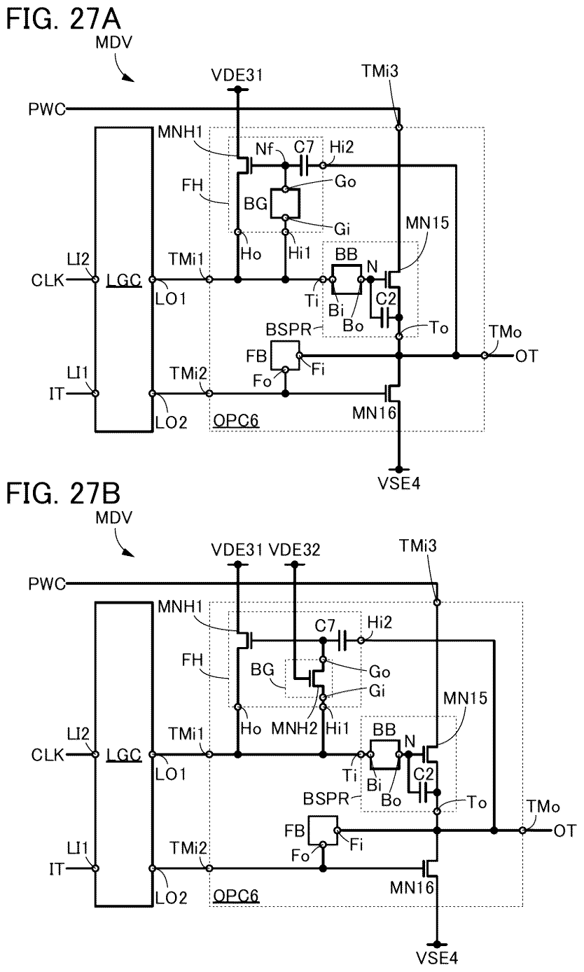

Like the circuit FH illustrated in FIG. 22, the circuit FH included in the circuit OPC6 illustrated in FIG. 27A is an example of an amplifier circuit that supplies feedback to the terminal Ti (the terminal TMi) in accordance with the potential output from the terminal To of the circuit BSPR. Note that the circuit FH of the circuit OPC6 in FIG. 27A is different from the circuit FH in FIG. 22 in including a terminal HiT and a terminal Hi2 which function as input terminals.

In the circuit OPC6 in FIG. 27A, the circuit FH includes the transistor MNH1, a capacitor element C7, and a circuit BG. As described above, the circuit FH included in the circuit OPC6 in FIG. 27A includes the terminal HiT and the terminal Hi2 which function as input terminals and the terminal Ho which functions as an output terminal. Note that the terminal Hi2 corresponds to the terminal Hi illustrated in FIG. 22.

The circuit BG can be a circuit that can be used as the circuit BB included in the circuit BSPR illustrated in FIG. 1. Specifically, the circuit BG can employ the structure of the circuit BB illustrated in FIG. 8A to FIG. 8F, for example. The circuit BG in FIG. 27A includes a terminal Gi corresponding to the terminal Bi and a terminal Go corresponding to the terminal Bo.

The terminal HiT is connected to the terminal Gi of the circuit BG. The terminal HiT is connected to the terminal Ti of the circuit BSPR, the terminal TMi of the circuit OPC6, and the terminal Ho of the circuit FH. The terminal Hi2 is connected to a first terminal of the capacitor element C7. The terminal Hi2 is connected to the terminal To of the circuit BSPR, the terminal TMo of the circuit OPC6, the terminal Fi of the circuit FB, and the first terminal of the transistor MN16. A second terminal of the capacitor element C7 is connected to the terminal Go of the circuit BG and the gate of the transistor MNH1. The terminal Ho is electrically connected to the second terminal of the transistor MNH1, and the first terminal of the transistor MNH1 is electrically connected to the wiring VDE31.

Note that in this embodiment, a portion where the terminal Go of the circuit BG, the gate of the transistor MNH1, and the second terminal of the capacitor element C7 are electrically connected to each other is referred to as a node Nf.

The circuit BG has a function of, for example, bringing the node Nf into a floating state like the circuit BB illustrated in FIG. 1. Thus, the circuit BG can have a structure including a switching element, for example. The circuit BG also has a function of outputting, to the terminal Go, a potential corresponding to the potential input to the terminal Gi. For example, the circuit BG can have a structure in which when the high-level potential V_{High} is supplied to the terminal Gi, a potential V_{Mid_f} is output to the terminal Go. Note that V_{Mid_f} is a potential lower than the high-level potential V_{High} and higher than the low-level potential V_{Low}.

For the wiring VDE31, the description of the wiring VDE31 described with reference to the circuit MDV in FIG. 23A can be referred to.

Here, an operation example of the circuit OPC6 in FIG. 27A is described.

For the operation of the circuit BSPR in FIG. 27A, the operation example of the circuit BSPR in FIG. 1 can be referred to. For example, when the high-level potential V_{High} is input to the terminal TMi of the circuit OPC6, the circuit BB outputs the potential V_{Mid} to the terminal Bo. Thus, V_{Mid} is supplied to the gate of the transistor MN15 (the first terminal of the capacitor element C2). At this time, the node N is assumed to be brought into a floating state by the circuit BB.

The low-level potential V_{Low} is assumed to be supplied to the first terminal of the transistor MN15 from the terminal PWC. At this time, the gate-source voltage (the gate-first terminal voltage at this timing) of the transistor MN15 is V_{Mid}−V_{Low}, whereby the transistor MN15 is in an on state. Consequently, the terminal PWC outputs the low-level potential V_{Low} to the terminal To of the circuit BSPR through the transistor MN15.

Thus, V_{Low}, which is the same as the potential of the terminal To of the circuit BSPR, is input to the terminal Hi2 of the circuit FH. In this manner, the low-level potential V_{Low} is supplied to the first terminal of the capacitor element C7.

When the high-level potential V_{High} is input to the terminal TMi of the circuit OPC6, the circuit BG outputs the potential V_{Mid_f} to the terminal Go. Thus, V_{Mid_f} is supplied to a gate of a transistor MNFH1 (the second terminal of the capacitor element C7 and the node Nf). As a result, the voltage retained in the capacitor element C7 becomes V_{Mid_f}−V_{Low} when the node Nf is regarded as a reference.

The transistor MNH1 is normally off and the threshold voltage of the transistor MNH1 is set to V_{th_MNH1}. The threshold voltage V_{th_MNH1} is set to satisfy V_{High}−V_{Low}>V_{th_MNH1}.

The high-level potential V_{High} is assumed to be supplied to the first terminal of the transistor MNH1 from the wiring VDE31. At this time, the potentials of the first terminal and the second terminal of the transistor MNH1 are V_{High} and the potential of the gate of the transistor MNH1 is V_{Mid_f}. At this time, the gate-source voltage (the gate-first terminal voltage at this timing) of the transistor MNF1 is V_{Mid_f}−V_{High}. Since V_{Mid_f}−V_{High}<V_{th_MNH1} is satisfied, the transistor MNH1 is in an on state. At this time, the node Nf is assumed to be brought into a floating state by the circuit BG.

Next, the potential supplied to the first terminal of the transistor MN15 from the terminal PWC is assumed to change from the low-level potential V_{Low} to the high-level potential V_{High}. At this time, the gate-source voltage (here, the gate-second terminal voltage) of the transistor MN15 is V_{Mid}−V_{Low}, whereby the transistor MN15 is in an on state. Consequently, current flows from the terminal PWC to the terminal To of the circuit BSPR through the transistor MN15, which renders the potential of the terminal To higher than V_{Low}. Note that since the node N is in a floating state, the capacitive coupling with the capacitor element C7 causes an increase in the potential of the node N from V_{Mid} in response to the increase in the potential of the terminal To. Accordingly, the gate-source voltage of the transistor MN15 is retained by the capacitor element C7, whereby the potential of the terminal To increases to V_{High}. Ideally, the potential of the node N becomes V_{Mid}+V_{High}−V_{Low}.

At this time, V_{High}, which is the same as the potential of the terminal To of the circuit BSPR, is input to the terminal Hi2 of the circuit FH. Thus, the potential of the first terminal of the capacitor element C7 changes from the low-level potential V_{Low} to the high-level potential V_{High}. Since the node Nf is in a floating state, the capacitive coupling with the capacitor element C7 causes an increase in the potential of the node Nf from V_{Mid} in response to the increase in the potential of the terminal Hi2. Note that here, the potential of the node Nf becomes V_{Mid_f}+V_{High}−V_{Low}.

In the above manner, the potential of the gate of the transistor MNH1 becomes V_{Mid_f}+V_{High}−V_{Low}. Since each of the potentials of the first terminal and the second terminal of the transistor MNH1 is V_{High}, the gate-source voltage of the transistor MNH1 at this time becomes V_{Mid_f}−V_{Low}. When V_{Mid_f}−V_{Low}>V_{th_MNH1} is satisfied, the transistor MNH1 is brought into an on state. That is, electrical continuity is established between the terminal TMi of the circuit OPC6 and the wiring VDE31.

As described above, the potential of the gate of the transistor MNH1 is V_{Mid_f}+V_{High}−V_{Low}. Here, when the potential V_{Mid_f}+V_{High}−V_{Low} of the gate of the transistor MNH1 is higher than V_{High}+V_{th_MNF1} (i.e., when V_{Mid_f}−V_{Low} is higher than V_{th_MNH1}), a decrease in the threshold voltage V_{th_MNH1} of the transistor MNH1 is not caused at the potential supplied from the wiring VDE31 to the terminal TMi of the circuit OPC6 (the terminal Ti of the circuit BSPR) through the transistor MN15. That is, the influence of the voltage drop in the transistor MNH1 can be almost eliminated; thus, the potential of the terminal TMi of the circuit OPC6 (the terminal Ti of the circuit BSPR) can be set to the high-level potential V_{High} supplied from the wiring VDE31.

Thus, for example, even when the amount of off-state current flowing between the source and the drain or the amount of leakage current flowing between the gate and the source or between the gate and the drain becomes large in the transistor for retaining the potential of the terminal Ti of the circuit BSPR (the terminal TMi of the circuit OPC6), the potential of the terminal Ti of the circuit BSPR (the terminal TMi of the circuit OPC6) remains a potential (high-level potential V_{High}) supplied from the circuit FH. When a noise signal is input to the terminal Ti of the circuit BSPR (the terminal TMi of the circuit OPC6), the potential of the terminal Ti of the circuit BSPR (the terminal TMi of the circuit OPC6) remains a potential (high-level potential V_{High}) supplied from the circuit FH. Accordingly, the potential of the terminal To of the circuit BSPR does not change due to the above-described factors, so that the potential of the node N in the circuit BSPR is less likely to be affected. Thus, the potential output from the terminal To of the circuit BSPR is stabilized.

FIG. 27B illustrates a structure example in which the circuit BB in FIG. 8A is used as the circuit BG in the circuit OPC6 in FIG. 27A. The circuit OPC6 in FIG. 27B has a structure in which the circuit BG includes a transistor MNFH2.

A first terminal of a transistor MNH2 is connected to the gate of the transistor MNH1 and the second terminal of the capacitor element C7, a second terminal of the transistor MNH2 is connected to the terminal Hi of the circuit FH, and a gate of a transistor MNF2 is electrically connected to a wiring VDE32.

For the wiring VDE32, the above description of the wiring VDE31 can be referred to.

The transistor MNH2 is normally off and the threshold voltage of the transistor MNH2 is set to V_{th_MNH2}. The threshold voltage V_{th_MNH2} is set to satisfy V_{High}−V_{Low}>V_{th_MNH2}.

Here, an operation example of the circuit FH of the circuit OPC6 in FIG. 27B is described. First, in the circuit FH, the potential of the node Nf is assumed to be the low-level potential V_{Low}. The high-level potential V_{High} is assumed to be supplied to a gate of the transistor MNH2 from the wiring VDE32. Since the gate-source voltage (the gate-first terminal voltage at this timing) of the transistor MNH2 is V_{High}−V_{Low} at this time, the transistor MNH2 is in an on state. Here, when the high-level potential V_{High} is input to the terminal TMi of the circuit OPC6, the potential of the first terminal of the transistor MNH2 increases until the potential becomes the gate-source voltage at which the transistor MNH2 is brought into an off state. Specifically, when the potential of the first terminal of the transistor MNH2 (the node Nf) reaches V_{High}−V_{th_MNH2}, the transistor MNH2 is brought into an off state. Note that V_{High}−V_{th_MNH2} corresponds to V_{Mid_f} described above.

After that, the high-level potential V_{High} is assumed to be output from the terminal To by the circuit BSPR. Thus, the potential of the node Nf changes from V_{High}−V_{th_MNH2} to 2V_{High}−V_{th_MNH2} −V_{Low} owing to capacitive coupling with the capacitor element C7. That is, the potential of the gate of the transistor MNH2 becomes 2V_{High}−V_{th_MNH2}−V_{Low} and the potential of each of the first terminal and the second terminal of the transistor MNH2 is V_{High}; thus, the gate-source voltage of the transistor MNH2 becomes V_{High}−V_{th_MNH2}−V_{Low}. When V_{High}−V_{th_MNH2}−V_{Low}>V_{thM_NH1} is satisfied, the transistor MNH1 is brought into an on state, and electrical continuity is established between the wiring VDE31 and the terminal Ti the circuit BSPR (the terminal TMi of the circuit OPC6).

When the potential 2V_{High}−V_{th_MNH2}−V_{Low} of the gate of the transistor MNH1 is higher than V_{High}+V_{th_MNH1} (i.e., when V_{High}−V_{Low}−V_{th_MNH2} is higher than V_{th_MNH1}), a decrease in the threshold voltage V_{th_MNH1} of the transistor MNH1 is not caused at the potential supplied from the wiring VDE31 to the terminal TMi of the circuit OPC6 (the terminal Ti of the circuit BSPR) through the transistor MNH1. That is, the influence of the voltage drop in the transistor MNH2 can be almost eliminated; thus, the potential of the terminal TMi of the circuit OPC6 (the terminal Ti of the circuit BSPR) can be set to the high-level potential V_{High} supplied from the wiring VDE31. Accordingly, the terminal TMi of the circuit OPC6 (the terminal Ti of the circuit BSPR) is not in a floating state; thus, the potential of the terminal TMi of the circuit OPC6 (the terminal Ti of the circuit BSPR) does not change due to a factor such as leakage current or a noise signal.

### <Structure Example 2 of Retention Circuit>

In the above, the circuit OPC6 in each of FIG. 22 to FIG. 27B is described as a structure example in which the circuit FH is provided in the circuit OPC1 in FIG. 1; the circuit FH can also be provided in the circuit OPC2 illustrated in FIG. 9.

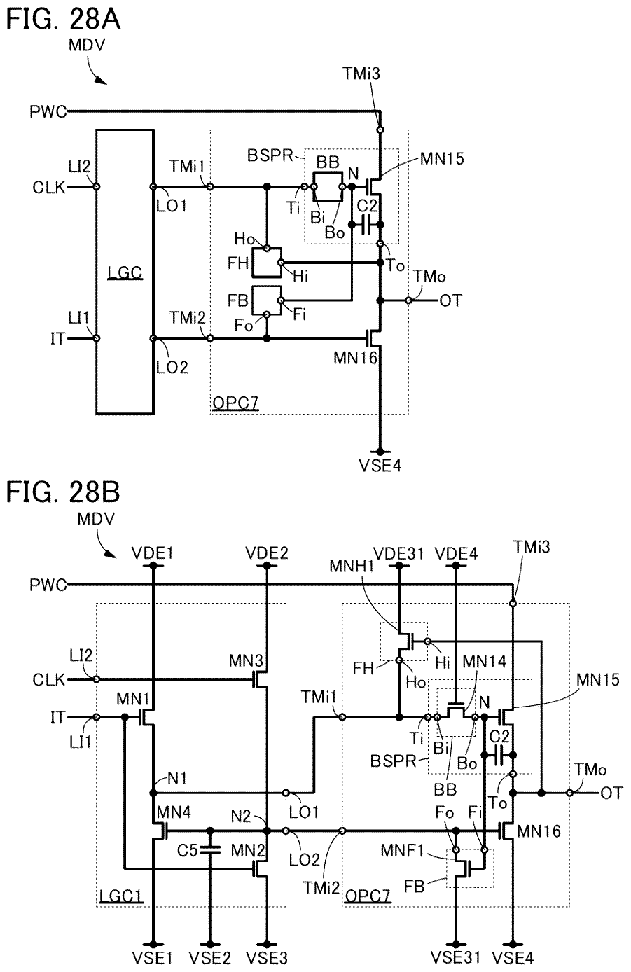

The circuit MDV illustrated in FIG. 28A is a retention circuit including the circuit LGC and a circuit OPC7. The circuit OPC7 is a modification example of the circuit OPC2 illustrated in FIG. 9, and is different from the circuit OPC2 in FIG. 9 in that the circuit FH is additionally provided. Note that the circuit LGC in FIG. 28A corresponds to the circuit LGC illustrated in FIG. 9.

For the circuit FH, the description of the circuit FH in FIG. 22 can be referred to. The circuit FH illustrated in each of FIG. 23A to FIG. 27B can be used as the circuit FH in FIG. 28A.

The terminal Hi of the circuit FH is connected to the terminal To of the circuit BSPR, the terminal TMo of the circuit OPC7, the terminal Fi of the circuit FB, and the first terminal of the transistor MN16. The terminal Ho of the circuit FH is connected to the terminal Ti of the circuit BSPR and the terminal TMo of the circuit OPC7.

For the operation of the circuit FH in FIG. 28A, the description of the operation example of the circuit FH in FIG. 22 can be referred to.

Like in the circuit OPC6 in FIG. 22, in the circuit OPC7 in FIG. 28A, when the high-level potential V_{High} is output from the terminal TMo and the potential of the terminal Ti of the circuit BSPR is varied by any factor, the circuit FH can return the potential of the terminal Ti of the circuit BSPR to a predetermined potential. Thus, the potential of the terminal Ti is kept almost constant, whereby the potential output from the terminal To of the circuit BSPR is stabilized.

FIG. 28B is a specific structure example of the circuit MDV in FIG. 28A, in which the circuit LGC1 illustrated in FIG. 1 is used as the circuit LGC, the circuit FH illustrated in FIG. 23A is used as the circuit FH, the circuit FB illustrated in FIG. 10 is used as the circuit FB, and the circuit BB in FIG. 8A is used as the circuit BB. Note that in the circuit BB in FIG. 28B, the transistor MN14 corresponds to the transistor MNa illustrated in FIG. 8A, and the wiring VDE4 corresponds to the wiring VAL2 illustrated in FIG. 8A. In FIG. 28B, the description of the circuit MDV in FIG. 1 can be referred to for the operation example of the circuit LGC1, the operation example of the circuit FB in FIG. 10 can be referred to for the operation example of the circuit FB, and the operation example of the circuit BB in FIG. 8A can be referred to for the operation example of the circuit BB.

FIG. 28A illustrates the circuit OPC7 as an example of the structure in which the circuit FH in FIG. 22 is provided in the circuit OPC2 in FIG. 9; in the circuit OPC7 in FIG. 28A, the terminal Hi of the circuit FH may be connected not to the terminal To of the circuit BSPR, the terminal TMo of the circuit OPC7, the terminal Fi of the circuit FB, and the first terminal of the transistor MN16, but to the terminal Bo of the circuit BB, the gate of the transistor MN15, the first terminal of the capacitor element C2, and the terminal Fi of the circuit FB.

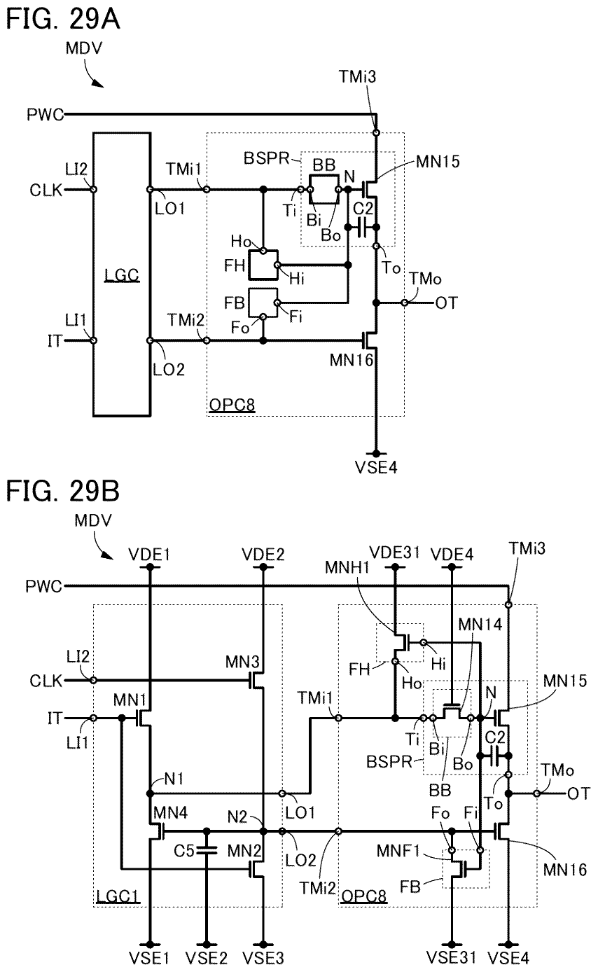

The circuit MDV illustrated in FIG. 29A is a retention circuit including the circuit LGC and a circuit OPC8. The circuit OPC8 is a modification example of the circuit OPC2 illustrated in FIG. 9, and is different from the circuit OPC2 in FIG. 9 in that the circuit FH is additionally provided. Furthermore, the circuit OPC8 is different from the circuit OPC7 in FIG. 28A in that the terminal Hi of the circuit FH is connected not to the terminal To of the circuit BSPR, the terminal TMo, the terminal Fi of the circuit FB, and the first terminal of the transistor MN16 but to the terminal Bo of the circuit BB, the gate of the transistor MN15, the first terminal of the capacitor element C2, and the terminal Fi of the circuit FB.

Note that the circuit LGC in FIG. 29A corresponds to the circuit LGC illustrated in FIG. 9.

For the circuit FH, the description of the circuit FH in FIG. 22 can be referred to. The circuit FH illustrated in each of FIG. 23A to FIG. 27B can be used as the circuit FH in FIG. 29A.

For the operation of the circuit FH in FIG. 29A, the description of the operation example of the circuit FH in FIG. 22 can be referred to.

The circuit OPC8 in FIG. 29A has a circuit structure in which the circuit FH supplies feedback to the terminal Ti of the circuit BSPR on the basis of the potential of the node N in the circuit BSPR (the gate of the transistor MN15 and the first terminal of the capacitor element C2).

Like the circuit FB in FIG. 9, the circuit OPC8 in FIG. 29A has a circuit structure in which the circuit FH supplies feedback to the terminal Ti of the circuit BSPR on the basis of the potential of the node N in the circuit BSPR (the gate of the transistor MN15 and the first terminal of the capacitor element C2); thus, when the potential of the node N is higher than V_{M}ia and the potential of the terminal Ti of the circuit BSPR is varied by any factor, the circuit FH can return the potential of the terminal Ti of the circuit BSPR to a predetermined potential. Thus, the potential of the terminal Ti is kept almost constant, whereby the potential output from the terminal To of the circuit BSPR is stabilized.

FIG. 29B is a specific structure example of the circuit MDV in FIG. 29A, in which the circuit LGC1 illustrated in FIG. 1 is used as the circuit LGC, the circuit FH illustrated in FIG. 23A is used as the circuit FH, the circuit FB illustrated in FIG. 10 is used as the circuit FB, and the circuit BB in FIG. 8A is used as the circuit BB. In the circuit BB in FIG. 29B, the transistor MN14 corresponds to the transistor MNa illustrated in FIG. 8A, and the wiring VDE4 corresponds to the wiring VAL2 illustrated in FIG. 8A. In FIG. 29B, the description of the circuit MDV in FIG. 1 can be referred to for the operation example of the circuit LGC1, the operation example of the circuit FB in FIG. 10 can be referred to for the operation example of the circuit FB, and the operation example of the circuit BB in FIG. 8A can be referred to for the operation example of the circuit BB.

### <Structure Example 3 of Retention Circuit>

In the above, the circuit OPC6 in each of FIG. 22 to FIG. 27B is described as a structure example in which the circuit FH is provided in the circuit OPC1 in FIG. 1, and the circuit OPC7 and the circuit OPC8 are described as a structure in which the circuit FH is provided in the circuit OPC2 in FIG. 9; the circuit FH can also be provided in the circuit OPC3 illustrated in FIG. 13.

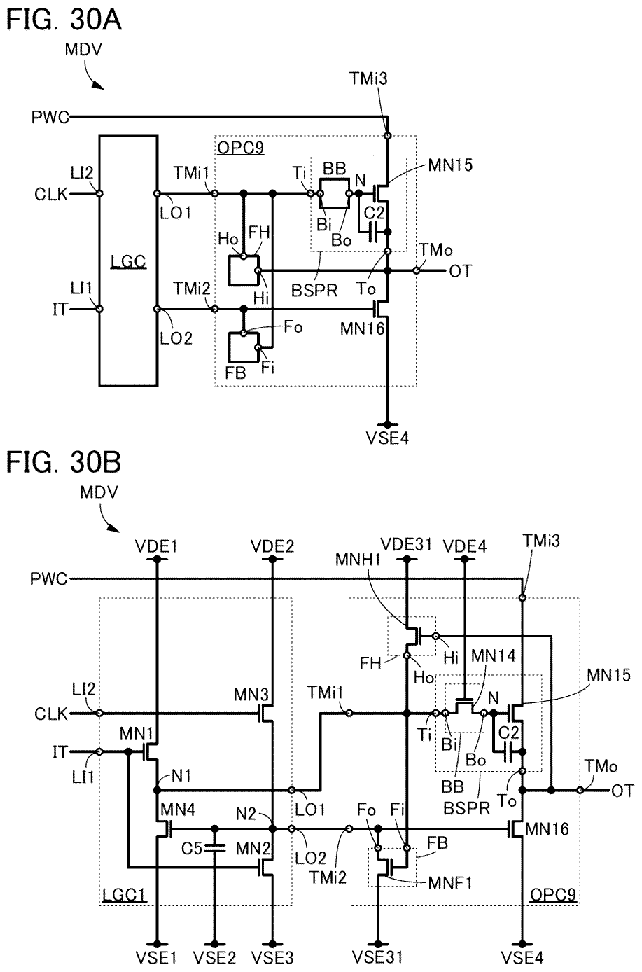

The circuit MDV illustrated in FIG. 30A is a retention circuit including the circuit LGC and a circuit OPC9. The circuit OPC9 is a modification example of the circuit OPC3 illustrated in FIG. 13, and is different from the circuit OPC3 in FIG. 13 in that the circuit FH is additionally provided. Note that the circuit LGC in FIG. 30A corresponds to the circuit LGC illustrated in FIG. 13.

For the circuit FH, the description of the circuit FH in FIG. 22 can be referred to. The circuit FH in FIG. 30A can be used as the circuit FH illustrated in each of FIG. 23A to FIG. 27B.

The terminal Hi of the circuit FH is connected to the terminal To of the circuit BSPR, the terminal TMo of the circuit OPC9, and the first terminal of the transistor MN16. The terminal Ho of the circuit FH is connected to the terminal Ti of the circuit BSPR and the terminal TMo of the circuit OPC9.

For the operation of the circuit FH in FIG. 30A, the description of the operation example of the circuit FH in FIG. 22 can be referred to.

Like the circuit OPC8 in FIG. 29, a circuit OPC10 in FIG. 30A has a circuit structure in which the circuit FH supplies feedback to the terminal Ti of the circuit BSPR on the basis of the potential of the node N in the circuit BSPR (the gate of the transistor MN15 and the first terminal of the capacitor element C2); thus, when the potential of the node N is higher than VMia and the potential of the terminal Ti of the circuit BSPR is varied by any factor, the circuit FH can return the potential of the terminal Ti of the circuit BSPR to a predetermined potential. Thus, the potential of the terminal Ti is kept almost constant, whereby the potential output from the terminal To of the circuit BSPR is stabilized.

FIG. 30B is a specific structure example of the circuit MDV in FIG. 30A, in which the circuit LGC1 illustrated in FIG. 1 is used as the circuit LGC, the circuit FH illustrated in FIG. 23A is used as the circuit FH, the circuit FB illustrated in FIG. 14 is used as the circuit FB, and the circuit BB in FIG. 8A is used as the circuit BB. Note that in the circuit BB in FIG. 30B, the transistor MN14 corresponds to the transistor MNa illustrated in FIG. 8A, and the wiring VDE4 corresponds to the wiring VAL2 illustrated in FIG. 8A. In FIG. 30B, the description of the circuit MDV in FIG. 1 can be referred to for the operation example of the circuit LGC1, the operation example of the circuit FB in FIG. 14 can be referred to for the operation example of the circuit FB, and the operation example of the circuit BB in FIG. 8A can be referred to for the operation example of the circuit BB.

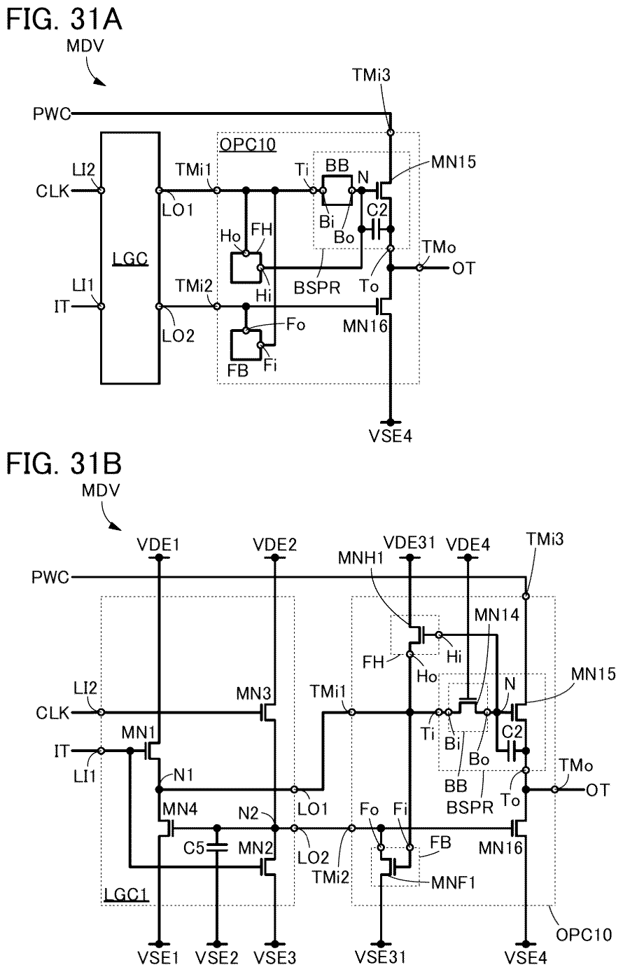

The circuit MDV illustrated in FIG. 31A is a retention circuit including the circuit LGC and the circuit OPC10. The circuit OPC10 is a modification example of the circuit OPC3 illustrated in FIG. 13, and is different from the circuit OPC3 in FIG. 13 in that the circuit FH is additionally provided. Furthermore, the circuit OPC10 is different from the circuit OPC9 in FIG. 30A in that the terminal Hi of the circuit FH is connected not to the terminal To of the circuit BSPR, the terminal TMo, the terminal Fi of the circuit FB, and the first terminal of the transistor IMN16 but to the terminal Bo of the circuit BB, the gate of the transistor MN15, the first terminal of the capacitor element C2, and the terminal Fi of the circuit FB.

Note that the circuit LGC in FIG. 31A corresponds to the circuit LGC illustrated in FIG. 9.

For the circuit FH, the description of the circuit FH in FIG. 22 can be referred to. The circuit FH illustrated in each of FIG. 23A to FIG. 27B can be used as the circuit FH in FIG. 31A.

For the operation of the circuit FH in FIG. 31A, the description of the operation example of the circuit FH in FIG. 22 can be referred to.

The circuit OPC10 in FIG. 31A has a circuit structure in which the circuit FH supplies feedback to the terminal Ti of the circuit BSPR on the basis of the potential of the node N in the circuit BSPR (the gate of the transistor MN15 and the first terminal of the capacitor element C2).

Like the circuit FB in FIG. 9, the circuit OPC10 in FIG. 31A has a circuit structure in which the circuit FH supplies feedback to the terminal Ti of the circuit BSPR on the basis of the potential of the node N in the circuit BSPR (the gate of the transistor MN15 and the first terminal of the capacitor element C2); thus, when the potential of the node N is higher than V_{M}ia and the potential of the terminal Ti of the circuit BSPR is varied by any factor, the circuit FH can return the potential of the terminal Ti of the circuit BSPR to a predetermined potential. Thus, the potential of the terminal Ti is kept almost constant, whereby the potential output from the terminal To of the circuit BSPR is stabilized.

FIG. 31B is a specific structure example of the circuit MDV in FIG. 31A, in which the circuit LGC1 illustrated in FIG. 1 is used as the circuit LGC, the circuit FH illustrated in FIG. 23A is used as the circuit FH, the circuit FB illustrated in FIG. 10 is used as the circuit FB, and the circuit BB in FIG. 8A is used as the circuit BB. Note that in the circuit BB in FIG. 31B, the transistor MN14 corresponds to the transistor MNa illustrated in FIG. 8A, and the wiring VDE4 corresponds to the wiring VAL2 illustrated in FIG. 8A. In FIG. 31B, the description of the circuit MDV in FIG. 1 can be referred to for the operation example of the circuit LGC1, the operation example of the circuit FB in FIG. 10 can be referred to for the operation example of the circuit FB, and the operation example of the circuit BB in FIG. 8A can be referred to for the operation example of the circuit BB.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 4

Described in this embodiment are a driver circuit including the retention circuit described in the above embodiment and a display apparatus including the driver circuit.

### <Structure Example of Display Apparatus>

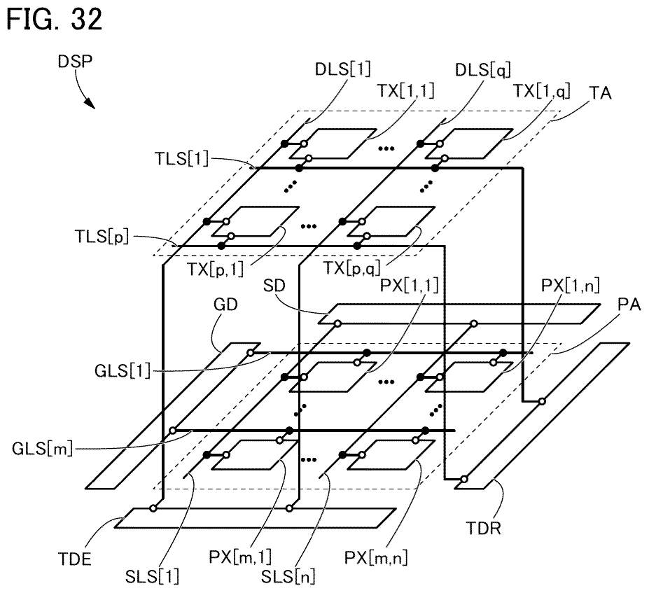

FIG. 32 is a schematic perspective view illustrating a structure example of a display apparatus. As illustrated in FIG. 32, a display apparatus DSP includes a pixel array PA, a sensor array TA, a driver circuit GD, a driver circuit SD, a driver circuit TDR, and a driver circuit TDE. The sensor array TA includes a region overlapping with the pixel array PA.

The pixel array PA has a function of displaying an image corresponding to an image signal transmitted from the driver circuit SD, for example.

In the pixel array PA, a plurality of pixel circuits PX are arranged in an array form, for example. Note that in the pixel array PA in FIG. 32, the pixel circuits PX are arranged in a matrix of m×n (each of m and n is an integer greater than or equal to 2). FIG. 32 selectively illustrates a pixel circuit PX[1, 1], a pixel circuit PX[m, 1], a pixel circuit PX[1, n], and a pixel circuit PX[m, n]. The pixel circuit PX[1, 1] represents the pixel circuit PX placed in the first row and the first column in the pixel array PA. Similarly, the pixel circuit PX[m, 1] represents the pixel circuit PX placed in the m-th row and the first column, the pixel circuit PX[1, n] represents the pixel circuit PX placed in the first row and the n-th column, and the pixel circuit PX[m, n] represents the pixel circuit PX placed in the m-th row and the n-th column.

Note that FIG. 32 illustrates the display apparatus DSP having a structure in which the pixel array PA includes m×n pixel circuits PX; the pixel array PA can have a structure with one pixel circuit PX (that is, m=n=1) in some situations.

The pixel circuit PX can be a pixel, for example, using one or more selected from a liquid crystal display device, a light-emitting device including an organic EL material, and a light-emitting device including a light-emitting diode such as a QLED (Quantum-dot Light Emitting Diode) or a micro LED. Note that in the description in this embodiment, the pixel circuit PX in the display apparatus DSP includes a light-emitting device including organic EL.

Note that the light-emitting device including an organic EL material included in the pixel circuit PX can have a structure in which red (R), green (G), and blue (B) are separately provided (SBS. Side By Side structure), a structure in which a tandem structure (a structure in which a plurality of colors such as R, G, and B are connected in series with an intermediate layer (charge-generation layer) therebetween) is combined with coloring layers (e.g., color filters), or the like. Note that the tandem structure enables a light-emitting device capable of emitting light with high luminance. The luminance of light emitted from the pixel array PA can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m².

In the sensor array TA, a plurality of sensors TX are arranged in an array form, for example. Note that in the sensor array TA in FIG. 32, the sensors TX are arranged in a matrix of p×q (each of p and q is an integer greater than or equal to 2). FIG. 32 selectively illustrates a sensor TX[1, 1], a sensor TX[p, 1], a sensor TX[1, q], and a sensor TX[p, q]. The sensor TX[1, 1] represents the sensor TX placed in the first row and the first column in the sensor array TA. Similarly, the sensor TX[p, 1] represents the sensor TX placed in thep-th row and the first column, the sensor TX[1, q] represents the sensor TX placed in the first row and the q-th column, and the sensor TX[p, q] represents the sensor TX placed in the p-th row and the q-th column.

Note that FIG. 32 illustrates the display apparatus DSP having a structure in which the sensor array TA includes p×q sensors TX; the sensor array TA can have a structure with one sensor TX (that is, p=q=1) in some situations.

The number m of rows of the matrix of the pixel array PA may be equal to or different from the number p of rows of the matrix of the sensor array TA. The number n of columns of the matrix of the pixel array PA may be equal to or different from the number q of columns of the matrix of the sensor array TA.

The sensor array TA has a function of a touch sensor (sometimes referred to as a touch panel), for example. In the case where the touch sensor is a mutual capacitive sensor, the sensor TX can include a capacitor element.

The pixel circuit PX placed in the i-th row and the j-th column (i is an integer greater than or equal to 1 and less than or equal to m, andj is an integer greater than or equal to 1 and less than or equal to n) in the pixel array PA is referred to as a pixel circuit PX[i, j](not illustrated). The pixel circuit PX[i, j] is connected to a wiring GLS[i](not illustrated), for example. The pixel circuit PX[i, j] is connected to a wiring SLS[j](not illustrated), for example.

The driver circuit GD is connected to a wiring GLS[1] to a wiring GLS[m], for example. The driver circuit SD is connected to a wiring SLS[1] to a wiring SLS[n], for example.

The wiring GLS[1] to the wiring GLS[m] can each be a wiring extending in the row direction in the pixel array PA, for example. Furthermore, [x] added to the wiring GLS represents the number of the row in which the wiring extends. For example, the reference of the wiring GLS[1] represents a wiring extending in the first row in the pixel array PA. For another example, the reference of the wiring GLS[m] represents a wiring extending in the m-th row in the pixel array PA.

The wiring SLS[1] to the wiring SLS[n] can each be a wiring extending in the column direction in the pixel array PA, for example. Furthermore, [y] added to the wiring SLS represents the number of the column in which the wiring extends. For example, the reference of the wiring SLS[1] represents a wiring extending in the first column in the pixel array PA. For another example, the reference of the wiring SLS[n] represents a wiring extending in the n-th column in the pixel array PA.

Note that the wiring GLS[i] may be one wiring or a wiring group including a large number of wirings. Similarly, the wiring SLS[j] may be one wiring or a wiring group including a large number of wirings.

The driver circuit GD has a function of selecting the pixel circuit PX to which image data is to be transmitted in the pixel array PA of the display apparatus DSP, for example. Accordingly, the driver circuit GD can be referred to as a gate driver circuit or the like.

From the above, the wiring GLS, which connects the driver circuit GD and the pixel circuit PX, functions as a wiring for transmitting a selection signal, for example. Note that the wiring GLS may have a function of, for example, not a wiring for transmitting a selection signal but a wiring for supplying a fixed potential.

The driver circuit SD has a function of transmitting image data to the pixel circuit PX in the pixel array PA of the display apparatus DSP, for example. Accordingly, the driver circuit SD can be referred to as a source driver circuit or the like.

From the above, the wiring SLS, which connects the driver circuit SD and the pixel circuit PX, functions as a wiring for transmitting image data as a signal, for example. Note that the wiring SLS may have a function of, for example, not a wiring for transmitting image data but a wiring for supplying a fixed potential.

Note that in the display apparatus DSP illustrated in FIG. 32, a wiring other than the wiring GLS[1] to the wiring GLS[m] and the wiring SLS[1] to the wiring SLS[n] may extend. For example, a wiring for supplying a fixed potential to the pixel circuit PX may extend in the display apparatus DSP.

The sensor TX placed in the h-th row and the k-th column (h is an integer greater than or equal to 1 and less than or equal to m, and k is an integer greater than or equal to 1 and less than or equal to n) in the sensor array TA is referred to as a sensor TX[h, k](not illustrated). The sensor TX[h, k] is connected to a wiring TLS[h](not illustrated), for example. The sensor TX[h, k] is connected to a wiring DLS[k](not illustrated), for example.

Note that the wiring TLS[h] may be one wiring or a wiring group including a large number of wirings. Similarly, the wiring DLS[k] may be one wiring or a wiring group including a large number of wirings.

The driver circuit TDR is connected to a wiring TLS[1] to a wiring TLS[p], for example. The driver circuit TDE is connected to a wiring DLS[1] to a wiring DLS[q], for example.

The wiring TLS[1] to the wiring TLS[p] can each be a wiring extending in the row direction in the sensor array TA, for example. Furthermore, [x] added to the wiring TLS represents the number of the row in which the wiring extends. For example, the reference of the wiring TLS[1] represents a wiring extending in the first row in the sensor array TA. For another example, the reference of the wiring TLS[p] represents a wiring extending in the p-th row in the sensor array TA.

The wiring DLS[1] to the wiring DLS[q] can each be a wiring extending in the column direction in the sensor array TA, for example. Furthermore, [y] added to the wiring DLS represents the number of the column in which the wiring extends. For example, the reference of the wiring DLS[1] represents a wiring extending in the first column in the pixel array PA. For another example, the reference of the wiring SLS[n] represents a wiring extending in the n-th column in the pixel array PA.

The driver circuit GD has a function of selecting the pixel circuit PX to which image data is to be transmitted in the pixel array PA of the display apparatus DSP, for example. Accordingly, the driver circuit GD can be referred to as a gate driver circuit or the like.

From the above, the wiring GLS, which connects the driver circuit GD and the pixel circuit PX, has a function of a wiring for transmitting a selection signal, for example. Note that the wiring GLS may have a function of, for example, not a wiring for transmitting a selection signal but a wiring for supplying a fixed potential.

The driver circuit SD has a function of transmitting image data to the pixel circuit PX in the pixel array PA of the display apparatus DSP, for example. Accordingly, the driver circuit SD can be referred to as a source driver circuit or the like.

From the above, the wiring SLS, which connects the driver circuit SD and the pixel circuit PX, has a function of a wiring for transmitting image data as a signal, for example. Note that the wiring SLS may have a function of, for example, not a wiring for transmitting image data but a wiring for supplying a fixed potential.

Note that in the pixel array PA of the display apparatus DSP illustrated in FIG. 32, a wiring other than the wiring GLS[1] to the wiring GLS[m] and the wiring SLS[1] to the wiring SLS[n] may extend. For example, a wiring for supplying a fixed potential to the pixel circuit PX may extend in the display apparatus DSP.

The driver circuit TDR has a function of sequentially transmitting a pulse signal (referred to as a pulse voltage or a pulse potential in some cases) to a plurality of sensors TX in the sensor array TA of the display apparatus DSP, for example. Thus, the driver circuit TDR can be referred to as a touch sensor driver circuit or the like.

From the above, the wiring TLS, which connects the driver circuit TDR and the sensor TX, has a function of a wiring for transmitting a pulse signal, for example. Note that the wiring TLS may have a function of, for example, not a wiring for transmitting a pulse signal but a wiring for supplying a fixed potential.

The driver circuit TDE has a function of sensing a change in the amount of current flowing from the sensor TX in the sensor array TA of the display apparatus DSP, for example. In particular, a contact of a finger, a pen, or the like over the sensor array TA changes the electrostatic capacitance value included in the sensor TX, so that current flows from the sensor TX to the wiring DLS. For this reason, the driver circuit TDE can be referred to as a detection circuit or the like for detecting the current.

From the above, the wiring DLS, which connects the driver circuit TDE and the sensor TX, has a function of a wiring that supplies current flowing from the sensor TX, for example. Note that the wiring DLS may have a function of, for example, not a wiring for supplying current but a wiring for supplying a fixed potential.

Note that in the sensor array TA of the display apparatus DSP illustrated in FIG. 32, a wiring other than the wiring TLS[1] to the wiring TLS[p] and the wiring DLS[1] to the wiring DLS[q] may extend. For example, a wiring for supplying a fixed potential to the sensor TX may extend in the display apparatus DSP.

A shift register can be provided in each of the above-described driver circuit GD, driver circuit SD, driver circuit TDR, and driver circuit TDE. In particular, when the retention circuit described in Embodiment 1 is used as a retention circuit included in the shift register, the potential output from the retention circuit is stabilized and a shift register capable of being driven at low speed can be achieved. Note that a structure example of a shift register included in each of the driver circuit GD and the driver circuit SD is described below and the shift register can also be used in each of the driver circuit TDR and the driver circuit TDE.

### <Structure Example of Driver Circuit GD>

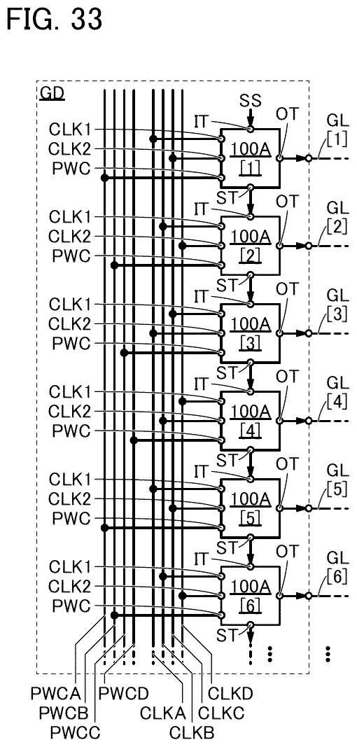

FIG. 33 illustrates a structure example of the driver circuit GD of one embodiment of the present invention that can be applied to the display apparatus DSP in FIG. 32. The driver circuit GD illustrated in FIG. 33 includes a circuit 100A[1] to a circuit 100A[m], for example. Note that FIG. 33 selectively illustrates the circuit 100A[1] to a circuit 100A[6].

Each of the circuit 100A[1] to the circuit 100A[m] includes, for example, the terminal IT, a terminal ST, the terminal CLK1, the terminal CLK2, the terminal PWC, and the terminal OT.

In the driver circuit GD, a wiring CLKA to a wiring CLKD and a wiring PWCA to a wiring PWCD extend.

In a circuit 100A[4k-3](here, k is an integer greater than or equal to 1 and 1≤4k−3≤m is satisfied), the terminal CLK1 is connected to the wiring CLKA, the terminal CLK2 is connected to a wiring CLKC, and the terminal PWC is connected to the wiring PWCA. In a circuit 100A[4k-2](here, k is an integer greater than or equal to 1 and 2≤4k−2≤n is satisfied), the terminal CLK1 is connected a wiring CLKB, the terminal CLK2 is connected to the wiring CLKD, and the terminal PWC is connected to a wiring PWCB. In a circuit 100A[4k-1](here, k is an integer greater than or equal to 1 and 3≤4k−1≤n is satisfied), the terminal CLK1 is connected the wiring CLKC, the terminal CLK2 is connected to the wiring CLKA, and the terminal PWC is connected to a wiring PWCC. In a circuit 100A[4k](here, k is an integer greater than or equal to 1 and 4≤4k≤n is satisfied), the terminal CLK1 is connected the wiring CLKD, the terminal CLK2 is connected to the wiring CLKB, and the terminal PWC is connected to the wiring PWCD.

Each of the wiring CLKA to the wiring CLKD and the wiring PWCA to the wiring PWCD has a functions of, for example, a wiring for supplying a variable potential (referred to as a pulse signal or a pulse voltage in some cases in this specification). Examples of the variable potential include a clock signal. Note that one or more selected from the wiring CLKA to the wiring CLKD and the wiring PWCA to the wiring PWCD may have a function of a wiring for supplying not the variable potential but a fixed potential.

The terminal ST of a circuit 100A[i](here, i is an integer greater than or equal to 1 and less than or equal to m−1) is connected to the terminal IT of a circuit 100A[i+1], for example.

The terminal OT of the circuit 100A[i](here, i is an integer greater than or equal to 1 and less than or equal to m) is connected to a wiring GL[i], for example. Note that the wiring GL[i] is a wiring corresponding to the wiring GLS[i] illustrated in FIG. 32.

Each of the circuit 100A[1] to the circuit 100A[m] has functions of, for example, retaining information input to the terminal IT and outputting the retained information to one or both of the terminal OT and the terminal ST.

For example, the circuit 100A[i] has a function of outputting information retained in the circuit 100A[i] to the terminal ST when a high-level potential is input to the terminal CLKT. For another example, the circuit 100A[i] has a function of outputting information retained in the circuit 100A[i] to the terminal OT when a high-level potential is input to the terminal PWC. For another example, the circuit 100A[i] has a function of resetting information retained in the circuit 100A[i] when a high-level potential is input to the terminal CLK2. The circuit 100A[i] is preferably configured to retain new information that is input to the terminal IT of the circuit 100A[i] after the information retained in the circuit 100A[i] is reset.

As described above, in the circuit 100A[1] to the circuit 100A[m], information is input to the terminal IT of the circuit 100A[1] and then a variable potential is input to the terminal CLKI1 and the terminal CLK2 at an appropriate timing, whereby the information can be sequentially transmitted to a circuit 100A[2] and the subsequent circuits. Furthermore, information is input to the terminal IT of the circuit 100A[1] and then a variable potential is input to the terminal PWC at an appropriate timing, whereby information retained in the circuit 100A[1] to the circuit 100A[m] can be output from the terminals OT of the circuit 100A[1] to the circuit 100A[m]. Accordingly, the structure of the circuit 100A[1] to the circuit 100A[m] can be referred to as a shift register in this specification and the like.

As described in Embodiment 1, the circuit 100A[1] to the circuit 100A[m] may each have a function of a level shifter when a higher-level potential of the variable potential input to the terminal PWC is a potential higher than V_{High} or a potential higher than Vow and lower than V_{High}.

The above-described information can be, for example, a selection signal for selecting the pixel circuit PX to which image data is to be written in the pixel array PA. Note that in FIG. 33, the selection signal is illustrated as a signal SS.

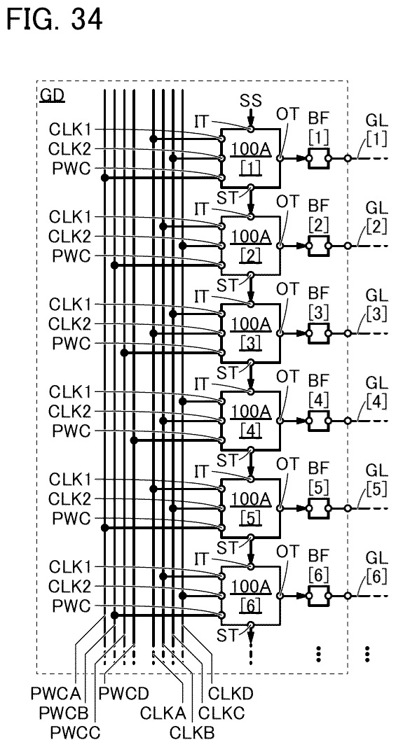

The structure of the driver circuit GD applicable to the display apparatus DSP in FIG. 32 is not limited to the structure in FIG. 33. For example, the driver circuit GD illustrated in FIG. 34 may be employed as the driver circuit GD applicable to the display apparatus DSP in FIG. 32. The driver circuit GD in FIG. 34 is different from the driver circuit GD in FIG. 33 in including a circuit BF[1] to a circuit BF[m].

In the driver circuit GD in FIG. 34, an input terminal of a circuit BF[i](here, i is an integer greater than or equal to 1 and less than or equal to m, and the circuit BF[i] is not illustrated in FIG. 33) is connected to the terminal OT of the circuit 100A[i](not illustrated in FIG. 34), and an output terminal of the circuit BF[i] is connected to the wiring GL[i](not illustrated in FIG. 34).

Each of the circuit BF[1] to the circuit BF[m] can have a structure including an amplifier circuit such as a buffer circuit, an inverter circuit, or a latch circuit, for example. Specifically, each of the circuit BF[1] to the circuit BF[m] can have a function of referring to and amplifying the potential of the terminal OT and outputting the amplified potential to the wiring GL.

Note that a wiring other than the wiring CLKA to the wiring CLKD and the wiring PWCA to the wiring PWCD may extend in the driver circuits GD illustrated in FIG. 33 and FIG. 34. For example, a wiring for supplying a fixed potential to drive each of the circuit 100A[1] to the circuit 100A[m] may extend.

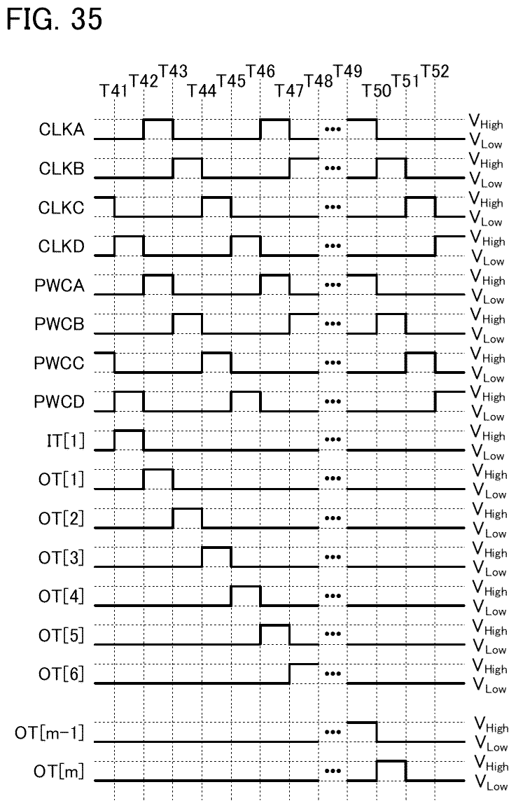

FIG. 35 is a timing chart showing an operation example of the driver circuit GD illustrated in FIG. 33 or FIG. 34. FIG. 35 shows potential changes of the wiring CLKA to the wiring CLKD, the wiring PWCA to the wiring PWCD, a terminal IT[1], a terminal OT[1] to a terminal OT[6], a terminal OT[n-1], and a terminal OT[m] in the period from Time T41 to Time T52 and around the period. Note that the terminal IT[1] is the terminal IT included in the circuit 100A[1], and a terminal OT[i](here, i is an integer greater than or equal to 1 and less than or equal to m) is the terminal OT included in the circuit 100A[i].

In the period from Time T42 to Time T43, the period from Time T46 to Time T47, and the period from Time T49 to Time T50, the high-level potential V_{High} is supplied to the wiring CLKA and the wiring PWCA. In the period from Time T43 to Time T44, the period from Time T46 to Time T47, and the period from Time T50 to Time T51, the high-level potential V_{High} is supplied to the wiring CLKB and the wiring PWCB. In the period from Time T44 to Time T45 and the period from Time T51 to Time T52, the high-level potential V_{High} is supplied to the wiring CLKC and the wiring PWCC. In the period from Time T41 to Time T42 and the period from Time T45 to Time T46, the high-level potential V_{High} is supplied to the wiring CLKD and the wiring PWCD.

In the period before Time T41 and the period after Time T52, the high-level potential V_{High} is supplied to the wiring CLKA to the wiring CLKD and the wiring PWCA to the wiring PWCD at the same timing as that in the period from Time T41 to Time T52. Specifically, for example, V_{High} is sequentially supplied to the pair of the wiring CLKA and the wiring PWCA, the pair of the wiring CLKB and the wiring PWCB, the pair of the wiring CLKC and the wiring PWCC, and the pair of the wiring CLKD and the wiring PWCD in the period from Time T42 to Time T46 as one cycle.

Since V_{High} is supplied to the wiring CLKA to the wiring CLKD and the wiring PWCA to the wiring PWCD at the above timings, the terminal OT[1] to the terminal OT[m] sequentially output V_{High} at predetermined timings when V_{High} is supplied to the terminal IT[1] in the period from Time T41 to Time T42. For example, the terminal OT[1] outputs V_{High} in the period from Time T42 to Time T43, a terminal OT[2] outputs V_{High} in the period from Time T43 to Time T44, a terminal OT[3] outputs V_{High} in the period from Time T44 to Time T45, a terminal OT[4] outputs V_{High} in the period from Time T45 to Time T46, and a terminal OT[5] outputs V_{High} in the period from Time T46 to Time T47. For example, a terminal OT[m-1] outputs V_{High} in the period from Time T49 to Time T50, and the terminal OT[m] outputs V_{High} in the period from Time T50 to Time T51.

Note that in the timing chart in FIG. 35, V_{High} is output from the terminal OT[m] when the high-level potential V_{High} is supplied to the wiring CLKD and the wiring PWCD in the period from Time T50 to Time T51; the timing at which V_{High} is output from the terminal OT[m] depends on the value of m (i.e., the number of circuits 100A). For example, in the case where m is 4k-2 (here, k is an integer greater than or equal to 3), as shown in the timing chart in FIG. 35, V_{High} is output from the terminal OT[m] when the high-level potential V_{High} is output from the previous terminal OT[m-1] and the high-level potential V_{High} is supplied to the wiring CLKB and the wiring PWCB. For another example, in the case where m is 4k-3, V_{High} is output from the terminal OT[m] when the high-level potential V_{High} is output from the previous terminal OT[m-1] and the high-level potential V_{High} is supplied to the wiring CLKA and the wiring PWCA. In the case where m is 4k-1, V_{High} is output from the terminal OT[m] when the high-level potential V_{High} is output from the previous terminal OT[m-1] and the high-level potential V_{High} is supplied to the wiring CLKC and the wiring PWCC. In the case where m is 4k, V_{High} is output from the terminal OT[m] when the high-level potential V_{High} is output from the previous terminal OT[m-1] and the high-level potential V_{High} is supplied to the wiring CLKD and the wiring PWCD.

The driver circuit GD is capable of transmitting the selection signals to the pixel circuits PX in the pixel array PA by performing the above operation as an example in the timing chart in FIG. 35.

### <<Structure Example of Circuit 100A>>

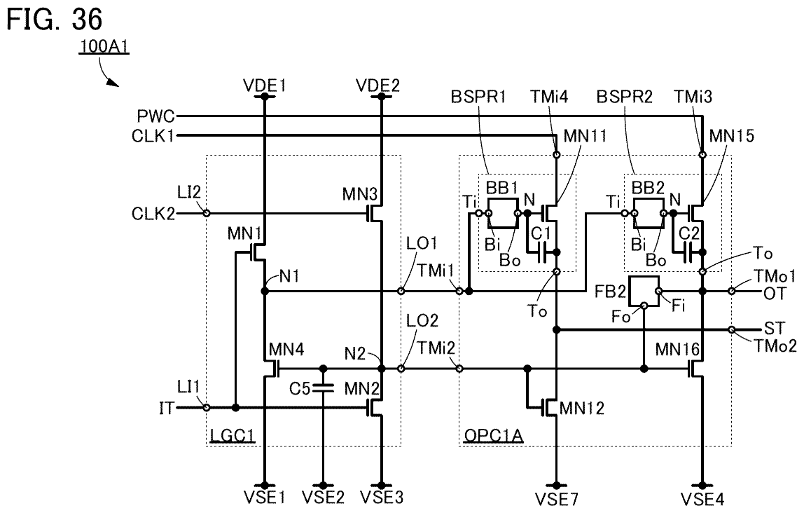

A circuit 100A1 in FIG. 36 is an example of a circuit structure that can be applied to each of the circuit 100A[1] to the circuit 100A[m] included in the driver circuit GD illustrated in each of FIG. 33 and FIG. 34.

The circuit 100A1 in FIG. 36 is a modification example of the circuit MDV in FIG. 1; the structure of a circuit OPC1A included in the circuit 100A1 is especially different from the that of the circuit OPC1 in the circuit MDV in FIG. 1. For example, the circuit OPC1A is different from the circuit OPC1 in including a terminal TMo1 instead of the terminal TMo and additionally including a terminal TMi4 and a terminal TMo2.

The circuit OPC1A in FIG. 36 includes a circuit BSPR1, a circuit BSPR2, a circuit FB2, a transistor MN12, and the transistor MN16, for example. The circuit BSPR1 includes a circuit BB1, a transistor MN11, and the capacitor element C1, and the circuit BSPR2 includes a circuit BB2, the transistor MN15, and the capacitor element C2. Note that the circuit BSPR2 corresponds to the circuit BSPR in FIG. 1, and the circuit FB2 corresponds to the circuit FB in FIG. 1. The terminal TMo1 corresponds to the terminal TMo in FIG. 1.

Note that the circuit BSPR1 and the circuit BSPR2 each have a circuit structure similar to that of the circuit BSPR illustrated in FIG. 2A. Thus, for the operation examples of the circuit BSPR1 and the circuit BSPR2, the description of the circuit BSPR illustrated in FIG. 8A to FIG. 8F in Embodiment 1 can be referred to. The circuit BB illustrated in FIG. 8A to FIG. 8F can be used as the circuit BB1 and the circuit BB2. Thus, for the operation examples of the circuit BB1 and the circuit BB2, the description of the circuit BB illustrated in FIG. 8A to FIG. 8F in Embodiment 1 can be referred to. The circuit FB illustrated in FIG. 3 to FIG. 7B can be used as the circuit FB2. Thus, for the operation example of the circuit FB2, the description of the circuit FB illustrated in FIG. 3 to FIG. 7B in Embodiment 1 can be referred to.

As each of the transistor MN11 and the transistor MN12, a transistor that can be used as the transistor MN15 or the transistor MN16 illustrated in FIG. 1 can be used, for example.

The circuit LGC1 has a circuit structure similar to that of the circuit LGC1 in FIG. 1. Thus, for the operation of the circuit LGC1 in FIG. 36, the description of the circuit LGC1 in FIG. 1 can be referred to.

Hereinafter, a circuit structure of the circuit 100A1 is described. Note that the description of the contents overlapping with those of the circuit MDV in FIG. 1 is omitted.

In the circuit 100A1 in FIG. 36, the terminal IT is connected to the terminal LIT, and the terminal CLK2 is connected to the terminal LI2. The terminal LO1 is connected to the terminal TMi1, the terminal L02 is connected to the terminal TMi2, the terminal CLKI1 is connected to the terminal TMi4, and the terminal PWC is connected to the terminal TMi3. The terminal TMo1 is connected to the terminal OT, and the terminal TMo2 is connected to the terminal ST.

In the circuit OPC1A in FIG. 36, the terminal TMi1 is connected to the terminal Ti of the circuit BSPR1 and the terminal Ti of the circuit BSPR2. The terminal Ti of the circuit BSPR1 is connected to the terminal Bi of the circuit BB1, and the terminal Bo of the circuit BB1 is connected to agate of the transistor MN11 and the first terminal of the capacitor element CT. The terminal Ti of the circuit BSPR2 is connected to the terminal Bi of the circuit BB2, and the terminal Bo of the circuit BB2 is connected to the gate of the transistor MN15 and the first terminal of the capacitor element C2. A first terminal of the transistor MN11 is connected to the terminal TMi4, and a second terminal of the transistor MN11 is connected to a second terminal of the capacitor element C1 and the terminal To of the circuit BSPR1. The first terminal of the transistor MN15 is connected to the terminal TMi3, and the second terminal of the transistor MN15 is connected to the second terminal of the capacitor element C2 and the terminal To of the circuit BSPR2.

In the circuit OPC1A in FIG. 36, the terminal TMi2 is connected to the gate of the transistor MN12, the gate of the transistor MN16, and the terminal Fo of the circuit FB2. The terminal To of the circuit BSPR1 is connected to the terminal TMo2 and a first terminal of the transistor MN12. A second terminal of the transistor MN12 is connected to the wiring VSE7. The terminal To of the circuit BSPR2 is connected to the terminal TMo1, the first terminal of the transistor MN16, and the terminal Fi of the circuit FB2. The second terminal of the transistor MN16 is connected to the wiring VSE4.

The wiring VSE7 has a function of a wiring for supplying a fixed potential, for example. The fixed potential can be a low-level potential, a ground potential, or a negative potential, for example. The wiring VSE7 may have a function of a wiring for supplying not a fixed potential but a variable potential.

Note that the wiring VSE1 to the wiring VSE4 and the wiring VSE7 can supply fixed potentials equal to each other or fixed potentials different from each other. Alternatively, two or more wirings selected from the wiring VSE1 to the wiring VSE4 and the wiring VSE7 may supply fixed potentials equal to each other, and the other wiring(s) may supply a potential different from the fixed potentials. Furthermore, the two or more wirings among the wiring VSE1 to the wiring VSE4 and the wiring VSE7 which supply fixed potentials equal to each other may be the same wiring. For example, in the case where the wiring VSE4 and the wiring VSE7 supply fixed potentials equal to each other, the wiring VSE4 and the wiring VSE7 may be the same wiring.

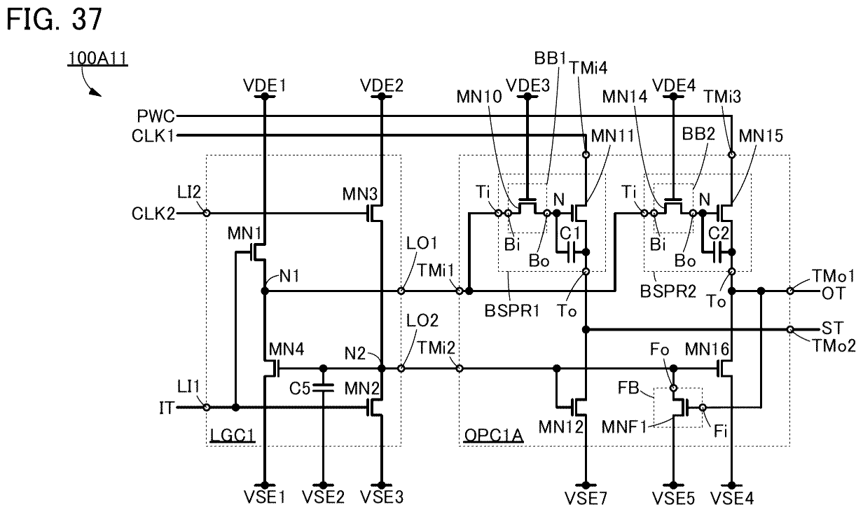

FIG. 37 illustrates another specific example of the circuit 100A1. A circuit 100A11 illustrated in FIG. 37 has a circuit structure in which the circuit BSPR in FIG. 8A is used as each of the circuit BSPR1 and the circuit BSPR2 in the circuit 100A1 in FIG. 36. Note that the circuit BB1 includes a transistor MN10 corresponding to the transistor MNa in FIG. 8A, and the circuit BB2 includes the transistor MN14 corresponding to the transistor MNa in FIG. 8A. In this case, the transistors that can be used as the transistor MN11 and the transistor MN15 can be used as the transistor MN10 and the transistor MN14 included in the circuit BB1 and the circuit BB2.

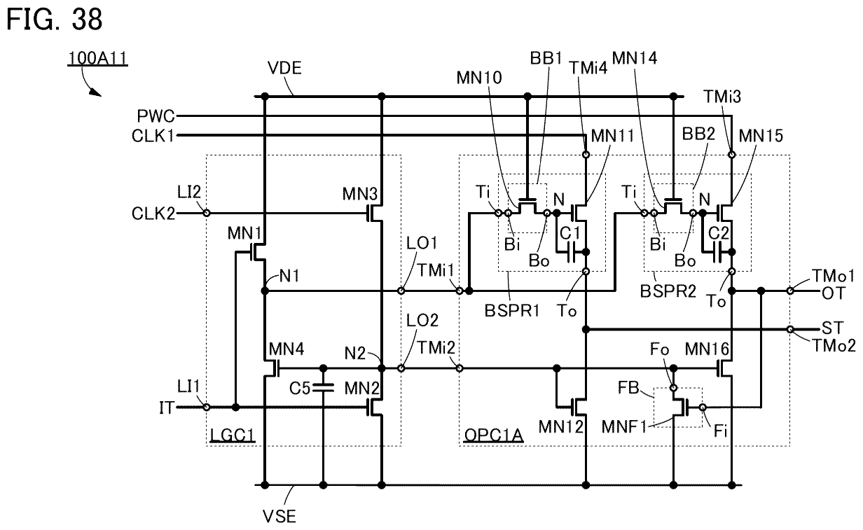

In the case where the same potential is supplied to the wiring VDE1 to the wiring VDE4 in FIG. 37, the wiring VDE1 to the wiring VDE4 can be combined into one wiring. Similarly, in the case where the same potential is supplied to the wiring VSE1 to the wiring VSE5 and the wiring VSE7, the wiring VSE1 to the wiring VSE5 and the wiring VSE7 can be combined into one wiring. FIG. 38 illustrates a circuit structure in which the wiring VDE1 to the wiring VDE4 are combined into one wiring VDE and the wiring VSE1 to the wiring VSE5 and the wiring VSE7 are combined into one wiring VSE in the circuit 100A11 in FIG. 37. When a plurality of wirings are combined into one wiring as illustrated in FIG. 38, the circuit area of a shift register including the circuit 100A11 can be reduced.

Although the circuit 100A11 in FIG. 37, which is the semiconductor device of one embodiment of the present invention, is a single-polarity circuit including an n-channel transistor, the structure of the circuit 100A11 in FIG. 37 may be changed into the structure of a single-polarity circuit including a p-channel transistor.

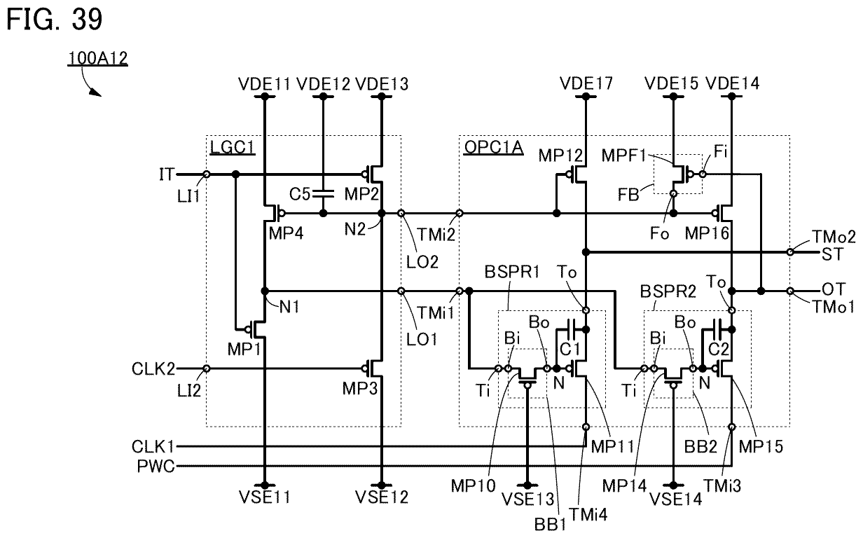

FIG. 39 illustrates a specific structure example. A circuit 100A12 illustrated in FIG. 39 is a modification example of the circuit 100A11 in FIG. 37 and has a structure in which the transistor MN1 to the transistor MN4, the transistor MN10 to the transistor MN12, the transistor MN14 to the transistor MN16, and the transistor MNF1 are respectively changed into a transistor MP1 to a transistor MP4, a transistor MP10 to a transistor MP12, a transistor MP14 to a transistor MP16, and a transistor MPF1; the wiring VSE1 to the wiring VSE5 and the wiring VSE7 are changed into a wiring VDE11 to a wiring VDE15 and a wiring VDE17; and the wiring VDE1 to the wiring VDE4 are changed into a wiring VSE11 to a wiring VSE14. Note that the transistor MP1 to the transistor MP4, the transistor MP10 to the transistor MP12, and the transistor MP14 to the transistor MP16 are p-channel transistors as described above.

The wiring VDE11 to the wiring VDE15 and the wiring VDE17 each has a function of a wiring for supplying a fixed potential, for example. The fixed potential can be a high-level potential, for example. Note that the wiring VDE11 to the wiring VDE15 and the wiring VDE17 can supply fixed potentials equal to each other or fixed potentials different from each other. Alternatively, two or more wirings selected from the wiring VDE11 to the wiring VDE15 and the wiring VDE17 may supply fixed potentials equal to each other, and the other wiring(s) may supply a potential different from the fixed potentials. Furthermore, the two or more wirings among the wiring VDE11 to the wiring VDE15 and the wiring VDE17 which supply fixed potentials equal to each other may be the same wiring. For example, in the case where the wiring VDE14 and the wiring VDE17 supply fixed potentials equal to each other, the wiring VDE14 and the wiring VDE17 may be the same wiring.

One or more of the wiring VDE11 to the wiring VDE15 and the wiring VDE17 may be a wiring for supplying not a fixed potential but a variable potential.

The wiring VSE11 to the wiring VSE14 each have a function of a wiring for supplying a fixed potential, for example. The fixed potential can be, for example, a low-level potential, a ground potential, or a negative potential. Note that the wiring VSE11 to the wiring VSE14 can supply fixed potentials equal to each other or fixed potentials different from each other. Alternatively, two or more wirings selected from the wiring VSE11 to the wiring VSE14 may supply fixed potentials equal to each other, and the other wiring(s) may supply a potential different from the fixed potentials. Furthermore, the two or more wirings among the wiring VSE11 to the wiring VSE14 which supply fixed potentials equal to each other may be the same wiring. For example, in the case where the wiring VSE11 and the wiring VSE12 supply fixed potentials equal to each other, the wiring VSE11 and the wiring VSE12 may be the same wiring.

One or more of the wiring VSE11 to the wiring VSE14 may be a wiring for supplying not a fixed potential but a variable potential.

For the operation of the circuit 100A12, the description of an operation example of the circuit 100A1 described later can be referred to. The circuit 100A12 is a single-polarity circuit including a p-channel transistor; thus, it should be noted that the logic of a signal, a potential, or the like handled in the circuit 100A12 is inverted from the logic of a signal, a potential, or the like handled in the circuit 100A1 in FIG. 36, which is a single-polarity circuit including an n-channel transistor.

Note that the semiconductor device of one embodiment of the present invention is not limited to the circuit 100A1 illustrated in FIG. 36 and the circuit 100A11 illustrated in FIG. 37. For example, in the circuit 100A11 in FIG. 37, at least one or more of the transistor MN1 to the transistor MN4, the transistor MN10 to the transistor MN12, and the transistor MN14 to the transistor MN16 may be a transistor including a back gate.

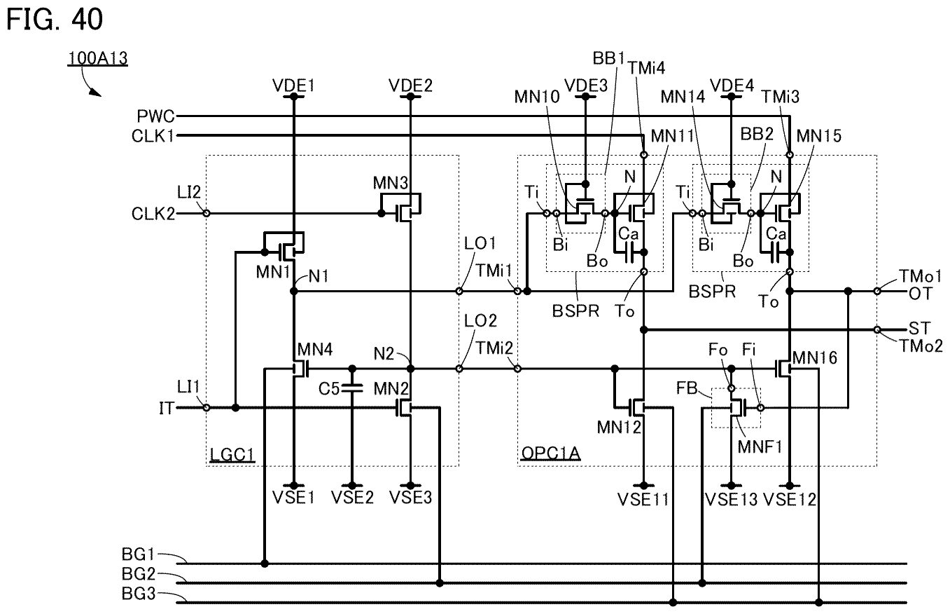

FIG. 40 illustrates a specific structure example. A circuit 100A13 illustrated in FIG. 40 is a modification example of the circuit 100A11 in FIG. 37 and is different from the circuit 100A11 in that the transistor MN1 to the transistor MN4, the transistor MN10 to the transistor MN12, and the transistor MN14 to the transistor MN16 each include a back gate.

In the circuit 100A13 illustrated in FIG. 40, the destinations to which the back gates of the transistor MN1 to the transistor MN4, the transistor MN10 to the transistor MN12, and the transistor MN14 to the transistor MN16 are connected are defined clearly.

In each of the transistor MN1, the transistor MN3, the transistor IMN10, and the transistor MN14, the gate is electrically connected to the back gate. The back gate of each of the transistor MN2 and the transistor MNF1 is connected to a wiring BG2. The back gate of the transistor MN4 is connected to a wiring BG1. The back gate of each of the transistor MN12 and the transistor MN16 is connected to a wiring BG3.

The wiring BGT to the wiring BG3 each have a function of a wiring for supplying a fixed potential, for example. The fixed potential can be, for example, a low-level potential, a ground potential, or a negative potential. Note that the wiring BGT to the wiring BG3 can supply fixed potentials equal to each other or fixed potentials different from each other. In the case where two or more selected from the wiring BGT to the wiring BG3 are wirings for supplying fixed potentials equal to each other, the two or more selected wirings may be the same wiring. One or more selected from the wiring BGT to the wiring BG3 may be a wiring for supplying not a fixed potential but a variable potential.

In the case where the wiring BGT to the wiring BG3 are wirings different from one another, different fixed potentials can be supplied to the back gates of the transistor MN2, the transistor MNF1, the transistor MN4, the transistor MNN12, and the transistor MN16. That is, the threshold voltages of the transistor MN2 and the transistor MNF1, the threshold voltage of the transistor MN4, and the threshold voltages of the transistor MN12 and the transistor MN16 can be controlled independently of one another.

With this structure, for example, when a negative potential is supplied to the back gates of the transistor MN2 and the transistor MNF2 and the ground potential or a low-level potential (a potential higher than the negative potential) is supplied to the back gates of the transistor MN12 and the transistor MIN16, the amounts of off-state current of the transistor MN12 and the transistor MN16 can be larger than the amounts of off-state current of the transistor MN2 and the transistor MNF1. Accordingly, in the case where the circuit 100A13 in FIG. 40 is used as each of the circuit 100A[1] to the circuit 100A[m] in the driver circuit GD in FIG. 33 or FIG. 34, the driving speed of the driver circuit GD can be increased.

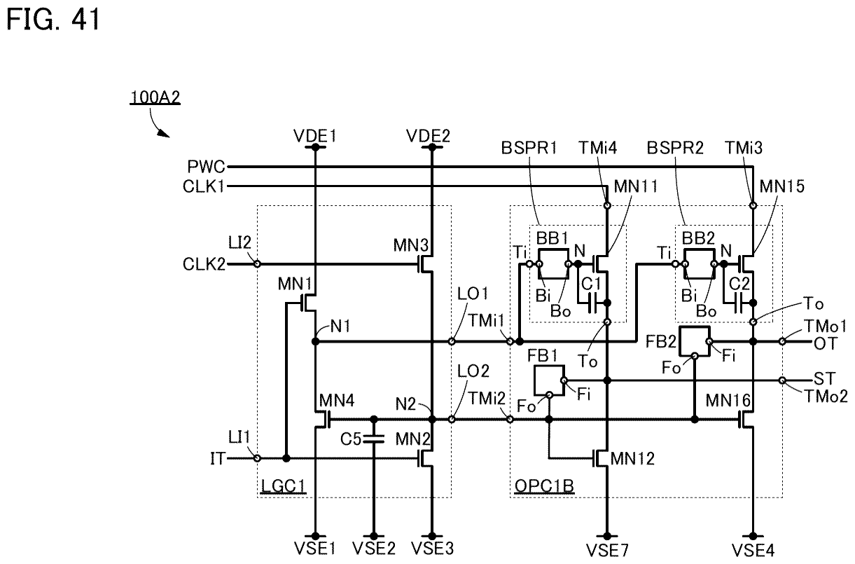

A circuit 100A2 illustrated in FIG. 41 can be used as each of the circuit 100A[1] to the circuit 100A[m] in the driver circuit GD in FIG. 33 or FIG. 34. The circuit 100A2 in FIG. 41 is a modification example of the circuit 100A1 in FIG. 36 and is different from the circuit 100A1 in FIG. 36 in that a circuit FB1 is additionally provided. Note that in the circuit 100A2 in FIG. 41, the circuit OPC1A illustrated in FIG. 36 is illustrated as a circuit OPC1B.

In the circuit 100A2 in FIG. 41, the circuit FB1 can have a structure similar to that of the circuit FB illustrated in FIG. 1. That is, the circuit FB illustrated in FIG. 3 to FIG. 7B can be used as the circuit FB1.

The terminal Fi of the circuit FB1 is connected to the second terminal of the transistor MN11, the second terminal of the capacitor element C1, the first terminal of the transistor MN12, and the terminal TMo2. The terminal Fo of the circuit FB1 is connected to the first terminal of the transistor MN2, the gate of the transistor MN4, the gate of the transistor MN12, the gate of the transistor MN16, the first terminal of the capacitor element C5, and the terminal Fo of the circuit FB2.

The circuit 100A2 in FIG. 41 has a circuit structure in which the circuit FB1 supplies feedback to the gate of the transistor MN12 and the gate of the transistor MN16 on the basis of the potential output from the terminal To of the circuit BSPR1. Thus, even when the high-level potential V_{High} is not output from the terminal To of the circuit BSPR2, the potential of the node N2 (the gates of the transistor MN12 and the transistor MN16) remains a fixed potential supplied from the circuit FB1 because the high-level potential V_{High} is output from the terminal To of the circuit BSPR1, and the potential of the node N2 remains a fixed potential supplied from the circuit FB1 even when a noise signal is input to the node N2. That is, an increase in the potential of the node N2 (the gates of the transistor MN12 and the transistor MN16) due to the above-described factors can be prevented. Thus, the potential output from the terminal TMo of the circuit OPC1 (the potential output from the terminal OT of the circuit MDV) can be stabilized.

### <<Operation Example of Circuit 100A11>>

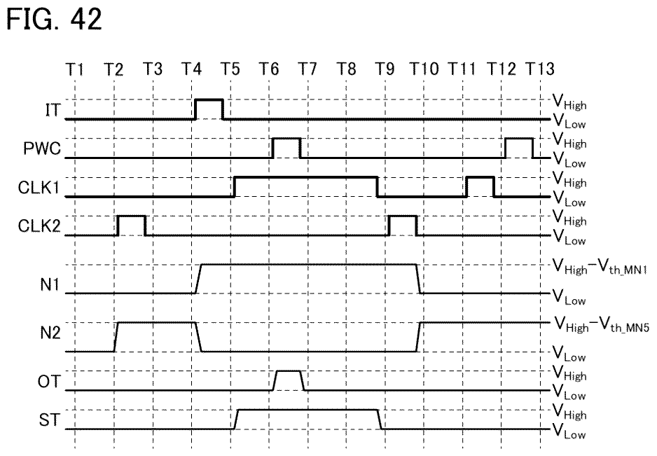

FIG. 42 is a timing chart showing an operation example of the circuit 100A11. The timing chart in FIG. 42 shows, as an example, changes in the potentials of the terminal IT, the terminal PWC, the terminal CLK1, the terminal CLK2, the node N1, the node N2, the terminal OT, and the terminal ST. In FIG. 42, high-level potentials are expressed as V_{High}, and low-level potentials are expressed as V_{Low}.

In the timing chart in FIG. 42, to simply describe the operation of the circuit 100A11, the length of an input period, the length of an output period, and the like of a signal shown in the timing chart in FIG. 42 are different from those in the actual circuit operation in some cases.

In this operation example, the fixed potentials supplied by the wiring VDE1 and the wiring VDE2 are the high-level potentials V_{High} that are equal to each other. The fixed potentials supplied by the wiring VSE1 to the wiring VSE4 and the wiring VSE7 are the low-level potentials V_{Low} that are equal to each other.

Note that the high-level potential V_{High} and the low-level potential V_{Low} are each set such that the difference between the high-level potential V_{High} and the low-level potential V_{Low} is greater than the threshold voltage of each of the transistors shown in FIG. 36.

[from Time T1 to Time T2]

In the period from Time T1 to Time T2, V_{Low} is supplied to the terminal IT, V_{Low} is supplied to the terminal PWC, V_{Low} is supplied to the terminal CLK1, and V_{Low} is supplied to the terminal CLK2. At the node N1 and the node N2, V_{Low} is retained as an example.

When the low-level potential V_{Low} is supplied to the terminal CLK2, the potential of the gate of the transistor MN3 is V_{Low}. It is also assumed that the threshold voltage of the transistor MN3 is within an appropriate range. Consequently, the transistor MN3 is in an off state.

The potential of the gate of the transistor MN4 (the node N2) is V_{Low} and V_{Low} is supplied from the wiring VSE1 to the second terminal of the transistor MN4, so that the transistor MN4 is in an off state.

It is also assumed that when V_{Low} is supplied to the terminal IT, the potential of a first gate of the transistor MN1 is V_{Low}. It is also assumed that the threshold voltage of the transistor MN1 is within an appropriate range. Consequently, the transistor MN1 is in an off state.

The potential of the gate of the transistor MN12 (the node N2) is V_{Low} and V_{Low} is supplied from the wiring VSE7 to the second terminal of the transistor MN12, so that the transistor MN12 is in an off state.

The potential of the gate of the transistor MN16 (the node N2) is V_{Low} and V_{Low} is supplied from the wiring VSE5 to the second terminal of the transistor MN16, so that the transistor MN16 is in an off state.

The potential of the gate of the transistor MN2 (the terminal IT) is V_{Low} and V_{Low} is supplied from the wiring VSE3 to the second terminal of the transistor MN2, so that the transistor MN2 is in an off state.

Note that in the period from Time T1 to Time T2 in the timing chart in FIG. 42, each of the potentials of the terminal ST and the terminal OT is V_{Low}, for example. In particular, since the potential of the terminal OT is V_{Low}, V_{Low} is input to the gate of the transistor MNF1 included in the circuit FB2. Since V_{Low} is supplied from the wiring VSE5 to the second terminal of the transistor MNF1, the transistor MNF1 is in an off state.

Note that in the period from Time T1 to Time T2, each of the potentials of the terminal ST and the terminal OT may be V_{High}. In that case, since the potential of the terminal OT is V_{High}, V_{High} is input to the gate of the transistor MNF1 included in the circuit FB2. Since V_{Low} is supplied from the wiring VSE5 to the second terminal of the transistor MNF1, the transistor MNF1 is in an off state, so that electrical continuity is established between the wiring VSE5 and the terminal Fo of the circuit FB2. Thus, V_{Low} is supplied from the wiring VSE5 to the gate of the transistor MN4, the first terminal of the transistor MN2, the gate of the transistor MN12, the gate of the transistor MN16, and the first terminal of the capacitor element C5.

[from Time T2 to Time T3]

In the period from Time T2 to Time T3, V_{High} is supplied to the terminal CLK2.

When V_{High} is supplied to the terminal CLK2, the potential of the gate of the transistor MN3 becomes V_{High}.

Here, the transistor MN3 is normally off and the threshold voltage of the transistor MN3 is set to V_{th_MN3}. The threshold voltage V_{th_MN3} is set to satisfy V_{High}−V_{Low}>V_{th_MN3}.

When the potential of the second terminal of the transistor MN3 (the node N2) is V_{Low}, the transistor MN3 is in an on state, and electric charge from the wiring VDE2 is accumulated in the second terminal of the transistor MN3 (the node N2). When electric charge is accumulated in the node N2 until the gate-source voltage (the gate-second terminal voltage at this timing) of the transistor MN3 becomes V_{High}−V_{th_MN3}, the transistor MN3 is brought into an off state. Thus, the potential V_{High}−V_{th_MN3} is retained in the node N2.

Note that when the potential of the second terminal of the transistor MN3 (the node N2) is higher than V_{High}, the first terminal of the transistor MN3 serves as a source, and electric charge is accumulated in the node N2 from the wiring VDE1. When the potential of the second terminal of the transistor MN3 (the node N2) becomes V_{High}−V_{th_MN3}, the transistor MN3 is brought into an off state. Thus, the potential V_{High}−V_{th_MN3} is retained in the node N2 in a manner similar to the above.

In the period from Time T2 to Time T3, after V_{High} is supplied to the terminal CLK2, V_{Low} is supplied to the terminal CLK2. Thus, the potential of a first gate of the transistor MN3 is assumed to be V_{Low}.

By the above operation, V_{High} is supplied to the terminal CLK2 in the circuit 100A11, so that the potential of the node N2 can be refreshed to be V_{High}−V_{th_MN3}.

Since the potential of the node N2 is V_{High}−V_{th_MN3}, the potential of a first gate of the transistor MN12 (the node N2) is V_{High}−V_{th_MN3}. Since V_{Low} is supplied from the wiring VSE7 to the second terminal of the transistor MN12, the transistor MN12 is in an on state. Thus, electrical continuity is established between the terminal ST and the wiring VSE4, whereby the potential of the terminal ST becomes V_{Low}.

Since the potential of the node N2 is V_{High}−V_{th_MN3}, the potential of a first gate of the transistor MN16 (the node N2) is V_{High}−V_{th_MN3}. Since V_{Low} is supplied from the wiring VSE4 to the second terminal of the transistor MN16, the transistor MN16 is in an on state. Thus, electrical continuity is established between the terminal OT and the wiring VSE5, whereby the potential of the terminal OT becomes V_{Low}.

### [From Time T3 to Time T4]

In the period from Time T3 to Time T4, V_{Low} is supplied to the terminal IT, V_{Low} is supplied to the terminal PWC, V_{Low} is supplied to the terminal CLK1, and V_{Low} is supplied to the terminal CLK2. Potentials input to the terminal IT, the terminal PWC, the terminal CLK1, and the terminal CLK2 in the period from Time T3 to Time T4 are equal to the potentials input to the terminal IT, the terminal PWC, the terminal CLK1, and the terminal CLK2 in the period from Time T1 to Time T2; therefore, for an operation example of the circuit 100A11 in the period from Time T3 to Time T4, the description of the operation example in the period from Time T1 to Time T2 is referred to.

### [From Time T4 to Time T5]

In the period from Time T4 to Time T5, V_{High} is supplied to the terminal IT. V_{High} is supplied from the terminal IT to a first gate of the transistor MN2, and V_{Low} is supplied from the wiring VSE3 to the second terminal of the transistor MN2, so that the transistor MN2 is in an off state. Thus, electrical continuity is established between the node N2 and the wiring VSE3, so that the potential of the node N2 changes from V_{High} to V_{Low}.

In the above manner, the potential of a first gate of the transistor MN4 (the node N2) is V_{Low} and V_{Low} is supplied from the wiring VSE1 to the second terminal of the transistor MN4, so that the transistor MN4 is in an off state.

In the above manner, the potential of the first gate of the transistor MN12 (the node N2) is V_{Low} and V_{Low} is supplied from the wiring VSE7 to the second terminal of the transistor MN12, so that the transistor MN12 is in an off state.

In the above manner, the potential of the first gate of the transistor MN16 (the node N2) is V_{Low} and the low-level potential V_{Low} is supplied from the wiring VSE4 to the second terminal of the transistor MN16, so that the transistor MN16 is in an off state.

When V_{High} is supplied to the terminal IT, the potential of the gate of the transistor MN1 becomes V_{High}. Since the potential of the second terminal of the transistor MN1 (the node N1) is V_{Low}, the transistor MN1 is in an on state. Thus, electric charge from the wiring VDE1 is accumulated in the second terminal of the transistor MN1 (the node N1).

Here, the transistor MN1 is normally off and the threshold voltage of the transistor MN1 is set to V_{th_MN1}. The threshold voltage V_{th_MN1} is set to satisfy V_{High}−V_{Low}>V_{th_MN1}.

Accordingly, when electric charge is accumulated in the node N1 until the gate-source voltage (the gate-second terminal voltage at this timing) of the transistor MN1 becomes V_{High}−V_{th_MN1}, the transistor MN1 is brought into an off state. Thus, the potential V_{High}−V_{th_MN1} is retained in the node N1.

In the period from Time T4 to Time T5, after V_{High} is supplied to the terminal IT, V_{Low} is supplied to the terminal IT. Thus, the potential of the gate of the transistor MN1 is assumed to be V_{Low}.

V_{Low} is supplied from the terminal IT to the gate of the transistor MN2, and V_{Low} is supplied from the wiring VSE3 to the second terminal of the transistor MN2, so that the transistor MN2 is in an off state. Thus, V_{Low} is retained in the node N2.

### [From Time T5 to Time T6]

In the period from Time T5 to Time T6, V_{High} is supplied to the terminal CLK1.

In the period from Time T4 to Time T5, the potential of the node N1 is V_{High}−V_{th_MN1}. At this time, V_{High}−V_{th_MN1} is input to the first terminal of the transistor MN11 in the circuit BB1. Here, the threshold voltage of the transistor MN11 is V_{th_MN11}. When the potential of the first terminal of the transistor MN11, V_{High}−V_{th_MN1}, is lower than V_{High}−V_{th_MN11} (the gate-source voltage at which the transistor MN11 is brought into an off state), the potential of the node N of the circuit BSPR1 becomes V_{High}−V_{th_MN1}, and when the potential of the first terminal of the transistor MN11, V_{High}−V_{th_MN1}, is higher than V_{High}−V_{th_MN11}, the potential of the node N of the circuit BSPR1 becomes V_{High}−V_{th_MN11}.

Similarly, V_{High}−V_{th_MN1} is input to the first terminal of the transistor MN14 in the circuit BB2. Here, the threshold voltage of the transistor MN14 is V_{th_MN14}. When the potential of the first terminal of the transistor MN14, V_{High}−V_{th_MN1}, is lower than V_{High}−V_{th_MN14} (the gate-source voltage at which the transistor MN14 is brought into an off state), the potential of the node N of the circuit BSPR2 becomes V_{High}−V_{th_MN1} and when the potential of the first terminal of the transistor MN14, V_{High}−V_{th_MN1}, is higher than V_{High}−V_{th_MN14}, the potential of the node N of the circuit BSPR1 becomes V_{High}−V_{th_MN14}.

### [From Time T6 to Time T7]

In the period from Time T6 to Time T7, V_{High} is supplied to the terminal PWC.

In the period from Time T4 to Time T6, the potential of the node N1 is V_{High}−V_{th_MN1}. At this time, V_{High} is supplied to the terminal PWC, whereby the potential of the second terminal (the terminal OT) of the transistor MN15 also becomes V_{High} in accordance with the description of the circuit BSPR in FIG. 2A.

Since the potential of the terminal OT is V_{High}, V_{High} is input to the gate of the transistor MNF1 included in the circuit FB2. Since V_{Low} is supplied from the wiring VSE5 to the second terminal of the transistor MNF1, the transistor MNF1 is in an off state, so that electrical continuity is established between the wiring VSE5 and the terminal Fo of the circuit FB2. Thus, V_{Low} is supplied from the wiring VSE5 to the gate of the transistor MN4, the first terminal of the transistor MN2, the gate of the transistor MN12, the gate of the transistor MN16, and the first terminal of the capacitor element C5.

Since electrical continuity is established between the wiring VSE5 and the terminal Fo of the circuit FB2, even when a change in the potential due to noise occurs in the node N2, V_{Low} is supplied from the wiring VSE5 to the node N2; thus, the potential of the node N2 immediately returns to V_{Low}. Thus, the influence of the noise on the gate of the transistor MN16 can be reduced, so that the output of the potential V_{High} to the terminal OT of the circuit 100A1 can be stabilized.

Since the terminal Fo of the circuit FB is also connected to the gate of the transistor MN12, even when a change in the potential due to noise occurs in the node N2, the influence of the noise on the gate of the transistor MN12 can be reduced. Accordingly, the output of the potential V_{High} to the terminal ST of the circuit 100A1 can be stabilized.

Then, V_{High} is supplied to the terminal PWC in the period from Time T6 to Time T7; after that, V_{Low} is supplied to the terminal PWC. Thus, the potential of the second terminal (the terminal OT) of the transistor MN15 becomes V_{Low} as in the operation example in the period from Time T5 to Time T6.

### [From Time T8 to Time T9]

In the period from Time T8 to Time T9, V_{Low} is supplied to the terminal CLK1.

Thus, the potential of the second terminal (the terminal ST) of the transistor MN11 becomes V_{Low} as in the operation example in the period from Time T4 to Time T5.

### [From Time T9 to Time T10]

In the period from Time T9 to Time T10, the high-level potential V_{High} is supplied to the terminal CLK2. At this time, operation of the circuit 100A11 in the period from Time T9 to Time T10 is similar to that in the period from Time T2 to Time T3.

For example, when V_{High} is supplied to the terminal CLK2, the potential of the second terminal of the transistor MN3 (the node N2) becomes V_{High}−V_{th_MN3}. Thus, the transistor MN4, the transistor MN12, and the transistor MN16 are brought into an on state, and each of the potentials of the node N1, the terminal ST, and the terminal OT becomes V_{Low}.

### [After Time T10]

After Time T10, for example, a variable potential with V_{Low} is input to the terminal CLK2 to set the potential of the node N1 to V_{Low} and the potential of the node N2 to V_{High}−V_{th_MN3}, and after that, V_{High} is supplied to the terminal CLK1 or the terminal PWC without input of V_{High} to the terminal IT. A specific operation example is described below.

### [From Time T11 to Time T12]

In the period from Time T11 to Time T12, V_{High} is supplied to the terminal CLK1.

The potential of the gate of the transistor MN11 is set to V_{Low}. The first terminal of the transistor MN11 is supplied with V_{High} from the terminal CLK1, and the potential of the second terminal of the transistor MN11 is V_{Low}. At this time, the potential of the second terminal of the transistor MN11 is lower than the potential of the first terminal thereof, so that the second terminal of the transistor MN11 serves as a source, and the transistor MN11 is in an off state. Thus, electrical continuity is not established between the terminal CLK1 and the terminal ST.

The potential of the gate of the transistor MN12 is V_{High}−V_{th_MN3}, and the second terminal of the transistor MN12 is supplied with V_{Low} from the wiring VSE4, whereby the transistor MN12 is in an on state. Thus, electrical continuity is established between the terminal ST and the wiring VSE4, so that the potential of the terminal ST becomes V_{Low}.

In the period from Time T11 to Time T12, after V_{High} is supplied to the terminal CLK1, V_{Low} is supplied to the terminal CLK1. The potential of the first gate of the transistor MN11 is V_{Low}, the first terminal of the transistor MN11 is supplied with V_{Low} from the terminal CLK1, and the potential of the second terminal of the transistor MN11 is V_{Low}; thus, the transistor MN11 is in an off state when the threshold voltage of the transistor MN11 is in an appropriate range.

The transistor MN11 remains in an off state even when the variable potential with V_{Low} is input to the terminal CLK2 to set the potential of the node N1 to V_{Low} and the potential of the node N2 to V_{High}−V_{th_MN3}, and then V_{High} is supplied to the terminal CLK1 without input of V_{High} to the terminal IT as described above. After that, even when V_{Low} is supplied to the terminal CLK1, the transistor MN11 remains in an off state.

### [From Time T12 to Time T13]

In the period from Time T12 to Time T13, V_{High} is supplied to the terminal PWC.

The potential of a first gate of the transistor MN15 is set to V_{Low}. The first terminal of the transistor MN15 is supplied with V_{High} from the terminal PWC, and the potential of the second terminal of the transistor MN15 is V_{Low}. At this time, the potential of the second terminal of the transistor MN15 is lower than the potential of the first terminal thereof, so that the second terminal of the transistor MN15 serves as a source, and the transistor MN15 is in an off state. Thus, electrical continuity is not established between the terminal PWC and the terminal OT.

The potential of the first gate of the transistor MN16 is V_{High}−V_{th_MN3}, and the second terminal of the transistor MN16 is supplied with V_{Low} from the wiring VSE5, whereby the transistor MN16 is in an on state. Thus, electrical continuity is established between the terminal OT and the wiring VSE5, so that the potential of the terminal OT becomes V_{Low}.

In the period from Time T12 to Time T13, after V_{High} is supplied to the terminal PWC, V_{Low} is supplied to the terminal PWC. The potential of the first gate of the transistor MN15 is V_{Low}, the first terminal of the transistor MN15 is supplied with V_{Low} from the terminal PWC, and the potential of the second terminal of the transistor MN15 is V_{Low}; thus, the transistor MN15 is in an off state.

The transistor MN15 remains in an off state even when the variable potential with V_{Low} is input to the terminal CLK2 to set the potential of the node N1 to V_{Low} and the potential of the node N2 to V_{High}−V_{th_MN3}, and then V_{High} is supplied to the terminal PWC without input of V_{High} to the terminal IT as described above. After that, even when V_{Low} is supplied to the terminal PWC, the transistor MN15 remains in an off state.

Although the operation example of the circuit 100A11 is described above, the operation method of the semiconductor device of one embodiment of the present invention is not limited thereto. For example, the operation method of the circuit 100A11 (the timing chart in FIG. 42) may be changed depending on the situation.

### <<Structure Example of Driver Circuit SD>>

Next, a structure example of the driver circuit SD is described.

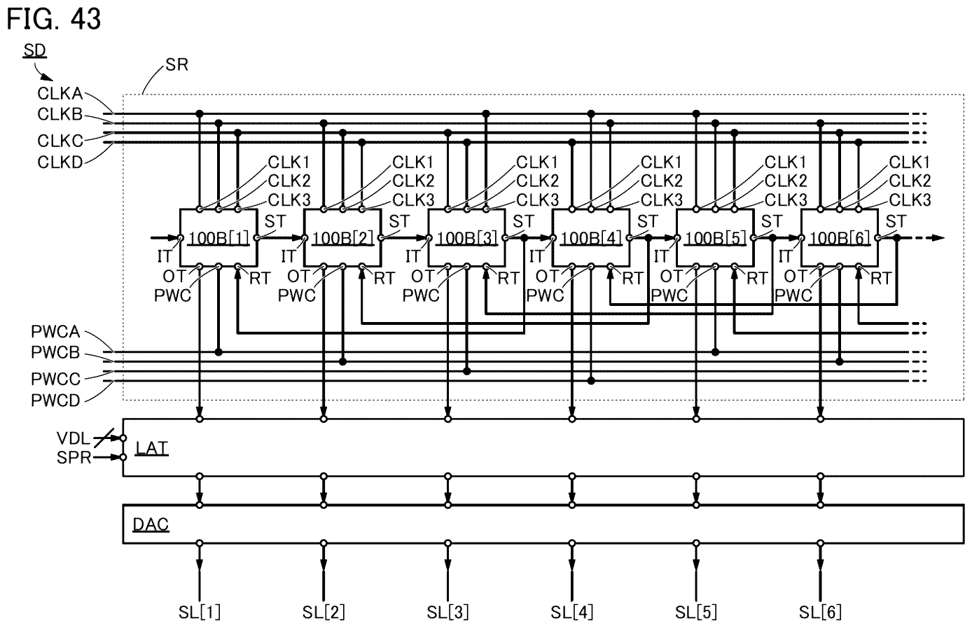

FIG. 43 illustrates a structure example of the driver circuit SD of one embodiment of the present invention that can be applied to the display apparatus DSP in FIG. 32. The driver circuit SD illustrated in FIG. 43 includes a circuit SR, a circuit LAT, and a circuit DAC, for example. Specifically, the circuit SR includes a circuit 100B[1] to a circuit 100B[n+1]. Note that the circuit 100B[n+1] is a circuit for transmitting data from the terminal ST of the circuit 100B[n+1] to a terminal RT of a circuit 100B[n]. FIG. 43 selectively illustrates the circuit 100B[1] to a circuit 100B[6].

Each of the circuit 100B[1] to the circuit 100B[n+1] includes, for example, the terminal IT, the terminal ST, the terminal CLK1, the terminal CLK2, a terminal CLK3, the terminal OT, the terminal PWC, and the terminal RT.

In the circuit SR, the wiring CLKA to the wiring CLKD and the wiring PWCA to the wiring PWCD extend.

In a circuit 100B[4k-3](here, k is an integer greater than or equal to 1 and 1≤4k−3≤n is satisfied), the terminal CLK1 is connected to the wiring CLKA, the terminal CLK2 is connected to the wiring CLKB, the terminal CLK3 is connected to the wiring CLKC, and the terminal PWC is connected to the wiring PWCA. In a circuit 100B[4k-2](here, k is an integer greater than or equal to 1 and 2≤4k−2≤n is satisfied), the terminal CLK1 is connected to the wiring CLKB, the terminal CLK2 is connected to the wiring CLKC, the terminal CLK3 is connected to the wiring CLKD, and the terminal PWC is connected to the wiring PWCB. In a circuit 100B[4k-1](here, k is an integer greater than or equal to 1 and 3≤4k−1≤n is satisfied), the terminal CLK1 is connected to the wiring CLKC, the terminal CLK2 is connected to the wiring CLKD, the terminal CLK3 is connected to the wiring CLKA, and the terminal PWC is connected to the wiring PWCC. In a circuit 100B[4k](here, k is an integer greater than or equal to 1 and 4≤4k≤n is satisfied), the terminal CLK1 is connected to the wiring CLKD, the terminal CLK2 is connected to the wiring CLKA, the terminal CLK3 is connected to the wiring CLKB, and the terminal PWC is connected to the wiring PWCD.

The terminal ST of a circuit 100B[ ](here, j is an integer greater than or equal to 1 and less than or equal to n) is connected to the terminal IT of a circuit 100B[+1]. The terminal RT of the circuit 100B[j] is connected to the terminal ST of the circuit 100B[j+1].

The terminals OT of the circuit 100B[1] to the circuit 100B[n] are connected to the respective input terminals of the circuit LAT. The output terminals of the circuit LAT are connected to the respective input terminals of the circuit DAC. The circuit LAT is connected to a wiring VDL. The circuit LAT is connected to a wiring SPR. The output terminals of the circuit DAC are connected to the wiring SL[1] to the wiring SL[n]. Note that the wiring SL[1] to the wiring SL[n] are wirings corresponding to the wiring SLS[1] to the wiring SLS[n] illustrated in FIG. 32. FIG. 43 selectively illustrates the wiring SL[1] to a wiring SL[6].

Each of the circuit 100B[1] to the circuit 100B[n] has functions of, for example, retaining information input to the terminal IT and outputting the retained information to one or both of the terminal OT and the terminal ST.

For example, the circuit 100B[j] has a function of outputting information retained in the circuit 100B[j] to the terminal ST when a high-level potential is input to the terminal CLK1. For another example, the circuit 100B[j] has a function of outputting information retained in the circuit 100B[j] to the terminal OT when a high-level potential is input to the terminal PWC. For another example, the circuit 100B[j] has a function of resetting information retained in the circuit 100B[j] when a high-level potential is input to one or both of the terminal RT and the terminals CLK2 and CLK3. The circuit 100B[j] is preferably configured to retain new information that is input to the terminal IT of the circuit 100B[j] after the information retained in the circuit 100B[j] is reset.

That is, the circuit SR illustrated in FIG. 43 functions as a shift register like the driver circuit GD illustrated in FIG. 33 and FIG. 34.

As described in Embodiment 1, the circuit 100B[1] to a circuit 100B[m] may each have a function of a level shifter when a higher-level potential of the variable potential input to the terminal PWC is a potential higher than V_{High} or a potential higher than V_{Low} and lower than V_{High}.

Note that in the case where a level shifter is provided between the terminal OT of the circuit 100B and the circuit LAT, it is preferable that a higher-level potential of the variable potential input to the terminal PWC of the circuit 100B be V_{High} and the circuit 100B not have a function of a level shifter.

The wiring VDL functions as a wiring for transmitting a video signal for display in the pixel circuit PX included in the pixel array PA, for example. Note that in FIG. 43, the wiring VDL is illustrated as a wiring for transmitting digital data.

The circuit LAT includes retention circuits of n columns, for example. The circuit LAT has a function of retaining video signals, which are input to the wiring VDL, in retention circuits in response to the signals from the terminals OT of the circuit 100B[1] to the circuit 1001B[n]. Specifically, for example, when the potential of the terminal OT in the circuit 100B[j] is a high-level potential, the circuit LAT retains the video signal, which is input to the wiring VDL, in the retention circuit in the j-th column. For example, the circuit LAT has a function of collectively outputting the video signals, which are retained in the retention circuits of the n columns, to the output terminals of the circuit LAT when a high-level potential is input to the wiring SPR.

The circuit DAC has a function of converting a video signal which is digital data output from the output terminals of the circuit LAT into analog data (analog potential), for example. Note that the analog data (analog potential) is transmitted to the wiring SL in the column.

Note that a wiring other than the wiring CLKA to the wiring CLKD and the wiring PWCA to the wiring PWCD may extend in the driver circuit SD illustrated in FIG. 43. The structure of the driver circuit SD illustrated in FIG. 43 is an example, and the number of wirings, the connection structure, and the like may be modified as appropriate.

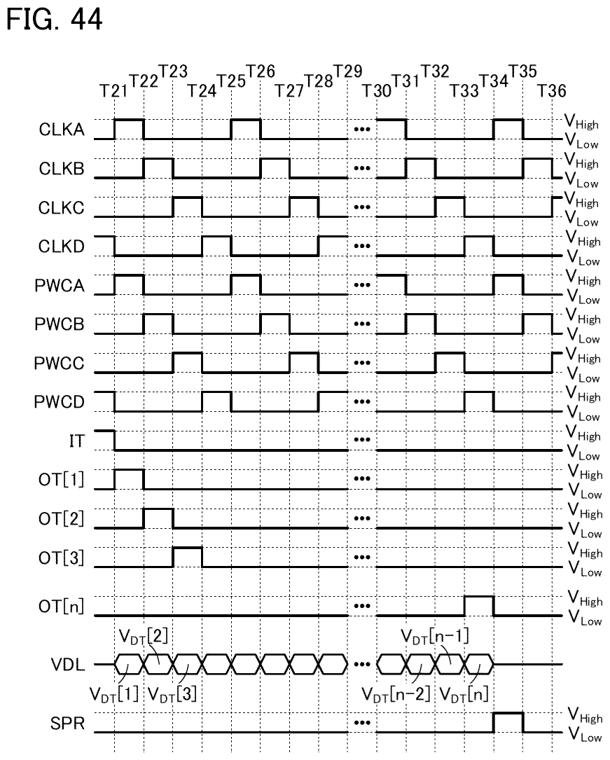

FIG. 44 is a timing chart showing an operation example of the driver circuit SD. FIG. 44 shows potential changes of the wiring CLKA to the wiring CLKD, the wiring PWCA to the wiring PWCD, the terminal IT, the terminal OT[1], the terminal OT[2], the terminal OT[3], a terminal OT[n], and the wiring SPR in the period from Time T21 to Time T36 and around the period. Note that a terminal OT[j] is the terminal OT included in the circuit 100B[j]. In the example shown in FIG. 44, a video signal V_{DT}[1] to a video signal V_{DT}[n] are sequentially input to the wiring VDL.

In the period from Time T21 to Time T22, the high-level potential V_{High} is supplied to the wiring CLKA and the wiring PWCA. In the period from Time T22 to Time T23, the high-level potential V_{High} is supplied to the wiring CLKB and the wiring PWCB. In the period from Time T23 to Time T24, the high-level potential V_{High} is supplied to the wiring CLKC and the wiring PWCC. In the period from Time T24 to Time T25, the high-level potential V_{High} is supplied to the wiring CLKD and the wiring PWCD. After Time T25, the high-level potential V_{High} is supplied to the wiring CLKA to the wiring CLKD and the wiring PWCA to the wiring PWCD at the same timing as that in the period from Time T21 to Time T25.

Since V_{High} is supplied to the wiring CLKA to the wiring CLKD and the wiring PWCA to the wiring PWCD at the above timings, the terminal OT[1] to the terminal OT[n] sequentially output V_{High} at predetermined timings when V_{High} is supplied to the terminal IT in the period before Time T21. For example, the terminal OT[1] outputs V_{High} in the period from Time T21 to Time T22, the terminal OT[2] outputs V_{High} in the period from Time T22 to Time T23, and the terminal OT[3] outputs V_{High} in the period from Time T23 to Time T24. For example, a terminal OT[n-2] outputs V_{High} in the period from Time T31 to Time T32, the terminal OT[n-1] outputs V_{High} in the period from Time T32 to Time T33, and the terminal OT[n] outputs V_{High} in the period from Time T33 to Time T34.

Note that the timing chart of FIG. 44 shows the case where n is a multiple of 4. In the case where n is not a multiple of 4 in the driver circuit SD, potentials supplied to the wiring CLKA to the wiring CLKD and the wiring PWCA to the wiring PWCD in the period from Time T30 to Time T34 need to be replaced as appropriate.

The circuit LAT retains the video signal V_{DT}[1], which is input to the wiring VDL, in the retention circuit of the first column at the timing when V_{High} is output from the terminal OT[1]. The circuit LAT retains a video signal V_{DT}[2], which is input to the wiring VDL, in the retention circuit of the second column at the timing when V_{High} is output from the terminal OT[2], and retains a video signal V_{DT}[3], which is input to the wiring VDL, in the retention circuit of the third column at the timing when the V_{High} is output from the terminal OT[3]. Similar operations are sequentially continued, and the video signal V_{DT}[n], which is input to the wiring VDL, is retained in the retention circuit of the n-th column at the timing when V_{High} is output from the terminal OT[n].

When the potential of the wiring SPR changes to the high-level potential V_{High} in the period from Time T34 to Time T35, the circuit LAT outputs the video signal V_{DT}[1] to the video signal V_{DT}[n], which have been retained in the retention circuits of the n columns in the circuit LAT, to the circuit DAC through the output terminals of the circuit LAT.

The driver circuit SD is capable of transmitting the video signals to the pixel circuits in the pixel array PA by performing the above operation as an example in the timing chart in FIG. 44.

### <<Structure Example of Circuit 100B>>

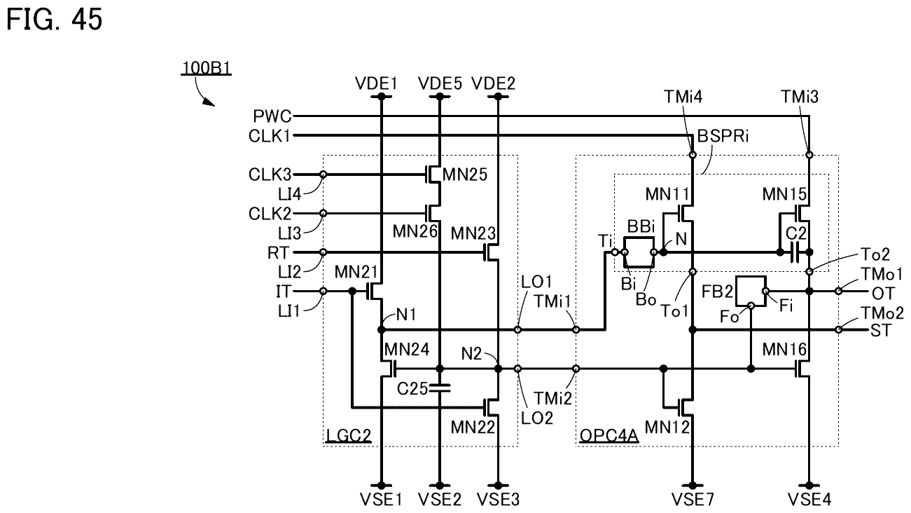

A circuit 100B1 in FIG. 45 has a circuit structure that can be applied to each of the circuit 100B[1] to a circuit 100B[n+2] included in the driver circuit SD.

The circuit 100B1 in FIG. 45 is a modification example of the circuit MDV in FIG. 1 and has a structure in which the circuit LGC1 in FIG. 1 is replaced with a circuit LGC2 and the circuit OPC1 in FIG. 1 is replaced with a circuit OPC4A. Note that in the circuit 100B1 in FIG. 45, portions similar to those in the circuit MDV in FIG. 1 are not described.

The circuit LGC2 in FIG. 45 includes a transistor MN21 to a transistor MN26 and a capacitor element C25, for example. The circuit LGC2 includes the terminal LIT to a terminal LI4, the terminal LOT, and the terminal L02.

The circuit OPC4A in FIG. 45 includes a circuit BSPRi, the circuit FB2, the transistor MN12, and the transistor MN16, for example. The circuit BSPRi includes a circuit BBi, the transistor MN11, the transistor MN15, the capacitor element C2, the terminal Ti, a terminal ToT, and a terminal To2. Note that the circuit BSPRi is a modification example of the circuit BSPR in FIG. 1, and is different from the circuit BSPR in FIG. 1 in that the transistor MN11 and the transistor MN15 are included in the circuit BSPRi and the terminal TMi4, the terminal To1, and the terminal To2 are included. Note that the terminal To1 and the terminal To2 of the circuit BSPRi are terminals corresponding to the terminal To of the circuit BSPR in FIG. 1, and it can be said that the circuit BSPRi includes two output terminals. The circuit OPC4A includes the terminal TMi1, the terminal TMi2, the terminal TMo1, and the terminal TMo2.

As the transistor MN21 to the transistor MN26, for example, any of the transistors that can be used as the transistor MN1 to the transistor MN4, the transistor MN11, the transistor MN12, the transistor IMN15, and the transistor MN16 can be used.

In the circuit 100B1 in FIG. 45, the terminal IT is connected to the terminal LIT, the terminal RT is connected to the terminal LI2, the terminal CLK2 is connected to a terminal LI3, and the terminal CLK3 is connected to the terminal LI4. The terminal LO1 is connected to the terminal TMi1, the terminal L02 is connected to the terminal TMi2, the terminal CLK1 is connected to the terminal TMi4, and the terminal PWC is connected to the terminal TMi3. The terminal TMo1 is connected to the terminal OT, and the terminal TMo2 is connected to the terminal ST.

In the circuit LGC2, the terminal LIT is connected to a gate of the transistor MN21 and a gate of a transistor MN22. A first terminal of the transistor MN21 is connected to the wiring VDE1, and a second terminal of the transistor MN21 is connected to a first terminal of a transistor MN24 and the terminal LOT. The terminal LI4 is connected to a gate of a transistor MN25, and the terminal LI3 is connected to a gate of the transistor MN26. A first terminal of the transistor MN25 is connected to a wiring VDE5, and a second terminal of the transistor MN25 is connected to a first terminal of a transistor MN26. The terminal LI2 is connected to a gate of a transistor MN23, and a first terminal of the transistor MN23 is connected to the wiring VDE2. A second terminal of the transistor MN23 is connected to a gate of the transistor MN24, a first terminal of the transistor MN22, a second terminal of the transistor MN26, a first terminal of the capacitor element C25, and the terminal L02. A second terminal of the transistor MN24 is connected to the wiring VSE1, a second terminal of the capacitor element C25 is connected to the wiring VSE2, and a second terminal of the transistor MN22 is connected to the wiring VSE3.

In the circuit OPC4A, the terminal TMi1 of the circuit OPC4A is connected to the terminal Ti of the circuit BSPRi, and the terminal Ti of the circuit BSPRi is connected to the terminal Bi of the circuit BBi. The terminal Bo of the circuit BBi is connected to the gate of the transistor MN11, the gate of the transistor MN15, and the first terminal of the capacitor element C2. The first terminal of the transistor MN11 is connected to the terminal TMi4, and the second terminal of the transistor MN11 is connected to the terminal To1 of the circuit BSPRi. The terminal To1 of the circuit BSPRi is connected to the first terminal of the transistor MN12 and the terminal TMo2. The first terminal of the transistor MN15 is connected to the terminal TMi3, and the second terminal of the transistor MN15 is connected to the terminal To2 of the circuit BSPRi. The terminal To2 of the circuit BSPRi is connected to the second terminal of the capacitor element C2, the terminal Fi of the circuit FB2, the first terminal of the transistor MN16, and the terminal TMo2. The terminal Fo of the circuit FB2 is connected to the gate of the transistor MN12, the gate of the transistor MN16, and the terminal TMi2. The second terminal of the transistor MN12 is connected to the wiring VSE7, and the second terminal of the transistor MN16 is connected to the wiring VSE4.

The circuit BSPRi is a circuit that increases the potential of the node N by bootstrapping in the capacitor element C2. Note that the first terminal of the capacitor element C2 is connected not only to the gate of the transistor MN15 but also to the gate of the transistor MN11; thus, the transistor MN11 can have a high on-state current.

The circuit BB illustrated in FIG. 8A to FIG. 8F can be used as the circuit BBi. Thus, for the operation example of the circuit BBi, the description of the circuit BB illustrated in FIG. 8A to FIG. 8F in Embodiment 1 can be referred to. The circuit FB illustrated in FIG. 3 to FIG. 7B can be used as the circuit FB2. Thus, for the operation example of the circuit FB2, the description of the circuit FB illustrated in FIG. 3 to FIG. 7B in Embodiment 1 can be referred to.

For the wiring VDE5, the description of the wiring VDE1 or the wiring VDE2 can be referred to, for example.

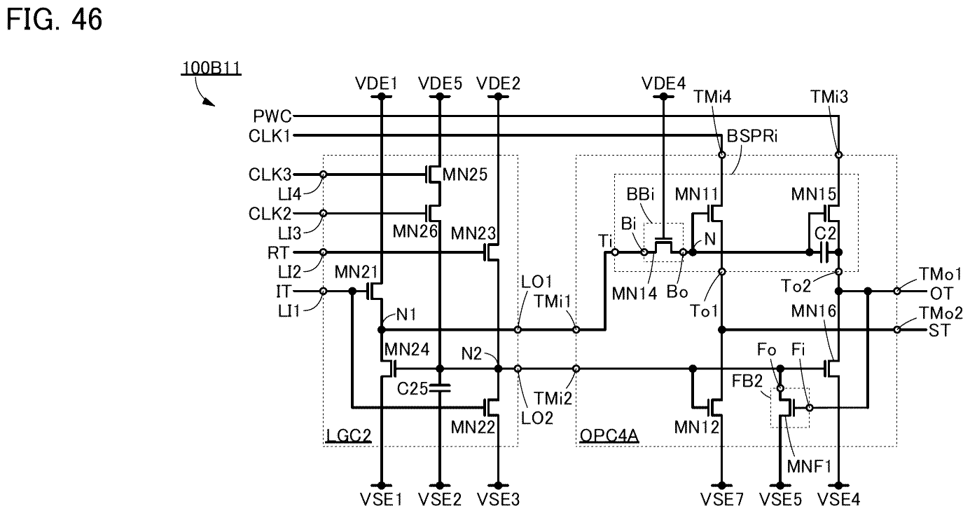

FIG. 46 illustrates another specific example of the circuit 100B1. A circuit 100B11 illustrated in FIG. 46 has a circuit structure in which the circuit BB illustrated in FIG. 8A is used the circuit BBi included in the circuit BSPRi in the circuit 100B1 in FIG. 45, and the circuit FB illustrated in FIG. 3 is used as the circuit FB2 in the circuit BSPRi of the circuit 100B1 in FIG. 45. In this case, for the transistor MN14 included in the circuit BBi, the description of the transistor MN14 illustrated in FIG. 37 is referred to. For the transistor MNF1 included in the circuit FB2, the description of the transistor MNF1 illustrated in FIG. 37 is referred to.

In FIG. 46, a gate of the transistor MN14 is connected to a wiring VDE4. The first terminal of the transistor MN14 is connected to the terminal Bi, and a second terminal of the transistor MN14 is connected to the terminal Bo. The gate of the transistor MNF1 is connected to the terminal Fi, the first terminal of the transistor MNF1 is connected to the terminal Fo, and the second terminal of the transistor MNF1 is connected to the wiring VSE5.

In each of the circuit 100B1 in FIG. 45 and the circuit 100B11 in FIG. 46, the potential of the terminal TMo1 can be fed back to the gates of the transistor MN12 and the transistor MN16 by the circuit FB2 included in the circuit OPC4A; thus, the potentials of the gates of the transistor MN12 and the transistor MN16 do not greatly change even when noise is input to the gates of the transistor MN12 and the transistor MN16. Thus, the use of the circuit 100B1 in FIG. 45 or the circuit 100B11 in FIG. 46 as the circuit 100B of the driver circuit SD in FIG. 43 can stabilize the operation of the driver circuit SD.

Note that the structure of the retention circuit in the semiconductor device of one embodiment of the present invention is not limited to the structure in FIG. 45. For example, in the circuit 100B1 in FIG. 45, the potential output to the terminal TMo1 is fed back to the gates of the transistor MN12 and the transistor MN16; alternatively, the potential output to the terminal TMo2 may be fed back to the gates of the transistor MN12 and the transistor MN16.

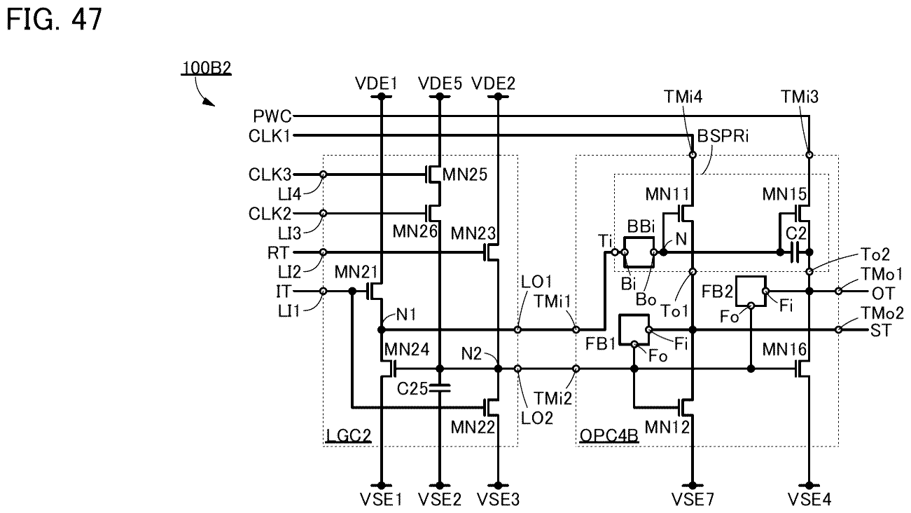

A circuit 100B2 illustrated in FIG. 47 is a modification example of the circuit 100B1 in FIG. 45 and is different from the circuit 100B1 in that the circuit FB1 is additionally provided. Specifically, the circuit 100B2 in FIG. 47 includes the circuit LGC2 and a circuit OPC4B, and the circuit OPC4B has a structure in which the circuit FB1 is provided in the circuit OPC4A illustrated in FIG. 45. Like the circuit FB2, the circuit FB1 includes the terminal Fi and the terminal Fo, and has a function of obtaining the potential of the terminal Fi and supplying a fixed potential to the terminal Fo with reference to the potential. Thus, the circuit FB illustrated in FIG. 3 to FIG. 7B can be used as the circuit FB1 like the circuit FB2.

In the circuit 100B2 in FIG. 47, even when the potential of the terminal TMo1 is V_{Low}, the potential of the terminal TMo2 can be fed back to the gates of the transistor MN12 and the transistor MN16 by the circuit FB1 as long as the potential of the terminal TMo2 is V_{High}. Thus, electrical continuity is established between the gate of each of the transistor MN12 and the transistor MN16 and a wiring for supplying the low-level potential V_{Low}, so that V_{Low} can be supplied to the gates of the transistor MN12 and the transistor MN16.

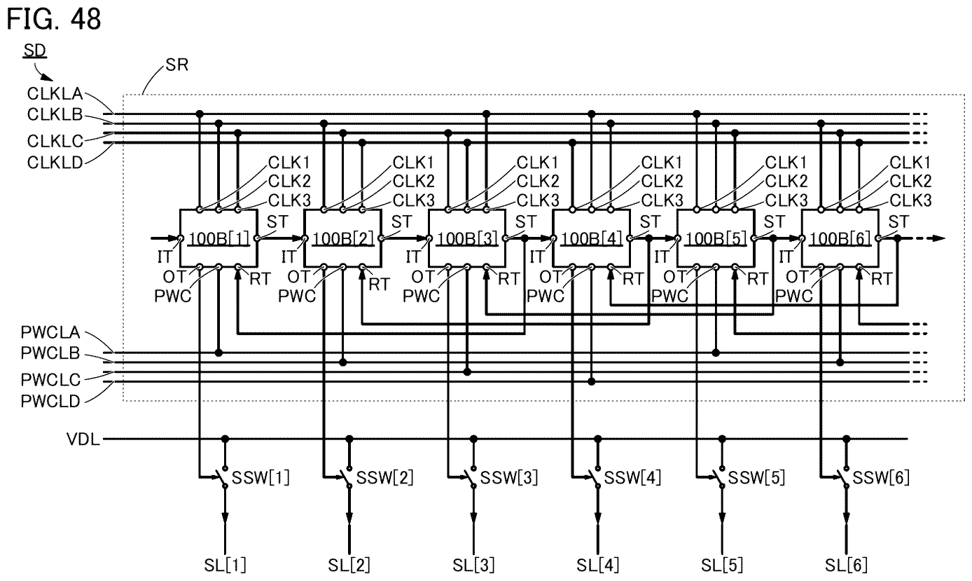

Note that the structure of the driver circuit of the semiconductor device of one embodiment of the present invention is not limited to the structure the driver circuit SD in FIG. 43. For example, the structure of the driver circuit SD in FIG. 43 can be changed into a circuit structure illustrated in FIG. 48.

The driver circuit SD illustrated in FIG. 48 is different from the driver circuit SD in FIG. 43 in not being provided with the circuit LAT and the circuit DAC and in including a switch SSW[1] to a switch SSW[n] (the switch SSW[1] to a switch SSW[6] are selectively illustrated in FIG. 48).

As each of the switch SSW[1] to the switch SSW[n], an electrical switch (e.g., an analog switch or a transistor) can be used, for example. When a transistor is used as each of the switch SSW[1] to the switch SSW[n], for example, the transistor can be a transistor having a structure similar to that of the transistor MN1 or the transistor MN2. A mechanical switch may be used other than the electrical switch.

The switch SSW[1] to the switch SSW[n] each include a control terminal. The control terminal has a function of a terminal that receives a signal for controlling a switch SSW[j]. In this specification and the like, it is assumed that the switch SSW[j] is brought into an on state when a high-level potential is input to the control terminal of the switch SSW[j], and the switch SSW[j] is brought into an off state when a low-level potential is input to the control terminal of the switch SSW[j].

In FIG. 48, the terminal OT of the circuit 100B[j] (here, j is an integer greater than or equal to 1 and less than or equal to n) is connected to the control terminal of the switch SSW[j]. A first terminal of the switch SSW[j] is connected to the wiring VDL, and a second terminal of the switch SSW[j] is connected to the wiring SL[j].

The wiring VDL in FIG. 48 functions as a wiring for transmitting a video signal, which is analog data, to each of first terminals of the switch SSW[1] to the switch SSW[n].

Although not illustrated in FIG. 48, a video signal generation circuit is assumed to be connected to the wiring VDL. The video signal generation circuit includes, for example, a digital-to-analog converter circuit and a buffer circuit. The video signal generation circuit has a function of converting a video signal, which is digital data, into analog data with use of the digital-to-analog converter circuit and outputting the video signal, which has been converted into the analog data, to the wiring VDL through the buffer circuit, for example.

The driver circuit SD in FIG. 48 inputs a start pulse signal to the terminal IT of the circuit 100B[1] and then periodically inputs clock signals to the terminal IT, whereby high-level potentials can be successively output from the terminals OT of the circuit 100B[1] to the circuit 100B[n]. Thus, the switch SSW[1] to the switch SSW[n] can be brought into on state one by one from the first column. Moreover, when a video signal is transmitted from the video signal generation circuit to the wiring VDL in accordance with the timing at which the switch SSWU[j] is brought into an on state, the video signal can be written to the pixel circuit PX positioned in the j-th column of the pixel array PA. That is, the use of the driver circuit SD in FIG. 48 enables line sequential driving.

In the driver circuit SD in FIG. 43, the scale of the circuit LAT and the circuit DAC is increased in accordance with the number of columns. Meanwhile, in the driver circuit SD in FIG. 48, the video signal generation circuit is connected to only the wiring VDL; thus, the circuit area of the driver circuit SD in FIG. 48 can be smaller than the circuit area of the driver circuit SD in FIG. 43.

Note that the above-described switch SSW[j] and the operation thereof are examples. The switch SSW[ ] may be a switch that is brought into an on state when a low-level potential is input to the control terminal, and is brought into an off state when a high-level potential is input to the control terminal depending on the situation.

### <Other Structure Examples of Retention Circuit>

Although a structure example of the retention circuit that can be used in the shift register included in the driver circuit is described above, the structure of the retention circuit, which is the semiconductor device of one embodiment of the present invention, is not limited to the above-described structure. The structure described below can be used as the structure in which a potential output from the retention circuit is fed back to the retention node.

### <<Structure Example 1>>

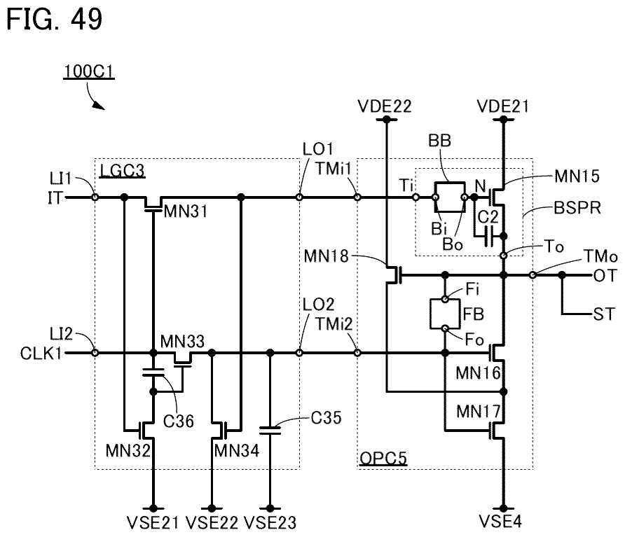

A circuit 100C1 illustrated in FIG. 49 has a circuit structure different from that of the above-described retention circuit. The circuit 100C1 includes a circuit LGC3 and a circuit OPC5, for example.

The circuit 100C1 includes, for example, the terminal IT and the terminal CLK2 which have functions of input terminals and the terminal OT and the terminal ST which have functions of output terminals.

For convenience, the circuit LGC3 in FIG. 49 is illustrated as including the terminal LIT, the terminal LI2, the terminal LO1, and the terminal L02. Likewise, the circuit OPC5 is illustrated as including the terminal TMi1, the terminal TMi2, and the terminal TMo. In the circuit 100C1 in FIG. 49, the terminal IT is connected to the terminal LIT, the terminal CLK1 is connected to the terminal LI2, the terminal LO1 is connected to the terminal TMi1, the terminal L02 is connected to the terminal TMi2, and the terminal TMo is connected to the terminal OT and the terminal ST.

Like the circuit LGC1, the circuit LGC3 has a function of, for example, outputting to the terminal LO1 a signal with the same logic as the signal input to the terminal IT and outputting to the terminal L02 a signal whose logic is inverted from the signal input to the terminal IT. Like the circuit OPC1, the circuit OPC5 has a function of, for example, a logic circuit that generates signals corresponding to potentials input to the terminal TMi1 and the terminal TMi2 and outputs the signals to the terminal TMo. Note that one or both of the circuit LGC3 and the circuit OPC5 may be not a logic circuit but an analog circuit.

As illustrated in FIG. 49, the circuit LGC3 includes a transistor MN31 to a transistor MN34, a capacitor element C35, and a capacitor element C36. The circuit OPC5 includes the circuit BSPR, the circuit FB, and the transistor MN16 to a transistor IMNi8. Note that the circuit BSPR includes the circuit BB, the transistor MIN15, and the capacitor element C2. Note that the circuit BSPR corresponds to the circuit BSPR in FIG. 1, and the circuit FB corresponds to the circuit FB in FIG. 1.

The circuit BSPR includes, for example, the terminal Ti having a function of an input terminal and the terminal To having a function of an output terminal. The circuit BB includes, for example, the terminal Bi having a function of an input terminal and the terminal Bo having a function of an output terminal. The circuit FB includes, for example, the terminal Fi having a function of an input terminal and the terminal Fo having a function of an output terminal.

Note that FIG. 49 shows an example of separating the transistor MN31 to the transistor MN34, the transistor MN15 to the transistor MN18, the capacitor element C2, the capacitor element C35, and the capacitor element C36 into the circuit LGC3 and the circuit OPC5, and the structures of the circuit LGC3 and the circuit OPC5 are not particularly limited. For example, in FIG. 49, the capacitor element C35 may be provided not in the circuit LGC3 but in the circuit OPC5.

As each of the transistor MN31 to the transistor MN34 and the transistor MN15 to the transistor MN18 illustrated in FIG. 49, any one of the transistors that can be used as the transistor MN1 to the transistor MN4, the transistor MN15, and the transistor MNN16 described in FIG. 1 can be used, for example.

In FIG. 49, the terminal LIT is connected to a first terminal of the transistor MN31 and a gate of a transistor MN32. A second terminal of the transistor MN31 is connected to a gate of the transistor MN34 and the terminal LOT. The terminal L12 is connected to a gate of the transistor MN31, a first terminal of a transistor MN33, and a first terminal of the capacitor element C36. A second terminal of the transistor MN33 is connected to a first terminal of the transistor MN34, a first terminal of the capacitor element C35, and the terminal L02. A gate of the transistor MN33 is connected to a first terminal of the transistor MN32 and a second terminal of the capacitor element C36. A second terminal of the transistor MN32 is connected to a wiring VSE21, a second terminal of the transistor MN34 is connected to a wiring VSE22, and a second terminal of the capacitor element C35 is connected to a wiring VSE23.

The terminal TMi1 is connected to the terminal Ti of the circuit BSPR, and the terminal Ti of the circuit BSPR is connected to the terminal Bi of the circuit BB. The terminal Bo of the circuit BB is connected to the gate of the transistor MN15 and the first terminal of the capacitor element C2, the first terminal of the transistor MN15 is connected to a wiring VDE21, and the second terminal of the transistor MN15 is connected to the second terminal of the capacitor element C2 and the terminal To of the circuit BSPR.

Note that the circuit BSPR in FIG. 49 has a circuit structure similar to that of the circuit BSPR illustrated in FIG. 2A. Thus, for the operation example of the circuit BSPR in FIG. 49, the description of the circuit BSPR illustrated in FIG. 8A to FIG. 8F in Embodiment 1 can be referred to. The circuit BB illustrated in FIG. 8A to FIG. 8F can be used as the circuit BB in FIG. 49. Thus, for the operation example of the circuit BB in FIG. 49, the description of the circuit BB illustrated in FIG. 8A to FIG. 8F in Embodiment 1 can be referred to. The circuit FB illustrated in FIG. 3 to FIG. 7B can be used as the circuit FB in FIG. 49. Thus, for the operation example of the circuit FB, the description of the circuit FB illustrated in FIG. 3 to FIG. 7B in Embodiment 1 can be referred to.

The terminal TMi2 is connected to the gate of the transistor MN16, a gate of a transistor MN17, and the terminal Fo of the circuit FB. The terminal To of the circuit BSPR is connected to the terminal TMo, the first terminal of the transistor MN16, a gate of the transistor MN18, and the terminal Fi of the circuit FB. A first terminal of the transistor MN18 is connected to a wiring VDE22. The second terminal of the transistor MN16 is connected to a first terminal of the transistor MN17 and a second terminal of the transistor MN18. A second terminal of the transistor MN17 is connected to the wiring VSE4.

The wiring VDE21 and the wiring VDE22 each has a function of a wiring for supplying a fixed potential, for example. The fixed potential can be a high-level potential, for example. Note that the wiring VDE21 and the wiring VDE22 can supply fixed potentials equal to each other or fixed potentials different from each other. Note that in the case where the wiring VDE21 and the wiring VDE22 supply fixed potentials equal to each other, for example, the wiring VDE21 and the wiring VDE22 may be the same wiring.

One or both of the wiring VDE21 and the wiring VDE22 may have a function of a wiring for supplying not a fixed potential but a variable potential (sometimes referred to as a pulse voltage, a pulse potential, a pulse signal, a clock signal, or the like).

The wiring VSE4 and the wiring VSE21 to the wiring VSE23 each have a function of a wiring for supplying a fixed potential, for example. The fixed potential can be, for example, a low-level potential, a ground potential, or a negative potential. Note that the wiring VSE4 and the wiring VSE21 to the wiring VSE23 can supply fixed potentials equal to each other or fixed potentials different from each other. Alternatively, two or more wirings selected from the wiring VSE4 and the wiring VSE21 to the wiring VSE23 may supply fixed potentials equal to each other, and the other wiring(s) may supply a potential different from the fixed potentials. Furthermore, the two or more wirings among the wiring VSE4 and the wiring VSE21 to the wiring VSE23 which supply fixed potentials equal to each other may be the same wiring. For example, in the case where the wiring VSE21 and the wiring VSE22 supply fixed potentials equal to each other, the wiring VSE21 and the wiring VSE22 may be the same wiring.

One or more selected from the wiring VSE4 and the wiring VSE21 to the wiring VSE23 may have a function of a wiring for supplying not a fixed potential but a variable potential.

The circuit 100C1 can be used as a retention circuit of a shift register included in a gate driver circuit of a display apparatus, for example. In the case where a shift register is formed using the circuit 100C, the terminal OT of the circuit 100C1 in the previous stage is connected to the terminal IT of the circuit 100C1 in the subsequent stage. The terminal ST is connected to a gate line extending to a display portion of the display apparatus. The terminal CLK1 is connected to a wiring for supplying a variable potential (e.g., a pulse potential such as a clock signal). That is, the shift register operates with a variable potential such as a clock signal input to the terminal CLK1.

The clock signal input to the shift register can be a multiphase clock signal. For example, a wiring for supplying a first clock signal is connected to the terminal CLK1 of the circuit 100C1 in the odd-numbered stage, and a wiring for supplying a second clock signal is connected to the terminal CLKI1 of the circuit 100C1 in the even-numbered stage, whereby a shift register that operates in a two-phase clock mode can be achieved. Similarly, a shift register that operates with a clock signal of three or more phases may be formed.

Note that a clock signal input to the shift register may be a single-phase clock signal in some situations.

### <<Structure Example 2>>

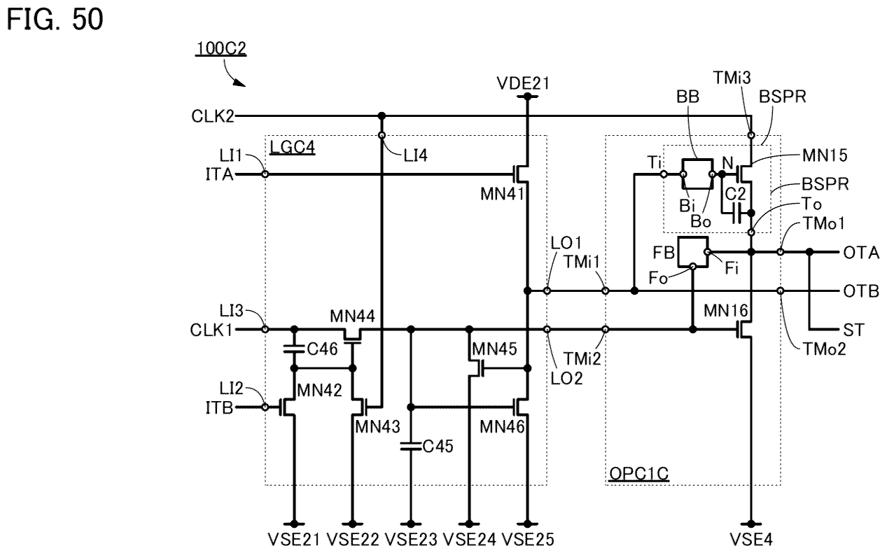

A circuit 100C2 illustrated in FIG. 50 has a circuit structure different from that of the above-described retention circuit. The circuit 100C2 includes a circuit LGC4 and a circuit OPC1C, for example. The circuit OPC1C is a modification example of the circuit OPC1 in FIG. 1 described in Embodiment 1, and is different from the circuit OPC1 in FIG. 1 in including not the terminal TMo but the terminal TMo1 and the terminal TMo2.

The circuit 100C2 includes, for example, a terminal ITA, a terminal ITB, the terminal CLK1, and the terminal CLK2 which have functions of input terminals and a terminal OTA, a terminal OTB, and the terminal ST which have functions of output terminals.

For convenience, the circuit LGC4 in FIG. 50 is illustrated as including the terminal LIT, the terminal LI2, the terminal LI3, the terminal LI4, the terminal LO1, and the terminal LO2. Likewise, the circuit OPC1 is illustrated as including the terminal TMi1, the terminal TMi2, the terminal TMo1, and the terminal TMo2. In the circuit 100C2 in FIG. 50, the terminal ITA is connected to the terminal LIT, the terminal ITB is connected to the terminal LI3, the terminal CLK1 is connected to the terminal LI2, the terminal LO1 is connected to the terminal TMi1, the terminal LO2 is connected to the terminal TMi2, the terminal CLK2 is connected to the terminal LI4 and the terminal TMi3, the terminal TMoT is connected to the terminal OTA and the terminal ST, and the terminal TMo2 is connected to the terminal OTB.

Like the circuit LGC1, the circuit LGC4 has a function of, for example, outputting to the terminal LO1 a signal with the same logic as the signal input to the terminal IT and outputting to the terminal LO2 a signal whose logic is inverted from the signal input to the terminal IT. Like the circuit OPC1, the circuit OPC1C has a function of, for example, a logic circuit that generates signals corresponding to potentials input to the terminal TMi1 to the terminal TMi3 and outputs the signals to the terminal TMo1 and the terminal TMo2. Note that one or both of the circuit LGC4 and the circuit OPCTC may be not a logic circuit but an analog circuit.

As illustrated in FIG. 50, the circuit LGC4 includes a transistor MN41 to a transistor MN46, a capacitor element C45, and a capacitor element C46. The circuit OPC1C includes the circuit BSPR, the circuit FB, and the transistor MN16. Note that the circuit BSPR includes the circuit BB, the transistor MN15, and the capacitor element C2. Note that the circuit BSPR corresponds to the circuit BSPR in FIG. 1, and the circuit FB corresponds to the circuit FB in FIG. 1.

The circuit BSPR includes, for example, the terminal Ti having a function of an input terminal and the terminal To having a function of an output terminal. The circuit BB includes, for example, the terminal Bi having a function of an input terminal and the terminal Bo having a function of an output terminal. The circuit FB includes, for example, the terminal Fi having a function of an input terminal and the terminal Fo having a function of an output terminal.

Note that FIG. 50 shows an example of separating the transistor MN41 to the transistor MN46, the transistor MN15, the transistor MN16, the capacitor element C2, the capacitor element C45, and the capacitor element C46 into the circuit LGC4 and the circuit OPC1C, and the structures of the circuit LGC4 and the circuit OPC1C are not particularly limited. For example, in FIG. 50, the capacitor element C45 may be provided not in the circuit LGC4 but in the circuit OPC1C.

As each of the transistor MN41 to the transistor MN46, the transistor MN15, and the transistor MN16 illustrated in FIG. 50, any one of the transistors that can be used as the transistor MN1 to the transistor MN4, the transistor MN15, and the transistor MN16 described in FIG. 1 can be used, for example.

In FIG. 50, the terminal LIT is connected to agate of the transistor MN41. The terminal LI2 is connected to a gate of a transistor MN42. The terminal LI3 is connected to a first terminal of a transistor MN44 and a first terminal of the capacitor element C46. A first terminal of the transistor MN41 is connected to the wiring VDE21, and a second terminal of the transistor MN41 is connected to the terminal LOT, a gate of a transistor MN45, and a first terminal of the transistor MN46. A second terminal of the transistor MN44 is connected to a first terminal of the transistor MN45, a gate of the transistor MN46, a first terminal of the capacitor element C45, and the terminal L02. A gate of the transistor MN44 is connected to a first terminal of the transistor MN42, a first terminal of a transistor MN43, and a second terminal of the capacitor element C46. A gate of the transistor MN43 is connected to the terminal LI4. A second terminal of the transistor MN42 is connected to the wiring VSE21, a second terminal of the transistor MN43 is connected to the wiring VSE22, a second terminal of the capacitor element C45 is connected to the wiring VSE23, a second terminal of the transistor MN45 is connected to a wiring VSE24, and a second terminal of the transistor MN46 is connected to a wiring VSE25.

The terminal TMi1 is connected to the terminal Ti of the circuit BSPR and the terminal TMo2, and the terminal Ti of the circuit BSPR is connected to the terminal Bi of the circuit BB. The terminal Bo of the circuit BB is connected to the gate of the transistor MN15 and the first terminal of the capacitor element C2, the first terminal of the transistor MN15 is connected to the terminal TMi3, and the second terminal of the transistor MN15 is connected to the second terminal of the capacitor element C2 and the terminal To of the circuit BSPR.

Note that the circuit BSPR in FIG. 50 has a circuit structure similar to that of the circuit BSPR illustrated in FIG. 2A. Thus, for the operation example of the circuit BSPR in FIG. 50, the description of the circuit BSPR illustrated in FIG. 8A to FIG. 8F in Embodiment 1 can be referred to. The circuit BB illustrated in FIG. 8A to FIG. 8F can be used as the circuit BB in FIG. 50. Thus, for the operation example of the circuit BB in FIG. 50, the description of the circuit BB illustrated in FIG. 8A to FIG. 8F in Embodiment 1 can be referred to. The circuit FB illustrated in FIG. 3 to FIG. 7B can be used as the circuit FB in FIG. 50. Thus, for the operation example of the circuit FB, the description of the circuit FB illustrated in FIG. 3 to FIG. 7B in Embodiment 1 can be referred to.

The terminal TMi2 is connected to the gate of the transistor MN16 and the terminal Fo of the circuit FB. The terminal To of the circuit BSPR is connected to the terminal TMo1, the first terminal of the transistor MN16, and the terminal Fi of the circuit FB. The second terminal of the transistor MN16 is connected the wiring VSE4.

The wiring VDE21 has a function of a wiring for supplying a fixed potential, for example. The fixed potential can be a high-level potential, for example. The wiring VDE21 may have a function of a wiring for supplying not a fixed potential but a variable potential (sometimes referred to as a pulse voltage, a pulse potential, a pulse signal, a clock signal, or the like).

The wiring VSE4 and the wiring VSE21 to the wiring VSE25 each have a function of a wiring for supplying a fixed potential, for example. The fixed potential can be, for example, a low-level potential, a ground potential, or a negative potential. Note that the wiring VSE4 and the wiring VSE21 to the wiring VSE25 can supply fixed potentials equal to each other or fixed potentials different from each other. Alternatively, two or more wirings selected from the wiring VSE4 and the wiring VSE21 to the wiring VSE25 may supply fixed potentials equal to each other, and the other wiring(s) may supply a potential different from the fixed potentials. Furthermore, the two or more wirings among the wiring VSE4 and the wiring VSE21 to the wiring VSE25 which supply fixed potentials equal to each other may be the same wiring. For example, in the case where the wiring VSE4 and the wiring VSE21 to the wiring VSE25 supply fixed potentials equal to each other, the wiring VSE4 and the wiring VSE21 to the wiring VSE25 may be the same wiring.

One or more selected from the wiring VSE4 and the wiring VSE21 to the wiring VSE25 may have a function of a wiring for supplying not a fixed potential but a variable potential.

The circuit 100C2 can be used as a retention circuit of a shift register included in a gate driver circuit of a display apparatus, for example. In the case where a shift register is formed using the circuit 100C2, the terminal OTA of the circuit 100C2 in the previous stage is connected to the terminal ITA of the circuit 100C2 in the subsequent stage, and the terminal OTB of the circuit 100C2 in the previous stage is connected to the terminal ITB of the circuit 100C2 in the subsequent stage. That is, the circuit 100C2 in the previous stage and the circuit 100C2 in the subsequent stage are cascaded to each other. The terminal ST is connected to a gate line extending to a display portion of the display apparatus. Each of the terminal CLK1 and the terminal CLK2 is connected to a wiring for supplying a variable potential (e.g., a pulse potential such as a clock signal). That is, the shift register operates with a variable potential such as a clock signal input to the terminal CLK1 and the terminal CLK2.

Thus, the clock signal input to the shift register is preferably a multiphase clock signal. For example, a wiring for supplying a first clock signal is connected to each of the terminal CLK1 and the terminal CLK2 of the circuit 100C2 in the (4k-3)th stage (here, k is an integer greater than or equal to 1), a wiring for supplying a second clock signal is connected to each of the terminal CLK1 and the terminal CLK2 of the circuit 100C2 in the (4k-2)th stage, a wiring for supplying a third clock signal is connected to each of the terminal CLK1 and the terminal CLK2 of the circuit 100C2 in the (4k-1)th stage, and a wiring for supplying a fourth clock signal is connected to each of the terminal CLK1 and the terminal CLK2 of the circuit 100C2 in the 4k-th stage, whereby a shift register that operates in a four-phase clock mode can be achieved.

Note that a clock signal input to the shift register may be a single-phase clock signal in some situations. Alternatively, a clock signal of two, three, or five more phases may be employed.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 5

In this embodiment, a cross-sectional structure example of the display apparatus described in the above embodiment will be described.

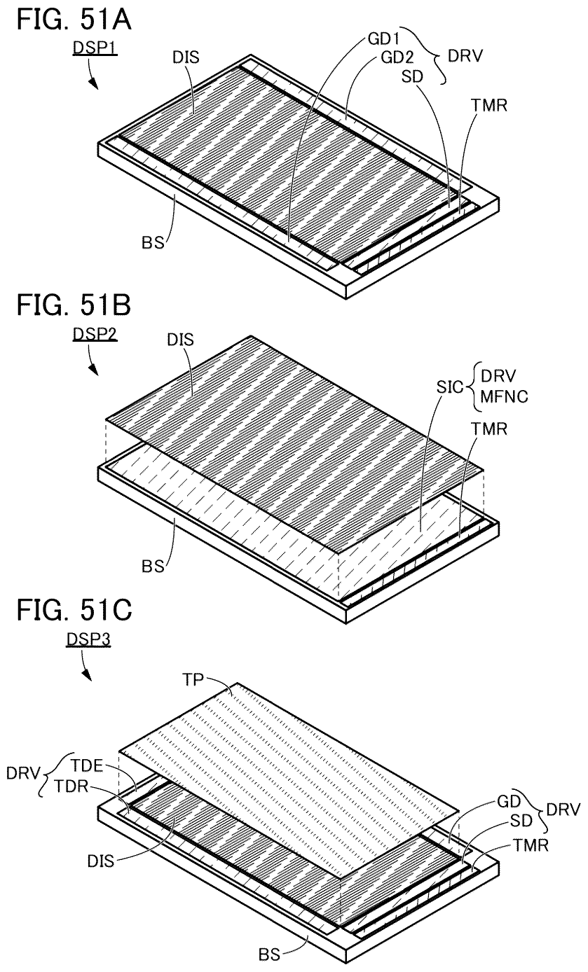

FIG. 51A is a schematic perspective view illustrating the display apparatus of one embodiment of the present invention. A display apparatus DSP1 includes a display region DIS, a driver circuit region DRV, and a terminal region TMR, for example. The display apparatus DSP1 includes a substrate BS, and the display region DIS, the driver circuit region DRV, and the terminal region TMR are located over the substrate BS. Note that the display region DIS can include the pixel array PA in FIG. 32 described in Embodiment 4, for example.

The driver circuit region DRV includes, for example, a driver circuit GD1, a driver circuit GD2, and the driver circuit SD. Note that the driver circuit GD1 and the driver circuit GD2 correspond to the driver circuit GD in FIG. 32 described in Embodiment 4, and the driver circuit SD corresponds to the driver circuit SD in FIG. 32 described in Embodiment 4.

As the substrate BS, a semiconductor substrate (e.g., a single crystal substrate including silicon or germanium as a material) can be used, for example. Besides the semiconductor substrate, any of the following can be used as the substrate BS: an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base material film including a fibrous material. Examples of the glass substrate include barium borosilicate glass, aluminoborosilicate glass, and soda lime glass. Examples of the flexible substrate, the attachment film, the base material film, and the like include plastics typified by polyethylene terephthalate (PET), polyethylene naphthalate (PEN), polyethersulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP1 involves heat treatment, a highly heat-resistant material is preferably used for the substrate BS.

For example, in the case where a semiconductor substrate including silicon as a material is used as the substrate BS, transistors included in the display region DIS and the driver circuit region DRV can be Si transistors and can be formed over the substrate BS.

For another example, in the case where a glass substrate is used as the substrate BS, transistors included in the display region DIS and the driver circuit region DRV can be OS transistors and can be formed over the substrate BS.

One or more selected from the driver circuit GD1, the driver circuit GD2, and the driver circuit SD included in the driver circuit region DRV may be mounted as an IC (Integrated Circuit) on the substrate BS by a COG (Chip On Glass) technique.

The driver circuit GD1 and the driver circuit GD2 each function as a driver circuit for displaying an image on the display region DIS, for example. Specifically, for example, the driver circuit GD1 and the driver circuit GD2 each function as a gate driver circuit for the display region DIS. For example, the driver circuit SD functions as a source driver circuit for the display region DIS.

Thus, for example, the driver circuit GD in FIG. 33 or FIG. 34 described in the above embodiment can be used as each of the driver circuit GD1 and the driver circuit GD2. In addition, for example, the driver circuit SD in FIG. 43 or FIG. 48 described in the above embodiment can be used as the driver circuit SD.

The terminal region TMR includes a terminal for supplying an image signal and a power supply voltage into the display apparatus DSP1 from the outside of the display apparatus DSP1. An FPC (Flexible Printed Circuit) may be connected to the terminal region TMR. A chip may be mounted as an IC over the FPC by a COF (Chip On Film) technique. The IC may include, for example, a driver circuit for displaying an image on the display region DIS.

The display region DIS includes, for example, a plurality of pixels. The plurality of pixels may be arranged in a matrix in the display region DIS.

The plurality of pixels can each be, for example, a pixel circuit provided with one or more selected from a liquid crystal display device, a light-emitting device including an organic EL material, a light-emitting device including an inorganic EL material, and a light-emitting device including a light-emitting diode such as a micro LED.

Each of the plurality of pixels can express one color or a plurality of colors. In particular, the plurality of colors can be, for example, three colors of red, green, and blue. Alternatively, the plurality of colors can be two or more colors selected from, for example, red, green, blue, cyan, magenta, yellow, and white. Note that in the case where each of pixels expressing different colors is called a subpixel and white is expressed by a plurality of subpixels expressing different colors, the plurality of subpixels are collectively called a pixel in some cases. In the description in this specification and the like, a subpixel is referred to as a pixel for convenience.

Note that the display apparatus of one embodiment of the present invention is not limited to having the structure of the display apparatus DSP1 illustrated in FIG. 51A. For example, the display apparatus of one embodiment of the present invention may have the structure of a display apparatus DSP2 illustrated in FIG. 51B.

The display apparatus DSP2 illustrated in FIG. 51B includes the display region DIS, a circuit region SIC, and the terminal region TMR, for example. The display apparatus DSP2 further includes the substrate BS, like the display apparatus DSP1. Note that the display apparatus DSP2 is different from the display region DSP1 in that the circuit region SIC and the terminal region TMR are provided over the substrate BS and the display region DIS is provided over the circuit region SIC.

The circuit region SIC includes, for example, the driver circuit region DRV described above. The circuit region SIC may include any of a variety of functional circuits other than the driver circuit region DRV. In the description of this embodiment, the functional circuit is assumed to be included in a functional circuit region MFNC.

The functional circuit region MFNC can include a GPU (Graphics Processing Unit), for example. In the case where the display apparatus DSP2 includes a touch panel, the functional circuit region MFNC can include a sensor controller for controlling a touch sensor included in the touch panel.

In the case where a light-emitting device containing an organic EL material is used as the display element of the display apparatus DSP2, an EL correction circuit may be provided in the functional circuit region MFNC. Note that the EL correction circuit has a function of appropriately adjusting the amount of current input to the light-emitting device containing an organic EL material. Since the emission luminance of the light-emitting device containing an organic EL material is proportional to the current, when the characteristics of a driving transistor connected to the light-emitting device are not favorable, the luminance of light emitted from the light-emitting device might be lower than a desired luminance. For example, the EL correction circuit monitors the amount of current flowing through the light-emitting device and increases the amount of current when the amount of current is smaller than a desired amount, whereby the luminance of light emitted from the light-emitting device can be increased. By contrast, when the amount of current is larger than a desired amount, the amount of current flowing through the light-emitting device may be adjusted to be small.

In the case where a liquid crystal element is used as the display element of the display apparatus DSP2, a gamma correction circuit may be provided in the functional circuit region MFNC.

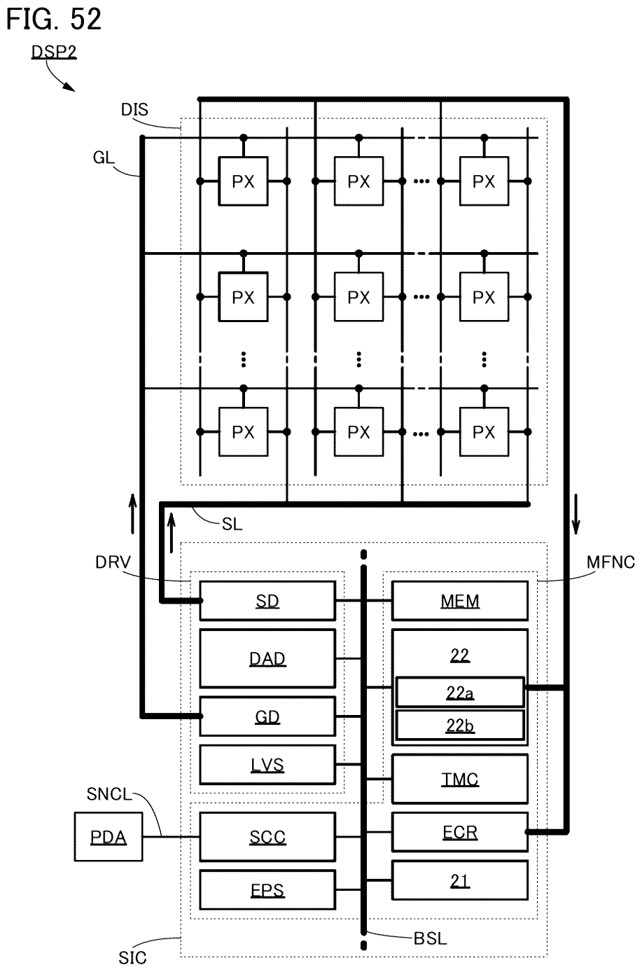

FIG. 52 is a block diagram showing a structure example of the display apparatus DSP2 illustrated in FIG. 51B. The display apparatus DSP2 illustrated in FIG. 52 includes the display region DIS and the circuit region SIC, for example. FIG. 52 illustrates a sensor PDA, and the sensor PDA may be placed inside or outside the display apparatus DSP2.

The display apparatus DSP1 in FIG. 51A can be connected to the functional circuit region MFNC located outside the display apparatus DSP1 through the terminal region TMR. The structure of the display apparatus DSP1 in this case can be regarded as being similar to the structure of the display apparatus DSP2 illustrated in FIG. 52.

In FIG. 52, the thick solid lines denote a plurality of wirings or bus wirings.

In FIG. 52, the plurality of pixel circuits PX are arranged in a matrix in the display region DIS, for example. The pixel circuits PX arranged in a matrix can be regarded as being included in the pixel array PA illustrated in FIG. 32 described in Embodiment 4.

In FIG. 52, the circuit region SIC includes the driver circuit region DRV and the functional circuit region MFNC, as described above.

The driver circuit region DRV functions as a peripheral circuit for driving the display region DIS, for example. Specifically, the driver circuit region DRV includes, for example, the driver circuit SD, a digital-to-analog converter circuit DAD, the driver circuit GD, and a level shifter LVS. Note that the driver circuit SD corresponds to the driver circuit SD in FIG. 32, and the driver circuit GD corresponds to the driver circuit GD in FIG. 32, for example.

The functional circuit region MFNC can be provided with, for example, a memory device storing image data to be displayed on the display region DIS, a decoder for decoding encoded image data, a GPU for processing image data, a power supply circuit, a correction circuit, and a CPU. In FIG. 52, the functional circuit region MFNC includes a memory device MEM, a GPU 22, an EL correction circuit ECR, a timing controller TMC, a CPU (NoffCPU (registered trademark)) 21, a sensor controller SCC, and a power supply circuit EPS, for example.

In the display apparatus DSP2 in FIG. 52, for example, a bus wiring BSL is connected to each of the circuits included in the driver circuit region DRV and each of the circuits included in the functional circuit region MFNC.

The driver circuit SD has a function of transmitting image data to the pixel circuit PX included in the display region DIS, for example. Thus, the driver circuit SD is connected to the pixel circuit PX through the wiring SL.

The digital-to-analog converter circuit DAD has a function of, for example, converting image data that has been digitally processed by the GPU or correction circuit described later, into analog data. The image data converted into analog data is transmitted to the display region DIS through the driver circuit SD. Note that the digital-to-analog converter circuit DAD may be included in the driver circuit SD, and the image data may be transmitted to the driver circuit SD, the digital-to-analog converter circuit DAD, and the display region DIS in this order.

The driver circuit GD has a function of selecting the pixel circuit PX to which image data is to be transmitted in the display region DIS, for example. Thus, the driver circuit GD is connected to the pixel circuit PX through the wiring GL.

The level shifter LVS has a function of converting the signals to be input to the driver circuit SD, the digital-to-analog converter circuit DAD, the driver circuit GD, and the like into signals having appropriate levels, for example.

The memory device MEM has a function of storing image data to be displayed on the display region DIS, for example. Note that the memory device MEM can be configured to store the image data as digital data or analog data.

In the case where the memory device MEM stores image data, the memory device MEM is preferably a nonvolatile memory. In this case, a NAND memory or the like can be used as the memory device MEM.

In the case where the memory device MEM stores temporary data generated in the GPU 22, the EL correction circuit ECR, the CPU 21, or the like, the memory device MEM is preferably a volatile memory. In this case, an SRAM (Static Random Access Memory), a DRAM (Dynamic Random Access Memory), or the like can be used as the memory device MEM.

The GPU 22 has a function of performing processing for plotting the image data read from the memory device MEM on the display region DIS, for example. Specifically, the GPU 22 is configured to perform pipeline processing in parallel and thus can perform high-speed processing of the image data to be displayed on the display region DIS. The GPU 22 can also have a function of a decoder for decoding an encoded image.

The functional circuit region MFNC may include a plurality of circuits that can increase the display quality of the display region DIS. As such circuits, for example, correction circuits (dimming or toning correction circuits) that detect and correct color irregularity of an image displayed on the display region DIS to optimize the image may be provided. In the case where the pixel in the display region DIS includes a light-emitting device using an organic EL material, the functional circuit region MFNC may be provided with an EL correction circuit. Note that because the description in this embodiment is made on the assumption that the pixel circuit PX in the display region DIS includes the light-emitting device containing an organic EL material, the functional circuit region MFNC in this example is provided with the EL correction circuit ECR.

The above-described image correction may be performed using artificial intelligence. For example, it is possible that a current flowing in the display device included in the pixel (or a voltage applied to the display device) is monitored and acquired, an image displayed on the display region DIS is acquired with an image sensor or the like, the current (or voltage) and the image are used as input data in an arithmetic operation of the artificial intelligence (e.g., an artificial neural network), and the output result is used to determine whether the image should be corrected.

The arithmetic operation of artificial intelligence can be applied to not only image correction but also upconversion processing on image data. In this case, upconversion of low-definition image data in accordance with the definition of the display region DIS allows a high-display-quality image to be displayed on the display region DIS. The arithmetic operation of artificial intelligence can also be applied to downconversion processing on image data.

Note that the above-described arithmetic operation of artificial intelligence can be performed using the GPU 22 included in the functional circuit region MFNC. That is, the GPU 22 can be used to perform arithmetic operations for various kinds of correction (e.g., color irregularity correction or upconversion processing). The GPU 22 may include a circuit 22a that corrects color irregularity and a circuit 22b that performs upconversion processing.

Note that in this specification and the like, a GPU performing an arithmetic operation of artificial intelligence is referred to as an AI accelerator. That is, the GPU included in the functional circuit region MFNC may be replaced with an AI accelerator in the description in this specification and the like.

The timing controller TMC has a function of changing the frame rate at which an image is displayed on the display region DIS. For example, the display apparatus DSP2 can be driven at a frame rate reduced by the timing controller TMC in the case where the display region DIS displays a still image; for another example, the display apparatus DSP2 can be driven at a frame rate increased by the timing controller TMC in the case where the display region DIS displays a moving image. In other words, the display apparatus DSP2 provided with the timing controller TMC can be driven at a frame rate that is changed depending on which of a still image and a moving image is displayed. Specifically, since the frame rate can be lowered in operation when the display region DIS displays a still image, the power consumption of the display apparatus DSP2 can be reduced.

The CPU 21 has a function of, for example, performing general-purpose processing such as execution of an operating system, control of data, and execution of various arithmetic operations and programs. In the display apparatus DSP2, the CPU 21 has a function of, for example, giving an instruction for an operation for writing or reading image data to/from the memory device MEM, an operation for correcting image data, an operation for a sensor described later, or the like. Furthermore, the CPU 21 may have a function of, for example, transmitting a control signal to at least one of the circuits included in the functional circuit region MFNC, such as the memory device, the GPU, the correction circuit, the timing controller, and a high frequency circuit.

The CPU 21 may include a circuit for temporarily backing up data (hereinafter referred to as a backup circuit). The backup circuit is preferably capable of retaining the data even after supply of a power supply voltage is stopped. For example, in the case where the display region DIS displays a still image, the CPU 21 can cease to work until an image different from the currently displayed still image is displayed. Accordingly, dynamic power consumption by the CPU 21 can be reduced in such a manner that the data under processing by the CPU 21 is backed up in the backup circuit and then supply of a power supply voltage to the CPU 21 is stopped to stop the CPU 21. In this specification and the like, a CPU including a backup circuit is referred to as a NoffCPU.

The sensor controller SCC has a function of, for example, controlling the sensor PDA. FIG. 52 illustrates a wiring SNCL as a wiring for connecting the sensor PDA to the sensor controller SCC.

Alternatively, the sensor PDA may be an illuminance sensor, for example. Specifically, the illuminance sensor acquiring the intensity of the external light with which the display region DIS is irradiated makes it possible to change the brightness (luminance) of an image displayed on the display region DIS in accordance with the intensity of the external light. For example, under intense external light, the luminance of an image displayed on the display region DIS can be increased to enhance the viewability of the image. By contrast, under weak external light, the luminance of an image displayed on the display region DIS can be lowered to reduce the power consumption.

Alternatively, the sensor PDA can be an image sensor, for example. For example, an image or the like acquired with the image sensor can be displayed on the display region DIS.

The power supply circuit EPS has a function of, for example, generating voltages to be supplied to the circuits included in the driver circuit region DRV, the circuits included in the functional circuit region MFNC, the pixels included in the display region DIS, and the like. Note that the power supply circuit EPS may have a function of selecting a circuit to which voltage is to be supplied. For example, the power supply circuit EPS stops supply of voltage to the circuits included in the driver circuit region DRV (e.g., the driver circuit SD and the digital-to-analog converter circuit DAD) and the circuits included in the functional circuit region MFNC (e.g., the CPU 21 and the GPU 22) during a period in which the display region DIS displays a still image, whereby the power consumption of the whole display apparatus DSP can be reduced.

The display apparatus of one embodiment of the present invention may be a display apparatus DSP3 illustrated in FIG. 51C, which is obtained by changing the structure of the display apparatus DSP1 in FIG. 51A.

The display apparatus DSP3 is a modification example of the display apparatus DSP1 and has a structure in which a sensor region TP is provided in a region overlapping with the display region DIS. Note that the sensor region TP can include the sensor array TA in FIG. 32 described in Embodiment 4, for example.

The display apparatus DSP3 includes the driver circuit TDE and the driver circuit TDR, and each of the driver circuit TDE and the driver circuit TDR is provided over the substrate BS. Each of the driver circuit TDE and the driver circuit TDR is assumed to be included in the driver circuit region DRV as illustrated in FIG. 51C. Note that the driver circuit TDE corresponds to the driver circuit TDE in FIG. 32 described in Embodiment 4, and the driver circuit TDR corresponds to the driver circuit TDR in FIG. 32 described in Embodiment 4.

As described in Embodiment 4, the driver circuit TDR has a function of sequentially transmitting a pulse signal to a plurality of sensors included in the sensor region TP. The driver circuit TDE has a function of sensing a change in the amount of current flowing from a plurality of sensors included in the sensor region TP.

As described above, the display apparatus DSP3 has a structure in which a touch panel is provided as a user interface.

Although not illustrated, the sensor region TP may also be provided above the display region DIS of the display apparatus DSP2. In this case, the driver circuit TDR and the driver circuit TDE are preferably provided in the circuit region SIC.

### <Cross-Sectional Structure Example 1 of Display Apparatus>

Next, a cross-sectional structure example of the display apparatus DSP1 illustrated in FIG. 51A is described.

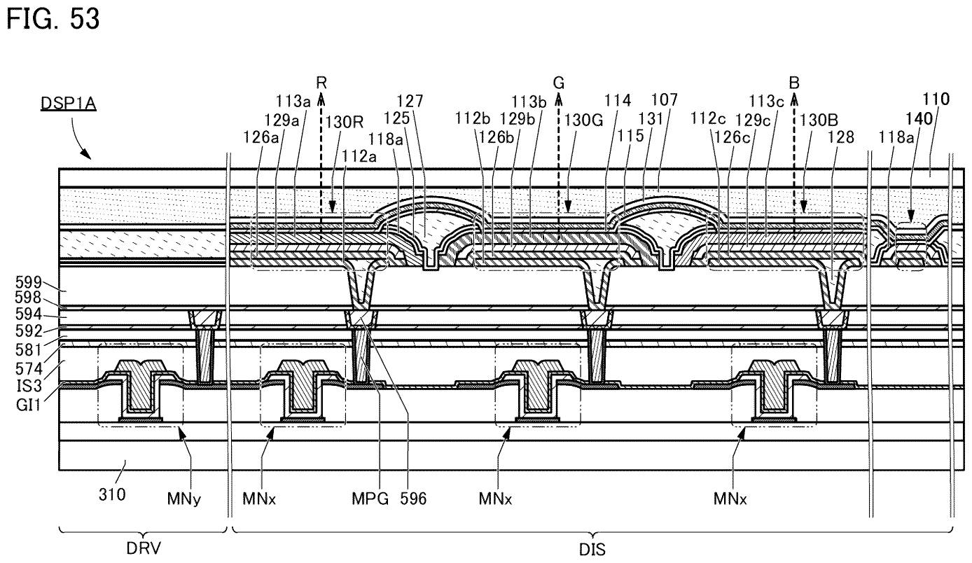

A display apparatus DSP1A illustrated in FIG. 53 is a cross-sectional structure example of the display apparatus DSP1 illustrated in FIG. 51A. The display apparatus DSP1A has a structure provided with a pixel circuit, a driver circuit, and the like over a substrate 310. In the display apparatus DSP1A in FIG. 53, the driver circuit region DRV and the display region DIS that are illustrated in FIG. 51A are illustrated.

The substrate 310 in FIG. 53 corresponds to the substrate BS illustrated in FIG. 51A. The diagonal size of the display apparatus DSP1A can be determined depending on the kind and the size of the substrate 310, for example. For example, in the case where a display apparatus with a diagonal size of greater than or equal to 30 inches, greater than or equal to 50 inches, greater than or equal to 70 inches, or greater than or equal to 100 inches is fabricated for a television device or an electronic device for digital signage application, a glass substrate is preferably used as the substrate 310. In the case where a display apparatus with a diagonal size of less than or equal to 1.5 inches, less than or equal to 1 inch, or less than or equal to 0.5 inches is fabricated for an XR device or a wearable information terminal, a semiconductor substrate is preferably used as the substrate 310.

Note that in the description of the display apparatus DSP1A in FIG. 53, the substrate 310 is assumed to be a glass substrate.

There is no particular limitation on the screen ratio (aspect ratio) of the display apparatus DSP1A. For example, the display apparatus DSP1A is compatible with a variety of screen ratios such as 1:1 (a square), 4:3, 16:9, 16:10, 21:9, and 32:9.

In the display apparatus DSP1 in FIG. 53, a transistor MNy and a transistor MNx are formed over the substrate. Note that in this specification and the like, the transistor MNy and the transistor MNx are collectively referred to as a transistor MN. Light-emitting devices 130 (a light-emitting device 130R, a light-emitting device 130G, and a light-emitting device 130B in FIG. 53) are provided above the transistor MNy and the transistor MNx.

The transistor MNx is included in the display region DIS and functions as, for example, a transistor included in the pixel circuit PX. The transistor MNy functions as a transistor included in the driver circuit region DRV. Thus, the transistor MNy can be, for example, a transistor included in any of the circuit 100A[1] to the circuit 100A[m] or the circuit 100B[1] to the circuit 100B[n] described in Embodiment 2. The light-emitting device 130 can be a light-emitting device included in the pixel circuit PX.

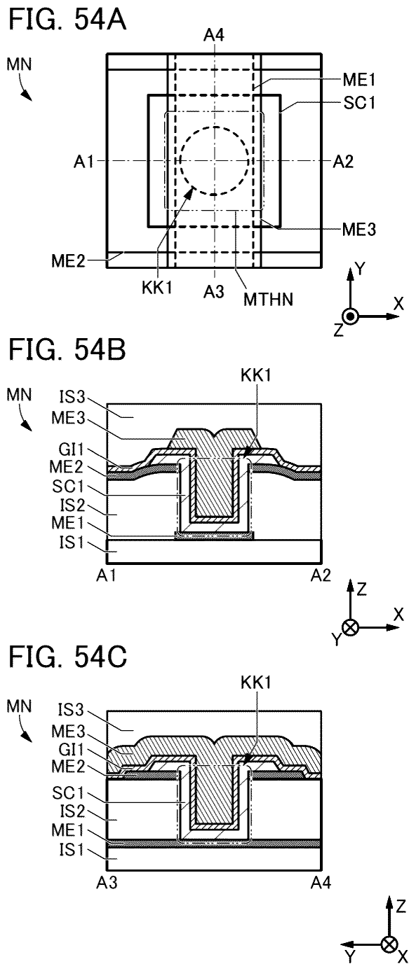

Next, specific structures of the transistor MNy and the transistor MNx are described. FIG. 54A illustrates a schematic plan view of the transistor MN. FIG. 54B is a schematic cross-sectional view corresponding to a portion along the dashed-dotted line A1-A2 illustrated in FIG. 54A, and is also a schematic cross-sectional view of the transistor MN. FIG. 54C is a schematic cross-sectional view corresponding to a portion along the dashed-dotted line A3-A4 illustrated in FIG. 54A, and is also a schematic cross-sectional view of the transistor MN.

Note that in FIG. 54A to FIG. 54C, the direction along the dashed-dotted line A1-A2 is the X direction and the direction along the dashed-dotted line A3-A4 is the Y direction. The direction perpendicular to both the X direction and the Y direction is the Z direction. The X direction and the Y direction can be perpendicular to each other. The definition of the X direction, the Y direction, and the Z direction applies to some of the following drawings and does not apply to other drawings. In the description of the schematic plan view in FIG. 54A and the like, in some cases, the right side, the left side, the upper side, and the lower side are referred to as X direction, −X direction, Y direction, and −Y direction, respectively. In the description of the schematic cross-sectional view in FIG. 54B and the like, in some cases, the right side, the left side, the upper side, and the lower side are referred to as X direction, −X direction, Z direction, and −Z direction, respectively. In the description of the schematic cross-sectional view in FIG. 54C and the like, in some cases, the right side, the left side, the upper side, and the lower side are referred to as −Y direction, +Y direction, Z direction, and −Z direction, respectively.

The transistor MN in FIG. 54A to FIG. 54C includes an insulating layer IS1 to an insulating layer IS3, an insulating layer GI1, a conductive layer MET to a conductive layer ME3, and a semiconductor layer SC1.

The insulating layer IS1 has a function of, for example, a base film or an interlayer film above which a source, a drain, a drain, and a channel formation region of the transistor MN are to be provided.

For the insulating layer IS1, silicon oxide, silicon oxynitride, silicon nitride oxide, or silicon nitride can be used, for example. Alternatively, for the insulating layer IS1, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for example, a resin can be used for the insulating layer IS1. A material combined with any of the above insulating materials as appropriate can be used for the insulating layer IS1.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

An insulating material with a low dielectric constant is preferably used for the insulating layer IS1. The use of an insulating material with a low dielectric constant for the interlayer film can reduce the parasitic capacitance generated between wirings. Specifically, the dielectric constant of the insulating layer IS1 is preferably lower than 4, further preferably lower than 3, for example. Examples of an insulating material with a low dielectric constant include silicon oxide, silicon oxynitride, and silicon nitride oxide.

The conductive layer MET is a conductor (sometimes rephrased as a terminal, a wiring, or the like) having a function of one of the source and the drain of the transistor MN. A conductive layer ME2 is a conductor (sometimes rephrased as a terminal, a wiring, or the like) having a function of the other of the source and the drain of the transistor MN.

The conductive layer MET corresponds to the conductive layer SDMB described in Embodiment 2. The conductive layer ME2 corresponds to the conductive layer SDMT described in Embodiment 2.

Note that in FIG. 54A to FIG. 54C, the conductive layer MET is provided to extend in the Y direction as a wiring, for example. The conductive layer ME2 is provided to extend in the X direction as a wiring, for example.

For each of the conductive layer MET and the conductive layer ME2, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements as its components; or an alloy containing a combination of two or more selected from the above metal elements. For the conductive layer MET, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel, for example. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) may be used, for example.

An insulating layer IS2 functions as an interlayer film that separates the source and the drain of the transistor MN, for example.

Any of the materials that can be used for the insulating layer IS1 can be used for the insulating layer IS2, for example.

In a region of the insulating layer IS2 where the transistor MN is provided, an opening KK1 whose side surface is substantially perpendicular to the along X-Y plane (the taper angle is greater than or equal to 700 and less than or equal to 110°) is formed. In particular, when the taper angle is closer to 90°, the opening area of the opening KK1 can be reduced and thus the area where the transistor MN is formed can be reduced. The semiconductor layer SC1 including the channel formation region of transistor MN is provided to be in contact with the conductive layer MET and the conductive layer ME2 through the opening KK1.

Although the opening KK1 has a perfect circular shape in the schematic top view in FIG. 54A, for example, one embodiment of the present invention is not limited thereto. The shape of the opening KK1 may be, for example, a shape with a single closed curve as an edge (including an elliptical shape) or a polygon with rounded corners.

For example, a metal oxide functioning as an oxide semiconductor can be used for the semiconductor layer SC1. In that case, the transistor MN is an OS transistor. The metal oxide preferably contains at least indium or zinc, for example. In particular, indium and zinc are preferably contained. In addition to them, an element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

For example, an In—Ga—Zn oxide is preferably used for the semiconductor layer SC1. In particular, the In—Ga—Zn oxide is preferably a metal oxide with a composition of In:Ga:Zn=1:1:1 [atomic ratio] or the neighborhood thereof, a composition of In:Ga:Zn=4:2:3 [atomic ratio] or the neighborhood thereof, or a composition of In:Ga:Zn=3:1:2 [atomic ratio] or the neighborhood thereof. For another example, an In—Zn oxide is preferably used for the semiconductor layer SC1. In particular, the In—Zn oxide is further preferably a metal oxide with a composition of In:Zn=4:1 [atomic ratio] or in the neighborhood thereof.

In the transistor MN, the insulating layer GI1 is provided over the semiconductor layer SC1. Specifically, the insulating layer GI1 is positioned above and overlaps with the channel formation region included in the semiconductor layer SC1 in the plan view. Thus, the insulating layer GI1 functions as a gate insulating film of the transistor MN.

The semiconductor layer SC1 corresponds to the semiconductor layer SMC described in Embodiment 2.

For the insulating layer GI1, a single layer or stacked layers of an insulator containing what is called a high-k material such as aluminum oxide, hafnium oxide, tantalum oxide, zirconium oxide, lead zirconate titanate (PZT), strontium titanate (SrTiO3), or (Ba,Sr)TiO₃ (BST) is preferably used, for example. Alternatively, for the insulating layer GI1, an insulator having a high dielectric constant, such as an oxide containing aluminum and hafnium, an oxynitride containing aluminum and hafnium, an oxide containing silicon and hafnium, an oxynitride containing silicon and hafnium, or a nitride containing silicon and hafnium, can be used.

In the transistor MN, the conductive layer ME3 is provided over the insulating layer GI1 to fill the opening KKT. In the transistor MN, the conductive layer ME3 is provided over the insulating layer GI1 to fill the opening KK1. The conductor ME3 is a conductor (sometimes rephrased as a terminal, a wiring, or the like) functioning as a gate in the transistor MN.

For the conductive layer ME3, a material that can be used for the conductive layer MET or the conductive layer ME2 can be used, for example.

Note that in FIG. 54A to FIG. 54C, the conductive layer ME3 is provided to extend in the Y direction as a wiring, for example.

The conductive layer ME3 corresponds to the conductive layer GEM described in Embodiment 2.

As described above, in the transistor MN illustrated in FIG. 54A to FIG. 54C, the conductive layer MET functioning as one of the source and the drain is positioned below the insulating layer IS2 functioning as an interlayer film, and the conductive layer ME2 functioning as the other of the source and the drain is positioned above the insulating layer IS2. Thus, the transistor MN has a structure in which the channel formation region is provided along the opening KK1.

As described above, the transistor MN has a structure in which a source electrode and a drain electrode are positioned at different levels, and current flowing through a semiconductor layer flows in the height direction. In other words, the channel length direction can be regarded as having a component of the height direction (the vertical direction); accordingly, the transistor MN can also be referred to as a VFET (Vertical Field Effect Transistor), a vertical transistor, a vertical-channel transistor, a vertical-channel-type transistor, and the like.

As illustrated in FIG. 54A to FIG. 54C, when the channel formation region of the transistor is provided along the side surface of the opening in the insulator functioning as an interlayer film, the transistor formation area can be smaller than that in the case where the channel formation region of the transistor is provided along the X-Y plane. In the transistor MN, the source electrode, the semiconductor, and the drain electrode can be provided to overlap with each other; thus, the area occupied by the transistor can be significantly smaller than the area occupied by what is called a planar transistor in which a semiconductor is provided in a planar shape. Thus, when a circuit is formed using one or both of the transistor MV, the area of the circuit can be small. This results in a reduction in size of a semiconductor device or a display apparatus including the circuit.

Note that the transistor MN can be a p-channel transistor or an n-channel transistor. Alternatively, a plurality of transistors MN may be provided and both a p-channel transistor and an n-channel transistor may be used as the transistors MN.

As the transistor MN, a transistor having a VLFET structure may be used instead of the vertical-channel-type transistor illustrated in FIG. 54A to FIG. 54C.

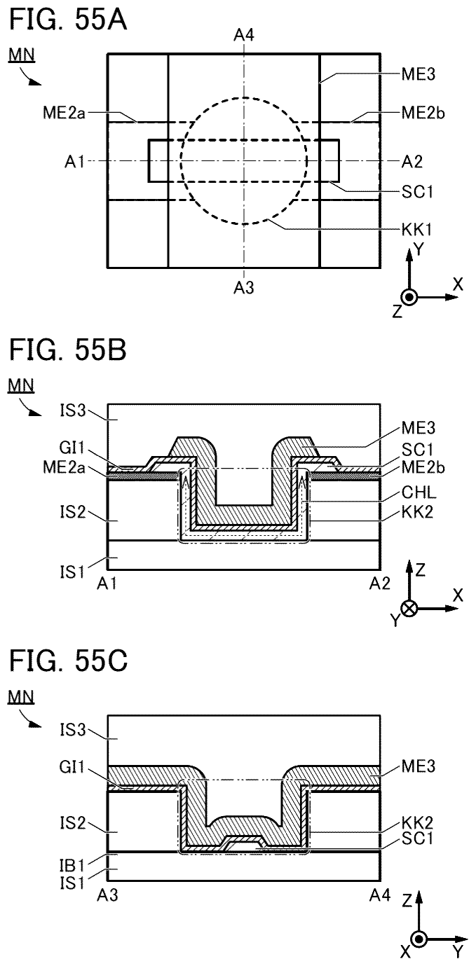

The transistor MN illustrated in FIG. 55A to FIG. 55C is a transistor having a VLFET structure and has a structure in which current flows in both the vertical direction and the lateral direction. Specifically, a semiconductor layer is positioned in contact with the side surface of an opening provided in a first insulating layer and the top surface of a second insulating layer corresponding to a bottom portion of the opening, and the semiconductor layer includes a channel formation region of the transistor MN. That is, the channel length of the transistor MN includes a component along the side surface of the opening and a component along the bottom portion of the opening, and thus is easily made longer than the channel length in a conventional transistor structure. Note that the channel length here can be the length of the channel formation region between the source and the drain.

Note that in the transistor MN in FIG. 55B, a channel length CHL of the channel formation region included in a semiconductor layer SC1 is illustrated.

By increasing the channel length, the off-state current (leakage current) of the transistor can be reduced. Thus, by using the transistor MN illustrated in FIG. 55A to FIG. 55C as each of the transistor MN2 and the transistor MN4 in FIG. 1, the potential of the node N1 or the node N2 in a floating state can be retained for a long time. In other words, it is possible to prevent an unintended change in the potential of the node N1 or the node N2, which is caused by leakage current or the like.

Similarly, when the transistor MN illustrated in FIG. 55A to FIG. 55C is used as the transistor MNF1 described in Embodiment 1 to Embodiment 4, the potential of the gate of the transistor MN16 (the terminal TMi2) can be retained for along time. In other words, it is possible to prevent an unintended change in the potential of the gate (the terminal TMi2) of the transistor MN16, which is caused by leakage current or the like.

FIG. 55A illustrates a schematic plan view of the transistor MN. FIG. 55B is a schematic cross-sectional view corresponding to a portion along the dashed-dotted line A1-A2 illustrated in FIG. 55A, and is also a schematic cross-sectional view of the transistor MN. FIG. 55C is a schematic cross-sectional view corresponding to a portion along the dashed-dotted line A3-A4 illustrated in FIG. 55A, and is also a schematic cross-sectional view of the transistor MN.

The transistor MN in FIG. 55A to FIG. 55C includes, for example, the insulating layer IS1 to the insulating layer IS3, the insulating layer GI1, a conductive layer ME2a, a conductive layer ME2b, the conductive layer ME3, and the semiconductor layer SC1.

Note that for the insulating layer IS1 to the insulating layer IS3, the insulating layer GI1, the conductive layer ME3, and the semiconductor layer SC1 illustrated in FIG. 55A to FIG. 55C, the description of the insulating layer IS1 to the insulating layer IS3, the insulating layer GI1, the conductive layer ME3, and the semiconductor layer SC1 illustrated in FIG. 54A to FIG. 54C can be referred to. For the conductive layer ME2a and the conductive layer ME2b illustrated in FIG. 55A to FIG. 55C, the description of the conductive layer ME2 illustrated in FIG. 54A to FIG. 54C can be referred to.

The insulating layer IS2 has a function of an insulating layer for forming the semiconductor layer SC1, for example. As illustrated in FIG. 55A to FIG. 55C, the insulating layer IS2 has an opening KK2, and the transistor MN has a structure in which part of the semiconductor layer SC1 is included in the opening KK2. Specifically, in the insulating layer IS2, the opening KK2 is provided so that the semiconductor layer SC1 includes a region in contact with the sidewall of the insulating layer IS2 corresponding to the side surface of the opening KK2 and the top surface of the insulating layer IS1 corresponding to a bottom portion of the opening KK2. Note that the transistor MN has a structure in which the semiconductor layer SC1 provided in the opening KK2 includes the channel formation region of the transistor MV.

Although the opening KK2 has a perfect circular shape in the schematic top view in FIG. 55A, for example, one embodiment of the present invention is not limited thereto. The shape of the opening KK2 may be, for example, a shape with a single closed curve as an edge (including an elliptical shape) or a polygon with rounded corners.

The conductive layer ME2a has a function of one of the source and the drain of the transistor MN, for example. The conductive layer ME2b has a function of the other of the source and the drain of the transistor MN, for example. Note that, for example, the whole or part of the conductive layer ME2a and the conductive layer ME2b may be rephrased as an electrode, a terminal, a wiring, or the like.

The conductive layer ME2a and the conductive layer ME2b are positioned above the insulating layer IS2. In particular, the conductive layer ME2a and the conductive layer ME2b are each divided into a pair of conductive layers by the opening KK2 in the schematic top view in FIG. 55A and the schematic cross-sectional view in FIG. 55B. Thus, in the transistor MN in FIG. 55A to FIG. 55C, the width of each of the conductive layer ME2a and the conductive layer ME2b in the Y direction is preferably smaller than the width of the opening KK2 in the Y direction in the schematic top view in FIG. 55A. Note that in the schematic top view in FIG. 55A, for example, the opening KK2 is a perfect circle, and the width of the opening KK2 in the Y direction corresponds to the diameter of the perfect circle.

Note that in FIG. 55A to FIG. 55C, the conductor ME2a is provided to extend in the −X direction as a wiring, for example. The conductor ME2b is provided to extend in the +X direction as a wiring, for example.

As described above, the semiconductor layer SC1 includes the region in contact with the sidewall of the insulating layer IS2 corresponding to the side surface of the opening KK2 and the top surface of the insulating layer IS1 corresponding to the bottom portion of the opening KK2. Furthermore, the semiconductor layer SC1 includes a region in contact with the top surface of the conductive layer ME2a and the top surface of the conductive layer ME2b. As described above, the semiconductor layer SC1 includes the channel formation region of the transistor MN. Note that the channel length CHL of the channel formation region of the transistor MN depends on the area of the bottom portion of the opening KK2 and the depth of the opening KK2 (the length of the side surface of the opening KK2 or the thickness of the insulating layer IS2).

The insulating layer GI1 has a function of a gate insulating layer (sometimes referred to as a gate insulating film) of the transistor MN, for example. The insulating layer GI1 includes a region in contact with the top surface of the semiconductor layer SC1, the top surface of the conductor ME2a, and the top surface of the conductor ME2b.

In particular, the thickness of the insulating layer GI1 greatly contributes to the electrical characteristics of the transistor MN. For example, in the case where the insulating layer GI1 is thick (the transistor MN includes a thick gate insulating layer), the transistor MN can have a gentle gradient of voltage between the gate (the conductor ME3) and the channel formation region in the semiconductor layer SC1, so that the transistor MN can have high resistance to a gate potential (sometimes referred to as a gate-source voltage or a gate-drain voltage). Meanwhile, in the case where the transistor includes a thin gate insulating film, the electric field applied from the gate to the channel formation region in a semiconductor rapidly changes when a gate potential is changed, so that the transistor can have a high driving frequency.

Thus, when the thickness of the insulating layer GI1 serving as the gate insulating layer is determined for each of a plurality of transistors MN, for example, the transistor having high resistance to a gate potential and the transistor having a high driving frequency can be separately formed in a simplified manner.

An insulating layer 574 is formed above the transistor MNy and the transistor MNx illustrated in FIG. 53, and an insulating layer 581 is formed over the insulating layer 574. An opening is provided in the insulating layer IS3, the insulating layer 574, and the insulating layer 581, and a conductive layer MPG is embedded in the opening. Thus, the conductive layer ME2 includes a region in contact with the conductive layer MPG.

The insulating layer 574 preferably has a function of inhibiting diffusion of impurities such as water and hydrogen (e.g., one or both of a hydrogen atom and a hydrogen molecule), for example. That is, the insulating layer 574 preferably functions as a barrier insulating film that inhibits entry of the impurities into the transistor MN. Moreover, the insulating layer 574 preferably has a function of inhibiting diffusion of oxygen (e.g., one or both of an oxygen atom and an oxygen molecule). For example, the insulating layer 574 preferably has a lower oxygen permeability than the insulating layer IS3 and the insulating layer 581. That is, the insulating layer 574 preferably has a function of inhibiting release of oxygen from the semiconductor layer SC1 and diffusion to above the insulating layer IS3.

For the film having a barrier property against hydrogen, silicon nitride formed by a CVD method can be used, for example.

The amount of released hydrogen can be analyzed by thermal desorption spectrometry (TDS), for example. For example, the amount of hydrogen released from an insulating layer 324 that is converted into hydrogen atoms per area of the insulating layer 324 is preferably less than or equal to 10×10¹⁵ atoms/cm², further preferably less than or equal to 5×10¹⁵ atoms/cm² in the TDS in a film-surface temperature range of 50° C. to 500° C.

Thus, as the insulating layer 574, an insulator having a function of inhibiting passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting passage of oxygen and impurities such as water and hydrogen include oxides containing aluminum and hafnium (hafnium aluminate). Other examples of the insulator having a function of inhibiting passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulating layer 574. Accordingly, it is possible to inhibit diffusion of impurities such as water and hydrogen to the transistor MN side from above the insulating layer 574. In addition, it is possible to inhibit diffusion of oxygen to the transistor MN side from above the insulating layer 574.

The dielectric constant of the insulating layer 581 is preferably lower than that of the insulating layer 574, for example. The use of a material with a low dielectric constant for the interlayer film can reduce the parasitic capacitance generated between wirings. The concentration of impurities such as water and hydrogen in the insulating layer 581 is preferably reduced.

Thus, any of the materials usable for any one of the insulating layer IS1 to the insulating layer IS3 can be used for the insulating layer 581, for example.

As a material of each of plugs and wirings (e.g., the conductive layer MPG), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used as the material. The use of a low-resistance conductive material can reduce wiring resistance.

An insulating layer 592 and an insulating layer 594 are stacked in this order over the insulating layer 581 and the conductive layer MPG.

For the insulating layer 592, it is preferable to use an insulating film having a barrier property (referred to as a barrier insulating film) which prevents diffusion of impurities such as water and hydrogen from the substrate 310 or the transistor MN to a region above the insulating layer 592 (e.g., the region where the light-emitting device 130R, the light-emitting device 130G, the light-emitting device 130B, and the like are provided). Thus, any of the materials usable for any one of the insulating layer IS1 to the insulating layer IS3 can be used for the insulating layer 592.

The dielectric constant of the insulating layer 594 is preferably lower than that of the insulating layer 592. The concentration of impurities such as water and hydrogen in the insulating layer 594 is preferably reduced. Thus, any of the materials usable for the insulating layer 574 can be used for the insulating layer 594, for example.

A conductive layer 596 that is connected to a light-emitting device and the like provided above the insulating layer 594 is embedded in the insulating layer 592 and the insulating layer 594. Note that the conductive layer 596 has a function of a plug or a wiring. A plurality of conductors each having a function of a plug or a wiring are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

Any of the materials usable for the conductive layer MPG can be used for the conductive layer 596, for example.

An insulating layer 598 and an insulating layer 599 are formed in this order over the insulating layer 594 and the conductive layer 596.

Like the insulating layer 581 and the insulating layer 592, for example, the insulating layer 598 is preferably formed using an insulating layer having a barrier property against one or more selected from hydrogen, oxygen, and water. Like the insulating layer 594, the insulating layer 599 is preferably formed using an insulator having a relatively low dielectric constant to reduce parasitic capacitance generated between wirings. Thus, any of the materials usable for the insulating layer 581 or the insulating layer 592 can be used for the insulating layer 598.

The insulating layer 599 has functions of an interlayer insulating film and a planarization film.

The dielectric constant of the insulating layer 599 is preferably lower than that of the insulating layer 598. The concentration of impurities such as water and hydrogen in the insulating layer 599 is preferably reduced. Thus, any of the materials usable for any one of the insulating layer IS1 to the insulating layer IS3 can be used for the insulating layer 599, for example.

The light-emitting device 130 and the connection portion 140 are formed over the insulating layer 599.

The connection portion 140 is referred to as a cathode contact portion in some cases, and is connected to cathode electrodes of the light-emitting device 130R, the light-emitting device 130G, and the light-emitting device 130B. The connection portion 140 in FIG. 53 includes one or more conductive layers selected from a conductive layer 112a to a conductive layer 112c described later, at least one of a conductive layer 126a to a conductive layer 126c described later, one or more conductive layers selected from a conductive layer 129a to a conductive layer 129c described later, a common layer 114 described later, and a common electrode 115 described later.

Note that the connection portion 140 can be provided to surround the four sides of a display portion in the plan view, or can be provided in the display portion (e.g., between adjacent light-emitting devices 130).

The light-emitting device 130R includes the conductive layer 112a, the conductive layer 126a over the conductive layer 112a, and the conductive layer 129a over the conductive layer 126a. All of the conductive layer 112a, the conductive layer 126a, and the conductive layer 129a can be referred to as a pixel electrode, or one or two of them can be referred to as a pixel electrode. The light-emitting device 130G includes a conductive layer 112b, a conductive layer 126b over the conductive layer 112b, and a conductive layer 129b over the conductive layer 126b. As in the light-emitting device 130R, all of the conductive layer 112b, the conductive layer 126b, and the conductive layer 129b can be referred to as a pixel electrode, or one or two of them can be referred to as a pixel electrode. The light-emitting device 130B includes the conductive layer 112c, the conductive layer 126c over the conductive layer 112c, and the conductive layer 129c over the conductive layer 126c. As in the light-emitting device 130R and the light-emitting device 130G, all of the conductive layer 112c, the conductive layer 126c, and the conductive layer 129c can be referred to as a pixel electrode, or one or two of them can be referred to as a pixel electrode.

For each of the conductive layer 112a to the conductive layer 112c and the conductive layer 126a to the conductive layer 126c, a conductive layer functioning as a reflective electrode can be used, for example. For the conductive layer functioning as a reflective electrode, a conductor with high visible-light reflectance such as silver, aluminum, or an alloy film of silver (Ag), palladium (Pd), and copper (Cu) (an Ag—Pd—Cu (APC) film) can be used. For each of the conductive layer 112a to the conductive layer 112c and the conductive layer 126a to the conductive layer 126c, a stacked-layer film in which aluminum is sandwiched between a pair of titanium films (a film in which Ti, Al, and Ti are stacked in this order), or a stacked-layer film in which silver is sandwiched between a pair of indium tin oxide films (a film in which ITO, Ag, and ITO are stacked in this order) can be used.

For example, a conductive layer functioning as a reflective electrode can be used as each of the conductive layer 112a to the conductive layer 112c, and a conductor with a high light-transmitting property can be used for each of the conductive layer 126a to the conductive layer 126c. Examples of the conductor with a high light-transmitting property include indium tin oxide (sometimes referred to as ITO). For the conductive layer 126a to the conductive layer 126c, an alloy film of silver and magnesium can also be used as long as the film is thin enough to transmit light.

A conductive layer functioning as a transparent electrode can be used as each of the conductive layer 129a to the conductive layer 129c. For the conductive layer functioning as a transparent electrode, for example, the above-described conductor with a high light-transmitting property can be used.

The conductive layer 112a is connected to the conductive layer 596 embedded in the insulating layer 594 through an opening provided in the insulating layer 599. An end portion of the conductive layer 126a is positioned on the outer side of an end portion of the conductive layer 112a. The end portion of the conductive layer 126a and an end portion of the conductive layer 129a are aligned or substantially aligned with each other.

The conductive layer 112b, the conductive layer 126b, and the conductive layer 129b of the light-emitting device 130G and the conductive layer 112c, the conductive layer 126c, and the conductive layer 129c of the light-emitting device 130B are not described in detail because they are similar to the conductive layer 112a, the conductive layer 126a, and the conductive layer 129a of the light-emitting device 130R.

Depression portions are formed in the conductive layer 112a, the conductive layer 112b, and the conductive layer 112c to cover the openings provided in the insulating layer 599. A layer 128 is embedded in the depression portions.

The layer 128 has a function of filling the depression portions of the conductive layer 112a to the conductive layer 112c. The conductive layer 126a to the conductive layer 126c, which are in contact with the conductive layer 112a to the conductive layer 112c, respectively, are provided over the conductive layer 112a to the conductive layer 112c and the layer 128. Thus, regions overlapping with the depression portions of the conductive layer 112a to the conductive layer 112c can also be used as light-emitting regions, increasing the aperture ratio of pixels.

The layer 128 can be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching or wet etching on the surfaces of the conductive layer 112a, the conductive layer 112b, and the conductive layer 112c. When the layer 128 is formed using a negative photosensitive resin, the layer 128 can sometimes be formed using the same photomask (light-exposure mask) as the photomask used for forming the opening in the insulating layer 599.

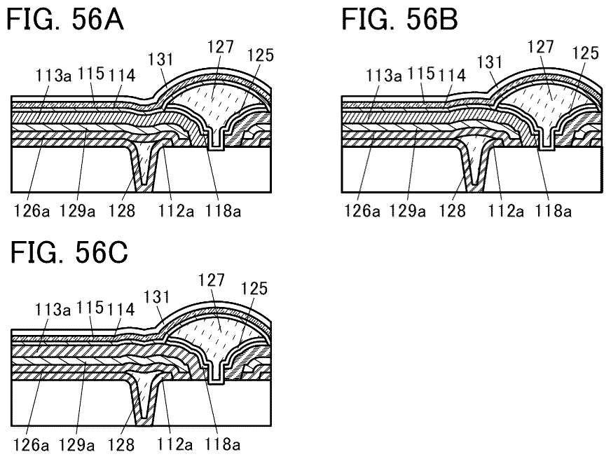

Although FIG. 53 shows an example in which the top surface of the layer 128 includes a flat portion, the shape of the layer 128 is not particularly limited. As illustrated in FIG. 56A, the middle and the vicinity of the top surface of the layer 128 may be concave in the cross-sectional view. As illustrated in FIG. 56B, the middle and the vicinity of the layer 128 may be convex in the cross-sectional view. As illustrated in FIG. 56C, the middle and the vicinity of the layer 128 may be concave and convex.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and side surface of the conductive layer 126a and the top surface and side surface of the conductive layer 129a. Similarly, the second layer 113b is formed to cover the top surface and side surface of the conductive layer 126b and the top surface and side surface of the conductive layer 129b. Similarly, the third layer 113c is formed to cover the top surface and side surface of the conductive layer 126c and the top surface and side surface of the conductive layer 129c. Accordingly, regions provided with the conductive layer 126a, the conductive layer 126b, and the conductive layer 126c can be entirely used as the light-emitting regions of the light-emitting device 130R, the light-emitting device 130G, and the light-emitting device 130B, respectively, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer.

There is no particular limitation on the structure of the light-emitting device in this embodiment, and the light-emitting device can have a single structure or a tandem structure.

The first layer 113a, the second layer 113b, and the third layer 113c each have an island shape after being processed by a lithography method. Thus, at each of end portions of the first layer 113a, the second layer 113b, and the third layer 113c, the angle between the top surface and side surface is approximately 90°. By contrast, for example, an organic film formed using an FMM (Fine Metal Mask) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top surface and side surface of each of the first layer 113a, the second layer 113b, and the third layer 113c are clearly distinguished from each other. Accordingly, the first layer 113a and the second layer 113b which are adjacent to each other are arranged so that one of the side surfaces of the first layer 113a and one of the side surfaces of the second layer 113b face each other. This applies to a combination of any two of the first layer 113a, the second layer 113b, and the third layer 113c.

The first layer 113a, the second layer 113b, and the third layer 113c each include at least alight-emitting layer. For example, a structure is preferable in which the first layer 113a includes alight-emitting layer that emits red light, the second layer 113b includes alight-emitting layer that emits green light, and the third layer 113c includes a light-emitting layer that emits blue light. Other than the above colors, cyan, magenta, yellow, or white can be employed for the light-emitting layers.

The first layer 113a, the second layer 113b, and the third layer 113c each preferably include a light-emitting layer and a carrier-transport layer (an electron-transport layer or a hole-transport layer) over the light-emitting layer. Since surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. As illustrated in FIG. 53, the common electrode 115 shared by the plurality of light-emitting devices is in contact with a conductor included in the connection portion 140.

An insulating layer 125 preferably has a function of a barrier insulating layer against one or both of water and oxygen. Alternatively, the insulating layer 125 preferably has a function of inhibiting diffusion of one or both of water and oxygen. Alternatively, the insulating layer 125 preferably has a function of capturing or fixing (also referred to as gettering) one or both of water and oxygen. When the insulating layer 125 has a function of a barrier insulating layer or a gettering function, entry of impurities (typically, one or both of water and oxygen) that would be diffused into the light-emitting devices from the outside can be inhibited. With this structure, a highly reliable light-emitting device and a highly reliable display panel can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against one or both of water and oxygen can be increased. For example, it is desirable that one of, preferably both of the hydrogen concentration and the carbon concentration in the insulating layer 125 be sufficiently low.

As an insulating layer 127, an insulating layer containing an organic material can be favorably used. As the organic material, a photosensitive organic resin is preferably used; for example, a photosensitive resin composition containing an acrylic resin can be used. The viscosity of the material of the insulating layer 127 is preferably greater than or equal to 1 cP and less than or equal to 1500 cP, further preferably greater than or equal to 1 cP and less than or equal to 12 cP. By setting the viscosity of the material of the insulating layer 127 in the above-described range, the insulating layer 127 having a tapered shape, which is described later, can be formed relatively easily. Note that in this specification and the like, an acrylic resin refers to not only a polymethacrylic acid ester or a methacrylic resin, but also all the acrylic polymer in a broad sense in some cases.

Note that in this specification and the like, a tapered shape refers to a shape in which at least part of a side surface of a structure is inclined to a substrate surface. For example, a tapered shape preferably includes a region where the angle formed between the inclined side surface and the substrate surface (such an angle is also referred to as a taper angle) is less than 90°.

Note that the organic material that can be used for the insulating layer 127 is not limited to the above as long as the insulating layer 127 has a tapered side surface as described later. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulating layer 127 in some cases. For the insulating layer 127, for example, a photoresist can be used as the photosensitive resin in some cases. Note that as the photosensitive resin, a positive material or a negative material can be used.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display panel can be improved. Since the display quality of the display panel can be improved without using a polarizing plate, the weight and thickness of the display panel can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

For example, the insulating layer 127 can be formed by a wet film-formation method such as spin coating, dipping, spray coating, ink-jetting, dispensing, screen printing, offset printing, doctor blade coating, slit coating, roll coating, curtain coating, or knife coating. Specifically, an organic insulating film to be the insulating layer 127 is preferably formed by spin coating.

The insulating layer 127 is formed at a temperature lower than the heat resistance temperature of the EL layer. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulating layer 127 or the like using the structure of the insulating layer 127 between the light-emitting device 130R and the light-emitting device 130G as an example. Note that the same applies to the insulating layer 127 between the light-emitting device 130G and the light-emitting device 130B, and the insulating layer 127 between the light-emitting device 130B and the light-emitting device 130R. The description made below sometimes using an end portion of the insulating layer 127 over the second layer 113b as an example applies to an end portion of the insulating layer 127 over the first layer 113a and an end portion of the insulating layer 127 over the third layer 113c.

In a cross-sectional view of the display apparatus, the side surface of the insulating layer 127 preferably has a tapered shape with a taper angle θ1. The taper angle θ1 is the angle formed between the side surface of the insulating layer 127 and the substrate surface. Note that the taper angle θ1 is not limited to the angle with the substrate surface, and may be the angle formed between the side surface of the insulating layer 127 and the top surface of the flat portion of the insulating layer 125 or the top surface of the flat portion of the second layer 113b. When the side surface of the insulating layer 127 has a tapered shape, the side surface of the insulating layer 125 and the side surface of the mask layer 118a also have a tapered shape in some cases.

The taper angle θ1 of the insulating layer 127 is less than 90°, preferably less than or equal to 60°, and further preferably less than or equal to 45°. Such a forward tapered shape of the end portion of the side surface of the insulating layer 127 can prevent disconnection, local thinning, or the like from occurring in the common layer 114 and the common electrode 115 which are provided over the end portion of the side surface of the insulating layer 127, leading to film formation with good coverage. The common layer 114 and the common electrode 115 can have improved in-plane uniformity in this manner, whereby the display apparatus can have improved display quality.

The top surface of the insulating layer 127 preferably has a convex shape in a cross-sectional view of the display apparatus. The top surface of the insulating layer 127 preferably has a convex shape that bulges gradually toward the center. The insulating layer 127 preferably has a shape such that the convex curved surface portion at the center portion of the top surface is connected smoothly to the tapered portion of the end portion of the side surface. When the insulating layer 127 has such a shape, the common layer 114 and the common electrode 115 can be formed with good coverage over the whole the insulating layer 127.

The insulating layer 127 is formed in a region between two EL layers (e.g., a region between the first layer 113a and the second layer 113b). At this time, part of the insulating layer 127 is placed at a position sandwiched between an end portion of the side surface of one of the EL layers (e.g., the first layer 113a) and an end portion of the side surface of the other of the EL layers (e.g., the second layer 113b).

One end portion of the insulating layer 127 preferably overlaps with the conductive layer 126a functioning as a pixel electrode, and the other end portion of the insulating layer 127 preferably overlaps with the conductive layer 126b functioning as a pixel electrode. With such a structure, the end portion of the insulating layer 127 can be formed over a substantially flat region of the first layer 113a (the second layer 113b). This makes it relatively easy to process the tapered shape of the insulating layer 127 as described above.

By providing the insulating layer 127 and the like in the above manner, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where the distance between two adjacent island-shaped EL layers is less than or equal to 1 μm, preferably less than or equal to 0.5 μm (500 nm), further preferably less than or equal to 100 nm. The distance between the light-emitting devices is shortened in this manner, whereby a display apparatus with high resolution and a high aperture ratio can be provided.

A protective layer 131 is provided over the light-emitting device 130. The protective layer 131 is a film functioning as a passivation film for protecting the light-emitting devices 130. Provision of the protective layer 131 covering the light-emitting device can inhibit an impurity such as water and oxygen from entering the light-emitting device, and increase the reliability of the light-emitting device 130. For the protective layer 131, aluminum oxide, silicon nitride, or silicon nitride oxide can be used, for example.

The protective layer 131 and a substrate 110 are bonded to each other with an adhesive layer 107. A solid sealing structure, a hollow sealing structure, or the like can be employed to seal the light-emitting devices. In FIG. 53, a solid sealing structure is employed in which a space between the substrate 310 and the substrate 110 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet may be used.

The display apparatus DSP1A has a top-emission structure. Light from the light-emitting device is emitted to the substrate 110 side. Thus, for the substrate 110, a material having a high visible-light-transmitting property is preferably used. For example, a substrate having a high visible-light-transmitting property is preferably selected as the substrate 110 from substrates usable as the substrate 310 and the substrate BS. The pixel electrode contains a material that reflects visible light, and a counter electrode (the common electrode 115) contains a material that transmits visible light.

Note that the display apparatus of one embodiment of the present invention can be not a top-emission display apparatus but a bottom-emission display apparatus where light from the light-emitting device is emitted to the substrate 310 side. In that case, a substrate having a high visible-light-transmitting property is preferably selected as the substrate 310.

Next, a cross-sectional structure example of the display apparatus DSP1 illustrated in FIG. 51A, which is different from the display apparatus DSP1A in FIG. 53 is described.

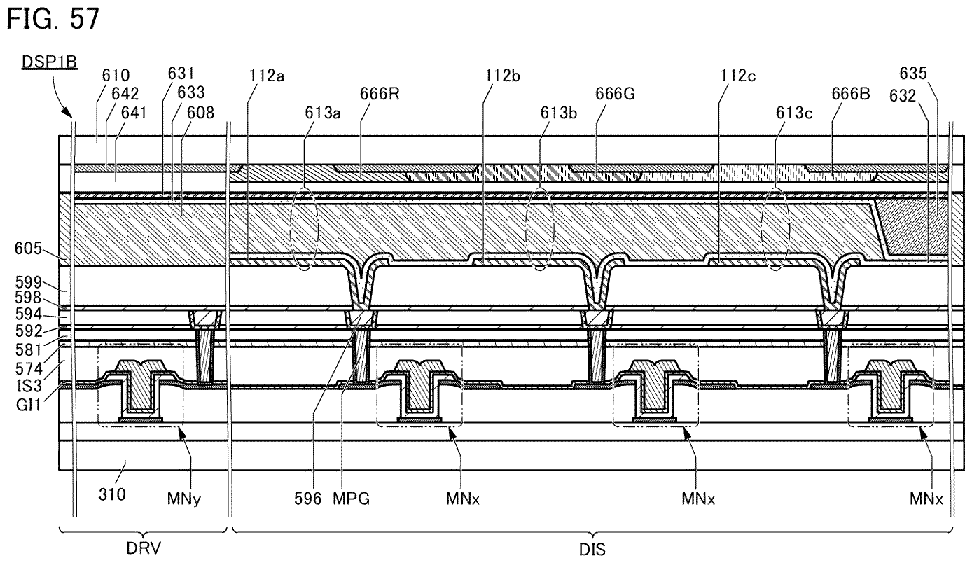

A display apparatus DSP1B illustrated in FIG. 57 is a cross-sectional structure example of the display apparatus DSP1 illustrated in FIG. 51A and is a display apparatus including a transmissive liquid crystal element (referred to as a liquid crystal display apparatus in some cases).

The display apparatus DSP1B includes the substrate 310 and a substrate 610, and a pixel circuit including a liquid crystal element and a driver circuit are sandwiched between the substrate 310 and the substrate 610.

In the display apparatus DSP1B, for example, light is emitted from a backlight (not illustrated) as a light source through a liquid crystal element 613a to a liquid crystal element 613c described later, whereby an image can be displayed. Thus, as the substrate 310 and the substrate 610, it is preferable to use a substrate having a high visible-light-transmitting property among the substrates that can be used as the substrate 310 of the display apparatus DSP1A described with reference to FIG. 53.

In FIG. 57, the liquid crystal element 613a serving as a display element includes the conductive layer 112a having a function of a first electrode, a conductive layer 631 having a function of a second electrode, and a liquid crystal layer 608. Similarly, a liquid crystal element 613b includes the conductive layer 112b having a function of a first electrode, the conductive layer 631 having a function of a second electrode, and the liquid crystal layer 608, and includes the conductive layer 112c having a function of a first electrode, the conductive layer 631 having a function of a second electrode, and the liquid crystal layer 608.

Hereinafter, the liquid crystal element 613a to the liquid crystal element 613c are collectively referred to as a liquid crystal element 613.

In the display apparatus DSP1B, an insulating layer 632 and an insulating layer 633 each having a function of an alignment film are provided to sandwich the liquid crystal layer 608. The conductive layer 631 is provided on the substrate 610 side, and the conductive layer 631 overlaps with the conductive layer 112a to the conductive layer 112c with the liquid crystal layer 608 therebetween. The liquid crystal layer 608 is sealed with a sealant 605 having a function of bonding the substrate 310 side and the substrate 610 side. The transistor MNx provided in the display region DIS is connected to the liquid crystal element 613.

A conductive material that transmits visible light is suitably used for the conductive layer 112a to the conductive layer 112c and the conductive layer 631. As the conductive material, for example, a material containing one or more kinds selected from indium (In), zinc (Zn), and tin (Sn) can be used. Specifically, examples include indium oxide, indium tin oxide (ITO), indium zinc oxide, indium oxide containing tungsten oxide, indium zinc oxide containing tungsten oxide, indium oxide containing titanium oxide, indium tin oxide containing titanium oxide, indium tin oxide containing silicon oxide (ITSO), zinc oxide, and zinc oxide containing gallium. Note that a film containing graphene can be used for the conductive layer 112a to the conductive layer 112c and the conductive layer 631. The film containing graphene can be formed, for example, by reducing a film that contains graphene oxide and is formed over a film of an insulator, a conductor, or the like.

A material having a high light-transmitting property is preferably used for the insulating layer IS1 to the insulating layer IS3, the insulating layer GI1, the conductive layer MET to the conductive layer ME3, the semiconductor layer SC1, the insulating layer 574, the insulating layer 581, the insulating layer 592, the insulating layer 594, the insulating layer 598, the insulating layer 599, the conductive layer 596, and the conductive layer MPG described with the display apparatus DSPTA in FIG. 53 and the transistor MN in FIG. 54, so that light from a backlight (not illustrated) as a light source can pass through the layers.

The liquid crystal element 613 can be a liquid crystal element using an FFS (Fringe Field Switching) mode, for example. In general, liquid crystal materials include a positive liquid crystal material with a positive dielectric anisotropy (AE) and a negative liquid crystal material with a negative dielectric anisotropy. Both of the materials can be employed for the liquid crystal element 613 shown in this embodiment, and an optimal liquid crystal material can be used according to the employed mode and design.

A negative liquid crystal material is preferably used in the display apparatus shown in this embodiment. The negative liquid crystal is less affected by a flexoelectric effect, which is attributed to the polarization of liquid crystal molecules, and thus the polarity causes little difference in transmittance. This inhibits flickering from being recognized by the user of the display apparatus. The flexoelectric effect is a phenomenon in which polarization is induced by the distortion of orientation, and mainly depends on the shape of a molecule. The negative liquid crystal material is less likely to experience deformation such as spreading and bending.

Note that the liquid crystal element 613 here is an element using an FFS mode, but can be a liquid crystal element using any other variety of modes. For example, it is possible to use a liquid crystal element using a VA (Vertical Alignment) mode, a TN (Twisted Nematic) mode, an IPS (In-Plane-Switching) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a VA-IPS mode, a guest-host mode, or the like.

A normally-black liquid crystal display apparatus such as a transmissive liquid crystal display apparatus using a vertical alignment (VA) mode can also be used in the display apparatus shown in this embodiment. As the vertical alignment mode, an MVA (Multi-Domain Vertical Alignment) mode, a PVA (Patterned Vertical Alignment) mode, an ASV (Advanced Super View) mode, and the like can be used.

Note that the liquid crystal element is an element that controls transmission and non-transmission of light by the optical modulation action of liquid crystal. The optical modulation action of the liquid crystal is controlled by an electric field applied to the liquid crystal (including a horizontal electric field, a vertical electric field, or an oblique electric field). As the liquid crystal used for the liquid crystal element, a thermotropic liquid crystal, a low-molecular liquid crystal, a high-molecular liquid crystal, a polymer dispersed liquid crystal (PDLC), a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Although FIG. 57 shows an example of a display apparatus including a liquid crystal element with a vertical electric field mode, a display apparatus including a liquid crystal element with a horizontal electric field mode can also be used in one embodiment of the present invention. In the case of employing a horizontal electric field mode, a liquid crystal exhibiting a blue phase for which an alignment film is not used can be used. A blue phase is one of liquid crystal phases, which appears just before a cholesteric phase changes into an isotropic phase while the temperature of a cholesteric liquid crystal is increased. Since the blue phase is only generated within a narrow temperature range, a liquid crystal composition that contains a chiral material at greater than or equal to 5 wt % is used for the liquid crystal layer 608 in order to improve the temperature range. A liquid crystal composition that contains a liquid crystal exhibiting a blue phase and a chiral material has a short response time and exhibits optical isotropy. The liquid crystal composition that contains a liquid crystal exhibiting a blue phase and a chiral material does not need alignment treatment and has small viewing angle dependence. Since an alignment film does not need to be provided and rubbing treatment is unnecessary, electrostatic discharge damage caused by the rubbing treatment can be prevented and defects or damage of the liquid crystal display apparatus in the manufacturing process can be reduced.

A spacer 635 is a columnar spacer obtained by selective etching of an insulating layer and is provided to adjust the distance (cell gap) between the conductive layer 631 and each of the conductive layer 112a to the conductive layer 112c. Note that a spherical spacer may be used instead of the columnar spacer.

A black matrix (a light-blocking layer), a coloring layer (a color filter), an optical member (an optical substrate) such as a polarizing member, a retardation member, or an anti-reflection member, or the like can be provided as appropriate if needed. For example, circular polarization may be employed by using a polarizing substrate and a retardation substrate. A backlight unit, a side light unit, or the like may be used as alight source (not illustrated). A micro LED or the like may be used as the backlight unit or the side light unit. For example, the display apparatus illustrated in FIG. 57 can have a structure in which a polarizing substrate is provided on the surface side of the substrate 610 (the surface opposite to the surface provided with a coloring layer 666R, a coloring layer 666G, a coloring layer 666B, and a light-blocking layer 642) and on the rear surface side of the substrate 310 (the surface opposite to the surface provided with the transistor MNx and the transistor MNy), and a backlight unit is provided on the rear surface side of the substrate 310 with the polarizing substrate therebetween (not illustrated).

In the display apparatus illustrated in FIG. 57, the light-blocking layer 642, the coloring layer 666R, the coloring layer 666G, the coloring layer 666B, and an insulating layer 641 are provided between the substrate 610 and the conductive layer 631.

Examples of a material that can be used for the light-blocking layer 642 include carbon black, titanium black, a metal, a metal oxide, and a composite oxide containing a solid solution of a plurality of metal oxides. A film containing a resin material or a thin film of an inorganic material such as a metal can be used as the light-blocking layer. A stacked-layer film of films containing any one of the materials for the coloring layer 666R to the coloring layer 666B can be used as the light-blocking layer 642. For example, it is possible to use a stacked-layer structure of a film containing a material used for the coloring layer 666R that transmits light of a certain color and a film containing a material used for the coloring layer 666G that transmits light of another color. Using the same material for the coloring layer 666R to the coloring layer 666B and the light-blocking layer 642 is preferable because process simplification as well as equipment sharing can be achieved.

Examples of a material that can be used for the coloring layer 666R to the coloring layer 666B include a metal material, a resin material, and a resin material containing a pigment or a dye. The light-blocking layer and the coloring layer can be formed by a method similar to the method for forming the above-described layers. Specifically, an inkjet method can be used for the formation, for example.

The insulating layer 641 is preferably an overcoat having a planarization function. With the insulating layer 641 having the planarization function, a flat insulating film can be formed over a formation surface of the coloring layer 666R to the coloring layer 666B and the light-blocking layer 642 having different thicknesses. Since the conductive layer 631 can be formed flat owing to the insulating layer 641 being planarized, a thickness variation of the liquid crystal layer 608 can be reduced. An acrylic resin or the like can be given as an example of such an insulating layer 641.

Described next is a cross-sectional structure example of the display apparatus DSP1 of the case where an LED package is included in a pixel of the display apparatus DSP1 in FIG. 51A.

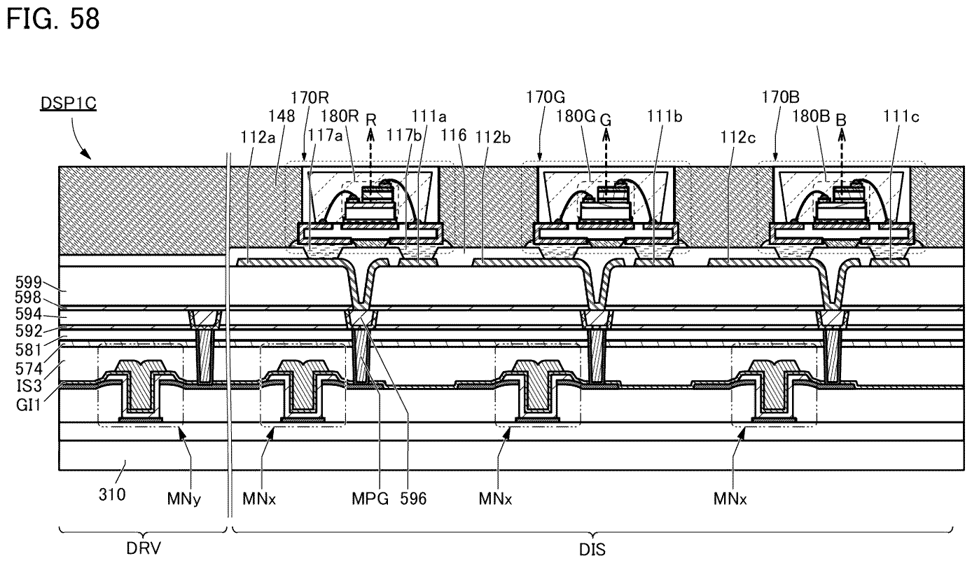

In a display apparatus DSP1C illustrated in FIG. 58, a packaged LED chip is mounted on the display apparatus. Specifically, the display apparatus DSP1C illustrated in FIG. 58 has a structure in which an LED package 170R, an LED package 170G, and an LED package 170B are provided as light-emitting devices in the display region DIS.

In the display apparatus DSP1C in FIG. 58, a conductive layer 111a to a conductive layer 111c and the conductive layer 112a to the conductive layer 112c are provided over the insulating layer 599, for example. A protective layer 116 is provided over the conductive layer lilato the conductive layer 111c, the conductive layer 112a to the conductive layer 112c, and the insulating layer 599. The protective layer 116 is formed to fill an opening of the insulating layer 599; the bottom portion of the opening is the top surface of the conductive layer 596. In particular, the protective layer 116 is preferably provided to cover end portions of the conductive layer 1la to the conductive layer 111c and the conductive layer 112a to the conductive layer 112c.

For example, a resin such as an acrylic resin, a polyimide resin, an epoxy resin, or a silicone resin is suitably used for the protective layer 116. Providing the protective layer 116 can inhibit a conductive layer 117a and a conductive layer 117b to be described later from being in contact with each other, that is, from being short-circuited. Note that depending on circumstances, the protective layer 116 is not necessarily provided over the insulating layer 599, the conductive layer 111a to the conductive layer II1c, and the conductive layer 112a to the conductive layer 112c.

Opening portions are formed in the protective layer 116 in regions partly overlapping with the conductive layer 111a to the conductive layer 111c and regions partly overlapping with the conductive layer 112a to the conductive layer 112c. The conductive layer 117a and the conductive layer 117b are provided over the protective layer 116. Specifically, the conductive layer 117a is provided to fill the openings of the protective layer 116 in the regions partly overlapping with the conductive layer 112a to the conductive layer 112c, and the conductive layer 117b is provided to fill the openings of the protective layer 116 in the regions partly overlapping with the conductive layer 111a to the conductive layer 111c.

A conductive paste including a material such as silver, carbon, or copper or a bump including a material such as gold or solder can be suitably used for the conductive layer 117a and the conductive layer 117b. For each of the conductive layer 112a to the conductive layer 112c (the conductive layer 111a to the conductive layer 111c) and an electrode 172 (an electrode 173) to be described later, which are electrically connected to the conductive layer 117a (the conductive layer 117b), a conductive material having low contact resistance with the conductive layer 117a (the conductive layer 117b) is preferably used. For example, in the case where a silver paste is used for the conductive layer 117a (the conductive layer 117b), aluminum, titanium, copper, or an alloy of silver, palladium, and copper (Ag—Pd—Cu (APC)) is used as the conductive material usable for the conductive layer 112a to the conductive layer 112c (the conductive layer 111a to the conductive layer 111c) and the electrode 172 (the electrode 173) to be described later, whereby the contact resistance with the conductive layer 117a (the conductive layer 117b) can be low.

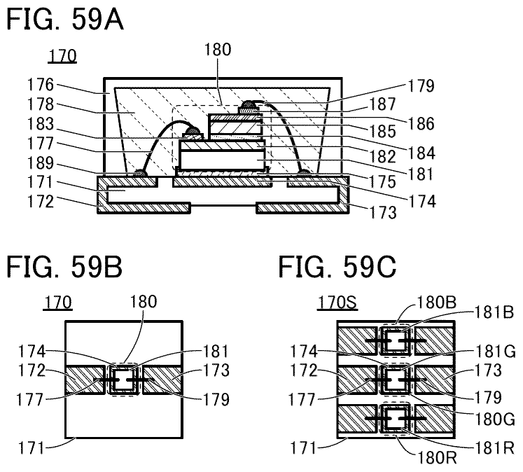

The LED package 170R, the LED package 170G, and the LED package 170B are mounted on the conductive layer 117a and the conductive layer 117b. Note that FIG. 59A illustrates specific structure examples of the LED package 170R, the LED package 170G, and the LED package 170B included in the display apparatus DSP1C in FIG. 58.

The LED package 170 in FIG. 59A includes a substrate 171, the electrode 172, the electrode 173, a heat sink 174, an adhesive layer 175, a case 176, a wire 177, a wire 179, a sealing layer 178, a ball 189, and an LED chip 180.

In this specification and the like, an LED chip is a light-emitting diode in which an electrode serving as a cathode, an electrode serving as an anode, a p-type semiconductor, an n-type semiconductor, and a light-emitting layer are provided over a substrate. Note that in this specification and the like, the term “LED chip” can be replaced with the term “light-emitting diode” in the description in some cases.

Specifically, in this specification and the like, a light-emitting diode whose LED chip area is less than or equal to 10000 μm² is referred to as a micro light-emitting diode, a light-emitting diode whose LED chip area is greater than 10000 μm² and less than or equal to 1 mm² is referred to as a mini light-emitting diode, and a light-emitting diode whose LED chip area is greater than 1 mm² is referred to as a macro light-emitting diode in some cases. Note that the area of an LED chip here can be, for example, the area of the top surface or the bottom surface of a substrate 181 in FIG. 59A.

For example, a light-emitting diode whose LED chip area is less than or equal to 100 μm² can be referred to as a micro light-emitting diode (micro LED chip). As a light-emitting diode usable for an LED package with an area of 1 mm², a micro LED chip or a mini LED chip can be used in some cases, for example.

Any of a micro light-emitting diode, a mini light-emitting diode, and a macro light-emitting diode can be used for the LED package in the display apparatus of one embodiment of the present invention. In particular, the display apparatus of one embodiment of the present invention preferably includes a micro light-emitting diode or a mini light-emitting diode, and more preferably includes a micro light-emitting diode.

In particular, the area of an LED chip of the light-emitting diode is preferably less than or equal to 1 mm², further preferably less than or equal to 10000 μm², still further preferably less than or equal to 3000 μm², even further preferably less than or equal to 700 μm²

The area of a light-emitting region of the light-emitting diode is preferably less than or equal to 1 mm², further preferably less than or equal to 10000 μm², still further preferably less than or equal to 3000 μm², even further preferably less than or equal to 700 μm². Note that the area of the light-emitting region of the light-emitting diode here can be, for example, the area of the top surface or the bottom surface of a light-emitting layer 184 in FIG. 59A.

In this embodiment, in particular, an example where a micro light-emitting diode is used as a light-emitting diode is described. A micro light-emitting diode having a double heterojunction is described in this embodiment. Note that there is no particular limitation on the light-emitting diode, and for example, a micro light-emitting diode having a quantum well junction or a nanocolumn light-emitting diode may be used.

The LED chip 180 includes the substrate 181, a semiconductor layer 182, an electrode 183, the light-emitting layer 184, a semiconductor layer 185, an electrode 186, and an electrode 187.

As the substrate 171, a glass epoxy resin substrate, a polyimide substrate, a ceramic substrate, an alumina substrate (an aluminum oxide substrate), or an aluminum nitride substrate can be used, for example.

The electrode 172 and the electrode 173 are formed on the top surface, side surfaces, and bottom surface of the substrate 171. Specifically, the electrode 172 formed on the top surface, side surface, and bottom surface of the substrate 171 functions as one wiring, and the electrode 173 formed on the top surface, side surface, and bottom surface of the substrate 171 functions as another wiring. Note that electrical continuity is not established between the electrode 172 and the electrode 173.

The substrate 171 is provided with the heat sink 174. The heat sink 174 has a function of releasing heat generated in the LED chip 180, for example.

Note that the electrode 172, the electrode 173, and the heat sink 174 can be formed with the same material. For example, for each of the electrode 172, the electrode 173, and the heat sink 174, one element selected from nickel, copper, silver, platinum, and gold, or an alloy material containing any of the elements at 50% or higher can be used.

The electrode 172, the electrode 173, and the heat sink 174 can be formed in the same step.

The LED chip 180 is attached above the substrate 171 with the adhesive layer 175. Specifically, the substrate 181 of the LED chip 180 is provided to overlap with the heat sink 174 on the substrate 171, with the adhesive layer 175 positioned therebetween. There is no particular limitation on a material of the adhesive layer 175. For example, the use of an adhesive with conductivity as a material of the adhesive layer 175 can increase the heat dissipation property of the LED chip 180.

The substrate 181 can be a single crystal substrate such as a sapphire substrate, a silicon carbide substrate, a silicon substrate, or a gallium nitride substrate, for example.

In the LED chip 180, the semiconductor layer 182 is formed over the substrate 181. The electrode 183 is formed over a part of the semiconductor layer 182, and the light-emitting layer 184 is formed over another part of the semiconductor layer 182. The semiconductor layer 185 is formed over the light-emitting layer 184, the electrode 186 is formed over the semiconductor layer 185, and the electrode 187 is formed over a part of the electrode 186.

In the LED chip 180, the light-emitting layer 184 is sandwiched between the semiconductor layer 182 and the semiconductor layer 185. In the light-emitting layer 184, electrons and holes are combined to emit light. One of the semiconductor layer 182 and the semiconductor layer 185 is an n-type semiconductor layer, and the other of the semiconductor layer 182 and the semiconductor layer 185 is a p-type semiconductor layer. An n-type semiconductor layer, an i-type semiconductor layer, or a p-type semiconductor layer can be used as the light-emitting layer 184. That is, a semiconductor layer can be used as each of the semiconductor layer 182, the light-emitting layer 184, and the semiconductor layer 185. Note that the semiconductor layer 182, the light-emitting layer 184, and the semiconductor layer 185 are collectively referred to as an LED layer or a light-emitting diode in some cases.

The LED layer is formed to emit light such as red light, yellow light, green light, blue light, or ultraviolet light. There is no particular limitation on the structure of the LED layer; a homostructure, a heterostructure, or a double-heterostructure having a pn junction or a pin junction can be used or a MIS (Metal Insulator Semiconductor) structure can be used. The LED layer can have a superlattice structure, a single quantum well structure, or a multi quantum well (MQW) structure. For example, a nanocolumn can be used in the LED layer.

A compound containing a Group 13 element and a Group 15 element can be used for the LED layer, for example. Examples of the Group 13 element include aluminum, gallium, and indium. Examples of the Group 15 element include nitrogen, phosphorus, arsenic, and antimony. For the LED layer, for example, a compound of gallium and phosphorus, a compound of gallium and arsenic, a compound of gallium, aluminum, and arsenic, a compound of aluminum, gallium, indium, and phosphorus, gallium nitride (GaN), a compound of indium and gallium nitride, or a compound of selenium and zinc can be used.

For example, gallium nitride can be used for an LED layer that emits light in the ultraviolet wavelength range to the blue wavelength range. A compound of indium and gallium nitride can be used for an LED layer that emits light in the ultraviolet wavelength range to the green wavelength range. A compound of aluminum, gallium, indium, and phosphorus or a compound of gallium and arsenic can be used for an LED layer that emits light in the green wavelength range to the red wavelength range. A compound of gallium and arsenic can be used for an LED layer that emits light in the infrared wavelength range.

In the display apparatus DSP1C in FIG. 58, a light-emitting diode included in an LED chip of each of the LED package 170R, the LED package 170G, and the LED package 170B has a stacked-layer structure of a pair of semiconductor layers and a light-emitting layer between the pair of semiconductor layers, and emits red light, green light, or blue light. Thus, the colors of light emitted from the light-emitting diodes of the LED chips can be freely determined separately in the LED package 170R, the LED package 170G, and the LED package 170B.

The colors of light emitted from the light-emitting diodes included in the LED chips 180 of the LED packages 170 can be cyan, magenta, yellow, and white in addition to red, green, and blue.

The electrode 183 is electrically connected to the electrode 172 through the wire 177. That is, the electrode 183 functions as a pixel electrode of the light-emitting diode. The electrode 187 is electrically connected to the electrode 173 through the wire 179. That is, the electrode 187 functions as a common electrode of the light-emitting diode.

A wire bonding method can be used as a method of bonding the electrode 183 and the wire 177, a method of bonding the electrode 172 and the wire 177, a method of bonding the electrode 187 and the wire 179, and a method of bonding the electrode 173 and the wire 179, for example. A thermocompression bonding method and an ultrasonic bonding method are kinds of the wire bonding method. In a step of bonding the wire 177 and the wire 179 by the wire bonding method, the ball 189 made of the same material as the wire 179 is formed over the electrode 172, the electrode 173, the electrode 183, and the electrode 187.

For example, a material usable for the conductive layer 111a to the conductive layer 111c or the conductive layer 112a to the conductive layer 112c is preferably used for each of the electrode 183, the electrode 186, and the electrode 187. In particular, since the light-emitting layer 184 of the LED chip 180 emits light to the upside of the LED package 170, the electrode 186 is preferably a light-transmitting conductor among the materials usable for each of the conductive layer 11la to the conductive layer 111c and the conductive layer 112a to the conductive layer 112c. For the same reason, the electrode 187 is preferably a light-transmitting conductor among the materials usable for each of the conductive layer ll1a to the conductive layer 111c and the conductive layer 112a to the conductive layer 112c.

As the wire 177 and the wire 179, a thin metal wire of gold, an alloy containing gold, copper, or an alloy containing copper can be used, for example.

A resin can be used as the material for the case 176. The case 176 preferably covers the side surface of the sealing layer 178, but does not necessarily cover the top surface of the LED chip 180. That is, for example, the sealing layer 178 may be exposed from the top surface of the LED chip 180. The inner side surface of the case 176, specifically, the periphery of the LED chip 180 (peripheries of the substrate 181, the semiconductor layer 182, the electrode 183, the light-emitting layer 184, the semiconductor layer 185, the electrode 186, and the electrode 187) is preferably provided with a reflector made of ceramics or the like. Part of light emitted by the light-emitting layer 184 of the LED chip 180 is reflected by the reflector, so that a larger amount of light can be extracted from the LED package 170.

The inside of the case 176 is filled with the sealing layer 178. For the sealing layer 178, a resin having a property of transmitting visible light is preferably used. Specifically, for the sealing layer 178, for example, an ultraviolet curable resin such as an epoxy resin or a silicone resin or a visible light curable resin can be used.

A variety of optical members can be provided on surfaces of a resin layer 148, the LED package 170R, the LED package 170G, and the LED package 170B, for example, in the display apparatus DSP1C. Examples of the optical members include a polarizing plate, a retardation plate, a light diffusion layer (e.g., a diffusion film), an anti-reflective layer, and a light-condensing film. The surfaces of the resin layer 148, the LED package 170R, the LED package 170G, and the LED package 170B in the display apparatus DSP1C may be provided with a surface protective layer such as an antistatic film suppressing the attachment of a foreign substance, a water repellent film suppressing the attachment of stain, a hard coat film suppressing generation of a scratch in use, or an impact absorption layer. For example, it is preferable to provide, as the surface protective layer, a glass layer or a silica layer (SiOₓ layer) because the surface contamination or damage can be inhibited from being generated. For the surface protective layer, DLC (diamond-like carbon), aluminum oxide (AlOₓ), a polyester-based material, a polycarbonate-based material, or the like can be used. For the surface protective layer, a material having a high transmitting property with respect to visible light is preferably used. For the surface protective layer, a material with high hardness is preferably used.

Note that the LED package 170 illustrated in FIG. 59A is an example, and the LED package 170R, the LED package 170G, and the LED package 170B in the display apparatus DSP1C can have different structures.

For example, in the LED package 170 in FIG. 59A, the LED chip 180 is connected to the electrode 172 and the electrode 173 through the wire 177 and the wire 179; alternatively, a conductive adhesive layer can be provided on one of the top surfaces of the electrode 172 and the electrode 173, and the LED chip 180 can be stacked over the adhesive layer. When the top surface of the LED chip (e.g., the electrode 187) is connected to the other of the electrode 172 and the electrode 173 through the wire 177 or the wire 179, electrical continuity can be established between the anode and the cathode of the LED chip and the electrode 172 and the electrode 173.

For example, the LED package used as the LED package 170R, the LED package 170G, and the LED package 170B in the display apparatus DSP1C can have a structure in which the LED chip 180 is bonded to the electrode 172 and the electrode 173 with a conductive layer having a function of a bump.

For example, in the LED package 170 in FIG. 59A, a color conversion layer can be provided above the LED chip 180 and inside the case 176. Alternatively, the color conversion layers can be dispersed inside the sealing layer 178.

For the color conversion layer, a phosphor or a quantum dot (QD) is preferably used. In particular, a quantum dot has an emission spectrum with a narrow peak, so that emission with high color purity can be obtained. The use of a quantum dot for the color conversion layer can improve the display quality of the display apparatus DSP1C.

For example, the color conversion layer has a function of converting light emitted by the light-emitting layer 184 included in the LED chip 180 of the LED package 170 into light of another color.

For example, as the color conversion layer, a color conversion layer converting blue light into green light or a conversion layer converting blue light into red light can be used. For example, in the case where a blue light-emitting diode is provided in a red subpixel, blue light emitted by the blue light-emitting diode passes through the color conversion layer, thereby being converted into red light and emitted to the upside of the case 176, that is, the outside of the display apparatus DSP1C. For example, in the case where a blue light-emitting diode is provided in a green subpixel, blue light emitted by the blue light-emitting diode passes through the color conversion layer, thereby being converted into green light and emitted to the upside of the case 176, that is, the outside of the display apparatus DSP1C.

A stacked-layer structure of a color conversion layer and a coloring layer may be provided inside or above the LED package 170. Thus, light that has been converted by the color conversion layer passes through the coloring layer, whereby the color purity of light can be increased. A coloring layer of the same color as light emitted by the light-emitting layer 184 may be provided in a position overlapping with the LED chip 180 (the substrate 181, the semiconductor layer 182, the electrode 183, the light-emitting layer 184, the semiconductor layer 185, the electrode 186, and the electrode 187). Providing a coloring layer of the same color can increase the color purity of light emitted by the light-emitting layer 184. In the case where a coloring layer is not provided in the LED package 170, the manufacturing process can be simplified.

Next, the number of LED chips 180 that can be provided in the LED package 170 is described. FIG. 59B is an example of a plan view of the LED package 170 in FIG. 59A. Note that FIG. 59B illustrates the substrate 181 which is a component of the LED chip 180. Although the LED package 170 including one LED chip 180 over the substrate 171 is described above as an example as illustrated in FIG. 59B, one embodiment of the present invention is not limited to this structure. For example, the LED package 170 may include not one LED chip but a plurality of LED chips over the substrate 171.

FIG. 59C illustrates a structure of an LED package 170S in which three LED chips 180R, 180G, and 180B are provided over the substrate 171. Note that FIG. 59C illustrates a substrate 181R which is a component of the LED chip 180R, a substrate 181G which is a component of the LED chip 180G, and a substrate 181B which is a component of the LED chip 180B. The light-emitting diodes included in the LED chip 180R, the LED chip 180G, and the LED chip 180B provided in the LED package 170S may include light-emitting layers emitting light of different colors. For example, the substrate 181R is provided with alight-emitting diode emitting red light, the substrate 181G is provided with a light-emitting diode emitting green light, and the substrate 181B is provided with a light-emitting diode emitting blue light, whereby the LED package 170S can emit light of three colors, red, green, and blue.

In the above-described LED package 170 and LED package 170S, the light-emitting diodes (the LED chip 180R, the LED chip 180G, and the LED chip 180B) can be driven by transistors having the same structure or transistors having different structures. For example, in the display apparatus DSP1C in FIG. 58, a transistor that drives the LED chip 180R included in the LED package 170R, a transistor that drives the LED chip 180G included in the LED package 170G, and a transistor that drives the LED chip 180B included in the LED package 170B can be different from one another in one or more selected from a transistor size, a channel length, a channel width, a structure, and the like. Specifically, depending on the amount of current required for light emission with desired luminance, one or both of the channel length and the channel width of the transistor can be changed for each color.

In the display apparatus DSP1C in FIG. 58, the top surface of the protective layer 116, the top surface and side surface of the conductive layer 117a, the top surface and side surface of the conductive layer 117b, the side surface of the LED package 170R, the side surface of the LED package 170G, and the side surface of the LED package 170B may be covered with the resin layer 148. Use of a black resin for the resin layer 148 can enhance the display contrast of the display apparatus DSP1C. One or more selected from the top surface of the resin layer 148 and the top surfaces of the LED package 170R, the LED package 170G, and the LED package 170B can be provided with a surface protective layer or an impact absorption layer. Since each of the LED package 170R, the LED package 170G, and the LED package 170B has a structure in which light is emitted upward, a layer provided on each of the top surfaces of the LED package 170R, the LED package 170G, and the LED package 170B preferably has a visible-light-transmitting property.

All the conductive layer 112a to the conductive layer 112c, the conductive layer 117a, and the electrode 172 in the LED package 170R, the LED package 170G, and the LED package 170B are referred to as pixel electrodes in some cases. Parts of the conductive layer 112a to the conductive layer 112c, the conductive layer 117a, and the electrode 172 are referred to as pixel electrodes in some cases.

Note that the display apparatus of one embodiment of the present invention is not limited to having the structure of the display apparatus DSP1C illustrated in FIG. 58. The display apparatus of one embodiment of the present invention can have the structure of the display apparatus DSP1C illustrated in FIG. 58, which is appropriately changed.

For example, the display apparatus of one embodiment of the present invention may have not a structure in which a plurality of LED packages 170 are mounted above the substrate 310 but a structure in which a substrate provided with a plurality of light-emitting diodes is attached above the substrate 310 (not illustrated).

Although the display apparatus DSP1C illustrated in FIG. 58 is provided with the LED packages exhibiting a plurality of colors, the whole display portion may be formed of LED packages exhibiting a single color, for example.

### <Cross-Sectional Structure Example 2 of Display Apparatus>

Next, a cross-sectional structure example of the display apparatus DSP2 illustrated in FIG. 51B is described.

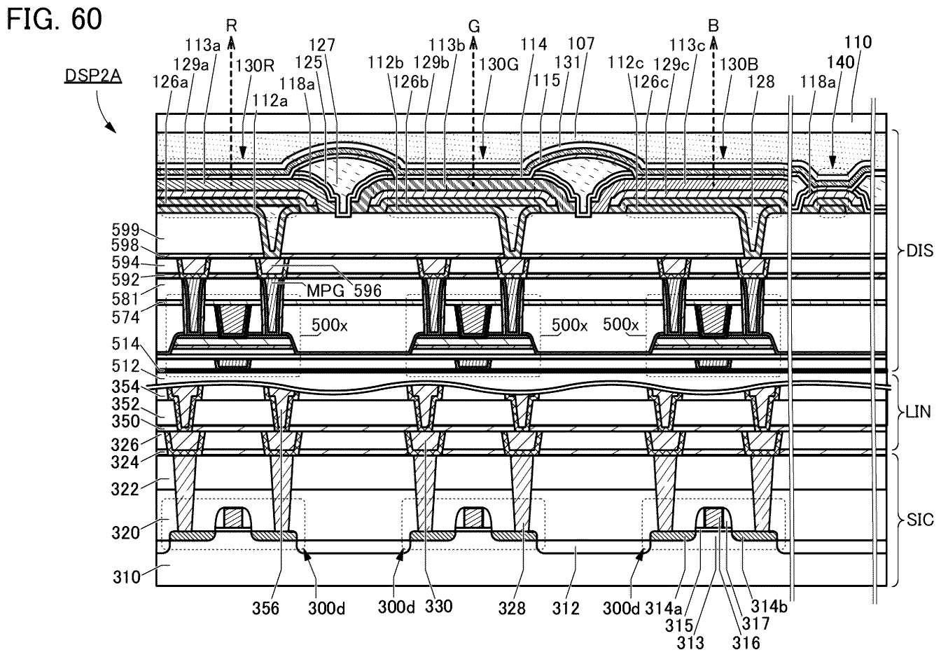

A display apparatus DSP2A illustrated in FIG. 60 is a cross-sectional structure example of the display apparatus DSP2 illustrated in FIG. 51B. The display apparatus DSP2A has a structure provided with a pixel circuit, a driver circuit, and the like over the substrate 310. In the display apparatus DSP2A in FIG. 60, a wiring region LIN is illustrated in addition to the circuit region SIC and the display region DIS that are illustrated in FIG. 51B.

The circuit region SIC includes the substrate 310, for example, and a transistor 300d is formed over the substrate 310. The wiring region LIN is provided above the transistor 300d, and the wiring region LIN is provided with a wiring connected to the transistor 300d, a transistor 500x described later, the light-emitting device 130R, the light-emitting device 130G, and the light-emitting device 130B. The display region DIS is provided above the wiring region LIN, and the display region DIS includes, for example, the transistor 500x, the light-emitting devices 130 (the light-emitting device 130R, the light-emitting device 130G, and the light-emitting device 130B in FIG. 60), and the like.

That is, the transistor 300d can be a transistor included in the circuit region SIC. The transistor 500x can be a transistor included in the pixel circuit PX. The light-emitting device 130 can be a light-emitting device included in the pixel circuit PX.

For the light-emitting devices 130 (the light-emitting device 130R, the light-emitting device 130G, and the light-emitting device 130B in FIG. 60) positioned above the transistor 500x, the description of the light-emitting devices 130 in FIG. 53 can be referred to.

As the substrate 310, a substrate that can be used as the substrate BS can be used, for example. In the description in this embodiment, the substrate 310 is a semiconductor substrate including silicon as a material. Therefore, a transistor included in the circuit region SIC can be a Si transistor. Examples of the Si transistor include a transistor including single crystal silicon in a channel formation region and a transistor including low-temperature polysilicon (LTPS) in a channel formation region.

Thus, the transistor 300d formed over the substrate 310 has a structure different from that of the transistor MNx and the transistor MNy illustrated in FIG. 53. Note that in the display apparatus DSP2A in FIG. 60, the transistors included in the circuit region SIC may be the transistor MNx and the transistor MNy illustrated in FIG. 53. In this case, the substrate 310 is preferably a glass substrate.

For the screen ratio (aspect ratio) of the display apparatus DSP2A, the description of the screen ratio of the display apparatus DSP1A can be referred to. For the diagonal size of the display apparatus DSP2A, the description of the diagonal size of the display apparatus DSP1A can be referred to.

The transistor 300d includes an element isolation layer 312, a conductive layer 316, an insulating layer 315, an insulating layer 317, a semiconductor region 313 that is part of the substrate 310, and a low-resistance region 314a and a low-resistance region 314b that function as a source region and a drain region. Thus, the transistor 300d is a Si transistor. Although FIG. 60 illustrates a structure in which one of a source and a drain of the transistor 300d is connected to a conductive layer 330 and a conductive layer 356, which are described later, through a conductive layer 328 described later, the electrical connection structure in the display apparatus of one embodiment of the present invention is not limited thereto. The display apparatus of one embodiment of the present invention may have a structure in which, for example, a gate of the transistor 300d is connected to the conductive layer 328.

The transistor 300d can be a Fin type when, for example, the top surface of the semiconductor region 313 and the side surface thereof in the channel width direction are covered with the conductive layer 316 with the insulating layer 315 functioning as a gate insulator therebetween. The effective channel width can be increased in the Fin-type transistor 300d, so that the on-state characteristics of the transistor 300d can be improved. In addition, contribution of the electric field of a gate electrode can be increased, so that the off-state characteristics of the transistor 300d can be improved. The transistor 300d may have a planar structure instead of a Fin-type structure.

Note that the transistor 300d may be either a p-channel transistor or an n-channel transistor. Alternatively, a plurality of the transistors 300d may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably include a silicon-based semiconductor, specifically, preferably include single crystal silicon. Alternatively, each of the regions may be formed using germanium, silicon germanium, gallium arsenide, aluminum gallium arsenide, or gallium nitride, for example. A structure using silicon whose effective mass is controlled by applying stress to the crystal lattice and changing the lattice spacing may be employed. Alternatively, the transistor 300d may be a HEMT (High Electron Mobility Transistor) using gallium arsenide and aluminum gallium arsenide, for example.

For the conductive layer 316 functioning as the gate electrode, a semiconductor material such as silicon containing an element that imparts n-type conductivity, such as arsenic or phosphorus, or an element that imparts p-type conductivity, such as boron or aluminum, can be used. Alternatively, for the conductive layer 316, a conductive material such as a metal material, an alloy material, or a metal oxide material can be used, for example.

Note that since the work function depends on the material of a conductor, the threshold voltage of the transistor can be adjusted by selecting the material of the conductor. Specifically, it is preferable to use one or both of titanium nitride and tantalum nitride as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation Of Silicon) method, an STI (Shallow Trench Isolation) method, or a mesa isolation method.

Over the transistor 300d illustrated in FIG. 60, an insulating layer 320 and an insulating layer 322 are sequentially stacked from the substrate 310 side.

For each of the insulating layer 320 and the insulating layer 322, one or more selected from silicon oxide, silicon oxynitride, silicon nitride oxide, silicon nitride, aluminum oxide, aluminum oxynitride, aluminum nitride oxide, and aluminum nitride are used, for example.

The insulating layer 322 may have a function of a planarization film for eliminating a level difference caused by the transistor 300d or the like covered with the insulating layer 320 and the insulating layer 322. For example, the top surface of the insulating layer 322 may be planarized by planarization treatment using a chemical mechanical polishing (CMP) method to improve planarity.

The conductive layer 328, which is connected to the transistor 500x and the like provided above the insulating layer 322, is embedded in the insulating layer 320 and the insulating layer 322. Note that the conductive layer 328 has a function of a plug or a wiring. Therefore, for the conductive layer 328, a material that can be used for the conductive layer MPG described above can be used.

In the display apparatus DSP2A, the wiring region LIN is provided over the transistor 300d. The wiring region LIN includes, for example, the insulating layer 324, an insulating layer 326, the conductive layer 330, an insulating layer 350, an insulating layer 352, an insulating layer 354, and the conductive layer 356.

Over the insulating layer 322 and the conductive layer 328, the insulating layer 324 and the insulating layer 326 are sequentially stacked. An opening is formed in the insulating layer 324 and the insulating layer 326 in a region overlapping with the conductive layer 328. In addition, the conductive layer 330 is embedded in the opening.

The insulating layer 350, the insulating layer 352, and the insulating layer 354 are stacked in this order over the insulating layer 326 and the conductive layer 330. An opening is formed in the insulating layer 350, the insulating layer 352, and the insulating layer 354 in a region overlapping with the conductive layer 330. The conductive layer 356 is embedded in the opening.

The conductive layer 330 and the conductive layer 356 have a function of a plug or a wiring that is connected to the transistor 300d. Note that the conductive layer 330 and the conductive layer 356 can be provided using a material similar to that for the conductive layer 328 or the conductive layer 596.

Note that like the insulating layer 592, for example, each of the insulating layer 324 and the insulating layer 350 is preferably formed using an insulator having a barrier property against one or more selected from hydrogen, oxygen, and water. Like the insulating layer 594, each of the insulating layer 326, the insulating layer 352, and the insulating layer 354 is preferably formed using an insulator having a relatively low dielectric constant to reduce parasitic capacitance generated between wirings. Each of the insulating layer 326, the insulating layer 352, and the insulating layer 354 has functions of an interlayer insulating film and a planarization film. Furthermore, each of the insulating layer 326, the insulating layer 352, and the insulating layer 354 preferably includes an insulating layer having a barrier property against one or more selected from hydrogen, oxygen, and water.

An insulating layer 512 and an insulating layer 514 are stacked in this order above the insulating layer 354 and the conductive layer 356. The transistor 500x is provided over the insulating layer 514.

The transistor 500x is a transistor including the insulating layer 512 and the insulating layer 514 as a base film and an island-shaped semiconductor layer formed over the base film as an active layer. A gate of the transistor 500x is provided to surround the top surface and the side surface of a part of the island-shaped semiconductor layer. Note that in FIG. 60, a conductive layer functioning as the gate is provided on the top surface of the part of the island-shaped semiconductor layer. A conductive layer functioning as one of a source and a drain and a conductive layer functioning as the other of the source and the drain are provided on the top surface of another part of the island-shaped semiconductor layer. Note that the conductive layer functioning as one of the source and the drain and the conductive layer functioning as the other of the source and the drain are provided to sandwich the gate.

The transistor 500x illustrated in FIG. 60 has a structure in which an island-shaped semiconductor layer and an interlayer film covering the semiconductor layer are provided and the interlayer film includes an opening in which the conductive layer having a function of the gate is to be embedded. When the conductive layer is formed after the formation of the opening, the conductive layer is formed in the opening in a self-aligned manner. In this specification and the like, the transistor 500x whose gate is formed in the opening in a self-aligned manner is referred to as a transistor having a TGSA structure in some cases.

In particular, in the transistor having the TGSA structure, a conductive layer functioning as a gate is formed after an insulating layer functioning as a gate insulating film is formed in the opening. That is, the insulating layer is positioned between the semiconductor layer and the conductive layer. The insulating layer having a function of a gate insulating film greatly contributes to the electrical characteristics of the transistor 500x. For example, in the case where the insulating layer is thick (the transistor MN includes a thick gate insulating film), the transistor 500x can have a gentle gradient of voltage between the gate and a channel formation region in the semiconductor layer, so that the transistor 500x can have high resistance to a gate potential (sometimes referred to as a gate-source voltage or a gate-drain voltage). Meanwhile, in the case where the transistor includes a thin gate insulating film, the electric field applied from the gate to the channel formation region in a semiconductor rapidly changes when a gate potential is changed, so that the transistor can have a high driving frequency.

Note that in the display apparatus DSP2A in FIG. 60, the transistor 500x included in the display region DIS can be the transistor MNx or the transistor MNy illustrated in FIG. 53. In particular, the channel length of each of the transistor MNx and the transistor MNy is shorter than the channel length of the transistor 500x, so that the area of the pixel circuit included in the display region DIS can be reduced. In the case where the on-state current of the transistor 500x included in the display region DIS is to be increased in the display apparatus DSP2A in FIG. 60, the transistor 500x is preferably changed to the transistor MN.

Above the transistor 500x, the insulating layer 574, the insulating layer 581, the insulating layer 592, the insulating layer 594, the insulating layer 598, and the insulating layer 599 are formed in this order. The conductive layer MPG is embedded in the insulating layer 574 and the insulating layer 581, and the conductive layer 596 is embedded in the insulating layer 592 and the insulating layer 594.

For the insulating layer 574, the insulating layer 581, the insulating layer 592, the insulating layer 594, the insulating layer 598, the insulating layer 599, the conductive layer MPG, and the conductive layer 596, the description of the display apparatus DSP1A in FIG. 53 can be referred to.

### <Cross-Sectional Structure Example 3 of Display Apparatus>

Next, a cross-sectional structure example of the display apparatus DSP3 illustrated in FIG. 51C is described.

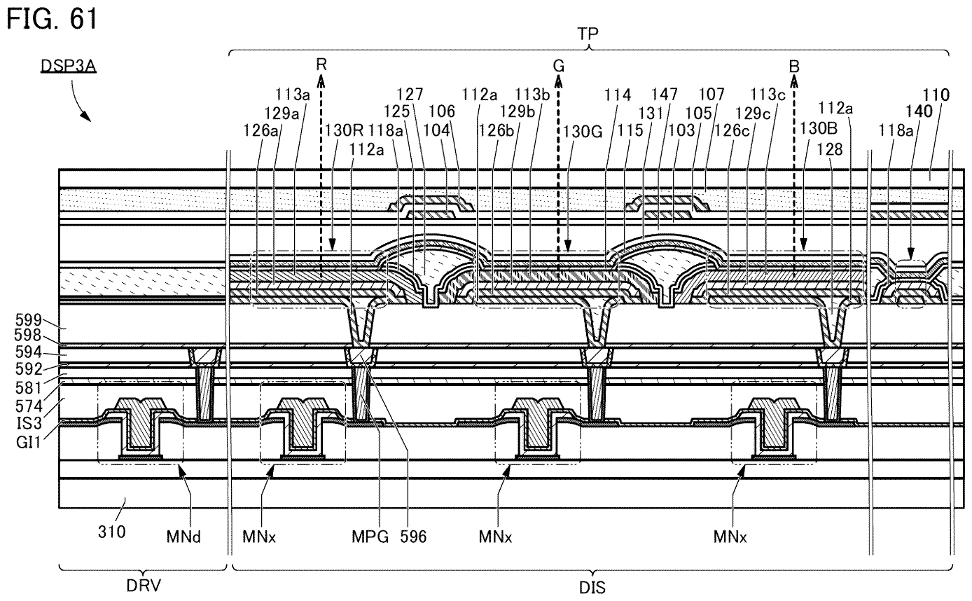

A display apparatus DSP3A illustrated in FIG. 61 is a cross-sectional structure example of the display apparatus DSP3 illustrated in FIG. 51C. The display apparatus DSP3A has a structure in which a touch sensor function is provided in the display apparatus DSP1A illustrated in FIG. 53. Thus, in the display apparatus DSP3A in FIG. 61, the sensor region TP illustrated in FIG. 51C is illustrated.

In the display apparatus DSP3A illustrated in FIG. 61, a resin layer 147, an insulating layer 103, a conductive layer 104, an insulating layer 105, and a conductive layer 106 are formed in this order over the protective layer 131, for example.

The resin layer 147 preferably contains an organic insulating material. Examples of the organic insulating material include an acrylic resin, a polyimide resin, an epoxy resin, a polyamide resin, a polyimide-amide resin, a siloxane resin, a benzocyclobutene-based resin, a phenol resin, and a precursor of any of these resins.

The insulating layer 103 preferably contains an inorganic insulating material. Examples of the inorganic insulating material include oxide and nitride such as silicon oxide, silicon oxynitride, silicon nitride oxide, silicon nitride, aluminum oxide, aluminum oxynitride, and hafnium oxide.

The conductive layer 104 and the conductive layer 106 function as electrodes of a touch sensor. In the case of using a mutual capacitive touch sensor, the touch sensor can have a structure in which a pulse potential is be supplied to one of the conductive layer 104 and the conductive layer 106, and an analog-digital (A-D) converter circuit or a sensing circuit such as a sense amplifier is connected to the other of the conductive layer 104 and the conductive layer 106, for example. In that case, capacitance is formed between the conductive layer 104 and the conductive layer 106. When a finger or the like approaches the conductive layer 104 and the conductive layer 106, the capacitance changes (specifically, the capacitance is reduced). This change in the capacitance appears, when a pulse potential is supplied to one of the conductive layer 104 and the conductive layer 106, as a change in the amplitude of a signal that occurs in the other of the conductive layer 104 and the conductive layer 106. Accordingly, the touch and approach of the finger or the like can be sensed.

In the display apparatus DSP3A, a self-capacitive touch sensor can be used. In this case, the electrode of the touch sensor in the sensor region TP of the display apparatus DSP3A can be at least one of the conductive layer 104 and the conductive layer 106.

For the insulating layer 105, an inorganic insulating film or an organic insulating film can be used, for example. Specifically, for the insulating layer 105, a resin such as an acrylic resin or an epoxy resin can be used, for example. Alternatively, for the insulating layer 105, an inorganic insulating material such as silicon oxide, silicon oxynitride, silicon nitride oxide, silicon nitride, or aluminum oxide can be used, for example. Note that the insulating layer 105 may have either a single-layer structure or a stacked-layer structure.

Note that although FIG. 61 illustrates the structure in which the electrode of the touch sensor is provided above the light-emitting device 130, the touch sensor may be provided in the same layer as the light-emitting device 130 (not illustrated). For example, when formed concurrently with the light-emitting device 130, the touch sensor can be provided in the same layer as the light-emitting device 130.

When the retention circuit, which is the semiconductor device of one embodiment of the present invention, is provided in the driver circuit and applied to any of the display apparatuses described above, the display apparatus having high screen definition and high resolution can be achieved in some cases. Specifically, for example, a display apparatus with a screen definition of HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320) can be achieved in some cases. Furthermore, specifically, for example, a display apparatus with a resolution of higher than or equal to 100 ppi, higher than or equal to 300 ppi, higher than or equal to 500 ppi, higher than or equal to 1000 ppi, higher than or equal to 2000 ppi, higher than or equal to 3000 ppi, higher than or equal to 5000 ppi, or higher than or equal to 6000 ppi can be achieved in some cases.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 6

In this embodiment, a display module that can be used for the electronic device of one embodiment of the present invention will be described.

### <Structure Example of Display Module>

First, a display module including a display apparatus that can be used for the electronic device of one embodiment of the present invention will be described.

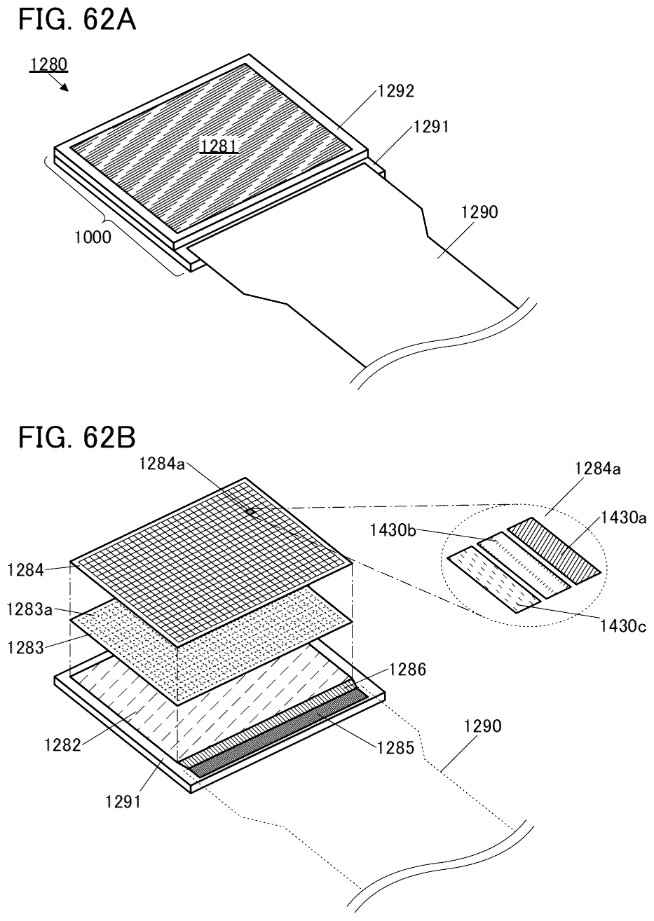

FIG. 62A is a perspective view of a display module 1280. The display module 1280 includes a display apparatus 1000 and an FPC 1290.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 62B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are connected to each other through a wiring portion 1286 formed of a plurality of wirings.

Note that the pixel portion 1284 and the pixel circuit portion 1283 correspond to the display region DIS described above, for example. The circuit portion 1282 corresponds to the circuit region SIC described above, for example.

The pixel portion 1284 includes a plurality of pixels 1284a arranged periodically. An enlarged view of one pixel 1284a is illustrated on the right side in FIG. 62B. The pixel 1284a includes a light-emitting device 1430a, a light-emitting device 1430b, and a light-emitting device 1430c that emit light of different colors. Note that the light-emitting device 1430a, the light-emitting device 1430b, and the light-emitting device 1430c correspond to the light-emitting device 130R, the light-emitting device 130G, and the light-emitting device 130B described above, for example. The above-described plurality of light-emitting devices may be arranged in a stripe pattern as illustrated in FIG. 62B. Alternatively, a variety of arrangement methods, such as S-stripe arrangement, matrix arrangement, delta arrangement, Bayer arrangement, and PenTile arrangement, can be employed.

The pixel circuit portion 1283 includes a plurality of pixel circuits 1283a arranged periodically.

One pixel circuit 1283a is a circuit that controls light emission from three light-emitting devices included in one pixel 1284a. One pixel circuit 1283a may be provided with three circuits each controlling light emission from one light-emitting device. For example, the pixel circuit 1283a can include at least one selection transistor, one current control transistor (driving transistor), and capacitance for one light-emitting device. In that case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, one or both of agate line driver circuit and a source line driver circuit are preferably included. In addition, one or more selected from an arithmetic circuit, a memory circuit, and a power supply circuit may be included.

The FPC 1290 functions as a wiring for supplying a video signal or a power supply potential to the circuit portion 1282 from the outside. In addition, an IC may be mounted on the FPC 1290.

The display module 1280 can have a structure in which one or both of the pixel circuit portion 1283 and the circuit portion 1282 are stacked below the pixel portion 1284; thus, the aperture ratio (the effective display area ratio) of the display portion 1281 can be significantly high. For example, the aperture ratio of the display portion 1281 can be higher than or equal to 40% and lower than 100%, preferably higher than or equal to 50% and lower than or equal to 95%, further preferably higher than or equal to 60% and lower than or equal to 95%. Furthermore, the pixels 1284a can be arranged extremely densely and thus the display portion 1281 can have an extremely high resolution. For example, the pixels 1284a are preferably arranged in the display portion 1281 with a resolution higher than or equal to 100 ppi, preferably higher than or equal to 300 ppi, further preferably higher than or equal to 500 ppi, still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 6000 ppi, and lower than or equal to 20000 ppi or lower than or equal to 30000 ppi.

Such a display module 1280 has an extremely high resolution and thus can be suitably used for a VR device such as ahead-mounted display or a glasses-type AR device. For example, even with a structure in which the display portion of the display module 1280 is seen through a lens, pixels of the extremely-high-resolution display portion 1281 included in the display module 1280 are prevented from being seen when the display portion is enlarged by the lens, so that display providing a strong sense of immersion can be performed. Without being limited thereto, the display module 1280 can be suitably used for electronic devices including relatively small display portions. For example, the display module 1280 can be suitably used for a display portion of a wearable electronic device such as a wristwatch.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 7

In this embodiment, electronic devices each including a display apparatus fabricated using one embodiment of the present invention will be described. Note that electronic devices described in this embodiment as examples are each provided with a display apparatus of one embodiment of the present invention in a display portion. Thus, the electronic devices achieve high resolution.

One embodiment of the present invention includes the display apparatus and one or more selected from an antenna, a battery, a housing, a camera, a speaker, a microphone, a touch panel, and an operation button.

The electronic device of one embodiment of the present invention may include a secondary battery, and it is preferable that the secondary battery be capable of being charged by contactless power transmission.

Examples of the secondary battery include a lithium ion secondary battery (such as a lithium polymer battery using a gel electrolyte (a lithium ion polymer battery)), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, or the like on a display portion. When the electronic device includes an antenna and a secondary battery, the antenna can be used for contactless power transmission.

The display portion of the electronic device of one embodiment of the present invention can display, for example, an image with full high definition, 4K2K, 8K4K, 16K8K, or higher screen definition.

Examples of the electronic device include electronic devices having a relatively large screen, such as a television device, a laptop personal computer, a monitor device, digital signage, a pachinko machine, and a game machine. Other examples of the electronic device include a digital camera, a digital video camera, a digital photo frame, a mobile phone device, a portable game machine, a portable information terminal, and an audio reproducing device.

An electronic device to which one embodiment of the present invention is applied can be incorporated along a flat surface or a curved surface of an inner wall or an outer wall of a house or a building. The electronic device can be incorporated along a flat surface or a curved surface of an interior, an exterior, or the like of an automobile or the like.

### [Mobile Phone]

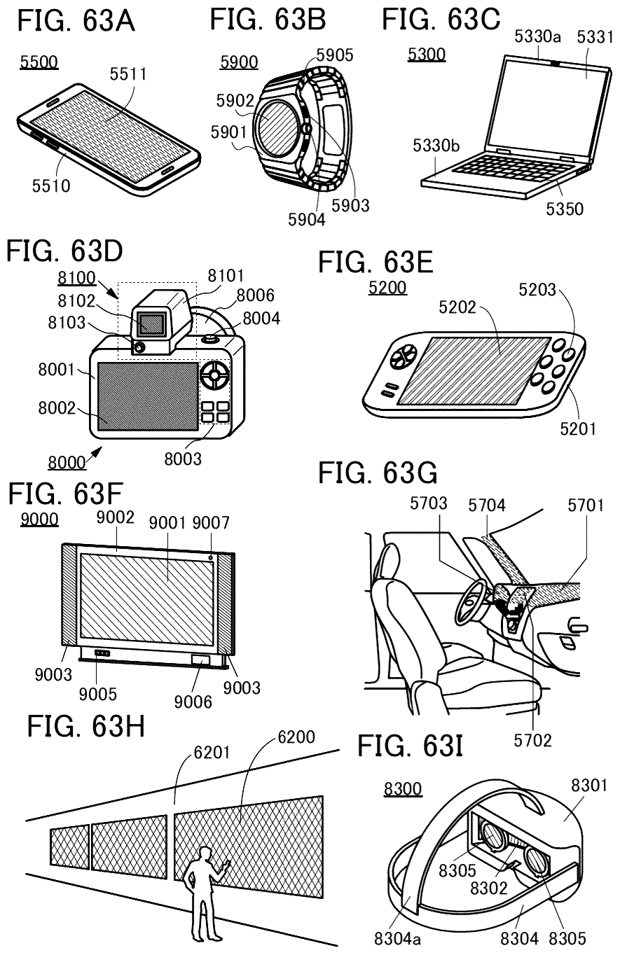

An information terminal 5500 illustrated in FIG. 63A is a mobile phone (smartphone), which is a type of information terminal. The information terminal 5500 includes a housing 5510 and a display portion 5511, and as input interfaces, a touch panel and a button are provided in the display portion 5511 and the housing 5510, respectively.

### [Wearable Terminal]

FIG. 63B is an external view of an information terminal 5900, which is an example of a wearable terminal. The information terminal 5900 includes a housing 5901, a display portion 5902, an operation button 5903, a crown 5904, and a band 5905.

### [Information Terminal]

FIG. 63C illustrates a laptop information terminal 5300. The laptop information terminal 5300 illustrated in FIG. 63C includes, for example, a display portion 5331 in a housing 5330a and a keyboard portion 5350 in a housing 5330b.

Note that although FIG. 63A to FIG. 63C illustrate a smartphone, a wearable terminal, and a laptop information terminal as examples of the electronic device in the above description, one embodiment of the present invention can also be applied to an information terminal other than a smartphone, a wearable terminal, and a laptop information terminal. Examples of the information terminals other than a smartphone, a wearable terminal, and a laptop information terminal include a PDA (Personal Digital Assistant), a desktop information terminal, and a workstation.

### [Camera]

FIG. 63D is an external view of a camera 8000 to which a finder 8100 is attached. The camera 8000 includes a housing 8001, a display portion 8002, operation buttons 8003, and a shutter button 8004. Furthermore, a detachable lens 8006 is attached to the camera 8000. The finder 8100 includes a housing 8101, a display portion 8102, and a button 8103.

Note that the camera 8000 can have a structure in which the lens 8006 and the housing are integrated with each other.

Images can be taken with the camera 8000 at the press of the shutter button 8004 or the touch of the display portion 8002 serving as a touch panel.

The housing 8001 includes a mount including an electrode, so that a stroboscope, for example, as well as the finder 8100 can be connected to the housing 8001.

The housing 8101 is attached to the camera 8000 by a mount for engagement with the mount of the camera 8000. The finder 8100 can display an image received from the camera 8000 on the display portion 8102.

The button 8103 functions as a power supply button.

The display apparatus of one embodiment of the present invention can be used in the display portion 8002 of the camera 8000 and the display portion 8102 of the finder 8100. Note that a finder can be incorporated in the camera 8000.

### [Game Machine]

FIG. 63E is an external view of a portable game machine 5200, which is an example of a game machine. The portable game machine 5200 includes a housing 5201, a display portion 5202, and a button 5203.

An image displayed on the portable game machine 5200 can be output with a display apparatus included in a television device, a personal computer display, a game display, or a head-mounted display.

When the portable game machine 5200 includes the display apparatus described in the above embodiment, the portable game machine 5200 with low power consumption can be achieved. Furthermore, heat generation from a circuit can be reduced owing to low power consumption; thus, the influence of heat generation on the circuit itself, the peripheral circuit, and the module can be reduced.

Although FIG. 63E illustrates the portable game machine as an example of a game machine, the electronic device of one embodiment of the present invention is not limited thereto. Examples of the electronic device of one embodiment of the present invention include a stationary game machine, an arcade game machine installed in entertainment facilities (e.g., a game center and an amusement park), and a throwing machine for batting practice installed in sports facilities.

### [Television Device]

FIG. 63F is a perspective view illustrating a television device. A television device 9000 includes a housing 9002, a display portion 9001, a speaker 9003, an operation key 9005 (including a power switch or an operation switch), a connection terminal 9006, a sensor 9007 (for example, a sensor having a function of measuring force, displacement, position, speed, acceleration, angular velocity, rotational frequency, distance, light (including infrared rays), liquid, magnetism, temperature, chemical substance, sound, time, hardness, electric field, current, voltage, power, radiation, flow rate, humidity, gradient, oscillation, or odor, and for another example, a sensor having a function of sensing or detecting odor or light (including infrared rays)). A memory device of one embodiment of the present invention can be provided in the television device. The television device can include the display portion 9001 having a screen size of, for example, 50 inches or more, or 100 inches or more.

When the television device 9000 includes the display apparatus described in the above embodiment, the television device 9000 with low power consumption can be achieved. Furthermore, heat generation from a circuit can be reduced owing to low power consumption; thus, the influence of heat generation on the circuit itself, the peripheral circuit, and the module can be reduced.

### [Moving Vehicle]

The display apparatus of one embodiment of the present invention can also be used around a driver's seat in a car, which is a moving vehicle.

FIG. 63G is a diagram illustrating a windshield and its vicinity inside a car. FIG. 63G illustrates a display panel 5701, a display panel 5702, and a display panel 5703 which are attached to a dashboard, and a display panel 5704 attached to a pillar.

The display panel 5701 to the display panel 5703 can display various kinds of information such as navigation information, a speedometer, a tachometer, a mileage, a fuel meter, a gearshift indicator, and air-condition settings. Items displayed on the display panel and their layout can be changed as appropriate to suit the user's preferences, resulting in more sophisticated design. The display panel 5701 to the display panel 5703 can also be used as lighting devices.

The display panel 5704 can compensate for the view obstructed by the pillar (blind areas) by showing an image taken by an imaging unit provided for the car body. That is, displaying an image taken by the imaging unit provided on the outside of the car leads to elimination of blind areas and enhancement of safety. Moreover, showing an image to compensate for the area that cannot be seen makes it possible for a driver to confirm safety more easily and comfortably. The display panel 5704 can also be used as a lighting device.

The display apparatus of one embodiment of the present invention can be used for each of the display panel 5701 to the display panel 5704, for example.

Although a car is described above as an example of a moving vehicle, moving vehicles are not limited to a car. Examples of the moving vehicles include a train, a monorail train, a ship, and a flying object (for example, a helicopter, an unmanned aircraft (a drone), an airplane, and a rocket), and these moving vehicles can use the display apparatus of one embodiment of the present invention.

### [Digital Signage]

FIG. 63H shows an example of a digital signage that can be attached to a wall. FIG. 63H illustrates a state where a digital signage 6200 is attached to a wall 6201. The display apparatus of one embodiment of the present invention can be used in a display portion in the digital signage 6200, for example. An interface such as a touch panel can be provided in the digital signage 6200.

Note that although an electronic device attachable to a wall is described above as an example of a digital signage, the kind of the digital signage is not limited thereto. Examples of the digital signage include a digital signage mounted on a pillar, a freestanding digital signage placed on the ground, and a digital signage mounted on a rooftop or a sidewall of a building.

### [Head-Mounted Display]

FIG. 63I is an external view of an electronic device 8300 which is a head-mounted display for VR. The electronic device 8300 includes a housing 8301, a display portion 8302, a band-like fixing member 8304, a fixture member 8304a worn on a head, and a pair of lenses 8305.

Although not illustrated in FIG. 631, the electronic device 8300 may include an interface such as an operation button or a power button.

A user can see display on the display portion 8302 through the lenses 8305. Note that the display portion 8302 is preferably placed in a curved state, in which case the user can feel high realistic sensation. Another image displayed in another region of the display portion 8302 is seen through the lenses 8305, so that three-dimensional display using parallax can be performed. Note that the number of the display portions 8302 is not limited to one; two display portions 8302 may be provided for user's respective eyes.

Note that a display apparatus with extremely high resolution is preferably used for the display portion 8302, for example. With use of a display apparatus with high resolution for the display portion 8302, even when the display portion 8302 is enlarged by the lens 8305, the user does not see pixels and thus a more realistic image can be displayed.

The head-mounted display, which is an electronic device of one embodiment of the present invention, may have a structure of an electronic device which is a glasses-type head-mounted display, instead of the electronic device 8300 in FIG. 631 which is a goggles-type head-mounted display. In particular, a glasses-type head-mounted display is suitable for an electronic device for AR.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 8

In this embodiment, a structure example in which the semiconductor device described in the above embodiment is used for a memory device and an electronic device including the memory device will be described.

### <Structure Example of Memory Device>

For example, the shift register provided in each of the driver circuit SD, the driver circuit GD, the driver circuit TDR, and the driver circuit TDE described in Embodiment 4 can be provided in a row decoder, a row driver, a column decoder, a column driver, or the like provided in a memory device. The transistor or the like described in any of the above embodiments can be used as a transistor provided in a memory device 200.

In particular, the shift register described in Embodiment 4 can be driven at low speed. Therefore, in the case where the shift register is used in a memory device, a writing operation and a reading operation of the memory device can be performed at low speed. In particular, the writing operation and the reading operation of a memory device consume less power in driving at lower speed than in driving at higher speed; thus, in the case where the amount of data to be written or read is small, low-speed driving is preferably performed.

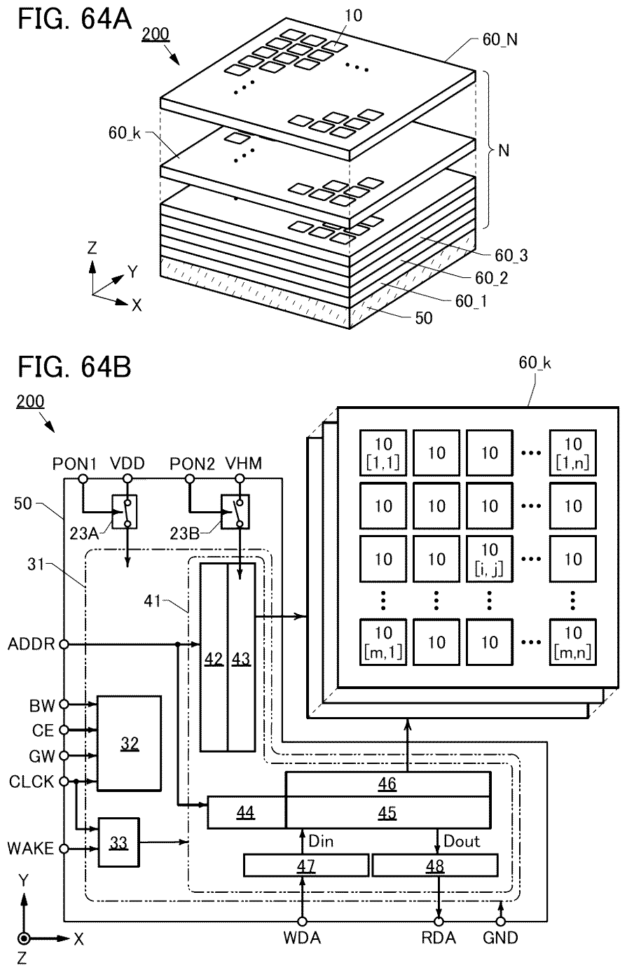

FIG. 64A is a schematic perspective view illustrating a structure example of the memory device 200. FIG. 64B is a block diagram illustrating the structure example of the memory device 200. The memory device 200 includes a driver circuit layer 50 and N (N is an integer greater than or equal to 1) memory layers 60. One memory layer 60 includes a plurality of memory cells 10 arranged in a matrix of m rows and n columns. Note that FIG. 64B shows an example in which a memory cell 10[1, 1], a memory cell 10[m, 1](here, m is an integer greater than or equal to 1), a memory cell 10[1, n] (here, n is an integer greater than or equal to 1), a memory cell 10[m, n], and a memory cell 10[i,j](here, i is an integer greater than or equal to 1 and less than or equal to m, and j is an integer greater than or equal to 1 and less than or equal to n) are provided in a memory layer 60_k.

The N memory layers 60 are provided over the driver circuit layer 50. Provision of the N memory layers 60 over the driver circuit layer 50 can reduce the area occupied by the memory device 200. Furthermore, the memory capacity per unit area can be increased.

In this embodiment, the first memory layer 60 is denoted by a memory layer 60_1, the second memory layer 60 is denoted by a memory layer 60_2, and the third memory layer 60 is denoted by a memory layer 603. Furthermore, the k-th memory layer 60 (k is an integer greater than or equal to 1 and less than or equal to N) is denoted by the memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

### <<Structure Example of Driver Circuit Layer 50>>

The driver circuit layer 50 includes a PSW 23A (power switch), a PSW 23B, and a peripheral circuit 31. The peripheral circuit 31 includes a peripheral circuit 41, a control circuit 32 (Control Circuit), and a voltage generation circuit 33.

In the memory device 200, each circuit, each signal, and each voltage can be appropriately selected as needed. Alternatively, another circuit or another signal may be added. A signal BW, a signal CE, a signal GW, a signal CLCK, a signal WAKE, a signal ADDR, a signal WDA, a signal PON1, and a signal PON2 are signals input from the outside, and a signal RDA is a signal output to the outside. The signal CLCK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 200. For example, the control circuit performs a logical operation on the signal CE, the signal GW, and the signal BW to determine an operation mode (e.g., a writing operation or a reading operation) of the memory device 200. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLCK to the voltage generation circuit 33. For example, when an H-level signal is supplied as the signal WAKE, the signal CLCK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42 (Row Decoder), a column decoder 44 (Column Decoder), a row driver 43 (Row Driver), a column driver 45 (Column Driver), an input circuit 47 (Input Cir.), an output circuit 48 (Output Cir.), and a sense amplifier 46 (Sense Amplifier).

The row decoder 42 and the column decoder 44 have a function of decoding the signal ADDR. The row decoder 42 is a circuit for addressing a row to be accessed, and the column decoder 44 is a circuit for addressing a column to be accessed.

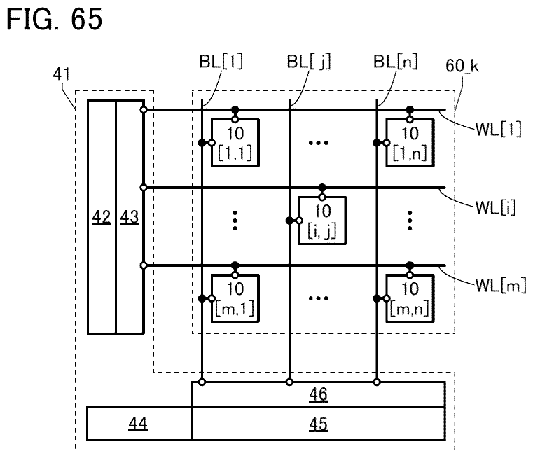

The row driver 43 has a function of selecting any one of word lines for writing and word lines for reading (e.g., any one of a wiring WL[1] to a wiring WL[m] illustrated in FIG. 65 described later) specified by the row decoder 42.

The column driver 45 has a function of writing data to the memory cells 10, a function of reading data from the memory cells 10, and a function of retaining the read data. The column driver 45 has a function of selecting any one of bit lines for writing and bit lines for reading (e.g., any one of a wiring BL[1] to a wiring BL[n] illustrated in FIG. 65 described later) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 200. Data output from the output circuit 48 is the signal RDA.

The PSW 23A has a function of controlling supply of VDD to the peripheral circuit 31. The PSW 23B has a function of controlling supply of VHM to the row driver 43. Here, in the memory device 200, a high power supply voltage is VDD and a low power supply voltage is GND (a ground potential). In addition, VHM is high power supply voltage used to set the word line at a high level and is higher than VDD. The on state and the off state of the PSW 23A are switched by the signal PON1, and the on state and the off state of the PSW 23B is switched by the signal PON2. The number of power domains to which VDD is supplied is one in the peripheral circuit 31 in FIG. 64B but can be more than one. In that case, a power switch is preferably provided for each power domain.

Next, electrical connection between the peripheral circuit 41 and the memory layer 60 is described.

FIG. 65 is a block diagram illustrating a structure example of the peripheral circuit 41 and the memory layer 60_k. In FIG. 65, the row decoder 42 and the row driver 43 are electrically connected to each of the wiring WL[1] to the wiring WL[m], and the column decoder 44, the column driver 45, and the sense amplifier 46 are electrically connected to each of the wiring BL[I] to the wiring BL[n].

Note that the wiring WL[1] to the wiring WL[m] function as word lines. The wiring WL[1] to the wiring WL[m] may each be a wiring group in which a plurality of wirings are combined.

The wiring BL[1] to the wiring BL[n] function as bit lines. Note that the wiring BL[1] to the wiring BL[n] may each be a wiring group in which a plurality of wirings are combined.

The memory cell 10[i, j] placed at the i-th row and the j-th column is electrically connected to a wiring WL[i] and a wiring BL[j].

As illustrated in FIG. 65, the memory layer 60_k is electrically connected to the peripheral circuit 41, whereby data writing to the memory layer 60_k and data reading from the memory layer 60_k can be performed.

### <Examples of Electronic Products>

Electronic components, electronic devices, a large computer, space equipment, and a data center (also referred to as DC) in which the memory device described above can be used will be described. Electronic components, electronic devices, a large computer, space equipment, and a data center in which the memory device is used are effective in improving performance, e.g., reducing power consumption. Note that electronic components, electronic devices, a large computer, space equipment, and a data center are collectively referred to as electronic products in some cases.

### [Electronic Component]

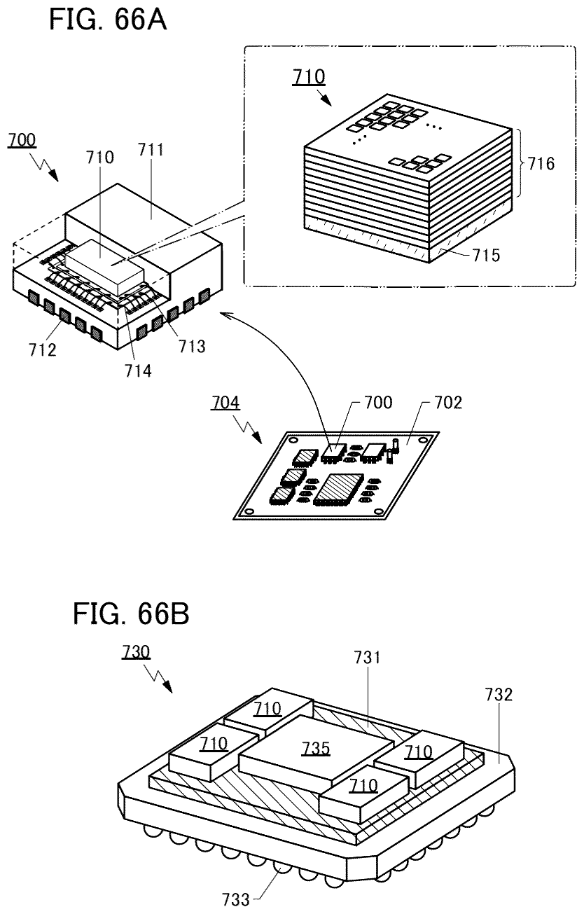

FIG. 66A is a perspective view of a substrate (a mounting board 704) on which an electronic component 700 is mounted. The electronic component 700 illustrated in FIG. 66A includes a semiconductor device 710 in a mold 711. Some components are omitted in FIG. 66A to show the inside of the electronic component 700. The electronic component 700 includes a land 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected on the printed circuit board 702, so that the mounting board 704 is completed.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu—Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those of the case where the through electrode technique such as TSV is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that the bandwidth refers to the data transfer amount per unit time, and the access latency refers to time between data access and start of data transmission. Note that in the case where Si transistors are used for the memory layer 716, the monolithic stacked-layer structure is difficult to form as compared with the case where OS transistors are used for the memory layer 716. Therefore, the OS transistors are superior to the Si transistors in the monolithic stacked-layer structure.

The semiconductor device 710 is referred to as a die in some cases. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 66B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is referred to as a “redistribution substrate” or an “intermediate substrate” in some cases. A through electrode may be provided in the interposer 731 to be used for electrically connecting the integrated circuit and the package substrate 732. In a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity, and poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, TSV, and the like, a space for the width of the terminal pitches and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the above-described monolithic stacked-layer structure using OS transistors is suitable. A composite structure where memory cell arrays stacked using a TSV and monolithically stacked memory cell arrays are combined may be employed.

The electronic component 730 can be provided to overlap with a heat sink (a radiator plate). In the case where a heat sink is provided, integrated circuits provided on the interposer 731 preferably have the same height. For example, in the electronic component 730 described in this embodiment, the semiconductor devices 710 and the semiconductor device 735 preferably have the same height.

Electrodes 733 may be provided on a bottom part of the package substrate 732 to mount the electronic component 730 on another substrate. FIG. 66B illustrates an example in which the electrodes 733 are formed of solder balls. When the solder balls are provided in a matrix on the bottom part of the package substrate 732, BGA (Ball Grid Array) mounting can be achieved. Alternatively, the electrodes 733 may be formed of conductive pins. When the conductive pins are provided in a matrix on the bottom part of the package substrate 732, PGA (Pin Grid Array) mounting can be achieved.

The electronic component 730 can be mounted on another substrate by a variety of mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

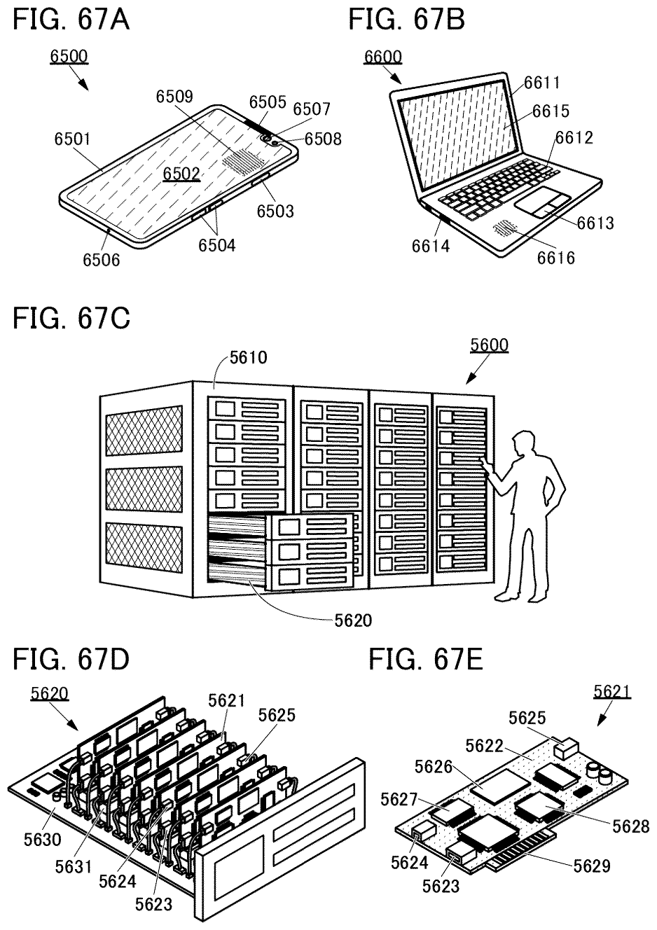

Next, FIG. 67A is a perspective view of an electronic device 6500. An electronic device 6500 illustrated in FIG. 67A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be applied to the display portion 6502, the control device 6509, or the like. Since the semiconductor device is capable of being driven at low speed, the power consumption of the electronic device 6500 can be reduced when the semiconductor device is used for the display portion 6502, the control device 6509, and the like.

An electronic device 6600 illustrated in FIG. 67B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be applied to the display portion 6615, the control device 6616, or the like. Note that when the semiconductor device of one embodiment of the present invention is used for the control device 6509 and the control device 6616 described above, lower power consumption can be achieved.

### [Large Computer]

Next, FIG. 67C is a perspective view of a large computer 5600. In the large computer 5600 illustrated in FIG. 67C, a plurality of rack mount computers 5620 are stored in a rack 5610. Note that the large computer 5600 is referred to as a supercomputer in some cases.

The computer 5620 can have a structure in the perspective view illustrated in FIG. 67D, for example. In FIG. 67D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 67E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 67E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

When the semiconductor device of one embodiment of the present invention is used for a memory device, power consumption of the large computer 5600 can be reduced.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space.

For example, when an OS transistor is used in the semiconductor device of one embodiment of the present invention, a retention circuit highly resistant to radiation can be formed. That is, when the semiconductor device of one embodiment of the present invention is used for space equipment, the resistance of the space equipment to radiation can be increased.

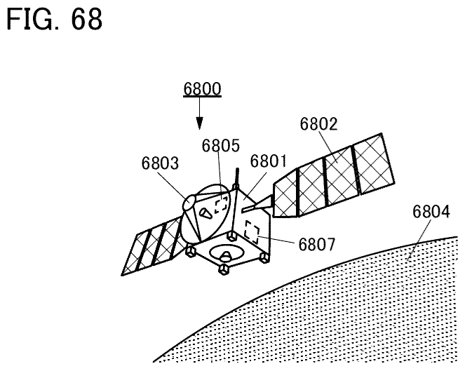

FIG. 68 illustrates an artificial satellite 6800 as an example of space equipment. The artificial satellite 6800 includes a body 6801, solar panels 6802, an antenna 6803, a secondary battery 6805, and a control device 6807. In FIG. 68, a planet 6804 in outer space is illustrated as an example. Note that outer space refers to, for example, space at an altitude of 100 km or higher, and outer space in this specification includes thermosphere, mesosphere, and stratosphere.

Although not illustrated in FIG. 68, a battery management system (also referred to as BMS) or a battery control circuit can be provided in the secondary battery 6805. An OS transistor is suitably used in the battery management system or the battery control circuit because low power consumption and high reliability even in outer space are achieved.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. One or more selected from a CPU, a GPU, and a memory device are used as the control device 6807, for example. Note that the semiconductor device of one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Note that although the artificial satellite is shown as an example of space equipment in this embodiment, the present invention is not limited thereto. The semiconductor device of one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device of one embodiment of the present invention can be suitably used for, for example, a storage system employed in a data center or the like. Long-term data management, such as a guarantee for data immutability, is required for the data center. The long-term management of data needs an increase in building size owing to installation of storages and servers for storing an enormous amount of data, stable power source for data retention, cooling equipment necessary for data retention, and the like.

With the use of the semiconductor device of one embodiment of the present invention for a storage system employed in a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. The use of the semiconductor device of one embodiment of the present invention can achieve a data center that stably operates even in a high-temperature environment. Thus, the reliability of the data center can be increased.

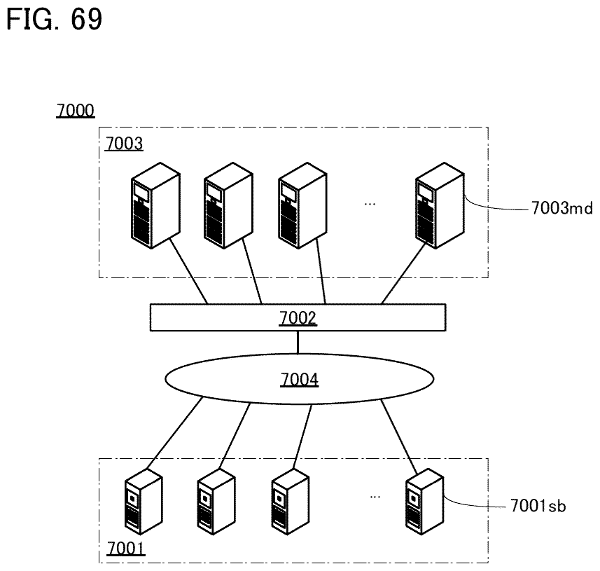

FIG. 69 illustrates a storage system that can be used in a data center. A storage system 7000 illustrated in FIG. 69 includes a plurality of servers 7001sb as a host 7001 (referred to as a host computer in some cases). The storage system 7000 includes a plurality of memory devices 7003md as a storage 7003. In the illustrated mode, the host 7001 and the storage 7003 are connected to each other through a storage area network (SAN) 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM (Dynamic Random Access Memory) that can be used as a cache memory in a storage. In the storage system, in order to solve the problem of low access speed of the storage 7003, a cache memory is normally provided in the storage to shorten data storage and output.

The cache memories are used in the storage control circuit 7002 and the storage 7003. The data transmitted between the host 7001 and the storage 7003 is stored in the cache memory in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device of one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

(Notes on Description of Circuits in this Specification and the Like)

Described below are remarks on “connection” and “circuit element” in the description of the circuits in this specification and the like.

### <Connection>

In this specification and the like, the expression “A and B are connected” includes the case where “A and B are directly connected”, the case where “A and B are indirectly connected”, the case where “A and B are electrically connected”, or the case where “A and B are functionally connected”.

The expression “A and B are directly connected” means that in a circuit diagram or a structure converted into a circuit diagram (hereinafter also referred to as “in a circuit diagram”), A and B are connected not through a circuit element (e.g., a transistor, a diode, and a resistor element). Thus, for example, the case where A and B are connected through one or more conductive layers is included in the expression “A and B are directly connected”.

The expression “A and B are indirectly connected” means that in a circuit diagram, A and B are connected through one or more circuit elements.

The expression “A and B are electrically connected” includes the case where A and B are directly connected or A and B are indirectly connected and electric charge transfer between A and B is possible (electrical continuity is established between A and B according to the expression in this specification).

The expression “A and B are indirectly connected and electrical continuity can be established between A and B” means that in a circuit diagram, A and B are connected through a circuit element and electric charge transfer between A and B is possible. For example, the case where A and B are connected through a source and a drain of one or more transistors (or a channel formation region of a transistor) is included in the expression “A and B are indirectly connected and electrical continuity can be established between A and B” because electric charge transfer between A and B is possible. Here, the interpretation of the expression “electrical continuity can be established between A and B through a circuit element” is not affected by the operation state of the circuit element (e.g., an on state or an off state of a transistor). For example, in the case where A and B are connected through a source and a drain of a transistor, the case where electric charge transfer from A to B is interrupted by bringing the transistor into an off state is also included in the expression “electrical continuity can be established between A and B”.

Meanwhile, examples of the case that is not included in the expression “A and B are indirectly connected and electrical continuity can be established between A and B” include the case where an insulator of a circuit element (e.g., a dielectric of a capacitor element and a gate insulating film of a transistor) is positioned between A and B in a circuit diagram. Another example is the case where a circuit element and a power supply line are positioned between A and B in a circuit diagram.

The expression “A and B are functionally connected” includes the case where A and B are directly connected and the case where A and B are indirectly connected and a signal corresponding to a signal supplied from A can be transmitted to B. Thus, the expression “A and B are functionally connected” includes the case where electric charge is transferred between A and B and the case where electric charge is not transferred between A and B.

The expression “A and B are functionally connected” means that, for example, in a circuit diagram, one or more circuits having any function (e.g., a logic circuit (an inverter circuit, a NAND circuit, or the like), a signal converter circuit (a DA converter circuit, a gamma correction circuit, or the like), a potential converter circuit (a step-up circuit, a level shifter circuit, or the like), an amplifier circuit (an operational amplifier, a source follower circuit, or the like), a filter circuit (a high-pass filter circuit, a low-pass filter circuit, or the like), a switching circuit, a signal generation circuit, a memory circuit, and a control circuit) are connected between A and B. Even when a plurality of circuits having different functions are interposed between A and B, A and B can be regarded as being functionally connected in the case where a signal corresponding to a signal supplied from A is regarded as being transmitted to B. The expression “A and B are functionally connected” can be used also in the case where A and B are connected through a filter circuit and signal transmission to B is interrupted in accordance with the frequency of a signal supplied from A.

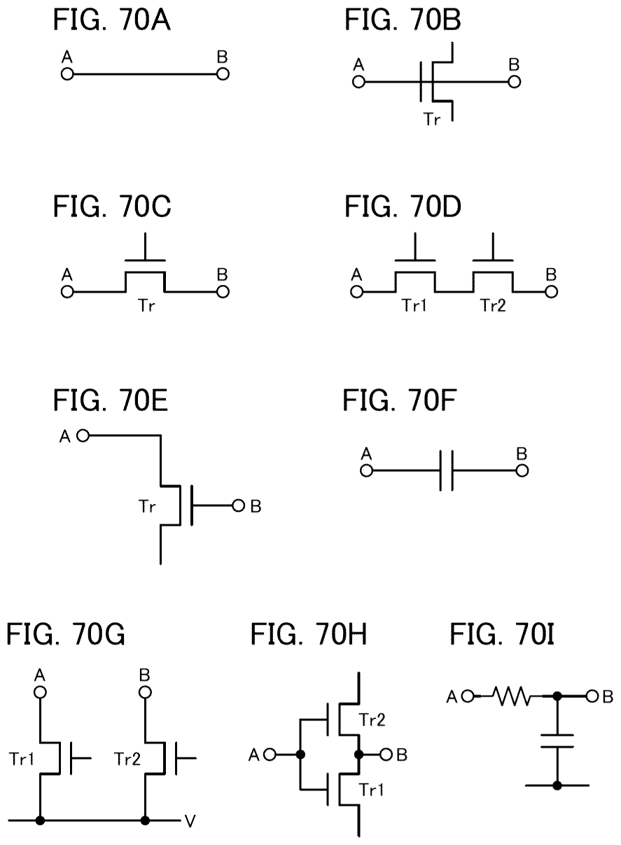

FIG. 70A to FIG. 70D each illustrate an example of a circuit diagram showing that “A and B are electrically connected”. Each of FIG. 70A and FIG. 70B illustrates an example in which A and B are directly connected. Even when part of a wiring that connects A and B includes a region functioning as a gate of the transistor as in FIG. 70B, A and B always have the same potential. Each of FIG. 70C and FIG. 70D illustrates an example in which A and B are indirectly connected and electrical continuity can be established between A and B. FIG. 70C illustrates an example in which A and B are connected through a source and a drain of a transistor Tr. FIG. 70D illustrates an example in which A and B are connected through a source and a drain of a transistor Tr1 and a source and a drain of a transistor Tr2.

FIG. 70E to FIG. 70G each illustrate a circuit diagram showing an example that is not included in the expression “A and B are electrically connected”. FIG. 70E illustrates an example in which A is connected to one of the source and the drain of the transistor Tr and B is connected to a gate of the transistor Tr. FIG. 70F illustrates an example in which A is connected to one terminal of a capacitor element and B is connected to the other terminal of the capacitor element. In the cases of FIG. 70E and FIG. 70F, electrical continuity cannot be established between A and B because an insulator of a circuit element is positioned between A and B. Thus, A and B cannot be regarded as being electrically connected in FIG. 70E and FIG. 70F.

FIG. 70G illustrates an example in which A is connected to a wiring through the transistor Tr1, B is connected to the wiring through the transistor Tr2, and a power supply potential V is supplied to the wiring. In the case of FIG. 70G, when the transistor Tr is brought into an on state, the power supply potential V is supplied to A. When the transistor Tr2 is brought into an on state, the power supply potential V is supplied to B. When both the transistor Tr and the transistor Tr2 are brought into an on state, the power supply potential V is supplied to both A and B. Thus, in the case of FIG. 70G, electric charge transfer between A and the wiring is possible, and electric charge transfer between B and the wiring is possible. However, the state where electric charge transfer between A and B is possible cannot be made because the power supply potential is supplied to the wiring. Thus, A and B cannot be regarded as being electrically connected in FIG. 70G.

FIG. 70H and FIG. 701 each illustrate an example of a circuit diagram showing that “A and B are functionally connected”. FIG. 70H illustrates an example in which A and B are connected through an inverter circuit. In FIG. 70H, A and B are respectively connected to an input and an output of the inverter circuit. In the circuit illustrated in FIG. 70H, an inverted signal of a signal supplied from A is supplied to B. In the circuit illustrated in FIG. 70H, electric charge transfer does not occur between A and B. FIG. 701 illustrates an example in which A and B are connected through a low-pass filter circuit. The circuit illustrated in FIG. 701 has a function of supplying a signal from A to B with almost no attenuation of components having lower frequency than the cutoff frequency, and has a function of attenuating components having higher frequency than the cutoff frequency. In the circuit illustrated in FIG. 701, not only signal transmission but also electric charge transfer can occur between A and B. Note that in the case of FIG. 70G, a signal corresponding to a signal supplied from A cannot be transmitted to B; thus, A and B cannot be regarded as being functionally connected.

### <Circuit Element>

In this specification and the like, a “resistor element” can be, for example, a circuit element having a resistance value higher than 0Ω or a wiring having a resistance value higher than 0Ω. Therefore, in this specification and the like, a “resistor element” includes a wiring having a resistance value, a transistor in which current flows between a source and a drain, a diode, or a coil. Thus, the term “resistor element” can sometimes be replaced with the term “resistor”, “load”, or “region having a resistance value”. Conversely, the term “resistor”, “load”, or “region having a resistance value” can sometimes be replaced with the term “resistor element”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor element” can be, for example, a circuit element having an electrostatic capacitance value higher than 0 F. A “capacitor” (including a “capacitor” with three or more terminals) has a structure including an insulator and a pair of conductors between which the insulator is sandwiched. Thus, the term “pair of conductors” of “capacitor element” can be replaced with “pair of electrodes”, “pair of conductive regions”, “pair of regions”, or “pair of terminals”. The terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 F.

Note that a circuit sometimes includes a region having unintended electrostatic capacitance, that is, “parasitic capacitance”. Examples of the “parasitic capacitance” include a region that includes different wirings with an insulator therebetween, and gate capacitance generated in a transistor. Unless otherwise specified, description in this specification is made assuming that a “capacitor element” does not include “parasitic capacitance”.

In this specification and the like, a transistor includes three terminals called a gate, a source, and a drain. The gate is a control terminal for controlling a conductive state of the transistor. The two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, the expressions “one of a source and a drain” and “the other of the source and the drain” are used in description of the connection relation of a transistor. In some cases, “one of a source and a drain” is referred to as a “first terminal of a transistor” or a “first electrode of a transistor”, and “the other of the source and the drain” is referred to as a “second terminal of a transistor” or a “second electrode of a transistor”.

Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected in series, which offers a structure in which a plurality of transistors are connected in series. Thus, the multi-gate structure can achieve lower off-state current and higher breakdown voltage (improved reliability) of the transistor. Alternatively, with the multi-gate structure, drain-source current hardly changes even if drain-source voltage changes at the time of operation in a saturation region, so that voltage-current characteristics with a flat slope can be obtained. For example, by utilizing the voltage-current characteristics with a flat slope, an ideal current source circuit, an active load having an extremely high resistance value, and the like can be obtained. As a result, a differential circuit, a current mirror circuit, and the like having excellent properties can be obtained.

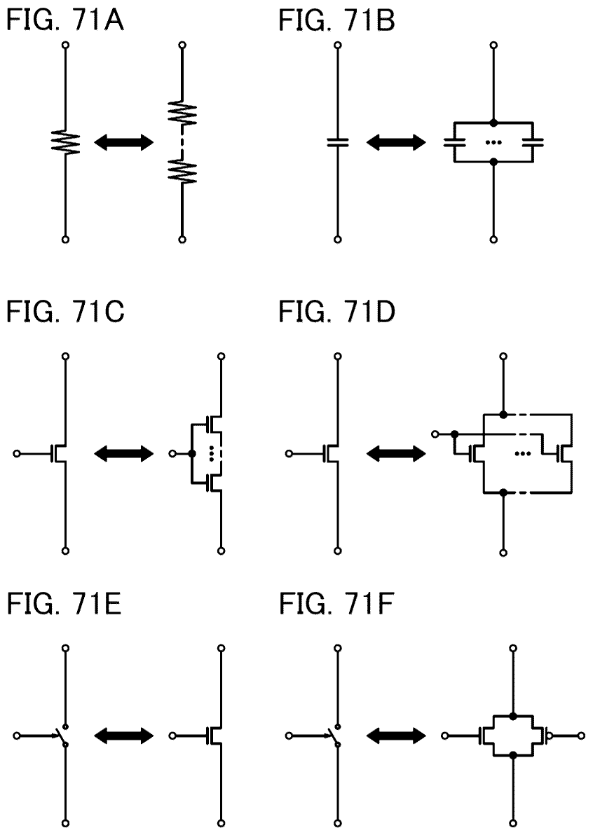

Even in the case where a single circuit element is illustrated in a circuit diagram, the circuit element includes a plurality of circuit elements in some cases. For example, the case where one resistor is illustrated in a circuit diagram includes the case where two or more resistors are directly connected in series. The two or more resistors directly connected in series can be represented as one resistor (see FIG. 71A). For example, the case where one capacitor element is illustrated in a circuit diagram includes the case where two or more capacitor elements are directly connected in parallel. The two or more capacitor elements directly connected in parallel can be represented as one capacitor element (see FIG. 71B). For example, the case where one transistor is illustrated in a circuit diagram includes the case where sources and drains of two or more transistors are directly connected in series and gates of the transistors are directly connected. The two or more transistors whose sources and drains are directly connected in series and gates are directly connected can be represented as one transistor (see FIG. 71C). For example, the case where one transistor is illustrated in a circuit diagram includes the case where first terminals of two or more transistors are directly connected, second terminals of the transistors are directly connected, and gates of the transistors are directly connected. The two or more transistors whose first terminals are directly connected, second terminals are directly connected, and gates are directly connected can be represented as one transistor (see FIG. 71D).

Note that n-channel transistors are illustrated as the transistors in FIG. 71C and FIG. 71D as an example; the same description can be made even when p-channel transistors are used.

In this specification and the like, a switch refers to an element that is brought into a conductive state (on state) or a non-conductive state (off state) and has a function of controlling whether current flows or not. Alternatively, a switch refers to an element having a function of selecting and changing a current path. Thus, a switch may have two terminals or three or more terminals through which current flows, in addition to a control terminal. For example, an electrical switch or a mechanical switch can be used. That is, a switch is not limited to a particular circuit element as long as the switch has a function of controlling current.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case where a transistor is used as a switch, a “conductive state” of the transistor refers to a state where a source and a drain of the transistor can be regarded as being electrically short-circuited or a state where current can be made to flow between the source and the drain. A “non-conductive state” of the transistor refers to a state where a source electrode and a drain electrode of the transistor can be regarded as being electrically disconnected. Note that in the case where a transistor operates just as a switch, there is no particular limitation on the polarity (conductivity type) of the transistor.

In the case where one switch is illustrated in a circuit diagram and the switch is an electrical switch, a structure including one or two or more transistors can be employed (see FIG. 71E). Note that an n-channel transistor is illustrated in FIG. 71E as an example; a p-channel transistor may be used. In particular, in the case where the switch includes two or more transistors, the transistors can be connected in series or in parallel as illustrated in FIG. 71C or FIG. 71D. In the case where the switch includes an analog switch, the analog switch can be represented as having a structure in which a first terminal of an n-channel transistor and a first terminal of a p-channel transistor are directly connected, and a second terminal of the n-channel transistor and a second terminal of the p-channel transistor are directly connected (see FIG. 71F). Note that signals whose logics are inverted from each other are input to gates of the n-channel transistor and the p-channel transistor.

An example of a mechanical switch is a switch formed using a MEMS (micro electro mechanical systems) technology. Such a switch includes an electrode that can be moved mechanically, and operates by controlling conduction and non-conduction with movement of the electrode.

### <Others>

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are different from each other in some cases. Similarly, in the case where two wirings are both described as “functioning as a wiring for supplying a low-level potential”, the levels of the low-level potentials supplied from the wirings are different from each other in some cases.

“Current” means an electric charge transfer phenomenon (electrical conduction); for example, the description “electrical conduction of positively charged particles occurs” can be rephrased as “electrical conduction of negatively charged particles occurs in the opposite direction”. Thus, unless otherwise specified, “current” in this specification and the like refers to an electric charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of current” in a wiring or the like refers to the direction in which a carrier with positive charge moves, and the amount of the current is expressed as a positive value. In other words, the direction in which a carrier with negative charge moves is opposite to the direction of current, and the amount of the current is expressed as a negative value. Thus, in the case where the polarity of current (or the direction of current) is not specified in this specification and the like, the description “current flows from element A to element B” can be rephrased as “current flows from element B to element A”. The description “current is input to element A” can be rephrased as “current is output from element A”.

### Example

Simulation was performed to confirm the operation in the retention circuit described in any of the above embodiments. This example describes the simulation.

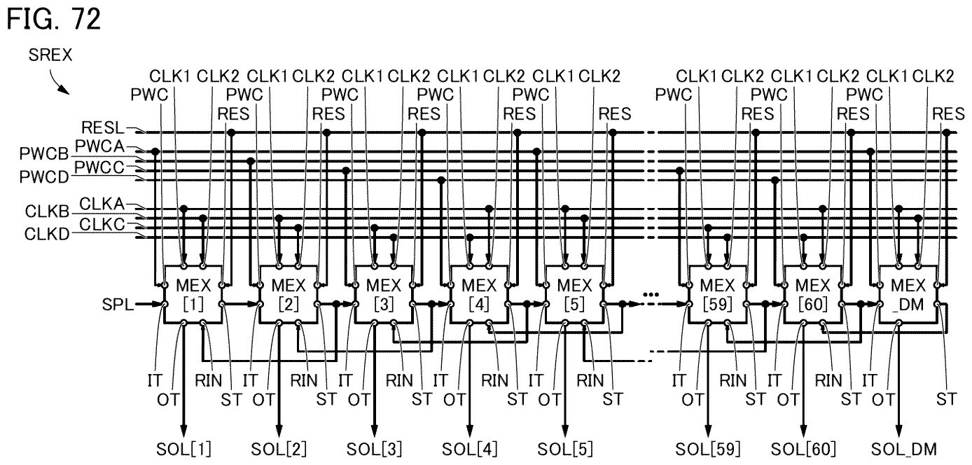

FIG. 72 illustrates a structure of a shift register SREX confirmed by the simulation, which includes a plurality of retention circuits connected. The shift register SREX includes a circuit MEX[1] to a circuit MEX[60], which are retention circuits, and a circuit MEX_DM.

Each of the circuit MEX[1] to the circuit MEX[60] and the circuit MEX_DM includes the terminal IT, the terminal PWC, the terminal CLK1, a terminal CLK2, a terminal RES, a terminal RIN, the terminal OT, and the terminal ST.

The terminal ST of a circuit MEX[i] (i is an integer greater than or equal to 1 and less than or equal to 59) is connected to the terminal IT of a circuit MEX[i+1]. The terminal ST of the circuit MEX[i+1] is connected to the terminal RIN of the circuit MEX[i]. The terminal ST of the circuit MEX[60] is connected to the terminal IT of the circuit MEX_DM. The terminal ST of the circuit MEX_DM is connected to the terminal RIN of the circuit MEX[60].

In a circuit MEX[4k-3](here, k is an integer greater than or equal to 1 and 1≤4k−3≤60 is satisfied), the terminal CLKI1 is connected to the wiring CLKA, the terminal CLK2 is connected to the wiring CLKB, and the terminal PWC is connected to the wiring PWCA. In a circuit MEX[4k-2](here, k is an integer greater than or equal to 1 and 2≤4k−2 n is satisfied), the terminal CLKI1 is connected the wiring CLKB, the terminal CLK2 is connected to the wiring CLKC, and the terminal PWC is connected to the wiring PWCB. In a circuit MEX[4k-1](here, k is an integer greater than or equal to 1 and 3≤4k−1 n is satisfied), the terminal CLKI1 is connected the wiring CLKC, the terminal CLK2 is connected to the wiring CLKD, and the terminal PWC is connected to the wiring PWCC. In a circuit MEX[4k](here, k is an integer greater than or equal to 1 and 4≤4k≤n is satisfied), the terminal CLKI1 is connected the wiring CLKD, the terminal CLK2 is connected to the wiring CLKA, and the terminal PWC is connected to the wiring PWCD. In the circuit MEX_DM, the terminal CLK1 is connected to the wiring CLKA, the terminal CLK2 is connected to the wiring CLKB, and the terminal PWC is connected to the wiring PWCA.

In each of the circuit MEX[1] to the circuit MEX[60] and the circuit MEX_DM, the terminal RES is connected to a wiring RESL.

The terminal IT of the circuit MEX[1] is connected to a wiring SPL. The terminal OT of the circuit MEX[i](here, i is an integer greater than or equal to 1 and less than or equal to 60) is connected to a wiring SOL[i]. The terminal OT of the circuit MEX_DM is connected to a wiring SOL_DM.

The shift register SREX illustrated in FIG. 72, which includes the circuit MEX[1] to the circuit MEX[60], has a 60-stage structure. The circuit MEX_DM is provided as a circuit for transmitting a signal to the terminal RIN of the circuit MEX[60].

In the shift register SREX in FIG. 72, information corresponding to a signal input from the wiring SPL to the terminal IT of the circuit MEX[1] is sequentially retained in the circuit MEX[1] to the circuit MEX[60] and the circuit MEX_DM by pulse signals transmitted to the wiring PWCA to the wiring PWCD. By pulse signals transmitted to the wiring CLKA to the wiring CLKD, potentials corresponding to the information retained in the circuit MEX[1] to the circuit MEX[60] are sequentially output to a wiring SOL[1] to a wiring SOL[60] and the wiring SOL_DM.

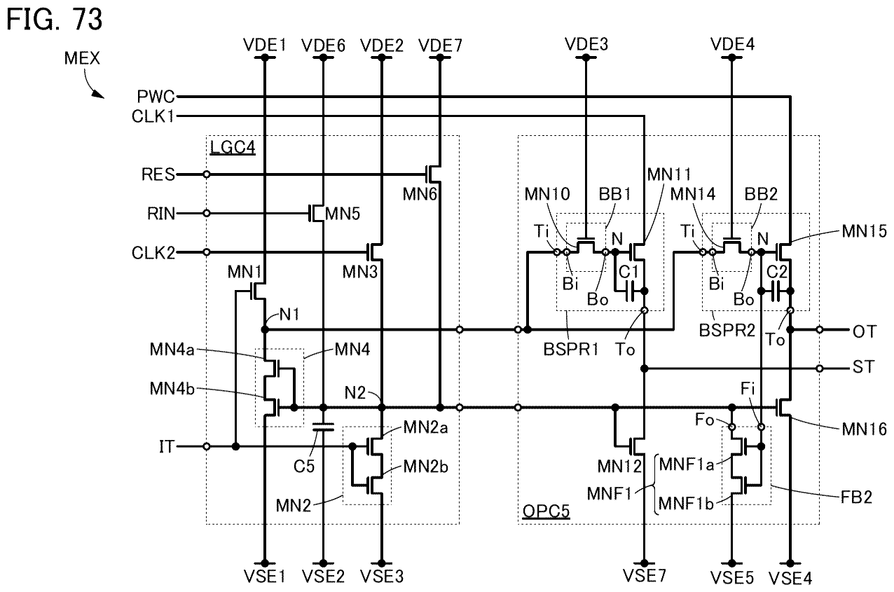

Next, circuit structures of the circuit MEX[1] to the circuit MEX[60] and the circuit MEX_DM are described. The circuit MEX illustrated in FIG. 73 is a circuit diagram illustrating the circuit structure of each of the circuit MEX[1] to the circuit MEX[60] and the circuit MEX_DM.

The circuit MEX includes the circuit LGC4 and the circuit OPC5. The circuit LGC4 includes the transistor MN1 to a transistor MN6 and the capacitor element C5. The circuit OPC5 includes the transistor MN10 to the transistor MN12, the transistor MN14 to the transistor MN16, the transistor MNF1, the capacitor element C1, and the capacitor element C2.

Note that the transistor MN10, the transistor MN11, and the capacitor element C1 are included in the circuit BSPR1, and the circuit BSPR1 corresponds to the circuit BSPR illustrated in FIG. 8A. Similarly, the transistor MN14, the transistor MN15, and the capacitor element C2 are included in the circuit BSPR2, and the circuit BSPR2 corresponds to the circuit BSPR illustrated in FIG. 8A. The transistor MN10 is included in the circuit BB1, and the circuit BB1 corresponds to the circuit BB illustrated in FIG. 8A. Similarly, the transistor MN14 is included in the circuit BB2, and the circuit BB2 corresponds to the circuit BB illustrated in FIG. 8A.

The transistor MNF1 is included in the circuit FB2, and the circuit FB2 corresponds to the circuit FB illustrated in FIG. 10.

The transistor MN2 has a multi-gate structure in which a source and a drain of two transistors are connected and gates thereof are connected to each other. In FIG. 73, the transistor MN2 has a structure including a transistor MN2a and a transistor MN2b. Similarly, the transistor MN4 and the transistor MNF1 each have a multi-gate structure in which a source and a drain of two transistors are connected and gates thereof are connected to each other; the transistor MN4 has a structure including a transistor MN4a and a transistor MN4b, and the transistor MNF1 has a structure including a transistor MNF1a and a transistor MNF1b.

The terminal IT is connected to the gate of the transistor MN1, a gate of the transistor MN2a, and a gate of the transistor MN2b. The terminal CLK2 is connected to the gate of the transistor MN3. The terminal RIN is connected to a transistor MN5. The terminal RES is connected to the transistor MN6.

The first terminal of the transistor MN1 is connected to the wiring VDE1, and the second terminal of the transistor MN1 is connected to a first terminal of the transistor MN4a, a first terminal of the transistor MP10, and a first terminal of the transistor MP14. A second terminal of the transistor MN4a is connected to a first terminal of the transistor MN4b, and a second terminal of the transistor MN4b is connected to the wiring VSE1.

The first terminal of the transistor MN3 is connected to the wiring VDE2, a first terminal of the transistor MN5 is connected to a wiring VDE6, and a first terminal of the transistor MN6 is connected to a wiring VDE7. The second terminal of the transistor MN3 is connected to a second terminal of the transistor MN5, a second terminal of the transistor MN6, a gate of the transistor MN4a, a gate of the transistor MN4b, a first terminal of the transistor MN2a, a gate of the transistor MN12, a gate of the transistor MNN16, a first terminal of the transistor MNF1a, and the first terminal of the capacitor element C5. The second terminal of the capacitor element C5 is connected to the wiring VSE2. A second terminal of the transistor MN2a is connected to a first terminal of the transistor MN2b, and a second terminal of the transistor MN2b is connected to the wiring VSE3. A second terminal of the transistor MNF1 a is connected to a first terminal of the transistor MNF1b, and a second terminal of the transistor MNF1b is connected to the wiring VSE5.

The terminal CLKI1 is connected to the first terminal of the transistor MN11. A gate of the transistor MN10 is connected to the wiring VDE3, and a second terminal of the transistor MN10 is connected to the gate of the transistor MN11 and the first terminal of the capacitor element C1. The second terminal of the transistor MN11 is connected to the first terminal of the transistor MN12 and the terminal ST. The second terminal of the transistor MN12 is connected to the wiring VSE7.

The terminal PWC is connected to the first terminal of the transistor MN15. The gate of the transistor MN14 is connected to the wiring VDE4, and the second terminal of the transistor MN14 is connected to the gate of the transistor MN15, a gate of the transistor MNFla, a gate of the transistor MNF1b, and the first terminal of the capacitor element C2. The second terminal of the transistor MN15 is connected to the first terminal of the transistor IMN16 and the terminal OT. The second terminal of the transistor MN12 is connected to the wiring VSE7. The second terminal of the transistor MN16 is connected to the wiring VSE4.

Each of the wiring VDE1 to the wiring VDE4, the wiring VDE6, and the wiring VDE7 is a power supply line that supplies 10 V as a high-level potential. Each of the wiring VSE1 to the wiring VSE5 and the wiring VSE7 is a power supply line that supplies −2.5 V as a low-level potential.

The transistor MN1 to the transistor MN6, the transistor MN10 to the transistor MN12, the transistor MN14 to the transistor MN16, and the transistor MNF1 are vertical-channel-type transistors described in Embodiment 5.

The electrostatic capacitance value of the capacitor element C1 is 0.12 pF, the electrostatic capacitance value of the capacitor element C2 is 0.33 pF, and the electrostatic capacitance value of the capacitor element C5 is 0.70 pF.

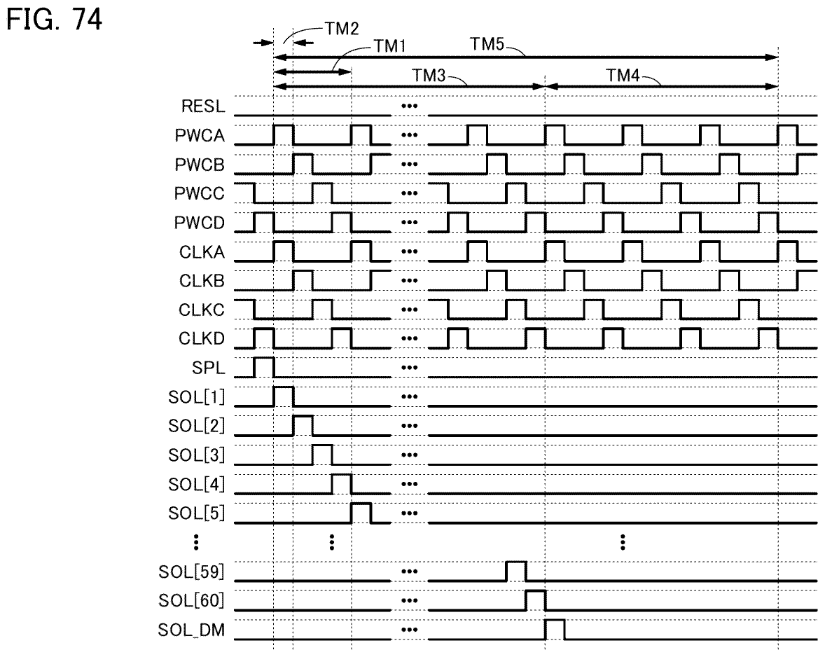

FIG. 74 is a timing chart illustrating an operation of a shift register SREX. Specifically, FIG. 74 shows changes in the potentials of the wiring RESL, the wiring PWCA, the wiring PWCB, the wiring PWCC, the wiring PWCD, the wiring CLKA, the wiring CLKB, the wiring CLKC, the wiring CLKD, the wiring SPL, the wiring SOL[1] to the wiring SOL[5], the wiring SOL[59], the wiring SOL[60], and the wiring SOL_DM.

Note that the changes in the potentials of the wiring SOL[1] to the wiring SOL[60] and the wiring SOL_DM shown in FIG. 74 are not the simulation results but ideal potential changes.

Note that a pulse signal is transmitted to each of the wiring CLKA to the wiring CLKD and the wiring PWCA to the wiring PWCD at a cycle TM1, and a period (pulse width) of TM1 during which a high-level potential is input is especially referred to as TM2 (=0.25×TM1). Hereinafter, the inverse of twice the pulse width TM2 of the pulse signal is referred to as a sampling frequency. A period from the time when the high-level potential is output from the wiring SOL[1] to the time when the high-level potential is output from the wiring SOL[60] is referred to as TM3 (=15×TM1). In addition, a blank period is set to TM4 (=3×TM1), and one horizontal period (cycle of horizontal scan line) is set to TM5 (TM3+TM4).

Next, a pulse signal output from the terminal OT of the circuit MEX[60] when a pulse signal having the pulse width TM2 with a voltage of 12.5 V (a low-level potential of −2.5 V and a high-level potential of 10 V) is transmitted to the wiring SPL was calculated by simulation. The sampling frequency of the pulse signal at this time was set to five conditions: 5.56 MHz, 0.556 MHz, 55.6 kHz, 5.56 kHz, and 0.556 kHz.

Note that when the sampling frequency is set to 5.56 MHz, TM1 is 360 ns and TM2 is 90 ns in the timing chart in FIG. 74. When the sampling frequency is set to 0.556 MHz, TM1 is 3.60 s and TM2 is 0.90 s in the timing chart in FIG. 74. When the sampling frequency is set to 55.6 kHz, TM1 is 36.0 s and TM2 is 9.0 s in the timing chartin FIG. 74. When the sampling frequency is set to 5.56 kHz, TM1 is 360 s and TM2 is 90 s in the timing chart in FIG. 74. When the sampling frequency is set to 0.556 kHz, TM1 is 3.60 ms and TM2 is 0.90 ms in the timing chart in FIG. 74.

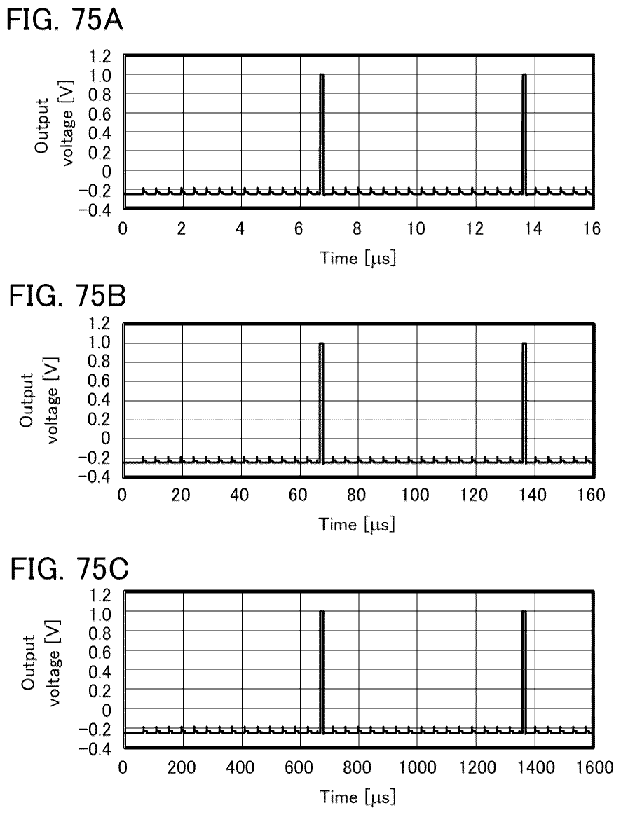

FIG. 75A is a graph showing the waveform of a pulse signal output from the terminal OT of the circuit MEX[60] when a pulse signal having a sampling frequency of 5.56 MHz, i.e., a pulse width TM2 of 90 ns, is transmitted to the wiring SPL at a cycle of 6.9 s. Specifically, in FIG. 75A, the horizontal axis represents time [s] and the vertical axis represents the voltage [V] of the pulse signal output from the terminal OT of the circuit MEX[60]. FIG. 75A confirms that the pulse width TM2 of the pulse signal output from the terminal OT of the circuit MEX[60] is approximately 90 ns.

FIG. 75B is a graph showing the waveform of a pulse signal output from the terminal OT of the circuit MEX[60] when a pulse signal having a sampling frequency of 0.556 MHz, i.e., a pulse width TM2 of 0.90 s, is transmitted to the wiring SPL at a cycle of 69 s. Specifically, in FIG. 75B, the horizontal axis represents time [s] and the vertical axis represents the voltage [V] of the pulse signal output from the terminal OT of the circuit MEX[60]. FIG. 75B confirms that the pulse width TM2 of the pulse signal output from the terminal OT of the circuit MEX[60] is approximately 0.90 s.

FIG. 75C is a graph showing the waveform of a pulse signal output from the terminal OT of the circuit MEX[60] when a pulse signal having a sampling frequency of 55.6 kHz, i.e., a pulse width TM2 of 9.0 s, is transmitted to the wiring SPL at a cycle of 0.69 ms. Specifically, in FIG. 75C, the horizontal axis represents time [s] and the vertical axis represents the voltage [V] of the pulse signal output from the terminal OT of the circuit MEX[60]. FIG. 75C confirms that the pulse width TM2 of the pulse signal output from the terminal OT of the circuit MEX[60] is approximately 9.0 s.

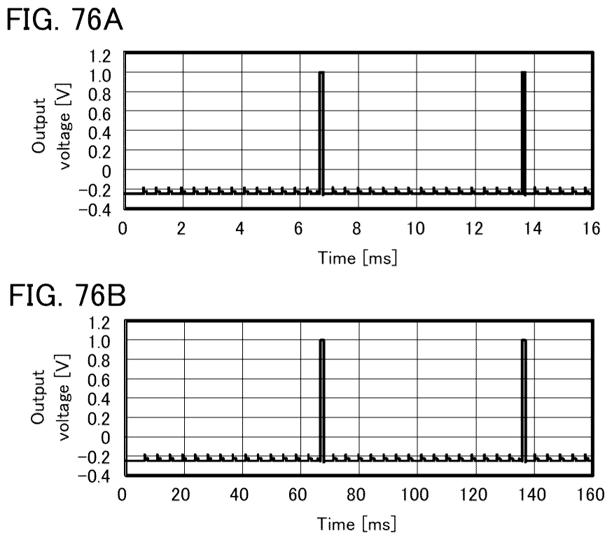

FIG. 76A is a graph showing the waveform of a pulse signal output from the terminal OT of the circuit MEX[60] when a pulse signal having a sampling frequency of 5.56 kHz, i.e., a pulse width TM2 of 90 s, is transmitted to the wiring SPL at a cycle of 6.9 ms. Specifically, in FIG. 76A, the horizontal axis represents time [ms] and the vertical axis represents the voltage [V] of the pulse signal output from the terminal OT of the circuit MEX[60]. FIG. 76A confirms that the pulse width TM2 of the pulse signal output from the terminal OT of the circuit MEX[60] is approximately 90 s.

FIG. 76B is a graph showing the waveform of a pulse signal output from the terminal OT of the circuit MEX[60] when a pulse signal having a sampling frequency of 0.556 kHz, i.e., a pulse width TM2 of 0.90 ms, is transmitted to the wiring SPL at a cycle of 69 ms. Specifically, in FIG. 76B, the horizontal axis represents time [ms] and the vertical axis represents the voltage [V] of the pulse signal output from the terminal OT of the circuit MEX[60]. FIG. 76B confirms that the pulse width TM2 of the pulse signal output from the terminal OT of the circuit MEX[60] is approximately 0.90 ms.

The results shown in FIG. 75A to FIG. 75C, FIG. 76A, and FIG. 76B confirm that the shift register SREX illustrated in FIG. 72 outputs a normal waveform from the terminal OT of its last stage, the circuit MEX[60]. The result in FIG. 76B also confirms that the shift register SREX illustrated in FIG. 72 is capable of performing low-speed operation with a sampling frequency of 0.556 kHz.

### REFERENCE NUMERALS

MDV: circuit, LGC: circuit, LGC1: circuit, LGC2: circuit, LGC3: circuit, LGC4: circuit, OPC1: circuit, OPC1A: circuit, OPC1B: circuit, OPC1C: circuit, OPC2: circuit, OPC3: circuit, OPC4A: circuit, OPC5: circuit, OPC6: circuit, OPC7: circuit, OPC8: circuit, OPC9: circuit, OPC10: circuit, BSPR: circuit, BSPR1: circuit, BSPR2: circuit, BSPRi: circuit, BB: circuit, BB1: circuit, BB2: circuit, BBi: circuit, BG: circuit, FB: circuit, FB1: circuit, FB2: circuit, FH: circuit, BUF: circuit, BUFH: circuit, SR: circuit, LAT: circuit, DAC: circuit, INV1: logic circuit, INV2: logic circuit, VDE: wiring, VDE1: wiring, VDE2: wiring, VDE3: wiring, VDE4: wiring, VDE5: wiring, VDE11: wiring, VDE12: wiring, VDE13: wiring, VDE14: wiring, VDE15: wiring, VDE17: wiring, VDE21: wiring, VDE22: wiring, VDE31: wiring, VDE32: wiring, VSE: wiring, VSE1: wiring, VSE2: wiring, VSE3: wiring, VSE4: wiring, VSE5: wiring, VSE6: wiring, VSE7: wiring, VSE11: wiring, VSE12: wiring, VSE13: wiring, VSE14: wiring, VSE21: wiring, VSE22: wiring, VSE23: wiring, VSE24: wiring, VSE25: wiring, VSE32: wiring, VAL1: wiring, VAL2: wiring, RST: wiring, IT: terminal, ITA: terminal, ITB: terminal, CLK: terminal, CLK1: terminal, CLK2: terminal, CLK3: terminal, OT: terminal, OTA: terminal, OTB: terminal, ST: terminal, RT: terminal, RES: terminal, PWC: terminal, LIT: terminal, LI2: terminal, LI3: terminal, LI4: terminal, LOT: terminal, L02: terminal, TMi: terminal, TMi1: terminal, TMi2: terminal, TMi3: terminal, TMi4: terminal, TMo: terminal, TMo1: terminal, TMo2: terminal, Ti: terminal, To: terminal, Bi: terminal, Bo: terminal, Fi: terminal, Fo: terminal, Gi: terminal, Go: terminal, Hi: terminal, Ho: terminal, BFi: terminal, BFo: terminal, BFHi: terminal, BFHo: terminal, RIN: terminal, MN: transistor, MN1: transistor, MN2: transistor, MN3: transistor, MN4: transistor, MN10: transistor, MN11: transistor, MN12: transistor, MN14: transistor, MN15: transistor, MN16: transistor, MN17: transistor, MN18: transistor, MN21: transistor, MN22: transistor, MN23: transistor, MN24: transistor, MN25: transistor, MN26: transistor, MN31: transistor, MN32: transistor, MN33: transistor, MN34: transistor, MN41: transistor, MN42: transistor, MN43: transistor, MN44: transistor, MN45: transistor, MN46: transistor, MNa: transistor, MNb: transistor, MNd: transistor, MNe: transistor, MNf: transistor, MNx: transistor, MNy: transistor, MNF1: transistor, MPT: transistor, MP2: transistor, MP3: transistor, MP4: transistor, MP10: transistor, MP11: transistor, MP12: transistor, MP14: transistor, MP15: transistor, MP16: transistor, MPF1: transistor, M1: transistor, M2: transistor, M3: transistor, M4: transistor, M5: transistor, M6: transistor, M7: transistor, CT: capacitor element, C2: capacitor element, C5: capacitor element, C25: capacitor element, C35: capacitor element, C36: capacitor element, C45: capacitor element, C46: capacitor element, Ca: capacitor element, N: node, N1: node, N2: node, Nf: node, GEM: conductive layer, SDMT: conductive layer, SDMB: conductive layer, SMC: semiconductor layer, SMCB: semiconductor layer, CT1: region, CT2: region, CT4: region, CT5: region, CT6: region, CT7: region, CT10: region, CT11: region, CT12: region, CT13: region, CT14: region, CT15: region, CT16: region, CT17: region, CT18: region, CT19: region, DSP: display apparatus, PA: pixel array, TA: sensor array, GD: driver circuit, SD: driver circuit, TDE: driver circuit, TDR: driver circuit, PX: pixel circuit, PX[1, 1]: pixel circuit, PX[m, 1]: pixel circuit, PX[1, n]: pixel circuit, PX[m, n]: pixel circuit, TX[1, 1]: sensor, TX[p, 1]: sensor, TX[1, q]: sensor, TX[p, q]: sensor, BF[1]: circuit, BF[2]: circuit, BF[3]: circuit, BF[4]: circuit, BF[5]: circuit, BF[6]: circuit, GLS[1]: wiring, GLS[m]: wiring, GL[1]: wiring, GL[2]: wiring, GL[3]: wiring, GL[4]: wiring, GL[5]: wiring, GL[6]: wiring, SLS[1]: wiring, SLS[n]: wiring, SL[1]: wiring, SL[2]: wiring, SL[3]: wiring, SL[4]: wiring, SL[5]: wiring, SL[6]: wiring, SOL[1]: wiring, SOL[2]: wiring, SOL[3]: wiring, SOL[4]: wiring, SOL[5]: wiring, SOL[6]: wiring, SOL[60]: wiring, SPL: wiring, TLS[1]: wiring, TLS[p]: wiring, DLS[1]: wiring, DLS[q]: wiring, CLKA: wiring, CLKB: wiring, CLKC: wiring, CLKD: wiring, PWCA: wiring, PWCB: wiring, PWCC: wiring, PWCD: wiring, BG1: wiring, BG2: wiring, BG3: wiring, VDL: wiring, SPR: wiring, SS: signal, DSP1: display apparatus, DSP1A: display apparatus, DSP2: display apparatus, DSP2A: display apparatus, DSP3: display apparatus, DSP3A: display apparatus, DIS: display region, TP: sensor region, SIC: circuit region, DRV: driver circuit region, MFNC: functional circuit region, TMR: terminal region, BS: substrate, GD1: driver circuit, GD2: driver circuit, DAD: digital-to-analog converter circuit, LVS: level shifter, MEM: memory device, TMC: timing controller, ECR: EL correction circuit, SCC: sensor controller, EPS: power supply circuit, PDA: sensor, SNCL: wiring, IS1: insulating layer, IS2: insulating layer, IS3: insulating layer, ME1: conductive layer, ME2: conductive layer, ME3: conductive layer, GI1: insulating layer, SC1: semiconductor layer, KK1: opening, MPG: conductive layer, BL[1]: wiring, BL[n]: wiring, WL[1]: wiring, WL[m]: wiring, CE: signal, ADDR: signal, GW: signal, WAKE: signal, WDA: signal, CLCK: signal, RDA: signal, BW: signal, 21: CPU, 22: GPU, 22a: circuit, 22b: circuit, 60_1: memory layer, 60_2: memory layer, 603: memory layer, 60_k: memory layer, 60_N: memory layer, 100A1: circuit, 100A11: circuit, 100A12: circuit, 100A13: circuit, 100A2: circuit, 100A[1]: circuit, 100A[2]: circuit, 100A[3]: circuit, 100A[4]: circuit, 100A[5]: circuit, 100A[6]: circuit, 100B: circuit, 100B1: circuit, 1001B11: circuit, 100B[1]: circuit, 100B[2]: circuit, 100B[3]: circuit, 100B[4]: circuit, 100B[5]: circuit, 100B[6]: circuit, 103: insulating layer, 104: conductive layer, 105: insulating layer, 106: conductive layer, 107: adhesive layer, 110: substrate, 111a: conductive layer, 111b: conductive layer, 111c: conductive layer, 112a: conductive layer, 112b: conductive layer, 112c: conductive layer, 113a: first layer, 113b: second layer, 113c: third layer, 114: common layer, 115: common electrode, 116: protective layer, 117a: conductive layer, 117b: conductive layer, 118a: mask layer, 125: insulating layer, 126a: conductive layer, 126b: conductive layer, 126c: conductive layer, 127: insulating layer, 128: layer, 129a: conductive layer, 129b: conductive layer, 129c: conductive layer, 130R: light-emitting device, 130G: light-emitting device, 130B: light-emitting device, 131: protective layer, 147: resin layer, 148: resin layer, 171: substrate, 175: adhesive layer, 181: substrate, 181R: substrate, 181G: substrate, 181B: substrate, 182: semiconductor layer, 185: semiconductor layer, 200: memory device, 300d: transistor, 310: substrate, 312: element isolation layer, 313: semiconductor region, 314a: low-resistance region, 314b: low-resistance region, 315: insulating layer, 316: conductive layer, 317: insulating layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 500x: transistor, 512: insulating layer, 514: insulating layer, 574: insulating layer, 581: insulating layer, 592: insulating layer, 594: insulating layer, 596: conductive layer, 598: insulating layer, 599: insulating layer, 610: substrate, 631: conductive layer, 632: insulating layer, 633: insulating layer, 641: insulating layer, 716: memory layer, 1000: display apparatus, 1280: display module, 1281: display portion, 1282: circuit portion, 1283a: pixel circuit, 1284: pixel portion, 1284a: pixel, 1285: terminal portion, 1290: FPC, 1291: substrate, 1292: substrate, 1430a: light-emitting device, 1430b: light-emitting device, 1430c: light-emitting device, 5200: portable game machine, 5201: housing, 5202: display portion, 5203: button, 5300: laptop information terminal, 5330a: housing, 5330b: housing, 5331: display portion, 5350: keyboard portion, 5500: information terminal, 5510: housing, 5511: display portion, 5623: connection terminal, 5624: connection terminal, 5625: connection terminal, 5629: connection terminal, 5701: display panel, 5702: display panel, 5703: display panel, 5704: display panel, 5900: information terminal, 5901: housing, 5902: display portion, 5903: operation button, 5904: crown, 5905: band, 6200: digital signage, 6201: wall, 6500: electronic device, 6501: housing, 6502: display portion, 6504: button, 6505: speaker, 6507: camera, 6600: electronic device, 6611: housing, 6615: display portion, 7003md: memory device, 8000: camera, 8001: housing, 8002: display portion, 8003: operation button, 8004: shutter button, 8006: lens, 8100: finder, 8101: housing, 8102: display portion, 8103: button, 8300: electronic device, 8301: housing, 8302: display portion, 8304: fixing member, 8304a: fixing member, 8305: lens, 9000: television device, 9001: display portion, 9002: housing, 9003: speaker, 9005: operation key, 9006: connection terminal, 9007: sensor

1. A semiconductor device comprising:
a first transistor, a second transistor, a third transistor, a fourth transistor, a fifth transistor, a sixth transistor, a seventh transistor, an eighth transistor, a first capacitor element, and a second capacitor element,
wherein a gate of the first transistor is electrically connected to a gate of the second transistor,
wherein one of a source and a drain of the first transistor is electrically connected to one of a source and a drain of the fourth transistor and one of a source and a drain of the fifth transistor,
wherein one of a source and a drain of the third transistor is electrically connected to one of a source and a drain of the second transistor, a gate of the fourth transistor, a first terminal of the first capacitor element, a gate of the seventh transistor, and one of a source and a drain of the eighth transistor,
wherein the other of the source and the drain of the fifth transistor is electrically connected to a gate of the sixth transistor and a first terminal of the second capacitor element, and
wherein one of a source and a drain of the sixth transistor is electrically connected to a second terminal of the second capacitor element, one of a source and a drain of the seventh transistor, and a gate of the eighth transistor.

2. A semiconductor device comprising:
a first transistor, a second transistor, a third transistor, a fourth transistor, a fifth transistor, a sixth transistor, a seventh transistor, an eighth transistor, a first capacitor element, and a second capacitor element,
wherein a gate of the first transistor is electrically connected to a gate of the second transistor,
wherein one of a source and a drain of the first transistor is electrically connected to one of a source and a drain of the fourth transistor and one of a source and a drain of the fifth transistor,
wherein one of a source and a drain of the third transistor is electrically connected to one of a source and a drain of the second transistor, a gate of the fourth transistor, a first terminal of the first capacitor element, a gate of the seventh transistor, and one of a source and a drain of the eighth transistor,
wherein the other of the source and the drain of the fifth transistor is electrically connected to a gate of the sixth transistor, a first terminal of the second capacitor element, and a gate of the eighth transistor, and
wherein one of a source and a drain of the sixth transistor is electrically connected to a second terminal of the second capacitor element and one of a source and a drain of the seventh transistor.

3. A semiconductor device comprising:
a first transistor, a second transistor, a third transistor, a fourth transistor, a fifth transistor, a sixth transistor, a seventh transistor, an eighth transistor, a first capacitor element, and a second capacitor element,
wherein a gate of the first transistor is electrically connected to a gate of the second transistor,
wherein one of a source and a drain of the first transistor is electrically connected to one of a source and a drain of the fourth transistor, one of a source and a drain of the fifth transistor, and a gate of the eighth transistor,
wherein one of a source and a drain of the third transistor is electrically connected to one of a source and a drain of the second transistor, a gate of the fourth transistor, a first terminal of the first capacitor element, a gate of the seventh transistor, and one of a source and a drain of the eighth transistor,
wherein the other of the source and the drain of the fifth transistor is electrically connected to a gate of the sixth transistor and a first terminal of the second capacitor element, and
wherein one of a source and a drain of the sixth transistor is electrically connected to a second terminal of the second capacitor element and one of a source and a drain of the seventh transistor.

4. The semiconductor device according to claim 1, further comprising:
a ninth transistor, a tenth transistor, an eleventh transistor, and a third capacitor element,
wherein one of a source and a drain of the ninth transistor is electrically connected to the one of the source and the drain of the first transistor, the one of the source and the drain of the fourth transistor, and the one of the source and the drain of the fifth transistor,
wherein the other of the source and the drain of the ninth transistor is electrically connected to a gate of the tenth transistor and a first terminal of the third capacitor element,
wherein one of a source and a drain of the tenth transistor is electrically connected to a second terminal of the third capacitor element and one of a source and a drain of the eleventh transistor, and
wherein a gate of the eleventh transistor is electrically connected to the one of the source and the drain of the third transistor, the one of the source and the drain of the second transistor, the gate of the fourth transistor, the first terminal of the first capacitor element, and the gate of the seventh transistor.

5. The semiconductor device according to claim 4,
wherein each of the first transistor, the second transistor, the third transistor, the fourth transistor, the fifth transistor, the sixth transistor, the seventh transistor, the eighth transistor, the ninth transistor, the tenth transistor, and the eleventh transistor is a vertical-channel-type transistor,
wherein the vertical-channel-type transistor comprises one or more selected from indium, zinc, and an element Min a channel formation region, and
wherein the element Mis one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

6. The semiconductor device according to claim 4, comprising:
a driver circuit comprising a first circuit and a second circuit,
wherein the first circuit and the second circuit each comprises the first transistor, the second transistor, the third transistor, the fourth transistor, the fifth transistor, the sixth transistor, the seventh transistor, the eighth transistor, the ninth transistor, the tenth transistor, the eleventh transistor, the first capacitor element, the second capacitor element, the third capacitor element, an input terminal, and a first output terminal,
wherein the first output terminal is electrically connected to the one of the source and the drain of the tenth transistor,
wherein the input terminal is electrically connected to the gate of the first transistor, and
wherein the first output terminal of the first circuit is electrically connected to the input terminal of the second circuit.

7. The semiconductor device according to claim 1, comprising:
a driver circuit and a pixel circuit,
wherein the driver circuit comprises the first transistor, the second transistor, the third transistor, the fourth transistor, the fifth transistor, the sixth transistor, the seventh transistor, the eighth transistor, the first capacitor element, the second capacitor element, and a second output terminal,
wherein the second output terminal is electrically connected to the one of the source and the drain of the sixth transistor, and
wherein the driver circuit is configured to transmit a signal output from the second output terminal to the pixel circuit.

8. The semiconductor device according to claim 1, comprising:
a driver circuit, a pixel circuit, and a sensor portion,
wherein the driver circuit comprises the first transistor, the second transistor, the third transistor, the fourth transistor, the fifth transistor, the sixth transistor, the seventh transistor, the eighth transistor, the first capacitor element, the second capacitor element, and a second output terminal,
wherein the second output terminal is electrically connected to the one of the source and the drain of the sixth transistor,
wherein the driver circuit is configured to transmit a signal output from the second output terminal to the sensor portion, and
wherein the sensor portion comprises a region overlapping with the pixel circuit.

9. The semiconductor device according to claim 2, further comprising:
a ninth transistor, a tenth transistor, an eleventh transistor, and a third capacitor element,
wherein one of a source and a drain of the ninth transistor is electrically connected to the one of the source and the drain of the first transistor, the one of the source and the drain of the fourth transistor, and the one of the source and the drain of the fifth transistor,
wherein the other of the source and the drain of the ninth transistor is electrically connected to a gate of the tenth transistor and a first terminal of the third capacitor element,
wherein one of a source and a drain of the tenth transistor is electrically connected to a second terminal of the third capacitor element and one of a source and a drain of the eleventh transistor, and
wherein a gate of the eleventh transistor is electrically connected to the one of the source and the drain of the third transistor, the one of the source and the drain of the second transistor, the gate of the fourth transistor, the first terminal of the first capacitor element, and the gate of the seventh transistor.

10. The semiconductor device according to claim 9,
wherein each of the first transistor, the second transistor, the third transistor, the fourth transistor, the fifth transistor, the sixth transistor, the seventh transistor, the eighth transistor, the ninth transistor, the tenth transistor, and the eleventh transistor is a vertical-channel-type transistor,
wherein the vertical-channel-type transistor comprises one or more selected from indium, zinc, and an element Min a channel formation region, and
wherein the element Mis one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

11. The semiconductor device according to claim 9, comprising:
a driver circuit comprising a first circuit and a second circuit,
wherein the first circuit and the second circuit each comprises the first transistor, the second transistor, the third transistor, the fourth transistor, the fifth transistor, the sixth transistor, the seventh transistor, the eighth transistor, the ninth transistor, the tenth transistor, the eleventh transistor, the first capacitor element, the second capacitor element, the third capacitor element, an input terminal, and a first output terminal,
wherein the first output terminal is electrically connected to the one of the source and the drain of the tenth transistor,
wherein the input terminal is electrically connected to the gate of the first transistor, and
wherein the first output terminal of the first circuit is electrically connected to the input terminal of the second circuit.

12. The semiconductor device according to claim 2, comprising:
a driver circuit and a pixel circuit,
wherein the driver circuit comprises the first transistor, the second transistor, the third transistor, the fourth transistor, the fifth transistor, the sixth transistor, the seventh transistor, the eighth transistor, the first capacitor element, the second capacitor element, and a second output terminal,
wherein the second output terminal is electrically connected to the one of the source and the drain of the sixth transistor, and
wherein the driver circuit is configured to transmit a signal output from the second output terminal to the pixel circuit.

13. The semiconductor device according to claim 2, comprising:
a driver circuit, a pixel circuit, and a sensor portion,
wherein the driver circuit comprises the first transistor, the second transistor, the third transistor, the fourth transistor, the fifth transistor, the sixth transistor, the seventh transistor, the eighth transistor, the first capacitor element, the second capacitor element, and a second output terminal,
wherein the second output terminal is electrically connected to the one of the source and the drain of the sixth transistor,
wherein the driver circuit is configured to transmit a signal output from the second output terminal to the sensor portion, and
wherein the sensor portion comprises a region overlapping with the pixel circuit.

14. The semiconductor device according to claim 3, further comprising:
a ninth transistor, a tenth transistor, an eleventh transistor, and a third capacitor element,
wherein one of a source and a drain of the ninth transistor is electrically connected to the one of the source and the drain of the first transistor, the one of the source and the drain of the fourth transistor, and the one of the source and the drain of the fifth transistor,
wherein the other of the source and the drain of the ninth transistor is electrically connected to a gate of the tenth transistor and a first terminal of the third capacitor element,
wherein one of a source and a drain of the tenth transistor is electrically connected to a second terminal of the third capacitor element and one of a source and a drain of the eleventh transistor, and
wherein a gate of the eleventh transistor is electrically connected to the one of the source and the drain of the third transistor, the one of the source and the drain of the second transistor, the gate of the fourth transistor, the first terminal of the first capacitor element, and the gate of the seventh transistor.

15. The semiconductor device according to claim 14,
wherein each of the first transistor, the second transistor, the third transistor, the fourth transistor, the fifth transistor, the sixth transistor, the seventh transistor, the eighth transistor, the ninth transistor, the tenth transistor, and the eleventh transistor is a vertical-channel-type transistor,
wherein the vertical-channel-type transistor comprises one or more selected from indium, zinc, and an element Min a channel formation region, and
wherein the element Mis one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

16. The semiconductor device according to claim 14, comprising:
a driver circuit comprising a first circuit and a second circuit,
wherein the first circuit and the second circuit each comprises the first transistor, the second transistor, the third transistor, the fourth transistor, the fifth transistor, the sixth transistor, the seventh transistor, the eighth transistor, the ninth transistor, the tenth transistor, the eleventh transistor, the first capacitor element, the second capacitor element, the third capacitor element, an input terminal, and a first output terminal,
wherein the first output terminal is electrically connected to the one of the source and the drain of the tenth transistor,
wherein the input terminal is electrically connected to the gate of the first transistor, and
wherein the first output terminal of the first circuit is electrically connected to the input terminal of the second circuit.

17. The semiconductor device according to claim 3, comprising:
a driver circuit and a pixel circuit,
wherein the driver circuit comprises the first transistor, the second transistor, the third transistor, the fourth transistor, the fifth transistor, the sixth transistor, the seventh transistor, the eighth transistor, the first capacitor element, the second capacitor element, and a second output terminal,
wherein the second output terminal is electrically connected to the one of the source and the drain of the sixth transistor, and
wherein the driver circuit is configured to transmit a signal output from the second output terminal to the pixel circuit.

18. The semiconductor device according to claim 3, comprising:
a driver circuit, a pixel circuit, and a sensor portion,
wherein the driver circuit comprises the first transistor, the second transistor, the third transistor, the fourth transistor, the fifth transistor, the sixth transistor, the seventh transistor, the eighth transistor, the first capacitor element, the second capacitor element, and a second output terminal,
wherein the second output terminal is electrically connected to the one of the source and the drain of the sixth transistor,
wherein the driver circuit is configured to transmit a signal output from the second output terminal to the sensor portion, and
wherein the sensor portion comprises a region overlapping with the pixel circuit.
